(19) United States
(12) Patent Application Publication
(10) Pub. No.: US 2024/0228523 A1
(43) Pub. Date: Jul. 11, 2024

(54) Metal complexes

(71) Applicant: UDC IRELAND LIMITED, Dublin (IE)

(72) Inventors: Anna Hayer, Darmstadt (DE); Rouven Linge, Darmstadt (DE); Armin Auch, Darmstadt (DE); Philipp Stoessel, Darmstadt (DE)

(21) Appl. No.: 18/509,698

(22) Filed: Nov. 15, 2023

(30) Foreign Application Priority Data
Dec. 8, 2022 (EP) 22212201.2

(51) Int. Cl. C07F 15/00; C09K 11/06; H10K 50/11; H10K 85/30

(52) U.S. Cl. CPC C07F 15/0033; C09K 11/06; H10K 50/11; H10K 85/342

(57) ABSTRACT

The present invention relates to iridium complexes suitable for use in organic electroluminescent devices, particularly as emitters.

### CROSS-REFERENCE TO RELATED APPLICATIONS

The present application claims priority under 35 U.S.C. § 119(a)-(d) to European Application No. 22212201.2, filed Dec. 8, 2022, which is incorporated herein by reference herein in its entirety.

### BACKGROUND OF THE INVENTION

The present invention relates to binuclear metal complexes suitable for use as emitters in organic electroluminescent devices.

According to the prior art, ortho-metalated iridium complexes with aromatic ligands are mainly used as triplet emitters in phosphorescent organic electroluminescent devices (OLEDs), wherein the ligands bind to the metal via a negatively charged carbon atom and a neutral nitrogen atom. From WO 2018/041769 and WO 2022/034046 binuclear iridium complexes, especially for red emission, are known, which can be processed from solution. Even though good emission properties are already obtained with these complexes, there is a further need for improvement, especially with respect to the spectral width of the emission band. An object of the present invention is therefore to provide new metal complexes which are suitable as emitters for use in OLEDs. In particular, the object is to provide emitters that have a narrower emission spectrum compared to similar emitters in the prior art. The present invention addresses this unmet need in the art.

### DETAILED DESCRIPTION

Surprisingly, it was found that the binuclear iridium complexes described below show significant improvements in the spectral width of the emission spectrum, i.e., a significantly narrower emission spectrum compared to similar complexes which do not contain a fused heteroaryl group as described below coordinating to both iridium atoms. These complexes and organic electroluminescent devices containing these complexes are the subject of the present invention.

Thus, the subject-matter of the invention is a compound according to the following formula (1),

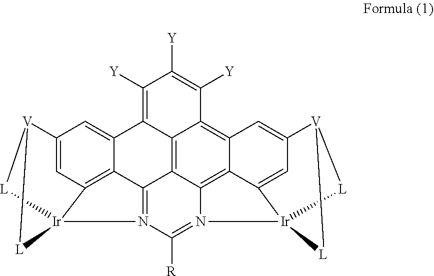

wherein the compound may also be partially or fully deuterated and the symbols used are as follows:
V at each occurrence is the same or different and is a group of the following formula (2),

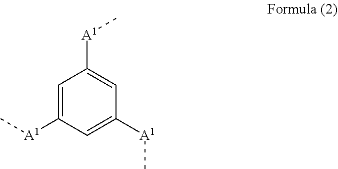

wherein the H atoms not explicitly drawn in may also be partially or completely replaced by D, the dashed bonds at A¹ each represent the bonds to the partial ligands L, and the dashed bond at A² represents the bond to the condensed heteroaryl group shown in formula (1);
A¹ at each occurrence is the same or different and is —CR₂—CR₂— or a group of the following formulae (3), (4), (5), (6) or (7),

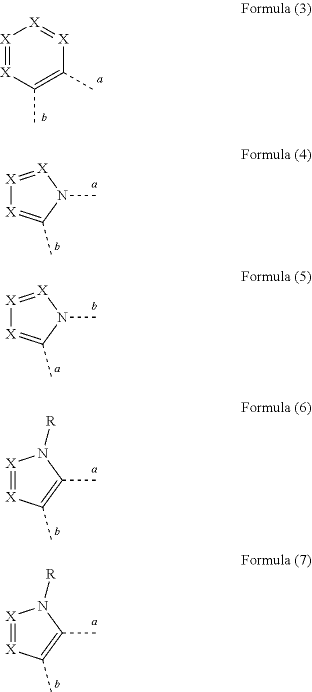

wherein in each case, the dashed bond marked “a” represents the bond to the partial ligand L and the dashed bond marked “b” represents the bond to the central benzene group in formula (2);
A² is the same or different and is A¹, or a group according to one of the following formulae (8), (9), (10), (11) or (12)

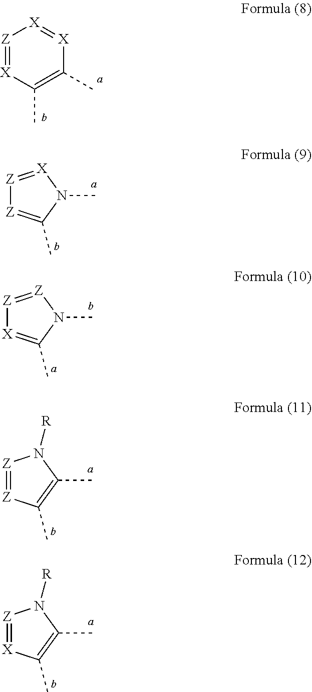

wherein in each case, the dashed bond marked “a” represents the bond to the fused heteroaryl group shown in formula (1) and the dashed bond marked “b” represents the bond to the central benzene group in formula (2);
X at each occurrence is the same or different and is CR or N, preferably with at most one X representing N;
Z at each occurrence is the same or different and is CY or N, preferably with at most one Z representing N;
L at each occurrence is the same or different and is a bidentate monoanionic partial ligand of the following formula (L-1)

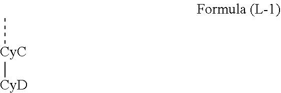

wherein the dashed bond represents the bond to A¹, and the bond between CyC and CyD represents a covalent bond;
CyC at each occurrence is the same or different and is an aryl or heteroaryl group having 5 to 14 aromatic ring atoms, which is coordinated to the iridium via an anionic carbon atom, and which may be substituted by one or more R radicals;
CyD at each occurrence is the same or different and is a heteroaryl group with 5 to 14 aromatic ring atoms, which is coordinated to the iridium via a neutral nitrogen atom or via a carbene carbon atom, and which may be substituted by one or more R radicals;
Y at each occurrence is the same or different and is R or —(Ar)ₙ—R, with the formulae (9) to (12) each containing a maximum of one group Y which is —(Ar)ₙ—R, and in the central fused heteroaryl group in formula (1) a maximum of two groups Y are —(Ar)ₙ—R;
Ar at each occurrence is the same or different and is a bivalent group selected from the structures (Ar1) to (Ar7),

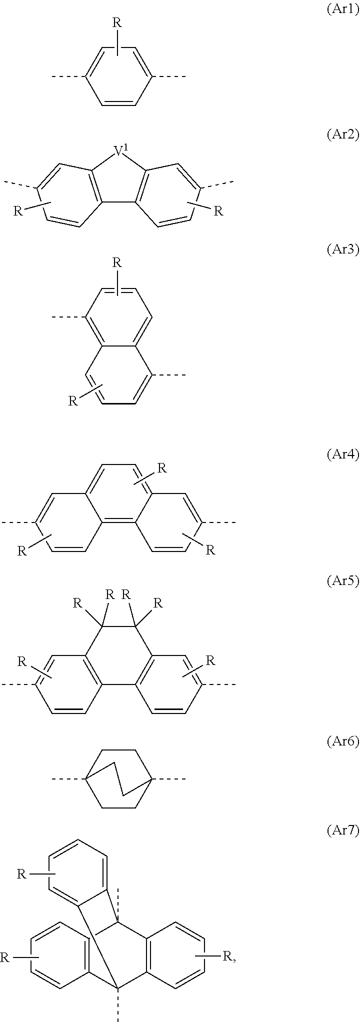

wherein the dashed bond represents the linkage of the units, and V¹ represents CR₂, O, S, or NR;
n at each occurrence is the same or different and is an integer from 3 to 20, with the proviso that at least 5 phenyl groups and/or cyclohexyl groups are linearly linked in each —(Ar)ₙ—R unit;
R at each occurrence is the same or different and is H, D, F, Cl, Br, I, N(R)¹₂, CN, NO₂, OR¹, SR¹, COOH, C(═O)N(R¹)₂, Si(R¹)₃, B(OR¹)₂, C(═O)R¹, P(═O)(R¹)₂, S(═O)R¹, S(═O)₂R¹, OR¹, a straight-chain alkyl group having 1 to 20 carbon atoms, or an alkenyl or alkynyl group having 2 to 20 carbon atoms, or a branched or cyclic alkyl group having 3 to 20 carbon atoms, wherein the alkyl, alkenyl or alkynyl group may in each case be substituted by one or more radicals R¹, wherein one or more non-adjacent CH₂ groups may be replaced by Si(R¹)₂, C═O, NR¹, O, S or CONR¹, or an aromatic or heteroaromatic ring system having 5 to 40 aromatic ring atoms, each of which may be substituted by one or more radicals R¹; wherein two radicals R can also form a ring system with each other;
R¹ at each occurrence is the same or different and is H, D, F, Cl, Br, I, N(R²)₂, CN, NO₂, OR², SR², Si(R²)₃, B(OR²)₂, C(═O)R², P(═O)(R²)₂, S(═O)R², S(═O)₂R², OSO₂R², a straight-chain alkyl group having 1 to 20 carbon-atoms, or an alkenyl or alkynyl group having 2 to 20 carbon atoms, or a branched or cyclic alkyl group having 3 to 20 carbon atoms, wherein the alkyl, alkenyl or alkynyl group may in each case be substituted by one or more radicals R², wherein one or more non-adjacent CH₂ groups may be replaced by Si(R²)₂, C═O, NR², O, S, or CONR², or an aromatic or heteroaromatic ring system having 5 to 40 aromatic ring atoms, which in each case may be substituted by one or more radicals R²; wherein two or more radicals R¹ can form a ring system with each other;
R² at each occurrence is the same or different and is H, D, F, or an aliphatic, aromatic or heteroaromatic organic radical, in particular a hydrocarbon radical, having 1 to 20 carbon atoms, wherein one or more H atoms may also be replaced by F.

If the group Y stands for —(Ar)ₙ—R, Ar are linearly linked aromatic or heteroaromatic groups, or cyclic aliphatic groups. Here, in the definition of n “with the proviso that at least 5 phenyl groups and/or cyclohexyl groups are linearly linked in each —(Ar)ₙ—R unit” means that structure Y has at least 5 phenyl or cyclohexane groups linked to each other, wherein only the phenyl or cyclohexane groups linked directly in series are counted, but not potential substituents on these structures. In this context, structures (Ar1) and (Ar3) each contribute one phenyl group, structures (Ar2), (Ar4) and (Ar5) each contribute two phenyl groups, and structures (Ar6) and (Ar7) each contribute one cyclohexane group, with structure (Ar7) also being considered a cyclohexane group for the purposes of this invention, even though aromatic groups are fused to this structure. Thus, for example, if the group Y is composed of groups (Ar1) only, n must be ≥5 for Y to have at least 5 phenyl groups linked to each other. On the other hand, if Y is composed of a combination of groups (Ar1) and (Ar2), for example, n=3 can be possible if one group (Ar1) and two groups (Ar2) are present.

When two radicals R or R¹ form a ring system with each other, this can be mono- or polycyclic, aliphatic, heteroaliphatic, aromatic, or heteroaromatic. In this context, the radicals forming a ring system with each other may be adjacent, i.e., these radicals are bonded to the same carbon atom or to carbon atoms that are directly bonded to each other, or they may be further apart. Preference is given to such a ring formation in the case of radicals which are bonded to carbon atoms directly bonded to each other or to the same carbon atom.

The formulation that two or more radicals can form a ring with each other should be understood in the context of the present description to mean, inter alia, that the two radicals are linked to each other by a chemical bond with formal elimination of two hydrogen atoms. This is illustrated by the following scheme.

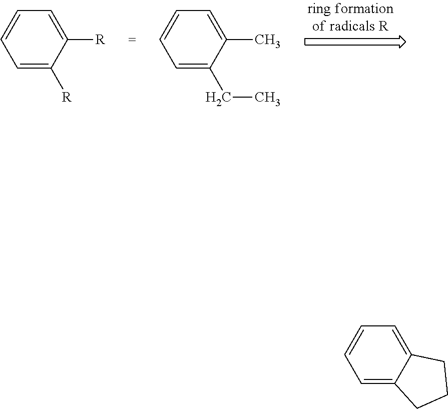

Furthermore, however, the above formulation should also be understood to mean that in the case wherein one of the two radicals represents hydrogen, the second radical binds to the position to which the hydrogen atom was attached, forming a ring. This is to be clarified by the following scheme:

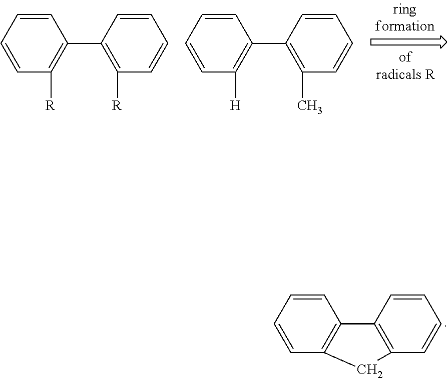

The formation of an aromatic or heteroaromatic ring system is illustrated by the following scheme:

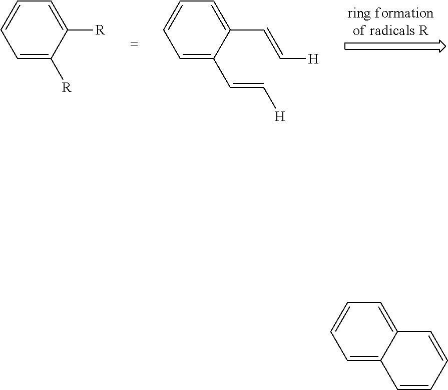

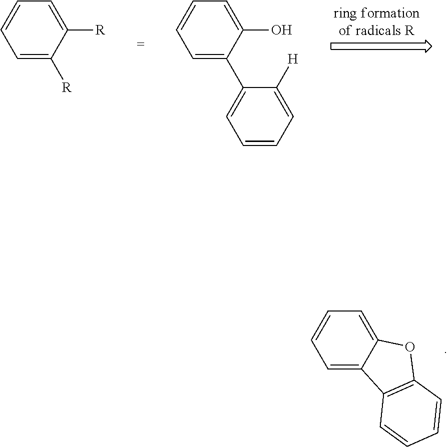

An aryl group within the meaning of this invention contains 6 to 40 C-atoms; a heteroaryl group within the meaning of this invention contains 2 to 40 C-atoms and at least one heteroatom, with the proviso that the sum of C-atoms and heteroatoms is at least 5. The heteroatoms are preferably selected from N, O, and/or S. In this context, an aryl group or heteroaryl group is understood to be either a simple aromatic cycle, i.e., benzene, or a simple heteroaromatic cycle, for example pyridine, pyrimidine, thiophene, etc., or a condensed aryl or heteroaryl group, for example naphthalene, anthracene, phenanthrene, quinoline, isoquinoline, etc.

An aromatic ring system within the meaning of this invention contains 6 to 40 C-atoms in the ring system. A heteroaromatic ring system in the sense of the present invention contains 1 to 40 C-atoms and at least one heteroatom in the ring system, with the proviso that the sum of C-atoms and heteroatoms is at least 5. The heteroatoms are preferably selected from N, O, and/or S. An aromatic or heteroaromatic ring system within the meaning of the present invention is intended to be a system which does not necessarily contain only aryl or heteroaryl groups, but in which several aryl or heteroaryl groups may also be interrupted by a non-aromatic unit (preferably less than 10% of the atoms other than H), such as a C, N, or O atom or a carbonyl group. For example, systems such as 9,9′-spirobifluorene, 9,9-diarylfluorene, triarylamine, diaryl ether, stilbene, etc. are also to be understood as aromatic ring systems in the sense of the present invention, and also systems in which two or more aryl groups are interrupted, for example, by a linear or cyclic alkyl group or by a silyl group. Furthermore, systems in which two or more aryl or heteroaryl groups are directly bonded to each other, such as biphenyl, terphenyl, quaterphenyl or bipyridine, are also to be understood as aromatic or heteroaromatic ring systems. Preferably, the aromatic or heteroaromatic ring system is a system in which two or more aryl or heteroaryl groups are directly linked to each other via a single bond, or is fluorene, spirobifluorene or another aryl or heteroaryl group to which an optionally substituted indene group is fused, such as indenocarbazole.

In the context of the present invention, the term alkyl group is used as a generic term for both linear or branched alkyl groups and cyclic alkyl groups. Similarly, the terms alkenyl group or alkynyl group are used as generic terms for both linear or branched alkenyl or alkynyl groups and cyclic alkenyl or alkynyl groups. A cyclic group within the meaning of the present invention is understood to mean a monocyclic, a bicyclic, or a polycyclic group.

In the context of the present invention, a C₁- to C₂₀-alkyl group, in which individual H atoms or CH₂ groups may also be substituted by the above-mentioned groups, means, for example, the radicals methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl-, 2-ethylhexyl, cyclooctyl, 1-bicyclo[2,2,2]octyl, 2-bicyclo[2,2,2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl, and 1-(n-decyl)-cyclohex-1-yl are understood. By an alkenyl group is understood, for example, ethenyl, propenyl, butenyl, pentenyl, cyclopentenyl, hexenyl, cyclohexenyl, heptenyl, cycloheptenyl, octenyl, cyclooctenyl, or cyclooctadienyl. By an alkynyl group is understood, for example, ethynyl, propynyl, butynyl, pentynyl, hexynyl, heptynyl or octynyl. A C₁- to C₂₀-alkoxy group, as present for OR¹ or OR², is understood to mean, for example, methoxy, trifluoromethoxy, ethoxy, n-propoxy, i-propoxy, n-butoxy, i-butoxy, s-butoxy, t-butoxy, or 2-methylbutoxy.

An aromatic or heteroaromatic ring system with 5-40 aromatic ring atoms, which may be substituted with the above-mentioned radicals, and which may be linked via any positions on the aromatic or heteroaromatic ring means, for example, groups derived from benzene, naphthalene, anthracene, benzanthracene, phenanthrene, benzophenanthrene, pyrene, chrysene, perylene, fluoranthene, benzfluoranthene, naphthacene, pentacene, benzpyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzo thiophene, isobenzothiophene, dibenzothiophene, pyrrole, indole, isoindole, carbazole, indolocarbazole, indenocarbazole, pyridine, quinoline, isoquinoline, quinazoline, quinoxaline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzpyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine-, 1,2,3-triazine, tetrazole, 1,2,4,5-tetrazine, 1,2,3,4-tetrazine, 1,2,3,5-tetrazine, purine, pteridine, indolizine and benzothiadiazole.

The central condensed cycle in formula (1), that is, the following structure:

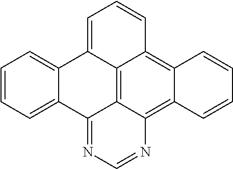 [SMILES: c1ccc2c(c1)c1cccc3c4ccccc4c4ncnc2c4c13]

is a tribenzo[e,gh,j]perimidine, so that this structure is also referred to in the following in simplified form as “tribenzoperimidine”.

For further illustration of the compound, one structure according to formula (1) is fully shown and explained below:

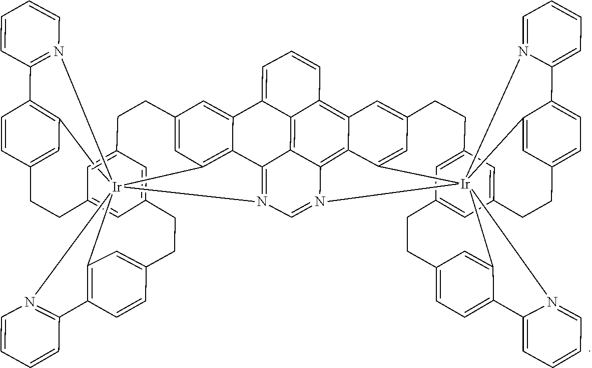

The characterizing feature of the invention is the tribenzoperimidine group, which coordinates to the two iridium atoms via one nitrogen atom and one carbon atom, respectively. Furthermore, in this structure, in the group V or the group of formula (2), each of the symbols A¹ and A² stands for —CH₂—CH₂—. Two partial ligands L are also attached to each of these groups, which in the structure described above represent phenyl pyridine. Each of the two iridium atoms is thus coordinated with two phenyl pyridine ligands and a condensated heteroaryl group in the structure shown above. The partial ligands are each linked by the group of formula (2) to form a polypodal system.

The term “bidentate partial ligand” for L means for the purpose of this application that this unit would be a bidentate ligand if the group V, i.e., the group of formula (2), were not present. However, due to the formal abstraction of a hydrogen atom at this bidentate ligand and the linkage with the group V, i.e., the group of formula (2), this is not a separate ligand, but a part of the dodecadentate ligand thus formed, i.e., a ligand with a total of 12 coordination sites, so that the term “partial ligand” is used for this.

The bonds of the ligand to the metal M can be both coordinating and covalent bonds, or the covalent portion of the bond can vary depending on the ligand. When in the present application reference is made to the ligand or the partial ligand coordinating or binding to M, this means in the sense of the present application any type of binding of the ligand or partial ligand to M, irrespective of the covalent part of the binding.

In a preferred embodiment of the invention, the compounds of formula (1) are selected from the compounds of the following formulae (1a), (1b) or (1c),

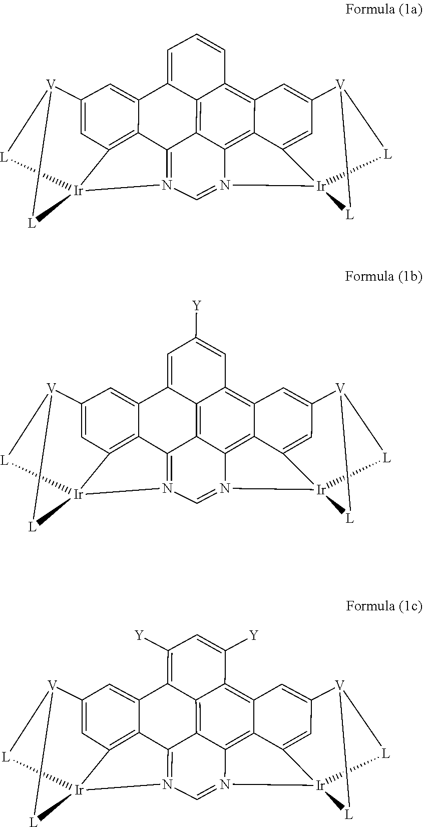

wherein the compound may also be partially or completely deuterated, Y is, at each occurrence, the same or different, preferably the same, and is —(Ar)ₙ—R, and the other symbols used have the meanings given above.

Preferred embodiments for V, i.e., the group of formula (2), are set forth below. In a preferred embodiment of the invention, both groups V are the same.

Preferred embodiments of groups A¹ are the same or different at each occurrence, preferably the same, and are —CR₂—CR₂—, or a group according to any of the following formulae (3a) to (7c),

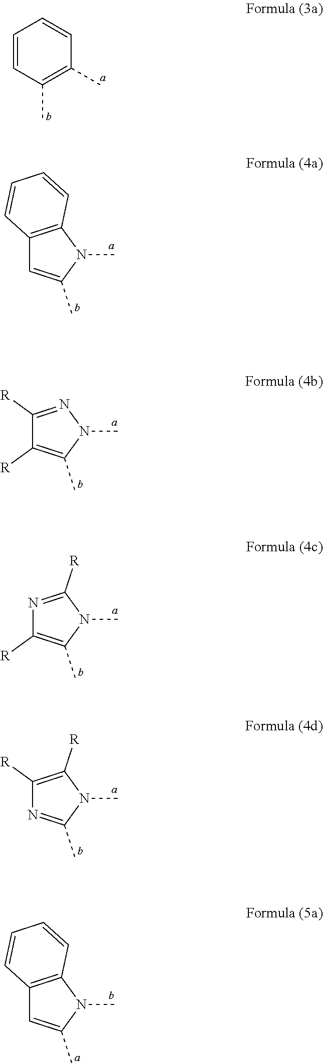

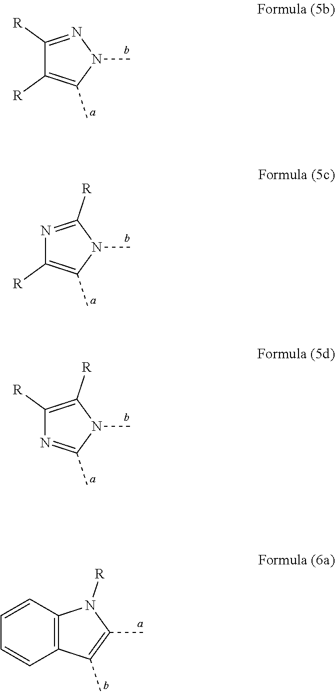

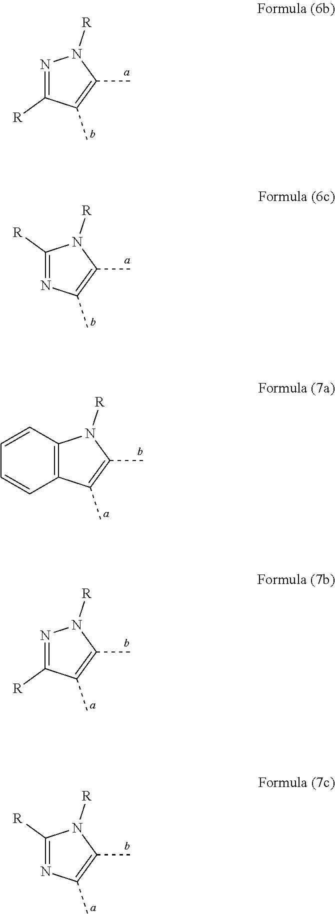

wherein in each case the dashed bond marked with “a” represents the bond to the partial ligand L, the dashed bond marked with “b” represents the bond to the central benzene group in formula (2), the H atoms not explicitly drawn in may be partially or fully replaced by D at all times, R, which may be the same or different at each occurrence, represents H, D, optionally deuterated methyl, or optionally deuterated phenyl, and the two radicals R in the formulae (4b), (4d), (5b) and (5d) together may also form an optionally deuterated fused benzo group.

Preferred embodiments of groups A² are —CR₂—CR₂—, or a group according to any of the following formulae (8a) to (12d),

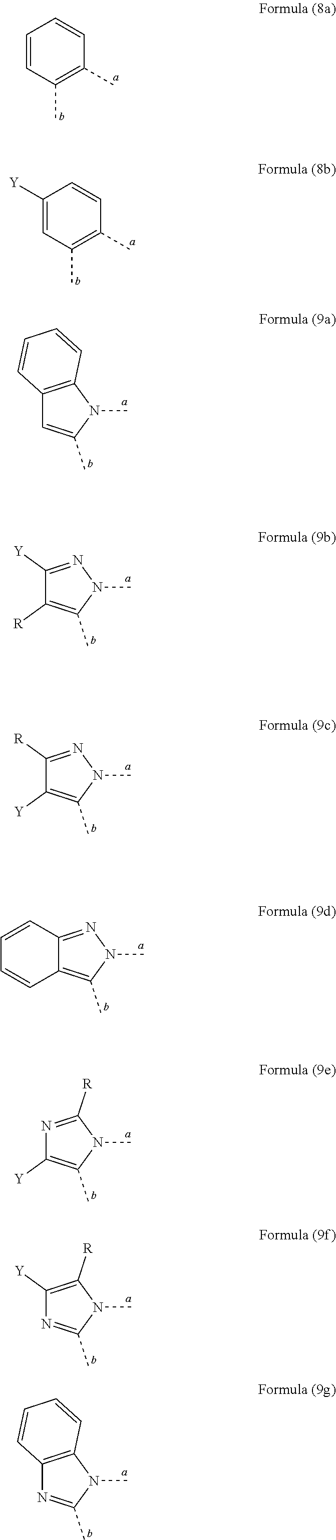

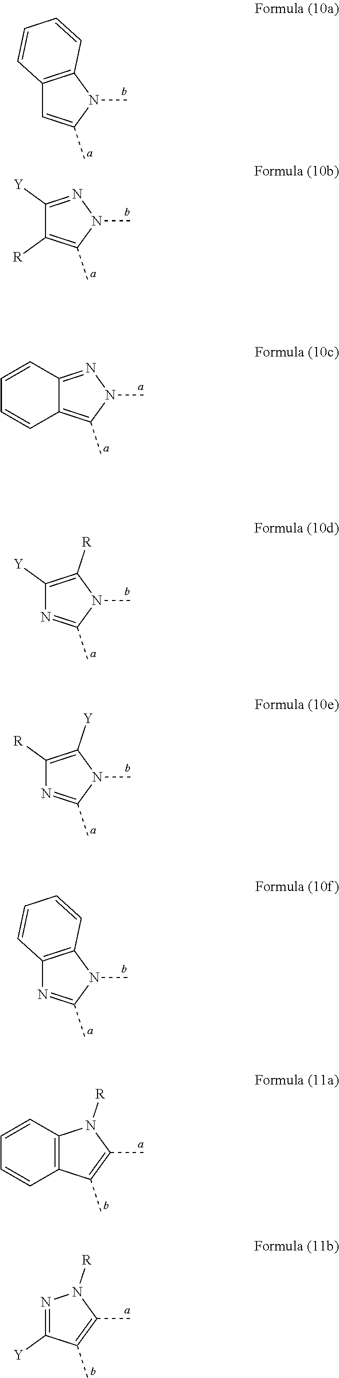

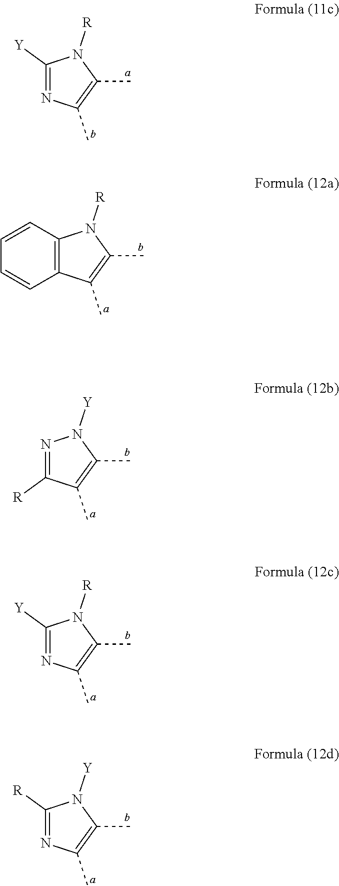

wherein in each case the dashed bond marked with “a” represents the bond to the tribenzoperimidine group, the dashed bond marked with “b” represents the bond to the central benzene group in formula (2), the H atoms not explicitly drawn in may be partially or fully permanently replaced by D, Y represents R, or —(Ar)ₙ—R, and R is the same or different at each occurrence, and represents H, D, optionally deuterated methyl, or optionally deuterated phenyl.

Preferred embodiments of A² are the groups of formulae (8), (9) and (11), or the preferred embodiments of these groups.

If A¹ or A² stands for —CR₂—CR₂—, R preferably stands for H or CH₃, which may also be partially or completely deuterated. Further preferred, A¹ or A²=—CHR—CHR—, wherein the two residues R together with the C-atoms to which they bind form a cyclopentyl or cyclohexyl group, wherein these structures may also be partially or completely deuterated. Preferred embodiments, when A¹ and A², respectively, stand for —CR₂—CR₂—, are —CH₂—CH₂—, —CH₂—C(CH₃)₂—, —C(CH₃)₂—C(CH₃)₂—, 1,2-cyclopentyl and 1,2-cyclohexyl, wherein these structures may be partially or completely deuterated.

In a preferred embodiment of the invention, the two groups A¹, which bind to the partial ligands L, are chosen to be the same.

In a preferred embodiment of the invention, A¹ and A² in formula (2) are as follows:

| A¹ | A² |
|---|---|
| —CH₂—CH₂— | —CH₂—CH₂— |
| Formula (3a) | —CH₂—CH₂— |
| —CH₂—CH₂— | Formula (8a) |
| Formula (3a) | Formula (8a) |
| —CH₂—CH₂— | Formula (8b) |
| Formula (3a) | Formula (8b) |
| —CH₂—CH₂— | Formula (9a) |
| Formula (3a) | Formula (9a) |
| —CH₂—CH₂— | Formula (9b) |
| Formula (3a) | Formula (9b) |
| —CH₂—CH₂— | Formula (9c) |
| Formula (3a) | Formula (9c) |
| —CH₂—CH₂— | Formula (9d) |
| Formula (3a) | Formula (9d) |
| —CH₂—CH₂— | Formula (9e) |
| Formula (3a) | Formula (9e) |
| —CH₂—CH₂— | Formula (9f) |
| Formula (3a) | Formula (9f) |
| —CH₂—CH₂— | Formula (9g) |
| Formula (3a) | Formula (9g) |

wherein these groups A¹ and A² may also be partially or completely deuterated.

When A² is a group of formula (8b), preferred embodiments are the compounds of the following formulae (13) and (14), and when A² is —CR₂—CR₂—, preferred embodiments are the compounds of the following formula (15),

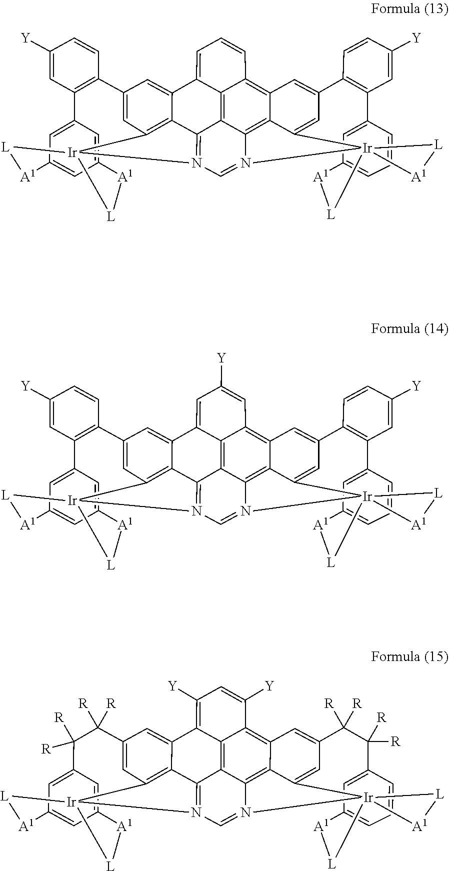

wherein Y is the same or different at each occurrence, preferably the same, and is H, D, or a group —(Ar)ₙ—R, the compound may also be partially or completely deuterated, and the explicitly drawn radicals R in formula (15) are the same or different at each occurrence and are H, D, or optionally deuterated methyl. Preferably, the structures are symmetrical, i.e., the two groups Y in formula (13) or formula (15) are chosen to be the same in each case, or the two groups Y attached to the ortho-phenylene group in formula (14) are chosen to be the same.

The partial ligands L are described below. These can be the same or different. It is preferred if the two partial ligands L which coordinate to the same Ir atom are the same and also equally substituted. Particularly preferably, all four partial ligands L are the same and also equally substituted.

It is further preferred that the metalacyclic structure spanned by the iridium and the partial ligands L is a five-membered ring. The formation of a five-membered ring is shown schematically below for carbon and nitrogen as coordinating atoms:

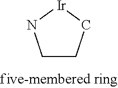

wherein N represents a coordinating nitrogen atom, and C represents a coordinating carbon atom, and the carbon atoms depicted represent atoms of the partial ligand L.

If several of the substituents, in particular several residues R, form a ring system with each other, the formation of a ring system from substituents attached to directly adjacent carbon atoms is possible. Furthermore, it is also possible for the substituents on CyC and CyD in formula (L-1) to form a ring with each other, whereby CyC and CyD together can form a single fused heteroaryl group as a bidentate partial ligand.

In a preferred embodiment of the present invention, CyC is an aryl or heteroaryl group having 6 to 13 aromatic ring atoms, more preferably having 6 to 10 aromatic ring atoms, most preferably having 6 aromatic ring atoms, in particular a phenyl group which coordinates to the metal via a carbon atom, which may be substituted with one or more radicals R, and which is linked to CyD via a covalent bond.

Preferred embodiments of the group CyC are the structures of the following formulae (CyC-1) to (CyC-7), wherein the group CyC in each case binds to CyD at the position indicated by #, coordinates to the iridium at the position indicated by * and is bound to the bridge V or the bridge of formula (2) at the position indicated by “o”,

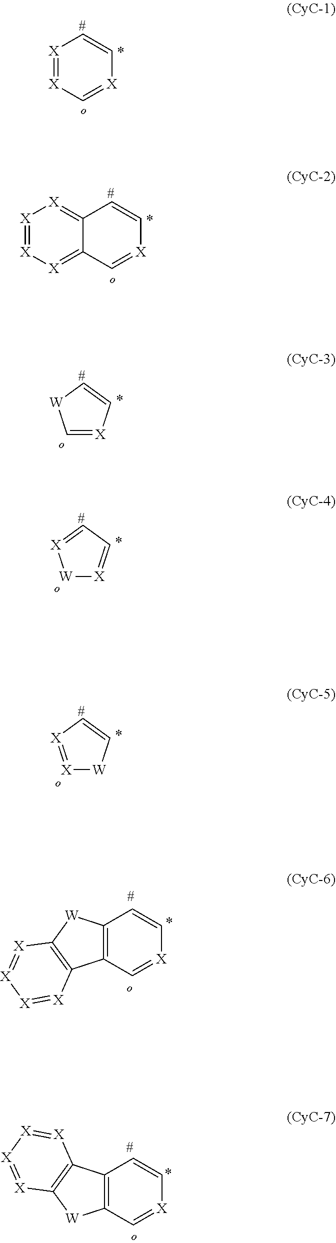

wherein R has the above meanings, and the following applies to the other symbols used:
X is at each occurrence the same or different, and is CR or N with the proviso that at most two symbols X per cycle is N;
W is at each occurrence the same or different, and is NR, O, S, or CR₂.

Preferably, at most one symbol X in CyC is N, and particularly preferred, all symbols X are CR.

Particularly preferred groups CyC are those of the following formulae (CyC-1a) to (CyC-7a),

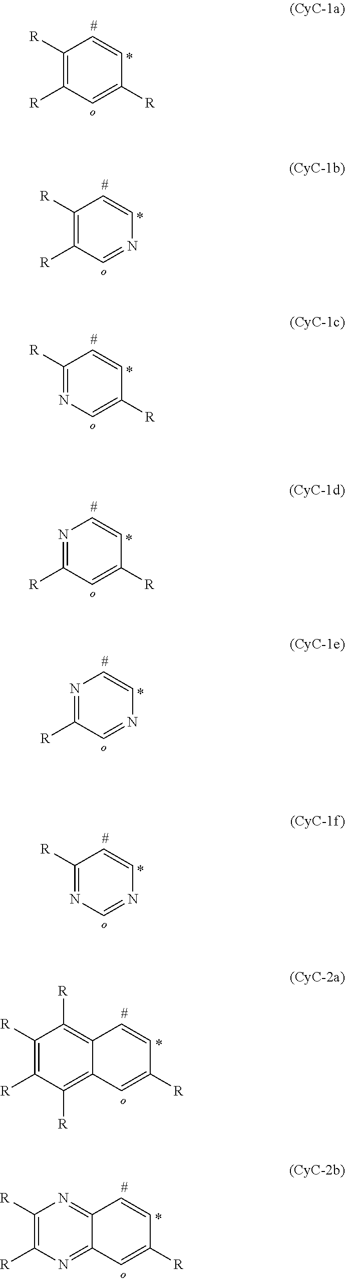

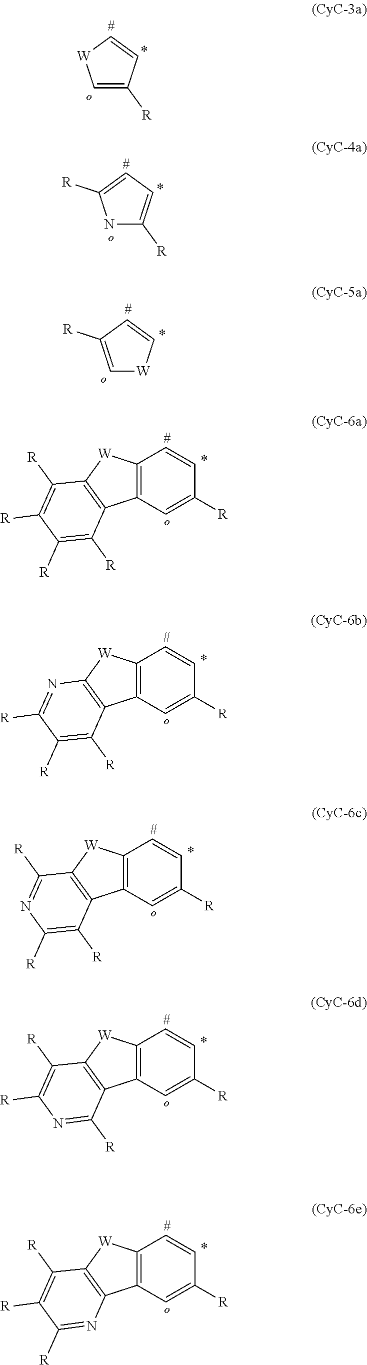

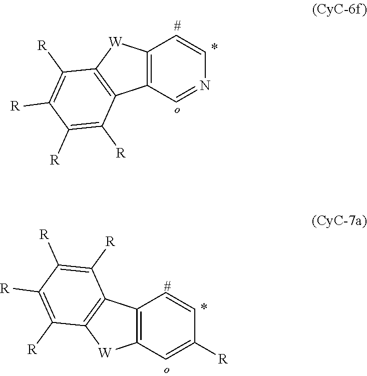

wherein the symbols used have the above mentioned meanings.

In a further preferred embodiment of the invention, CyD is a heteroaryl group having 5 to 13 aromatic ring atoms, particularly preferably having 6 to 10 aromatic ring atoms, which coordinates to the metal via a neutral nitrogen atom, or via a carbene carbon atom, and it may be substituted with one or more radicals R, and it is linked to CyC via a covalent bond.

Preferred embodiments of the group CyD are the structures of the following formulae (CyD-1) to (CyD-18), wherein the group CyD binds to CyC at the position indicated by #, respectively, and coordinates to the iridium at the position indicated by *,

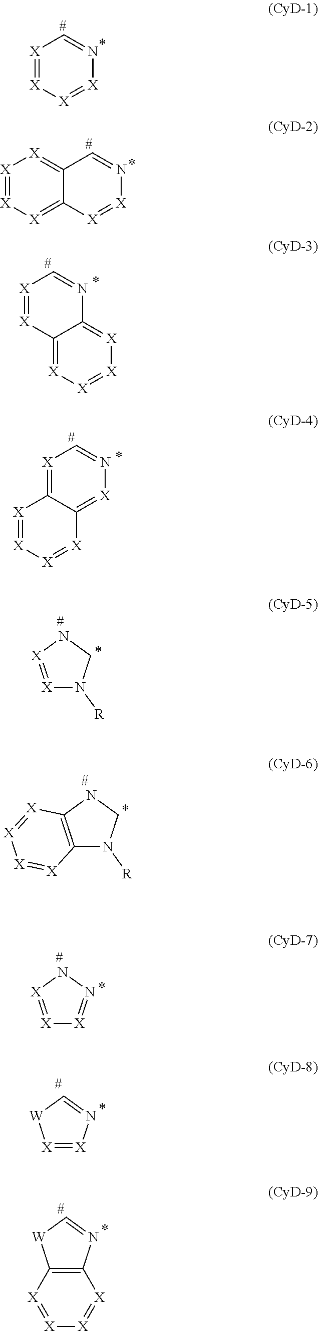

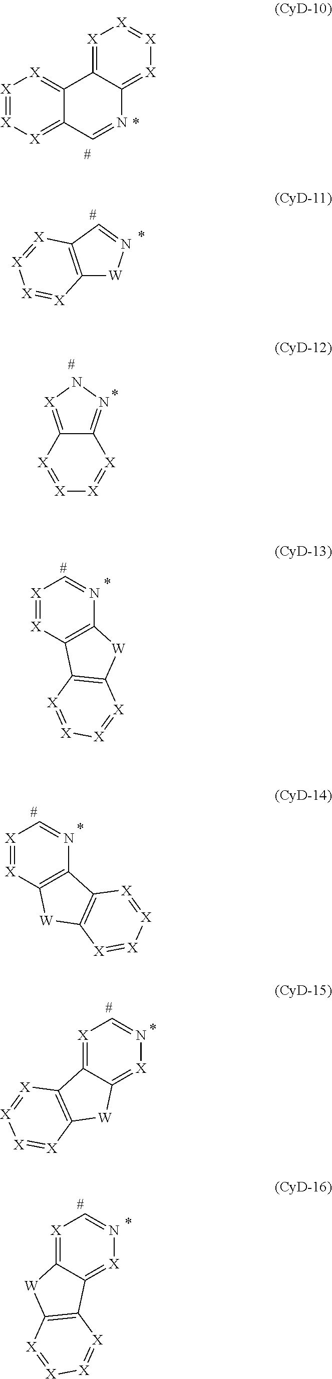

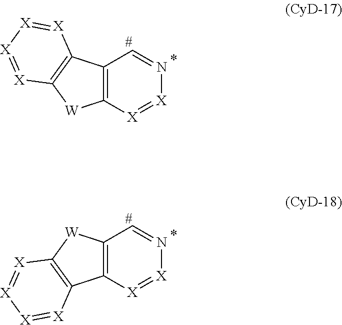

wherein R has the meanings given above and X and W have the meanings given above for the formulae (CyC-1) to (CyC-7).

Herein, the groups (CyD-1) to (CyD-4) and (CyD-7) to (CyD-18) coordinate to the metal via a neutral nitrogen atom and (CyD-5) and (CyD-6) coordinate to the metal via a carbene carbon atom.

Preferably, at most one symbol X in CyD is N, and particularly preferred all symbols X are CR.

Particularly preferred groups CyD are those of the following formulae (CyD-1a) to (CyD-18a),

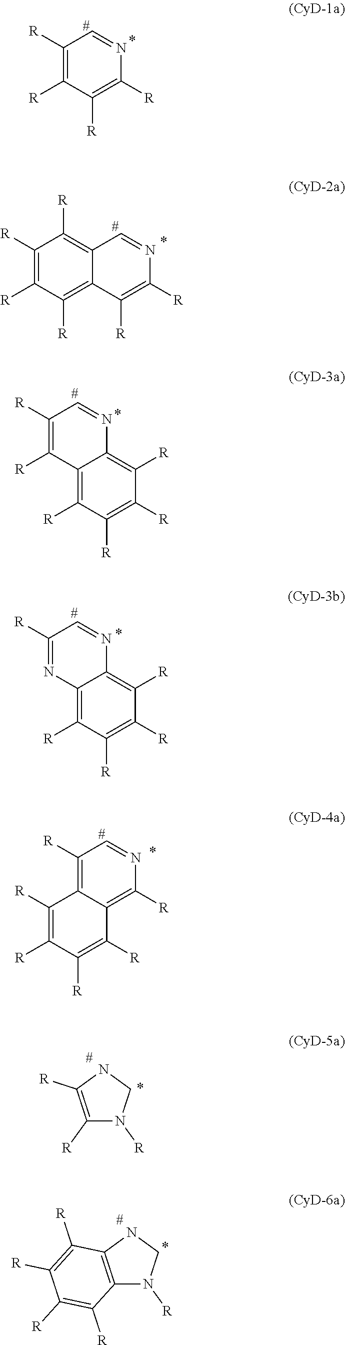

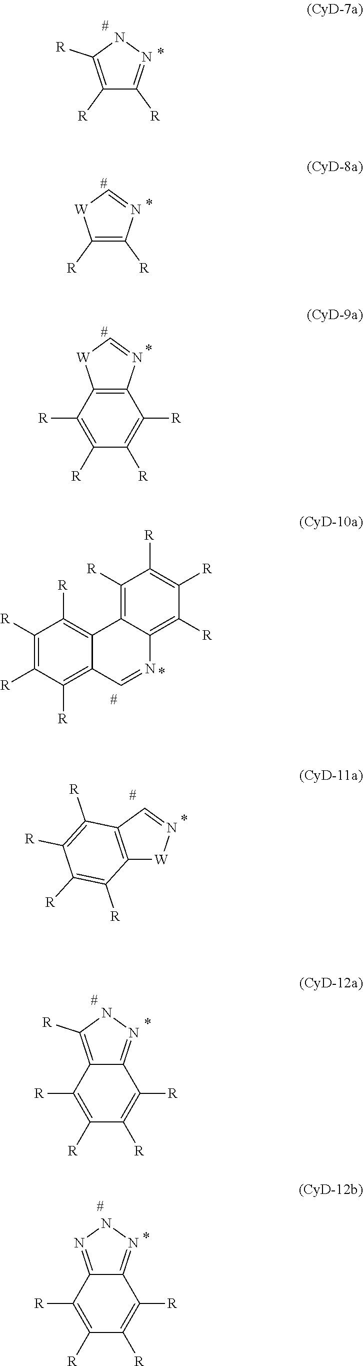

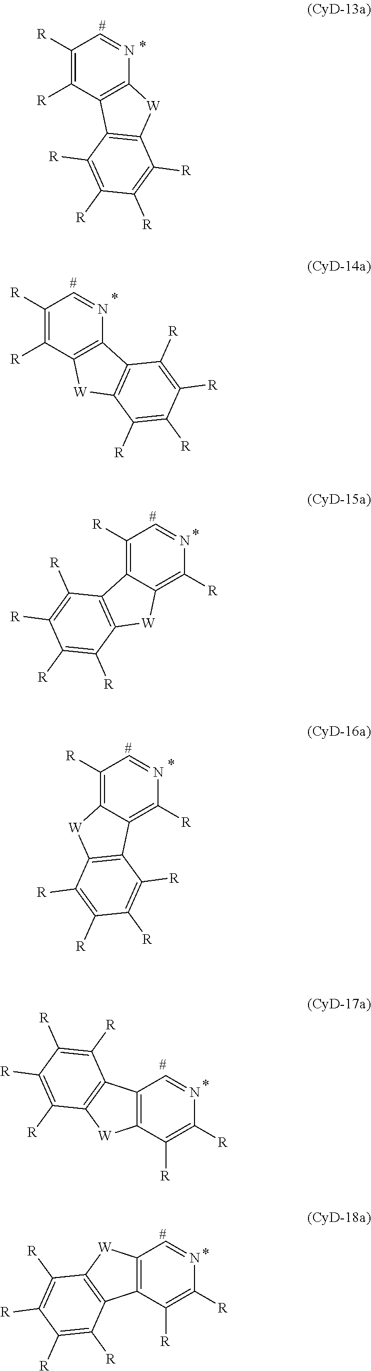

wherein the symbols used have the above meanings.

In a preferred embodiment of the present invention, CyC is an aryl or heteroaryl group having 6 to 13 aromatic ring atoms, and at the same time CyD is a heteroaryl group having 5 to 13 aromatic ring atoms. Particularly preferably, CyC is an aryl or heteroaryl group having 6 to 10 aromatic ring atoms, and at the same time CyD is a heteroaryl group having 5 to 10 aromatic ring atoms. Most preferably, CyC is an aryl or heteroaryl group having 6 aromatic ring atoms, in particular phenyl, and CyD is a heteroaryl group having 6 to 10 aromatic ring atoms. CyC and CyD may each be substituted by one or more R radicals.

The above-mentioned preferred groups (CyC-1) to (CyC-7) and (CyD-1) to (CyD-18) can be combined with each other as desired in the partial ligands of the formulae (L-1). In particular, it is preferred if the groups CyC and CyD mentioned above as particularly preferred, i.e., the groups of the formulae (CyC-1a) to (CyC-7a) and the groups of the formulae (CyD-1a) to (CyD-18a) are combined with each other.

Preferred partial ligands (L-1) are the structures of the formulae (L-1-1) to (L-1-5),

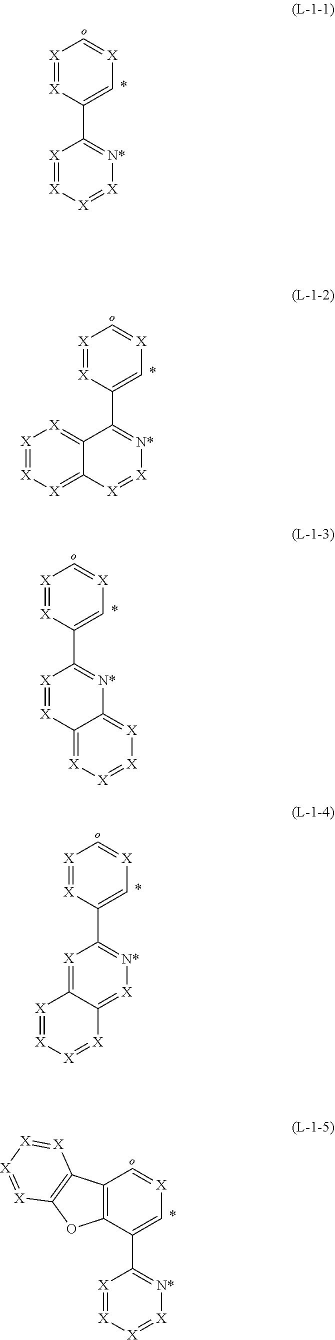

wherein the symbols used have the meanings given above, * represents the positions of coordination to the iridium and “o” represents the position of the bond to the bridge V. Preferably, at most one group X in each partial ligand represents N. Preferred partial ligands are those of formula (L-1-1).

Particularly preferred partial ligands (L-1) are the structures of the formulae (L-1-1a) to (L-1-5b),

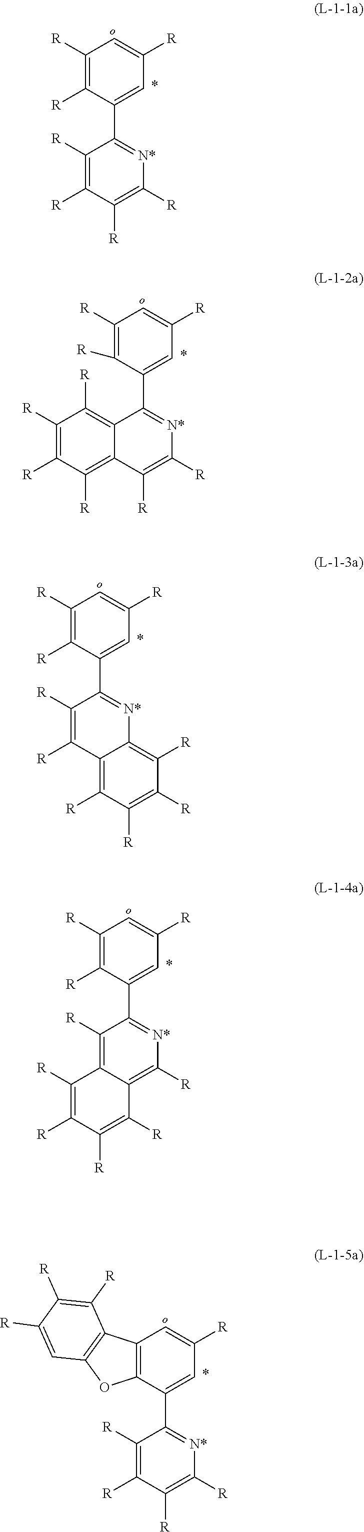

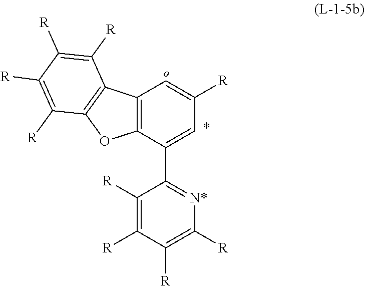

wherein the symbols used have the meanings given above, * represents the positions of coordination to the iridium and “o” represents the position of the bond to the bridge V. Preferably, a maximum of three substituents R are not equal to H or D, particularly preferably a maximum of two substituents R and most preferably a maximum of one substituent. Particularly preferred are the partial ligands of the formula (L-1-1).

If two residues R, one of which is bonded to CyC and the other to CyD, form an aromatic ring system with each other, bridged partial ligands and, for example, partial ligands may result which together represent a single larger heteroaryl group, such as benzo[h]quinoline, etc. The ring formation between the substituents on CyC and CyD is preferably achieved by a group according to one of the following formulae (16) to (25),

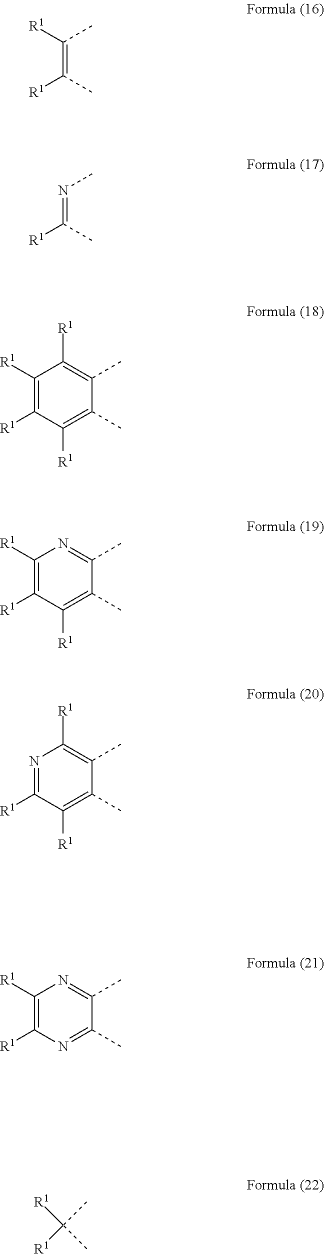

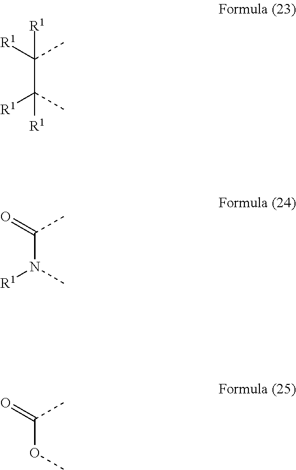

wherein R¹ has the above meanings, and the dashed bonds indicate the bonds to CyC and CyD, respectively. In this regard, the asymmetric ones of the above groups can be incorporated in either of the two ways, for example, in the group of formula (25), the oxygen atom can bond to the group CyC, and the carbonyl group can bond to the group CyD, or the oxygen atom can bond to the group CyD, and the carbonyl group can bond to the group CyC.

In this regard, the group of formula (22) is particularly preferred when it results in the formation of a ring to form a six-membered ring, such as shown below by formula (L-11).

Preferred ligands formed by ring formation of two residues R on CyC and CyD are the structures of formulae (L-2) to (L-15) listed below,

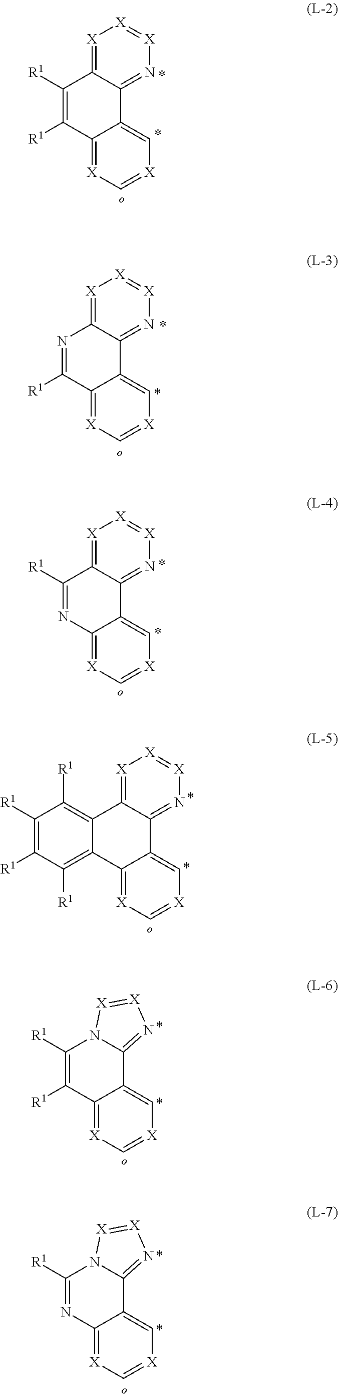

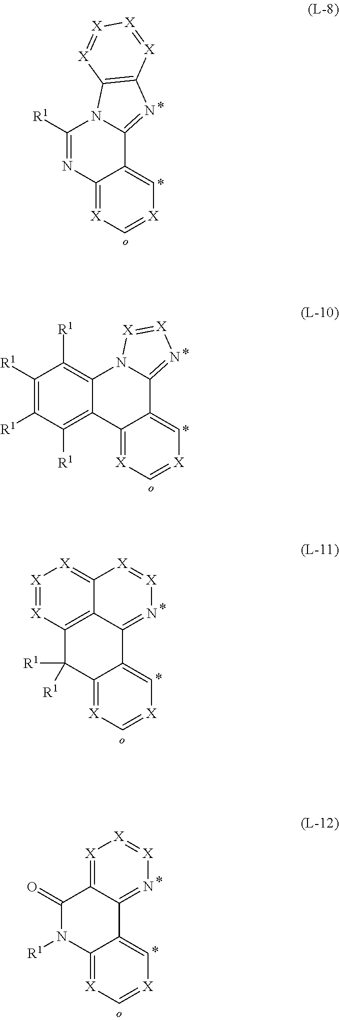

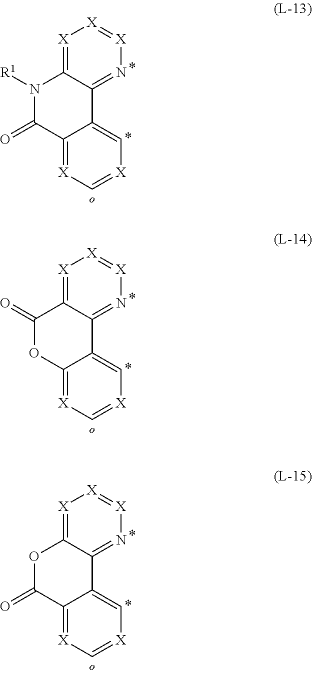

wherein the symbols used have the meanings given above, * represent the positions of coordination to the iridium, and “o” indicates the position at which this partial ligand is linked to the bridge V.

In a preferred embodiment of the partial ligands of formulae (L-2) to (L-15), in total one symbol X represents N and the other symbols X represent CR, or all symbols X represent CR.

In a further embodiment of the invention, it is preferred if in the groups (CyC-1) to (CyC-7) or (CyD-1) to (CyD-18) or in the partial ligands (L-1-1) to (L-15) one of the atoms X is N, if adjacent to this nitrogen atom a group R is bonded as substituent which is not hydrogen or deuterium. This applies analogously to the preferred structures (CyC-1a) to (CyC-7a) or (CyD-1a) to (CyD-18a), in which a group R other than hydrogen or deuterium is preferably bonded as substituent adjacent to a non-coordinating nitrogen atom. This substituent R is preferably a group selected from CF₃, OCF₃, alkyl groups having 1 to 10 carbon atoms, in particular branched or cyclic alkyl groups having 3 to 10 carbon atoms, OR¹, wherein R¹ is an alkyl group having 1 to 10 carbon atoms, in particular a branched or cyclic alkyl group having 3 to 10 carbon atoms, a dialkylamino group having 2 to 10 carbon atoms, aromatic, or heteroaromatic ring systems, or a group selected from heteroaromatic ring systems, or aralkyl, or heteroaralkyl groups. These groups can also be partially or completely deuterated. These groups are sterically demanding groups. Preferably, this radical R can also form a cycle with an adjacent radical R.

In the following, preferred embodiments of Y are described wherein Y represents a group —(Ar)ₙ—R.

The residue R in the group —(Ar)ₙ—R is at each occurrence the same or different, and preferably represents H, D, a linear alkyl group with 1 to 10 C-atoms, or a branched or cyclic alkyl group with 3 to 10 C-atoms, in particular H or D.

Preferred groups Ar are described below. As described above, these are the bivalent structures (Ar1) to (Ar7), each of which may be the same or different. The groups (Ar1) to (Ar7) have in common that they lead to a linear linkage of the units within the group Y by the para linkage, or in formula (Ar3) a linkage similar to the para linkage. This is essential if the compounds according to the invention are to show orientation when deposited from solution.

Preferred embodiments of structures (Ar1) are the following structures (Ar1a) to (Ar1f),

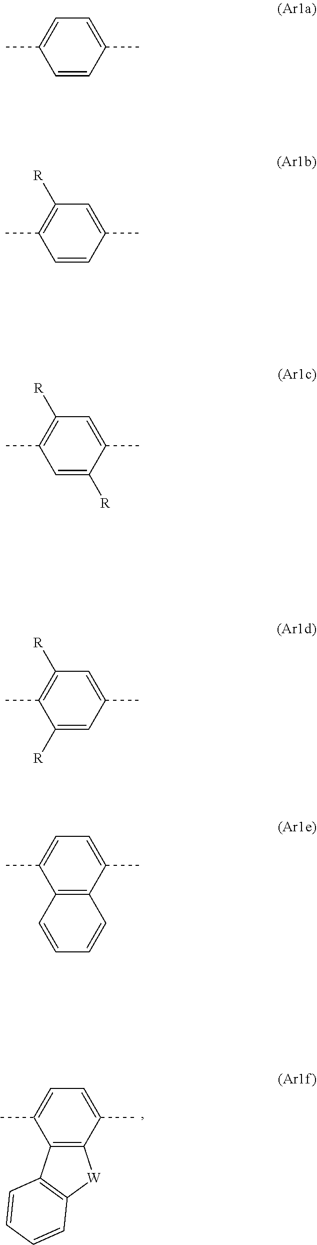

wherein the dashed bonds represent the linkage of the structures, W is C(R¹)₂, O, S, or NR¹, R and R¹ have the meanings given above and the structures may also be partially or completely deuterated. In this context, W preferably represents O or S.

Preferred substituents R in structures (Ar1 b) to (Ar1d) are the same or different at each occurrence, and are selected from the group consisting of a linear alkyl group having 1 to 10 carbon atoms or a branched or cyclic alkyl group having 3 to 10 carbon atoms, each of which may be substituted by one or more radicals R¹, but is preferably unsubstituted, or an aromatic ring system having 6 to 12 aromatic ring atoms, which may be substituted by one or more radicals R¹, wherein R¹ preferably represents a linear alkyl group having 1 to 10 C-atoms or a branched or cyclic alkyl group having 3 to 10 C-atoms, or a group OR¹, wherein R¹ represents a linear alkyl group having 1 to 10 C-atoms, or a branched or cyclic alkyl group having 3 to 10 C-atoms.

When W in formula (Ar1f) stands for C(R¹)₂, R¹ preferably represents a linear alkyl group with 1 to 10 C-atoms, or a branched or cyclic alkyl group with 3 to 10 C-atoms. When W in formula (Ar1f) stands for NR¹, R¹ preferably represents an aromatic ring system with 6 to 24 aromatic ring atoms, preferably with 6 to 12 aromatic ring atoms, which may also be substituted by one or more alkyl groups each having 1 to 10 C-atoms.

Preferred embodiments of structures (Ar2) are structures (Ar2a) and (Ar2b),

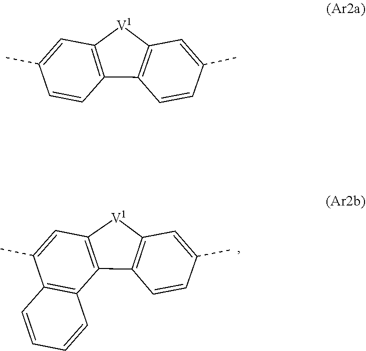

wherein the dashed bonds represent the linkages of the structures, V¹ has the above meanings, and the structures may also be partially or completely deuterated.

Particularly preferred embodiments of structure (Ar2) are the following structures (Ar2a-1) to (Ar2a-5) and (Ar2b-1),

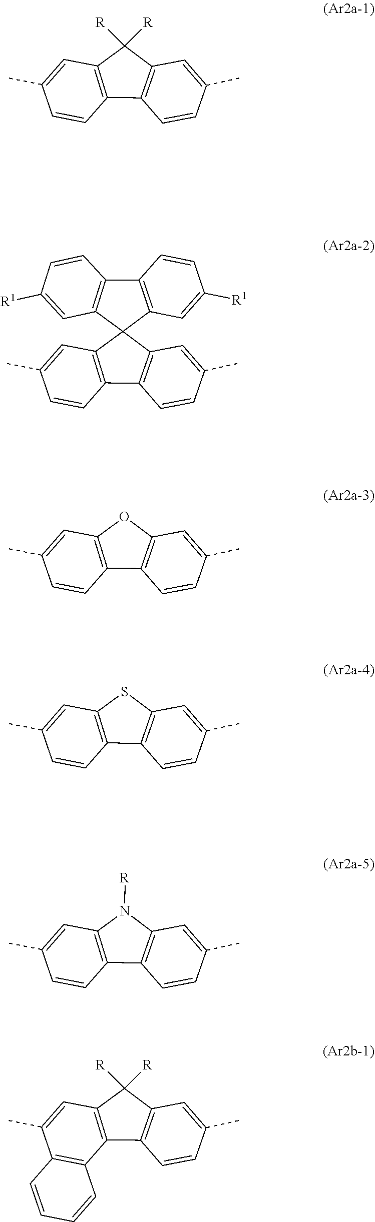

wherein the dashed bonds represent the linkage of the structure, R and R¹ have the above meanings, and the structures may also be partially or completely deuterated.

Preferred substituents R in the structures (Ar2a-1) and (Ar2b1-) are the same or different at each occurrence and are selected from the group consisting of a linear alkyl group having 1 to 10 carbon atoms or a branched or cyclic alkyl group having 3 to 10 carbon atoms, each of which may be substituted by one or more radicals R¹, but is preferably unsubstituted, or an aromatic ring system having 6 to 12 aromatic ring atoms, which may be substituted by one or more radicals R¹, wherein R¹ is preferably a linear alkyl group having 1 to 10 carbon atoms, or a branched or cyclic alkyl group having 3 to 10 carbon atoms.

Preferred substituents R¹ in the structures (Ar2a-2) are the same or different at each occurrence and are selected from the group consisting of H, a linear alkyl group having 1 to 10 C-atoms, or a branched or cyclic alkyl group having 3 to 10 C-atoms, each of which may be substituted by one or more radicals R², but is preferably unsubstituted.

Preferred substituents R in the structures (Ar2a-5) are the same or different at each occurrence and are selected from the group consisting of an aromatic or heteroaromatic ring system having 6 to 18 aromatic ring atoms which may be substituted by one or more radicals R¹, preferably an aromatic ring system having 6 to 12 aromatic ring atoms, which may be substituted by one or more radicals R¹, wherein R¹ is preferably a linear alkyl group having 1 to 20 carbon atoms, or a branched or cyclic alkyl group having 3 to 20 carbon atoms.

Preferred embodiments of the structures (Ar3) are as follows (Ar3a),

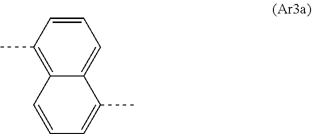

wherein the dashed bonds represent the linkage of the structure, and the structure may also be partially or fully deuterated.

Preferred embodiments of structures (Ar4) are the following structures (Ar4a) and (Ar4b),

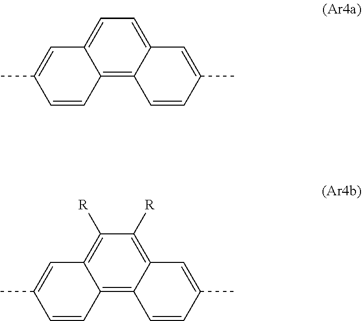

wherein the dashed bonds represent the linkage of the structure, R has the above meanings, and the structures may also be partially or fully deuterated.

Preferred substituents R in the structures (Ar4b) are the same or different at each occurrence and are selected from the group consisting of a linear alkyl group having 1 to 10 carbon atoms, or a branched or cyclic alkyl group having 3 to 10 carbon atoms, each of which may be substituted by one or more radicals R¹, but is preferably unsubstituted, or an aromatic ring system having 6 to 12 aromatic ring atoms, which may be substituted by one or more radicals R¹, wherein R¹ is preferably a linear alkyl group having 1 to 10 carbon atoms, or a branched or cyclic alkyl group having 3 to 10 carbon atoms.

Preferred embodiments of structures (Ar5) are the following structures (Ar5a) and (Ar5b),

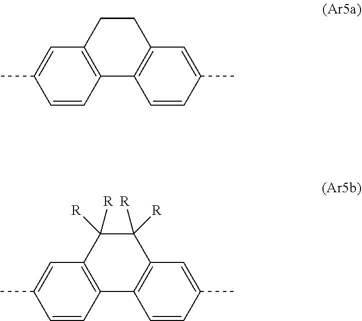

wherein the dashed bonds represent the linkage of the structure, R has the above meanings, and the structures may also be partially or fully deuterated.

Preferred substituents R in the structures (Ar5b) are the same or different at each occurrence and are selected from the group consisting of H, a linear alkyl group having 1 to 10 C-atoms, or a branched or cyclic alkyl group having 3 to 10 C-atoms, each of which may be substituted by one or more radicals R¹, but is preferably unsubstituted.

Preferred embodiments of the structures (Ar7) are the structures (Ar7a) as follows,

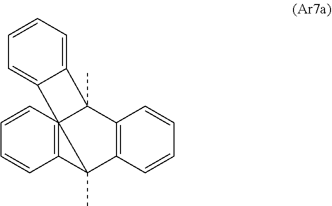

wherein the dashed bonds represent the linkage of the structure, and the structure may also be partially or fully deuterated.

In a preferred embodiment of the invention, at least one group Ar is the same or different at each occurrence and is selected from the structures (Ar1) and/or (Ar2), more preferably at least two groups Ar and most preferably at least 3 groups Ar. More preferably, all groups Ar are selected from structures (Ar1) and/or (Ar2). Thereby, the structures (Ar1) are preferably the same or different at each occurrence and are selected from the structures (Ar1a) to (Ar1d), and the structures (Ar2) are selected from the structures (Ar2a), particularly preferably the structures (Ar2a-1).

If the radicals R or R¹ in the structures (Ar1) to (Ar7) or in the preferred structures set out above stand for linear, branched or cyclic alkyl groups, the alkyl groups preferably have 1 to 15 C-atoms, particularly preferably 1 to 12 C-atoms, and very particularly preferably 1 to 10 C-atoms. Examples of suitable alkyl groups as substituents R or R¹ in the structures (Ar1) to (Ar7) or in the preferred structures are methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]octyl, 2-(2,6-dimethyl)octyl, 3-(3,7-dimethyl)octyl, adamantyl, 1,1-dimethyl-n-hex-1-yl-, 1,1-dimethyl-n-hept-1-yl-, 1,1-dimethyl-n-oct-1-yl-, 1,1-dimethyl-n-dec-1-yl-, 1,1-dimethyl-n-dodec-1-yl-, 1,1-dimethyl-n-tetradec-1-yl-, 1,1-dimethyl-n-hexadec-1-yl-, 1,1-dimethyl-n-octadec-1-yl-, 1,1-diethyl-n-hex-1-yl-, 1,1-diethyl-n-hept-1-yl-, 1,1-diethyl-n-oct-1-yl-, 1,1-diethyl-n-dec-1-yl-, 1,1-diethyl-n-dodec-1-yl-, 1,1-diethyl-n-tetradec-1-yl-, 1,1-diethyl-n-hexadec-1-yl-, 1,1-diethyl-n-octadec-1-yl-, 1-(n-propyl)-cyclohex-1-yl-, 1-(n-butyl)-cyclohex-1-yl-, 1-(n-hexyl)-cyclohex-1-yl-, 1-(n-octyl)-cyclohex-1-yl-, and 1-(n-decyl)-cyclohex-1-yl-. In this context, the alkyl groups can each also have one or more stereocenters, wherein both the enantiomerically or diastereomerically pure structures and the corresponding racemates can be used.

As described above, n represents an integer from 3 to 20, with the proviso that at least 5 phenyl or cyclohexane groups are linearly linked. In a preferred embodiment of the invention, n is an integer from 5 to 20, in particular from 5 to 15. Particularly preferably, n is chosen such that a total of 8 to 24 phenyl or cyclohexane groups are linearly linked to each other, more preferably 12 to 24 phenyl or cyclohexane groups, and most preferably 15 to 20 phenyl or cyclohexane groups. As described above, the structures (Ar2), (Ar4) and (Ar5) each contribute two phenyl groups.

In a further embodiment of the invention, the metal complex according to the invention contains two substituents R bonded to adjacent carbon atoms, which together form an aliphatic ring according to one of the formulae described below. The aliphatic ring formed by the ring formation of two substituents R with each other is preferably described by one of the following formulae (26) to (32),

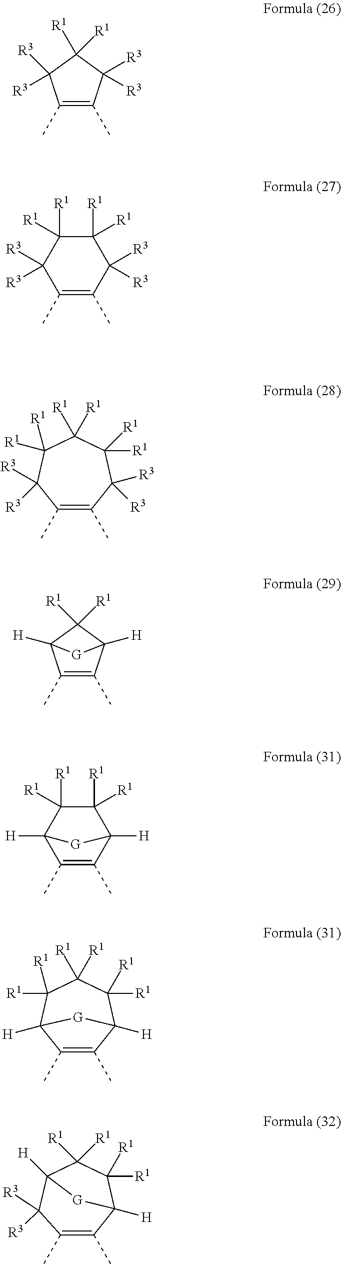

wherein R¹ and R² have the meanings given above, the dashed bonds indicate the linkage of the two carbon atoms in the ligand, and further:
G is an alkylene group having 1, 2 or 3 carbon atoms, which may be substituted by one or more radicals R², —CR²═CR²—, or an ortho-linked arylene or heteroarylene group having 5 to 14 aromatic ring atoms, which may be substituted by one or more radicals R²;
R³ is the same or different at each occurrence, and is H, D, F, a straight-chain alkyl or alkoxy group having 1 to 10 C-atoms, a branched or cyclic alkyl or alkoxy group having 3 to 10 C-atoms, wherein the alkyl or alkoxy group in each case may be substituted by one or more radicals R², wherein one or more non-adjacent CH₂ groups may be replaced by R²C═CR², C≡C, Si(R²)₂, C═O, NR², O, S, or CONR², or an aromatic or heteroaromatic ring system having 5 to 24 aromatic ring atoms, each of which may be substituted by one or more radicals R², or an aryloxy or heteroaryloxy group having 5 to 24 aromatic ring atoms, each of which may be substituted by one or more radicals R²; wherein two radicals R³, which are bonded to the same carbon atom, can form an aliphatic or aromatic ring system with each other and thus form a spiro system; furthermore, R³ can form an aliphatic ring system with an adjacent radical R or R¹.

If adjacent residues in the structures according to the invention form an aliphatic ring system, then it is preferred if this does not have acidic benzylic protons. By benzylic protons are meant protons that bind to a carbon atom that is directly bonded to the ligand. This can be achieved by ensuring that the carbon atoms of the aliphatic ring system that bind directly to an aryl or heteroaryl group are fully substituted and contain no bonded hydrogen atoms. Thus, the absence of acidic benzylic protons in formulae (26) to (28) is achieved by R³ not being hydrogen or deuterium. This can further be achieved also by the fact that the carbon atoms of the aliphatic ring system which bind directly to an aryl or heteroaryl group are the bridgeheads of a bicyclic or polycyclic structure. The protons bonded to bridgehead carbon atoms are much less acidic than benzylic protons on carbon atoms not bonded in a bi- or polycyclic structure, due to the spatial structure of the bi- or polycycle, and are considered non-acidic protons for the purposes of the present invention. Thus, the absence of acidic benzylic protons is achieved in formulae (29) to (32) by being a bicyclic structure, whereby R¹, when H or D, is significantly less acidic than benzylic protons because the corresponding anion of the bicyclic structure is not mesomerically stabilized. Therefore, even though R¹ in formulae (29) to (32) represents H or D, it is a non-acidic proton within the meaning of the present application. In a preferred embodiment of the invention, R³ is not H or D.

Preferred embodiments of the groups of formulae (26) to (32) can be found in applications WO 2014/023377, WO 2015/104045 and WO 2015/117718.

If the compounds according to the invention have radicals R which do not correspond to the radicals R described above, these radicals R at each occurrence are the same or different, and preferably selected from the group consisting of H, D, F, Br, I, N(R¹)₂, CN, Si(R¹)₃, B(OR¹)₂, C(═O)R¹, a straight-chain alkyl group having 1 to 10 carbon atoms, or an alkenyl group having 2 to 10 carbon atoms, or a branched or cyclic alkyl group having 3 to 10 carbon atoms, wherein the alkyl or alkenyl group may in each case be substituted by one or more radicals R¹, or an aromatic or heteroaromatic ring system having 5 to 30 aromatic ring atoms, which in each case may be substituted by one or more radicals R¹; wherein two adjacent radicals R, or R with R¹ can also form together a monocyclic or polycyclic, aliphatic or aromatic ring system. Particularly preferably, these radicals R at each occurrence are the same or different and are selected from the group consisting of H, D, F, N(R¹)₂, a straight-chain alkyl group having 1 to 6 C-atoms or a branched or cyclic alkyl group having 3 to 10 C-atoms, wherein one or more H-atoms may be replaced by D or F, or an aromatic or heteroaromatic ring system having 5 to 24 aromatic ring atoms, each of which may be substituted by one or more radicals R¹; wherein two adjacent radicals R, or R with R¹ can also form together a mono- or polycyclic, aliphatic or aromatic ring system.

Preferred radicals R¹, which are bonded to R, are at each occurrence the same or different, and are H, D, F, N(R²)₂, CN, a straight-chain alkyl group having 1 to 10 carbon atoms, or an alkenyl group having 2 to 10 carbon atoms, or a branched or cyclic alkyl group having 3 to 10 carbon atoms, wherein the alkyl group may in each case be substituted by one or more radicals R², or an aromatic or heteroaromatic ring system having 5 to 24 aromatic ring atoms, which may in each case be substituted by one or more radicals R²; wherein two or more adjacent radicals R¹ can together form a monocyclic or polycyclic aliphatic ring system. Particularly preferred radicals R¹, which are bonded to R, are at each occurrence the same or different, and are H, F, CN, a straight-chain alkyl group having 1 to 5 C-atoms or a branched or cyclic alkyl group having 3 to 5 C-atoms, each of which can be substituted by one or more radicals R², or an aromatic or heteroaromatic ring system having 5 to 13 aromatic ring atoms, each of which can be substituted by one or more radicals R²; wherein two or more adjacent radicals R¹ can form a monocyclic or polycyclic aliphatic ring system with each other.

Preferred radicals R² at each occurrence are the same or different and are H, F or an aliphatic carbon radical having 1 to 5 carbon atoms or an aromatic carbon radical having 6 to 12 carbon atoms; in this case, two or more substituents R² can also form a mono- or polycyclic aliphatic ring system with each other.

The above preferred embodiments may be combined with each other as desired within the scope of the claims. In a particularly preferred embodiment of the invention, the above preferred embodiments apply simultaneously.

The compounds according to the invention are chiral structures. Depending on the exact structure of the complexes and ligands, the formation of diastereomers and multiple pairs of enantiomers is possible.

The complexes according to the invention then comprise both the mixtures of the various diastereomers or the corresponding racemates and the individual isolated diastereomers or enantiomers.

In the ortho-metalation reaction of the ligands, the associated bimetallic complexes typically arise as a mixture of \hat{ }\hat{ }- and ΔΔ-isomers as well as Δ\hat{ }- and \hat{ }Δ-isomers. A more detailed description of the formation of possible isomers and the separation of enantiomers or diastereomers can be found in WO 2018/041769, the explanations given therein being equally applicable to the complexes of the present invention.

The synthesis of the compounds according to the invention can be carried out by reacting the corresponding free ligand with iridium compounds. Therefore, a further object of the present invention is a process for the preparation of the compounds according to the invention by reaction of the corresponding free ligands with iridium alcoholates of formula (Ir-1), with iridium ketoketonates of formula (Ir-2), with iridium halides of formula (Ir-3) or with iridium carboxylates of formula (Ir-4),

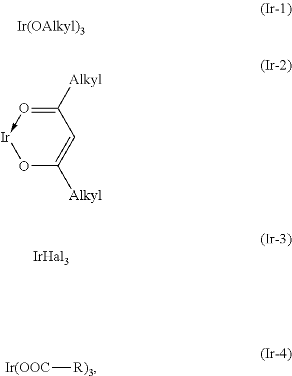

wherein R has the meanings given above, Hal=F, Cl, Br, or I, alkyl stands for an alkyl group with 1 to 4 C-atoms, and the iridium educts can also be present as the corresponding hydrates. Herein, R in formula (Ir-4) preferably stands for an alkyl group with 1 to 4 C-atoms.

Iridium compounds bearing alcoholate and/or halide and/or hydroxy as well as ketoketonate residues can also be used. These compounds may also be charged. Corresponding iridium compounds that are particularly suitable as reactants are disclosed in WO 2004/085449. Particularly suitable are [IrCl₂(acac)₂]-, for example Na[IrCl₂(acac)₂], metal complexes with acetylacetonate derivatives as ligands, for example Ir(acac)₃ or tris(2,2,6,6-tetramethylheptane-3,5-dionato)iridium, and IrCl₃ xH₂O, wherein x usually stands for a number between 2 and 4.

The synthesis of the complexes is preferably carried out as described in WO 2002/060910 and in WO 2004/085449. Synthesis in an organic acid or a mixture of an organic acid and an organic solvent, as described in WO 2021/013775, is also particularly suitable, with particularly suitable reaction media being, for example, acetic acid or a mixture of salicylic acid and an organic solvent, for example mesitylene. In this context, the synthesis can also be activated thermally, photochemically and/or by microwave radiation. Furthermore, the synthesis can also be carried out in an autoclave at elevated pressure and/or temperature.

The reactions can be carried out without the addition of solvents or melting aids in a melt of the corresponding ligands to be o-metalated. If necessary, solvents or melting aids can also be added. Suitable solvents are protic or aprotic solvents, such as aliphatic and/or aromatic alcohols (methanol, ethanol, iso-propanol, t-butanol, etc.), oligo- and polyalcohols (ethylene glycol, 1,2-propanediol, glycerol, etc.), alcohol ethers (ethoxyethanol, diethylene glycol, triethylene glycol, polyethylene glycol, etc.), ethers (di- and triethyleneglycol dimethylether, diphenyl ether, etc.), aromatic, heteroaromatic and or aliphatic hydrocarbons (toluene, xylene, mesitylene, chlorobenzene, pyridine, lutidine, quinoline, isoquinoline, tridecane, hexadecane, etc.), amides (DMF, DMAC, etc.), lactams (NMP), sulfoxides (DMSO) or sulfones (dimethyl sulfone, sulfolane, etc.). Suitable melting aids are compounds that are solid at room temperature but melt and dissolve the reactants when the reaction mixture is heated, resulting in a homogeneous melt. Particularly suitable are biphenyl, m-terphenyl, triphenylene, R- or S-binaphthol, or also the corresponding racemate, 1,2-, 1,3-, 1,4-bisphenoxybenzene, triphenylphosphine oxide, 18-Crone-6, phenol, 1-naphthol, hydroquinone, propofol, etc. The use of hydroquinone is particularly preferred.

The synthesis of the fully or partially deuterated complexes is possible either by using the partially or fully deuterated ligand in the complexation reaction and/or by deuterating the complex after the complexation reaction, as also shown in the example section.

By these methods, optionally followed by purification, such as recrystallization or sublimation, the compounds of the invention according to formula (1) can be obtained in high purity, preferably more than 99% (determined by ¹H-NMR and/or HPLC).

Formulations of the iridium complexes according to the invention are required for processing them from liquid phase, for example by spin coating or by printing processes. These formulations may be, for example, solutions, dispersions or emulsions. It may be preferred to use mixtures of two or more solvents for this purpose. Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, a-terpineol, benzothiazole, butyl benzoate, cumene, cyclohexanol, cyclohexanone, cyclohexylbenzene, decalin, dodecylbenzene, ethyl benzoate, indane, NMP, p-cymene, phenetol, 1,4-diisopropylbenzene, dibenzyl ether, diethyleneglycol butyl methyl ether, triethyleneglycol butyl methyl ether, diethyleneglycol dibutyl ether, triethyleneglycol dimethyl ether, diethyleneglycol monobutyl ether, tripropyleneglycol dimethyl ether, tetraethyleneglycol dimethyl ether, 2-isopropylnaphthalene, pentylbenzene, hexylbenzene, heptylbenzene, octylbenzene, 1,1-bis(3,4-dimethylphenyl)ethane, hexamethylindane, 2-methylbiphenyl, 3-methylbiphenyl, 1-methylnaphthalene, 1-ethylnaphthalene, ethyl octanoate, diethyl sebacate, octyl octanoate, heptylbenzene, menthyl isovalerate, cyclohexyl hexanoate or mixtures of these solvents.

A further object of the present invention is therefore a formulation comprising at least one compound according to the invention and at least one further compound. The further compound may be, for example, a solvent, in particular one of the solvents mentioned above or a mixture of these solvents. However, the further compound may also be a further organic or inorganic compound that is also used in the electronic device, for example one or more matrix materials and/or one or more further phosphorescent emitters. This further compound may also be polymeric.

Still another object of the present invention is an electronic device comprising at least one compound according to the invention.

The compound according to the invention can be used in the electronic device as an active component, preferably as an emitter in the emissive layer or as a hole or electron transporting material in a hole or electron transporting layer, or as an oxygen sensitizer or as a photoinitiator or photocatalyst. Thus, another object of the present invention is to use a compound of the invention in an electronic device or as an oxygen sensitizer or as a photoinitiator or photocatalyst. Enantiomerically pure iridium complexes according to the invention are suitable as photocatalysts for chiral photoinduced syntheses.

An electronic device is understood to be a device comprising an anode, a cathode and at least one layer, said layer comprising at least one organic or organometallic compound. Thus, the electronic device according to the invention comprises an anode, a cathode and at least one layer comprising at least one iridium complex according to the invention. In this context, preferred electronic devices are selected from the group consisting of organic electroluminescent devices (OLEDs, PLEDs), organic integrated circuits (O-ICs), organic field-effect transistors (O-FETs), organic thin-film transistors (O-TFTs), organic-light-emitting transistors (O-LETs), organic solar cells (O-SCs), wherein this includes both purely organic solar cells and dye-sensitized solar cells, organic optical detectors, organic photoreceptors, organic field quench devices (O-FQDs), light-emitting electrochemical cells (LECs), oxygen sensors or organic laser diodes (O-Lasers), containing in at least one layer at least one compound of the invention. Compounds that emit in the infrared are suitable for use in organic infrared electroluminescent devices and infrared sensors. Organic electroluminescent devices are particularly preferred. Active components are generally the organic or inorganic materials which are interposed between the anode and cathode, for example charge injection, charge transport or charge blocking materials, but in particular emission materials and matrix materials. The compounds according to the invention show particularly good properties as emission materials in organic electroluminescent devices. Thus, a preferred embodiment of the invention is organic electroluminescent devices. Furthermore, the compounds according to the invention can be used for the generation of singlet oxygen or in photocatalysis.

In addition to the cathode, anode and the at least one emitting layer, the organic electroluminescent device may contain further layers, for example one or more hole injection layers, hole transport layers, hole blocking layers, electron transport layers, electron injection layers, exciton blocking layers, electron blocking layers, charge generation layers and/or organic or inorganic p/n junctions. In this context, it is possible that one or more hole transport layers are p-doped, for example with metal oxides, such as MoO₃ or WO₃, or with (per)fluorinated electron-poor aromatics or with electron-poor cyano-substituted heteroaromatics (e.g., according to JP 4747558, JP 2006-135145, US 2006/0289882, WO 2012/095143), or with quinoid systems (e.g. e.g. according to EP1336208) or with Lewis acids, or with boranes (e.g. according to US 2003/0006411, WO 2002/051850, WO 2015/049030) or with carboxylates of the elements of the 3rd, 4th or 5th main group (WO 2015/018539) and/or that one or more electron transport layers are n-doped.

Likewise, interlayers can be introduced between two emitting layers, which, for example, have an exciton-blocking function and/or control the charge balance in the electroluminescent device and/or generate charges (charge-generation layers, e.g., in layer systems with multiple emitting layers, e.g., in white-emitting OLED devices). It should be noted, however, that each of these layers need not necessarily be present.

In this context, the organic electroluminescence device may contain one emitting layer, or it may contain several emitting layers. When multiple emitting layers are present, they preferably have a total of multiple emission maxima between 380 nm and 750 nm, resulting in overall white emission, i.e., different emitting compounds that can fluoresce or phosphoresce are used in the emitting layers. In particular, three-layer systems are preferred, where the three layers show blue, green and orange or red emission (for the principle structure see e.g., WO 2005/011013) or systems which have more than three emitting layers. It can also be a hybrid system, wherein one or more layers fluoresce, and one or more other layers phosphoresce. Tandem OLEDs are a preferred embodiment. White emitting organic electroluminescent devices can be used for lighting applications or, with color filters, for full-color displays.

In a preferred embodiment of the invention, the organic electroluminescent device contains the iridium complex of the invention as an emitting compound in one or more emitting layers.

Many of the compounds according to the invention emit light in the red spectral range. However, it is also possible, by suitable choice of ligands and substitution patterns, to shift the emission on the one hand into the infra-red range and on the other hand to shift it hypsochromically, preferably into the orange or yellow range.

When the iridium complex according to the invention is used as an emitting compound in an emitting layer, it is preferably used in combination with one or more matrix materials. The mixture of the iridium complex according to the invention and the matrix material contains between 0.1 and 99 vol %, preferably between 1 and 90 vol %,—particularly preferably between 3 and 40 vol %-, especially between 5 and 20 vol % of the iridium complex according to the invention relative to the total mixture of emitter and matrix material.

Accordingly, the mixture contains between 99.9 and 1 vol. %, preferably between 99 and 10 vol. %, particularly preferably between 97 and 60 vol. %, especially between 95 and 85 vol. % of the matrix material relative to the total mixture of emitter and matrix material.

In general, all materials known in the prior art can be used as matrix material. Preferably, the triplet level of the matrix material is higher than the triplet level of the emitter.

Suitable matrix materials for the compounds according to the invention are ketones, phosphine oxides, sulfoxides and sulfones, e.g. according to WO 2004/013080, WO 2004/093207, WO 2006/005627 or WO 2010/006680, triarylamines, carbazole derivatives, e.g. CBP (N,N-biscarbazolylbiphenyl), m-CBP or carbazole derivatives disclosed in WO 2005/039246, US 2005/0069729, JP 2004/288381, EP 1205527, WO 2008/086851 or US 2009/0134784, biscarbazole derivatives, indolocarbazole derivatives, e.g. e.g. according to WO 2007/063754 or WO 2008/056746, indenocarbazole derivatives, e.g. according to WO 2010/136109 or WO 2011/000455, azacarbazoles, e.g. according to EP 1617710, EP 1617711, EP 1731584, JP 2005/347160, bipolar matrix materials, e.g. according to WO 2007/137725, silanes, e.g. according to WO 2005/111172, azaboroles or boronic esters, e.g. according to WO 2006/117052, diazasilol derivatives, e.g. according to WO 2010/054729, diazaphosphol derivatives, e.g. according to WO 2010/054730, triazine derivatives, e.g. according to WO 2010/015306, WO 2007/063754 or WO 2008/056746, pyrimidine derivatives, quinazoline derivatives, quinoxaline derivatives, zinc complexes, e.g. according to EP 652273 or WO 2009/062578, dibenzofuran derivatives, e.g. according to WO 2009/148015 or WO 2015/169412, aza or diazadibenzofuran derivatives, dibenzothiophene derivatives, triphenylene derivatives or bridged carbazole derivatives, e.g. according to US 2009/0136779, WO 2010/050778, WO 2011/042107 or WO 2011/088877. For solution processed OLEDs, suitable matrix materials include polymers, e.g., according to WO 2012/008550 or WO 2012/048778, oligomers or dendrimers, e.g., according to Journal of Luminescence 183 (2017), 150-158.

It may also be preferred to use several different matrix materials as a mixture, in particular at least one electron-conducting matrix material and at least one hole-conducting matrix material. For example, one preferred combination is the use of a triazine derivative with a triarylamine derivative or a carbazole derivative as a mixed matrix. Equally preferred is the use of a mixture of one or more charge transporting matrix materials and an electrically inert matrix material (so-called “wide bandgap host”), which is not or not significantly involved in charge transport, as described, for example, in WO 2010/108579 or WO 2016/184540. Equally preferred is the use of two electron transporting matrix materials, for example triazine derivatives and lactam derivatives, as described e.g., in WO 2014/094964.

It is not difficult for the skilled person to draw on a variety of materials known in the prior art to select suitable materials for use in the layers of the organic electroluminescent device described above. In doing so, the person skilled in the art makes common considerations concerning the chemical and physical properties of the materials, since it is known to him that the materials in an organic electroluminescence device are interrelated. This concerns, for example, the energy positions of the orbitals (HOMO, LUMO) or the position of triplet and singlet energies, but also other material properties.

Preferred electron transporting matrix materials are selected from the group consisting of triazine derivatives, pyrimidine derivatives, quinazoline derivatives and quinoxaline derivatives. Preferred triazine, pyrimidine, quinazoline and quinoxaline derivatives, respectively, which can be used as a mixture together with the compounds of the invention are the compounds of the following formulae (eTMM1), (eTMM2), (eTMM3) and (eTMM4),

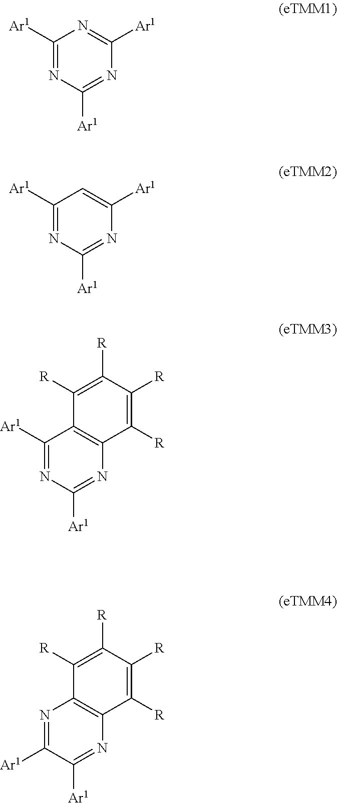

wherein R and R¹ are as defined above and Ar¹ is the same or different at each occurrence and is an aromatic or heteroaromatic ring system having 5 to 40 aromatic ring atoms, each of which may be substituted by one or more radicals R¹.

Particularly preferred are the triazine derivatives of formula (eTMM1) and the quinazoline derivatives of formula (eTMM4), especially the triazine derivatives of formula (eTMM1).

In a preferred embodiment of the invention, Ar¹ in the formulas (eTMM1) to (eTMM4) is at each occurrence the same or different, and is an aromatic or heteroaromatic ring system having 6 to 30 aromatic ring atoms, in particular having 6 to 24 aromatic ring atoms, which may be substituted by one or more radicals R¹.

Examples of suitable triazine compounds, which can be used as matrix materials together with the compounds according to the invention, are the compounds shown in the following table.

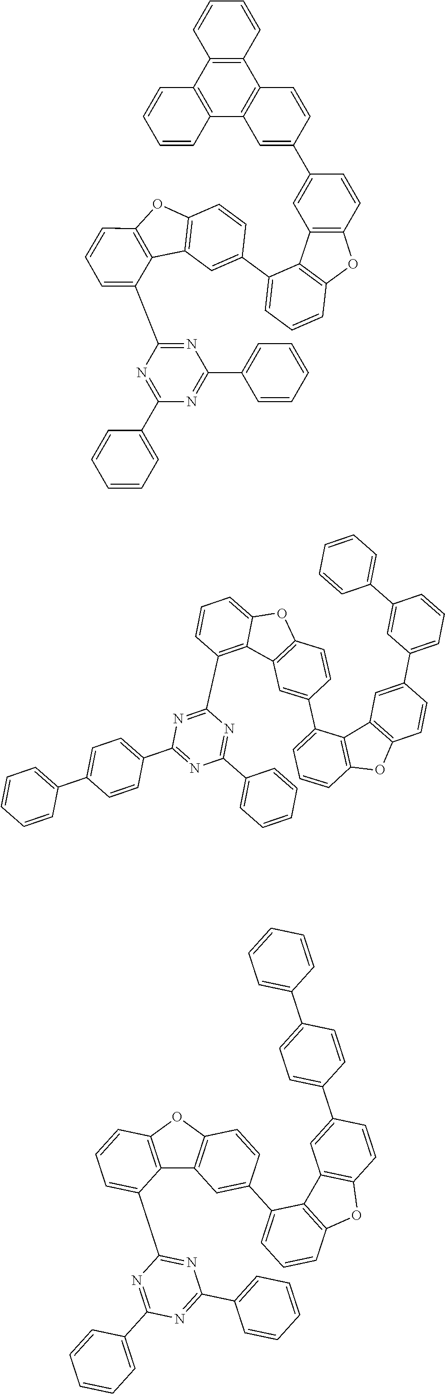 [SMILES: c1ccc(-c2nc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1 ; c1ccc(-c2ccc(-c3nc(-c4ccccc4)nc(-c4cccc5oc6ccc(-c7cccc8oc9ccc(-c%10cccc(-c%11ccccc%11)c%10)cc9c78)cc6c45)n3)cc2)cc1 ; c1ccc(-c2ccc(-c3ccc4oc5cccc(-c6ccc7oc8cccc(-c9nc(-c%10ccccc%10)nc(-c%10ccccc%10)n9)c8c7c6)c5c4c3)cc2)cc1]

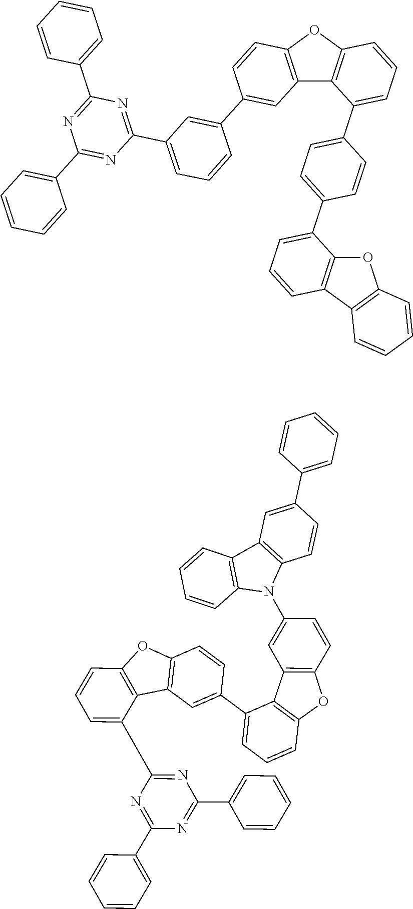 [SMILES: c1ccc(-c2nc(-c3ccccc3)nc(-c3cccc(-c4ccc5oc6cccc(-c7ccc(-c8cccc9c8oc8ccccc89)cc7)c6c5c4)c3)n2)cc1 ; c1ccc(-c2ccc3c(c2)c2ccccc2n3-c2ccc3oc4cccc(-c5ccc6oc7cccc(-c8nc(-c9ccccc9)nc(-c9ccccc9)n8)c7c6c5)c4c3c2)cc1]

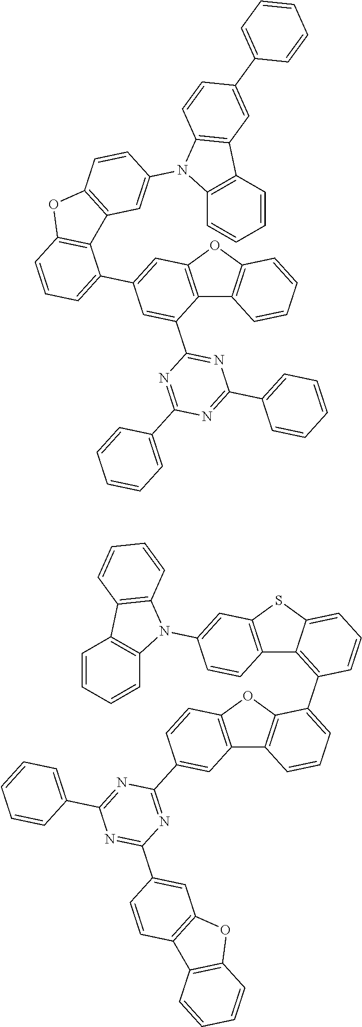 [SMILES: c1ccc(-c2ccc3c(c2)c2ccccc2n3-c2ccc3oc4cccc(-c5cc(-c6nc(-c7ccccc7)nc(-c7ccccc7)n6)c6c(c5)oc5ccccc56)c4c3c2)cc1 ; c1ccc(-c2nc(-c3ccc4c(c3)oc3ccccc34)nc(-c3ccc4oc5c(-c6cccc7sc8cc(-n9c%10ccccc%10c%10ccccc%109)ccc8c67)cccc5c4c3)n2)cc1]

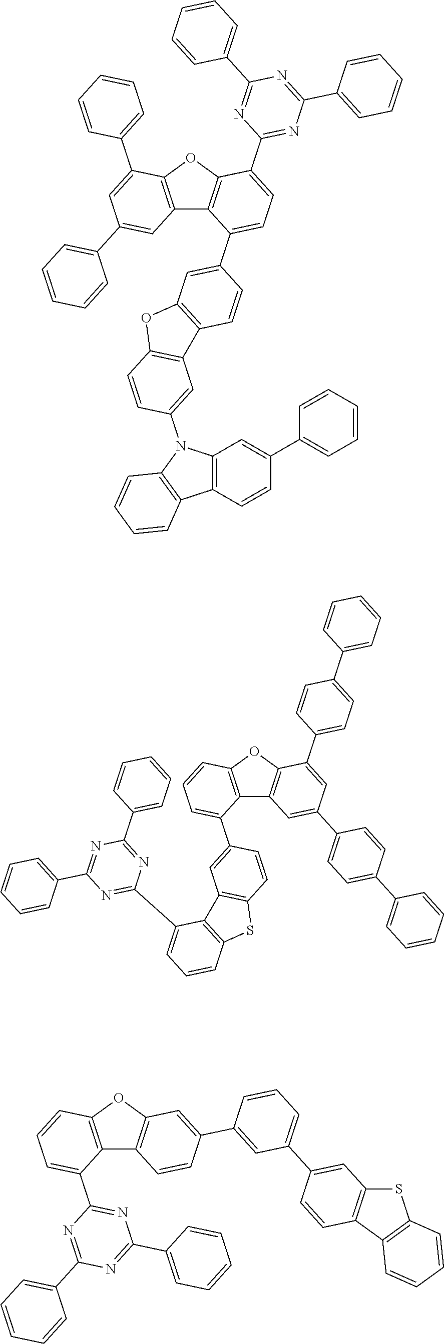 [SMILES: c1ccc(-c2cc(-c3ccccc3)c3oc4c(-c5nc(-c6ccccc6)nc(-c6ccccc6)n5)ccc(-c5ccc6c(c5)oc5ccc(-n7c8ccccc8c8ccc(-c9ccccc9)cc87)cc56)c4c3c2)cc1 ; c1ccc(-c2ccc(-c3cc(-c4ccc(-c5ccccc5)cc4)c4oc5cccc(-c6ccc7sc8cccc(-c9nc(-c%10ccccc%10)nc(-c%10ccccc%10)n9)c8c7c6)c5c4c3)cc2)cc1 ; c1ccc(-c2nc(-c3ccccc3)nc(-c3cccc4oc5cc(-c6cccc(-c7ccc8c(c7)sc7ccccc78)c6)ccc5c34)n2)cc1]

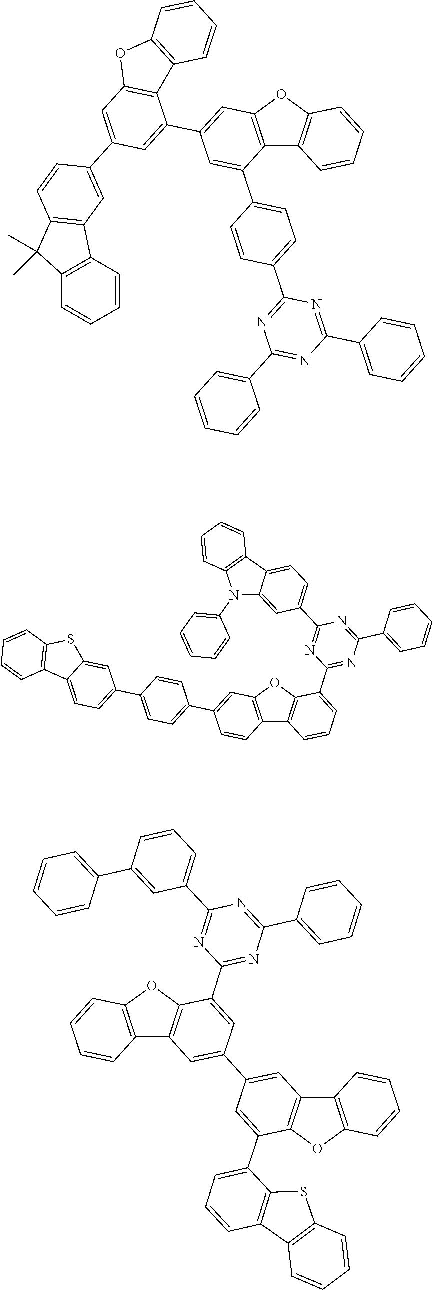 [SMILES: CC1(C)c2ccccc2-c2cc(-c3cc(-c4cc(-c5ccc(-c6nc(-c7ccccc7)nc(-c7ccccc7)n6)cc5)c5c(c4)oc4ccccc45)c4c(c3)oc3ccccc34)ccc21 ; c1ccc(-c2nc(-c3ccc4c5ccccc5n(-c5ccccc5)c4c3)nc(-c3cccc4c3oc3cc(-c5ccc(-c6ccc7c(c6)sc6ccccc67)cc5)ccc34)n2)cc1 ; c1ccc(-c2cccc(-c3nc(-c4ccccc4)nc(-c4cc(-c5cc(-c6cccc7c6sc6ccccc67)c6oc7ccccc7c6c5)cc5c4oc4ccccc45)n3)c2)cc1]

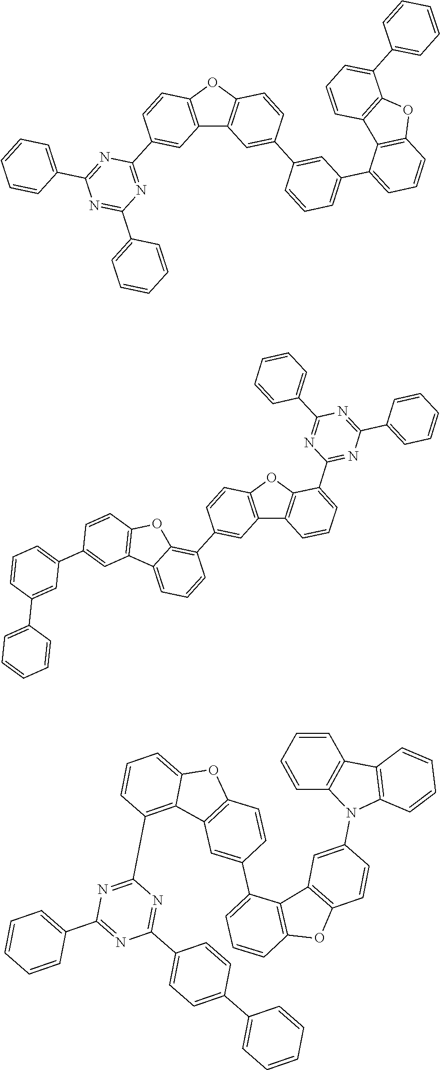 [SMILES: c1ccc(-c2nc(-c3ccccc3)nc(-c3ccc4oc5ccc(-c6cccc(-c7cccc8oc9c(-c%10ccccc%10)cccc9c78)c6)cc5c4c3)n2)cc1 ; c1ccc(-c2cccc(-c3ccc4oc5c(-c6ccc7oc8c(-c9nc(-c%10ccccc%10)nc(-c%10ccccc%10)n9)cccc8c7c6)cccc5c4c3)c2)cc1 ; c1ccc(-c2ccc(-c3nc(-c4ccccc4)nc(-c4cccc5oc6ccc(-c7cccc8oc9ccc(-n%10c%11ccccc%11c%11ccccc%11%10)cc9c78)cc6c45)n3)cc2)cc1]

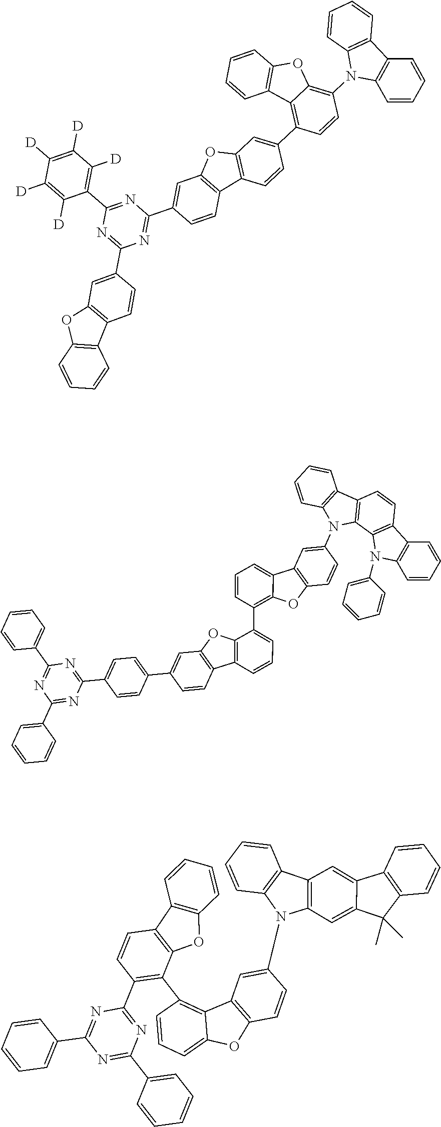 [SMILES: [2H]c1c([2H])c([2H])c(-c2nc(-c3ccc4c(c3)oc3ccccc34)nc(-c3ccc4c(c3)oc3cc(-c5ccc(-n6c7ccccc7c7ccccc76)c6oc7ccccc7c56)ccc34)n2)c([2H])c1[2H] ; c1ccc(-c2nc(-c3ccccc3)nc(-c3ccc(-c4ccc5c(c4)oc4c(-c6cccc7c6oc6ccc(-n8c9ccccc9c9ccc%10c%11ccccc%11n(-c%11ccccc%11)c%10c98)cc67)cccc45)cc3)n2)cc1 ; CC1(C)c2ccccc2-c2cc3c4ccccc4n(-c4ccc5oc6cccc(-c7c(-c8nc(-c9ccccc9)nc(-c9ccccc9)n8)ccc8c7oc7ccccc78)c6c5c4)c3cc21]

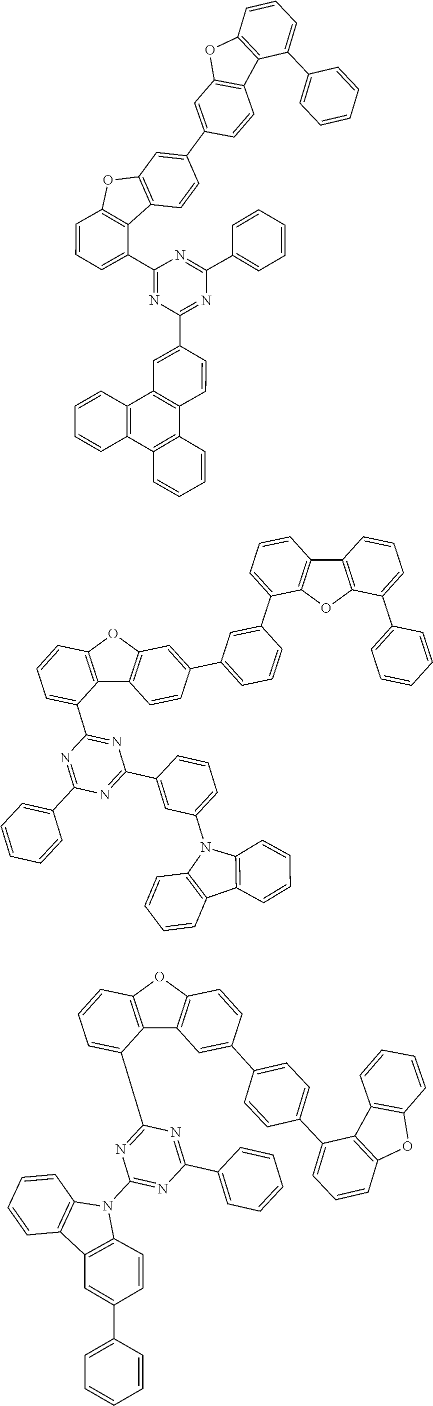 [SMILES: c1ccc(-c2nc(-c3ccc4c5ccccc5c5ccccc5c4c3)nc(-c3cccc4oc5cc(-c6ccc7c(c6)oc6cccc(-c8ccccc8)c67)ccc5c34)n2)cc1 ; c1ccc(-c2nc(-c3cccc(-n4c5ccccc5c5ccccc54)c3)nc(-c3cccc4oc5cc(-c6cccc(-c7cccc8c7oc7c(-c9ccccc9)cccc78)c6)ccc5c34)n2)cc1 ; c1ccc(-c2ccc3c(c2)c2ccccc2n3-c2nc(-c3ccccc3)nc(-c3cccc4oc5ccc(-c6ccc(-c7cccc8oc9ccccc9c78)cc6)cc5c34)n2)cc1]

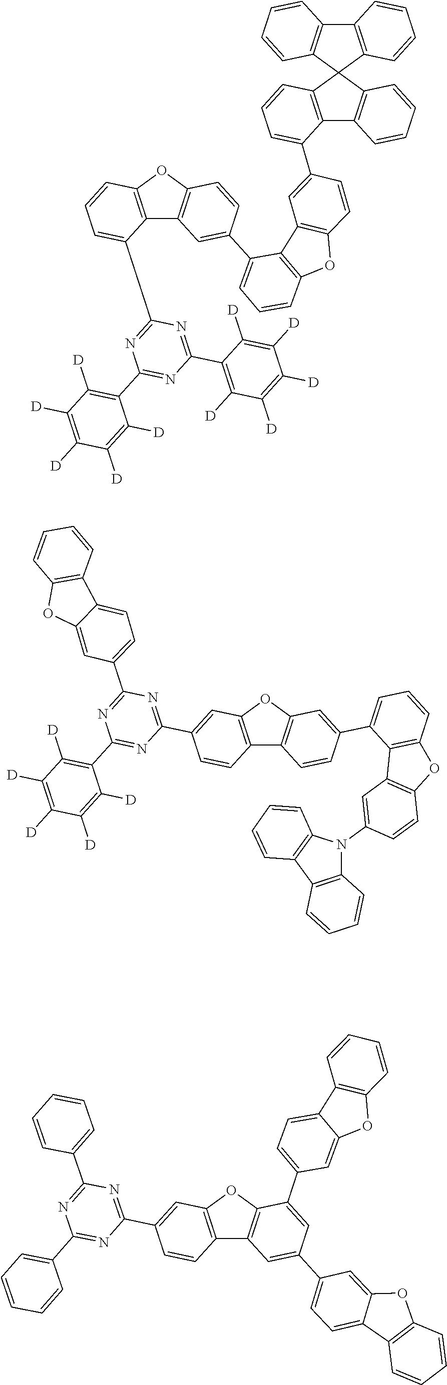 [SMILES: [2H]c1c([2H])c([2H])c(-c2nc(-c3c([2H])c([2H])c([2H])c([2H])c3[2H])nc(-c3cccc4oc5ccc(-c6cccc7oc8ccc(-c9cccc%10c9-c9ccccc9C%109c%10ccccc%10-c%10ccccc%109)cc8c67)cc5c34)n2)c([2H])c1[2H] ; [2H]c1c([2H])c([2H])c(-c2nc(-c3ccc4c(c3)oc3ccccc34)nc(-c3ccc4c(c3)oc3cc(-c5cccc6oc7ccc(-n8c9ccccc9c9ccccc98)cc7c56)ccc34)n2)c([2H])c1[2H] ; c1ccc(-c2nc(-c3ccccc3)nc(-c3ccc4c(c3)oc3c(-c5ccc6c(c5)oc5ccccc56)cc(-c5ccc6c(c5)oc5ccccc56)cc34)n2)cc1]

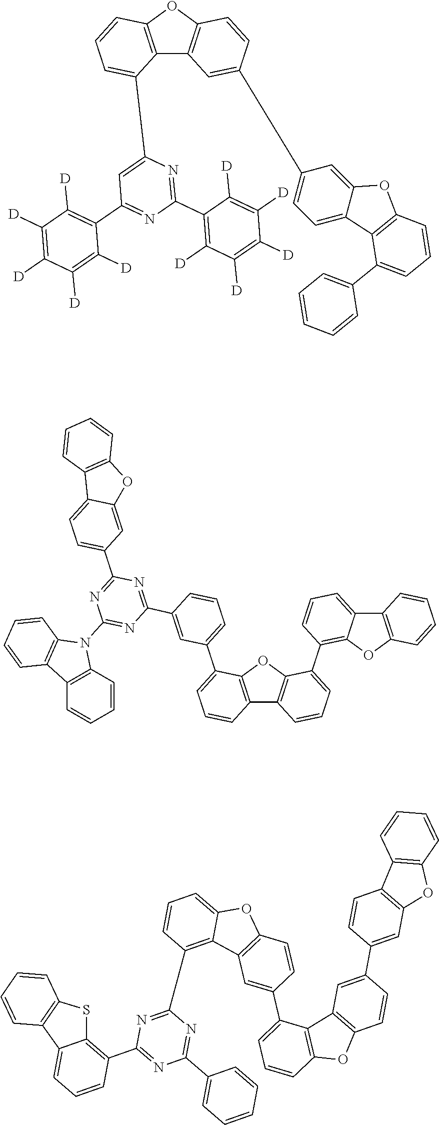 [SMILES: [2H]c1c([2H])c([2H])c(-c2cc(-c3cccc4oc5ccc(-c6ccc7c(c6)oc6cccc(-c8ccccc8)c67)cc5c34)nc(-c3c([2H])c([2H])c([2H])c([2H])c3[2H])n2)c([2H])c1[2H] ; c1cc(-c2nc(-c3ccc4c(c3)oc3ccccc34)nc(-n3c4ccccc4c4ccccc43)n2)cc(-c2cccc3c2oc2c(-c4cccc5c4oc4ccccc45)cccc23)c1 ; c1ccc(-c2nc(-c3cccc4c3sc3ccccc34)nc(-c3cccc4oc5ccc(-c6cccc7oc8ccc(-c9ccc%10c(c9)oc9ccccc9%10)cc8c67)cc5c34)n2)cc1]

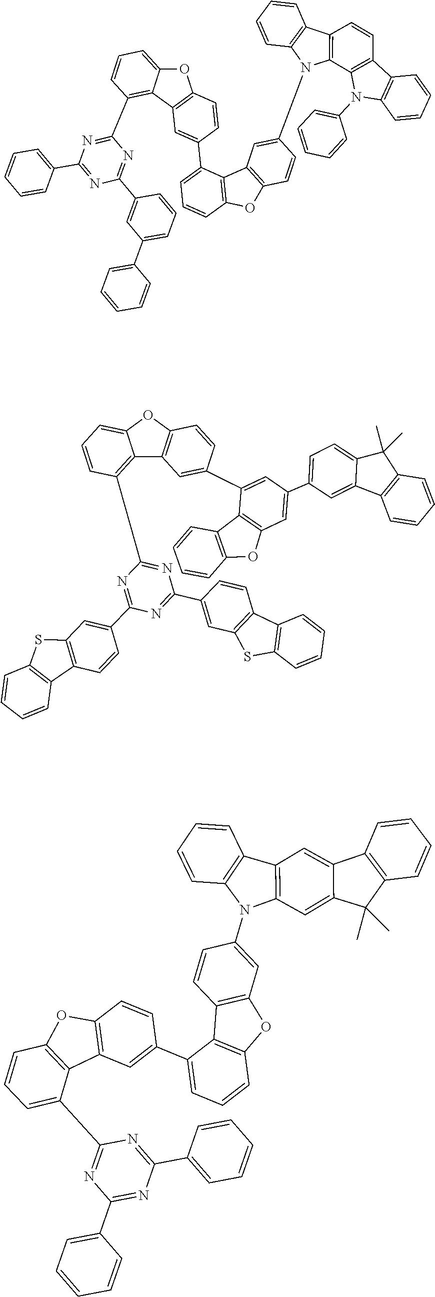 [SMILES: c1ccc(-c2cccc(-c3nc(-c4ccccc4)nc(-c4cccc5oc6ccc(-c7cccc8oc9ccc(-n%10c%11ccccc%11c%11ccc%12c%13ccccc%13n(-c%13ccccc%13)c%12c%11%10)cc9c78)cc6c45)n3)c2)cc1 ; CC1(C)c2ccccc2-c2cc(-c3cc(-c4ccc5oc6cccc(-c7nc(-c8ccc9c(c8)sc8ccccc89)nc(-c8ccc9c(c8)sc8ccccc89)n7)c6c5c4)c4c(c3)oc3ccccc34)ccc21 ; CC1(C)c2ccccc2-c2cc3c4ccccc4n(-c4ccc5c(c4)oc4cccc(-c6ccc7oc8cccc(-c9nc(-c%10ccccc%10)nc(-c%10ccccc%10)n9)c8c7c6)c45)c3cc21]

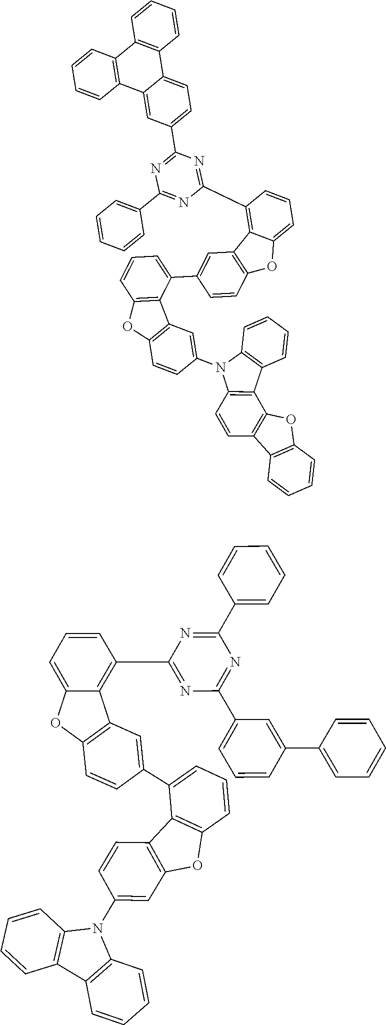 [SMILES: c1ccc(-c2nc(-c3ccc4c5ccccc5c5ccccc5c4c3)nc(-c3cccc4oc5ccc(-c6cccc7oc8ccc(-n9c%10ccccc%10c%10c%11oc%12ccccc%12c%11ccc%109)cc8c67)cc5c34)n2)cc1 ; c1ccc(-c2cccc(-c3nc(-c4ccccc4)nc(-c4cccc5oc6ccc(-c7cccc8oc9cc(-n%10c%11ccccc%11c%11ccccc%11%10)ccc9c78)cc6c45)n3)c2)cc1]

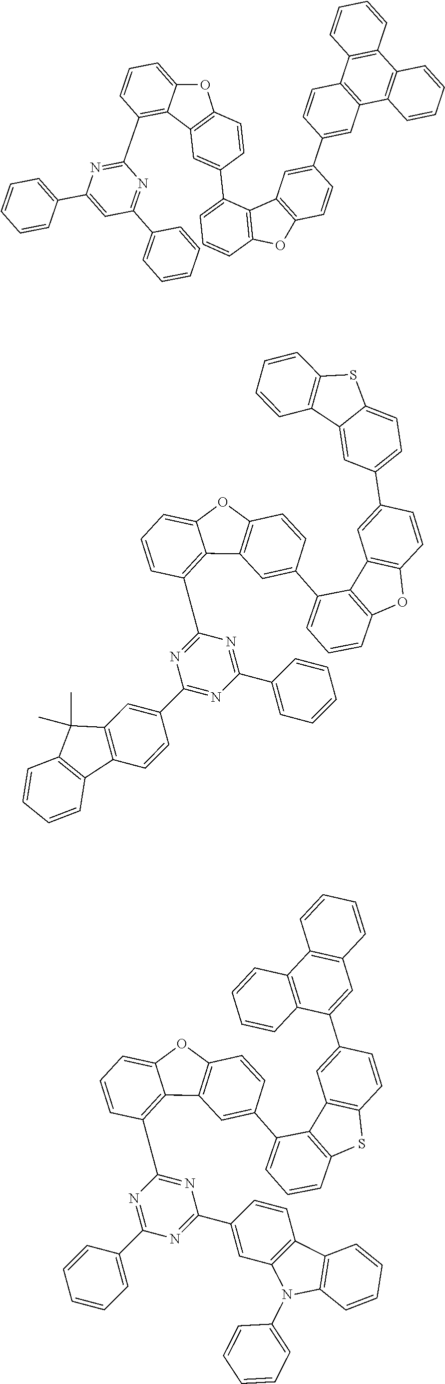 [SMILES: c1ccc(-c2cc(-c3ccccc3)nc(-c3cccc4oc5ccc(-c6cccc7oc8ccc(-c9ccc%10c%11ccccc%11c%11ccccc%11c%10c9)cc8c67)cc5c34)n2)cc1 ; CC1(C)c2ccccc2-c2ccc(-c3nc(-c4ccccc4)nc(-c4cccc5oc6ccc(-c7cccc8oc9ccc(-c%10ccc%11sc%12ccccc%12c%11c%10)cc9c78)cc6c45)n3)cc21 ; c1ccc(-c2nc(-c3ccc4c5ccccc5n(-c5ccccc5)c4c3)nc(-c3cccc4oc5ccc(-c6cccc7sc8ccc(-c9cc%10ccccc%10c%10ccccc9%10)cc8c67)cc5c34)n2)cc1]

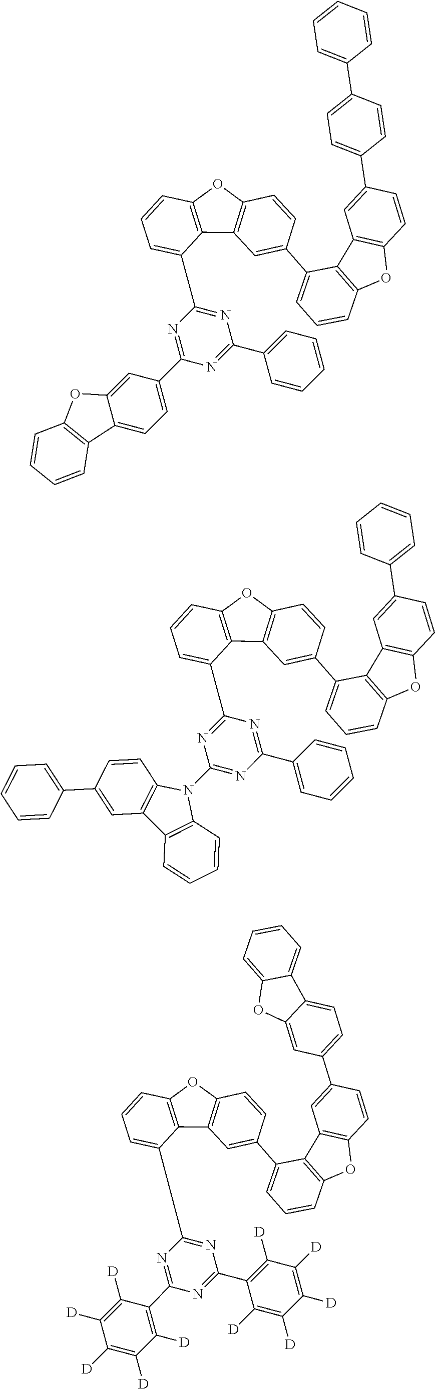 [SMILES: c1ccc(-c2ccc(-c3ccc4oc5cccc(-c6ccc7oc8cccc(-c9nc(-c%10ccccc%10)nc(-c%10ccc%11c(c%10)oc%10ccccc%10%11)n9)c8c7c6)c5c4c3)cc2)cc1 ; c1ccc(-c2ccc3oc4cccc(-c5ccc6oc7cccc(-c8nc(-c9ccccc9)nc(-n9c%10ccccc%10c%10cc(-c%11ccccc%11)ccc%109)n8)c7c6c5)c4c3c2)cc1 ; [2H]c1c([2H])c([2H])c(-c2nc(-c3c([2H])c([2H])c([2H])c([2H])c3[2H])nc(-c3cccc4oc5ccc(-c6cccc7oc8ccc(-c9ccc%10c(c9)oc9ccccc9%10)cc8c67)cc5c34)n2)c([2H])c1[2H]]

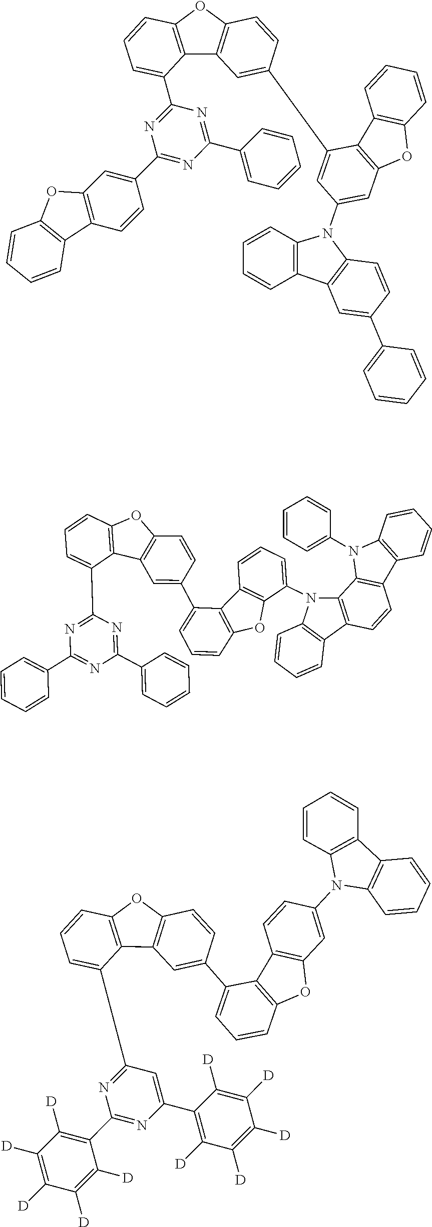 [SMILES: c1ccc(-c2ccc3c(c2)c2ccccc2n3-c2cc(-c3ccc4oc5cccc(-c6nc(-c7ccccc7)nc(-c7ccc8c(c7)oc7ccccc78)n6)c5c4c3)c3c(c2)oc2ccccc23)cc1 ; c1ccc(-c2nc(-c3ccccc3)nc(-c3cccc4oc5ccc(-c6cccc7oc8c(-n9c%10ccccc%10c%10ccc%11c%12ccccc%12n(-c%12ccccc%12)c%11c%109)cccc8c67)cc5c34)n2)cc1 ; [2H]c1c([2H])c([2H])c(-c2cc(-c3cccc4oc5ccc(-c6cccc7oc8cc(-n9c%10ccccc%10c%10ccccc%109)ccc8c67)cc5c34)nc(-c3c([2H])c([2H])c([2H])c([2H])c3[2H])n2)c([2H])c1[2H]]

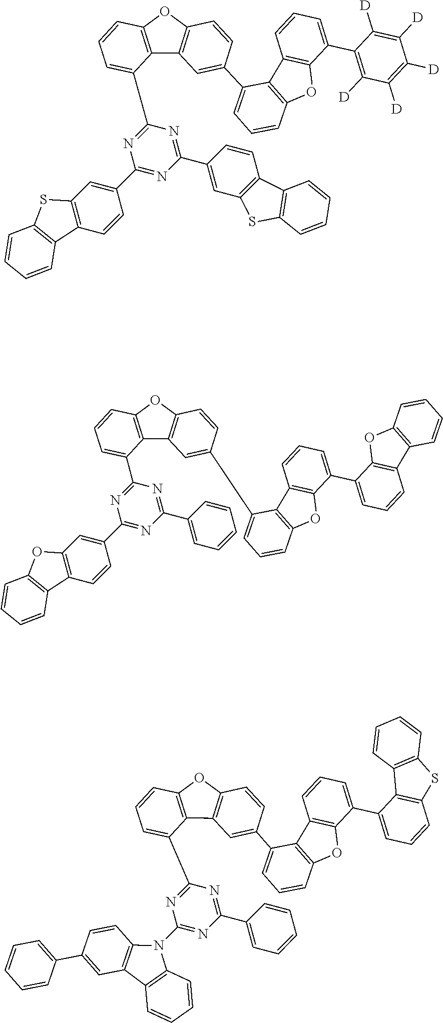 [SMILES: [2H]c1c([2H])c([2H])c(-c2cccc3c2oc2cccc(-c4ccc5oc6cccc(-c7nc(-c8ccc9c(c8)sc8ccccc89)nc(-c8ccc9c(c8)sc8ccccc89)n7)c6c5c4)c23)c([2H])c1[2H] ; c1ccc(-c2nc(-c3ccc4c(c3)oc3ccccc34)nc(-c3cccc4oc5ccc(-c6cccc7oc8c(-c9cccc%10c9oc9ccccc9%10)cccc8c67)cc5c34)n2)cc1 ; c1ccc(-c2ccc3c(c2)c2ccccc2n3-c2nc(-c3ccccc3)nc(-c3cccc4oc5ccc(-c6cccc7oc8c(-c9cccc%10sc%11ccccc%11c9%10)cccc8c67)cc5c34)n2)cc1]

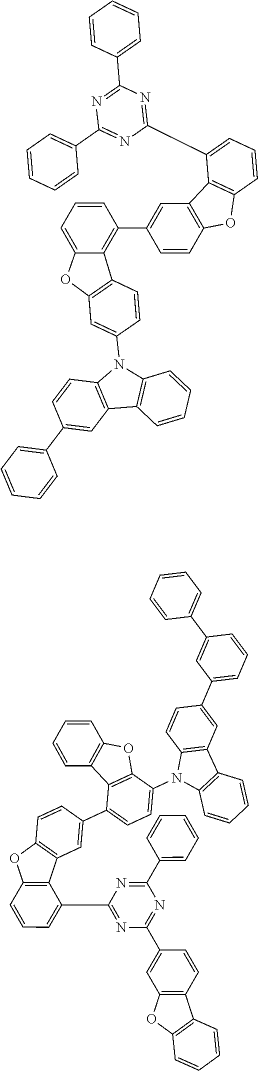 [SMILES: c1ccc(-c2ccc3c(c2)c2ccccc2n3-c2ccc3c(c2)oc2cccc(-c4ccc5oc6cccc(-c7nc(-c8ccccc8)nc(-c8ccccc8)n7)c6c5c4)c23)cc1 ; c1ccc(-c2cccc(-c3ccc4c(c3)c3ccccc3n4-c3ccc(-c4ccc5oc6cccc(-c7nc(-c8ccccc8)nc(-c8ccc9c(c8)oc8ccccc89)n7)c6c5c4)c4c3oc3ccccc34)c2)cc1]

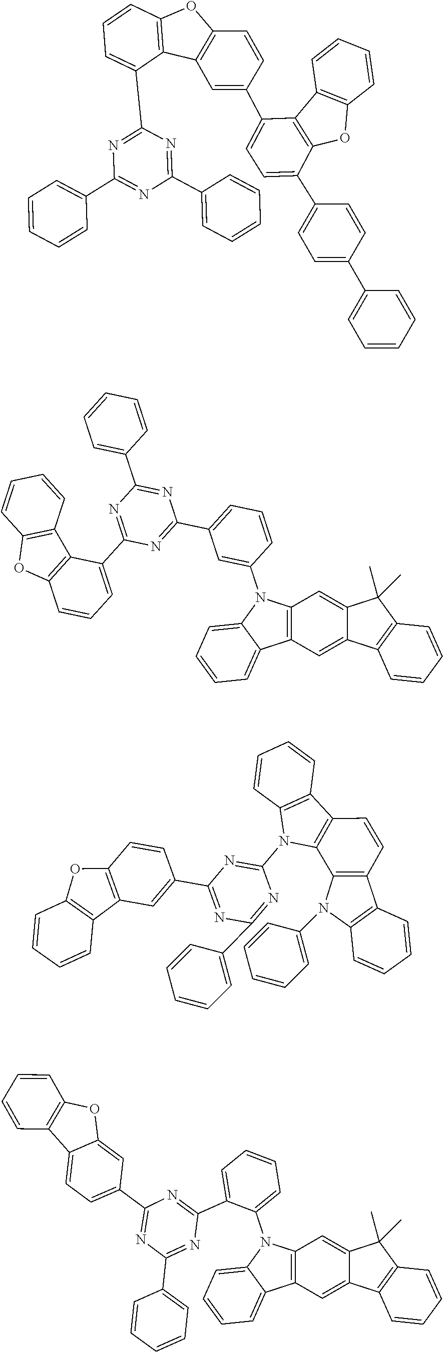 [SMILES: c1ccc(-c2ccc(-c3ccc(-c4ccc5oc6cccc(-c7nc(-c8ccccc8)nc(-c8ccccc8)n7)c6c5c4)c4c3oc3ccccc34)cc2)cc1 ; CC1(C)c2ccccc2-c2cc3c4ccccc4n(-c4cccc(-c5nc(-c6ccccc6)nc(-c6cccc7oc8ccccc8c67)n5)c4)c3cc21 ; c1ccc(-c2nc(-c3ccc4oc5ccccc5c4c3)nc(-n3c4ccccc4c4ccc5c6ccccc6n(-c6ccccc6)c5c43)n2)cc1 ; CC1(C)c2ccccc2-c2cc3c4ccccc4n(-c4ccccc4-c4nc(-c5ccccc5)nc(-c5ccc6c(c5)oc5ccccc56)n4)c3cc21]

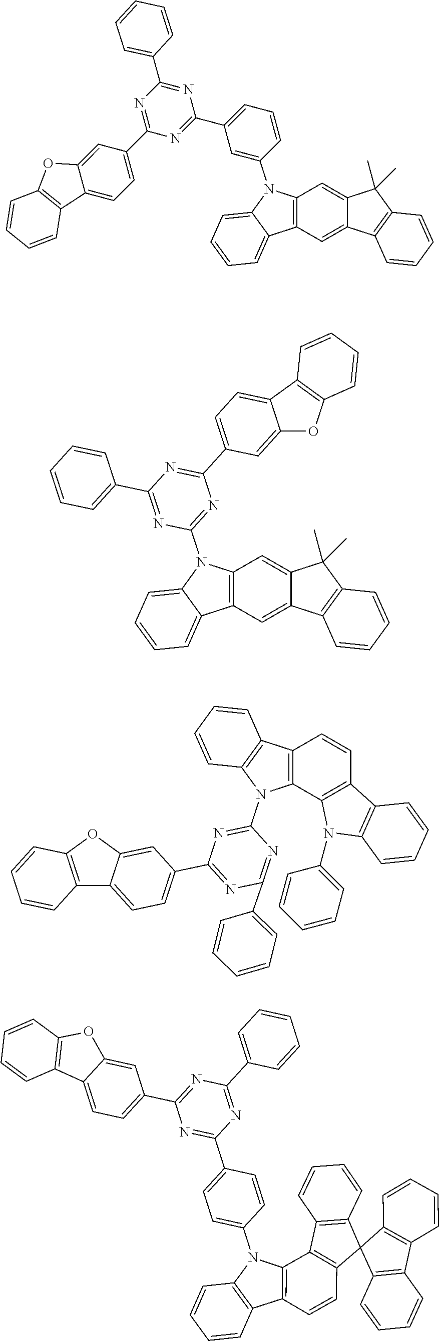

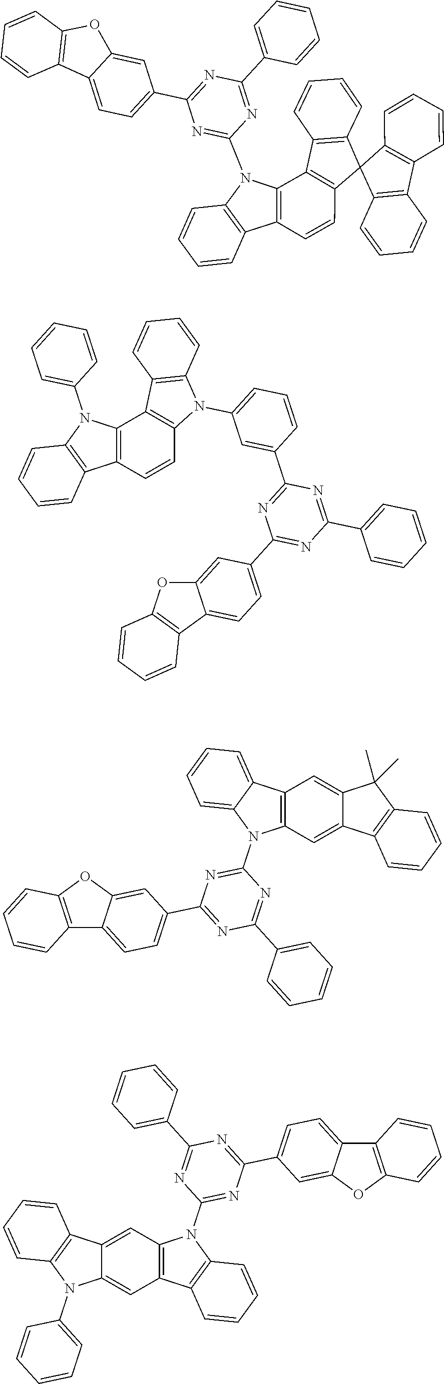 [SMILES: c1ccc(-c2nc(-c3ccc4c(c3)oc3ccccc34)nc(-n3c4ccccc4c4ccc5c(c43)-c3ccccc3C53c4ccccc4-c4ccccc43)n2)cc1 ; c1ccc(-c2nc(-c3cccc(-n4c5ccccc5c5c4ccc4c6ccccc6n(-c6ccccc6)c45)c3)nc(-c3ccc4c(c3)oc3ccccc34)n2)cc1 ; CC1(C)c2ccccc2-c2cc3c(cc21)c1ccccc1n3-c1nc(-c2ccccc2)nc(-c2ccc3c(c2)oc2ccccc23)n1 ; c1ccc(-c2nc(-c3ccc4c(c3)oc3ccccc34)nc(-n3c4ccccc4c4cc5c(cc43)c3ccccc3n5-c3ccccc3)n2)cc1]

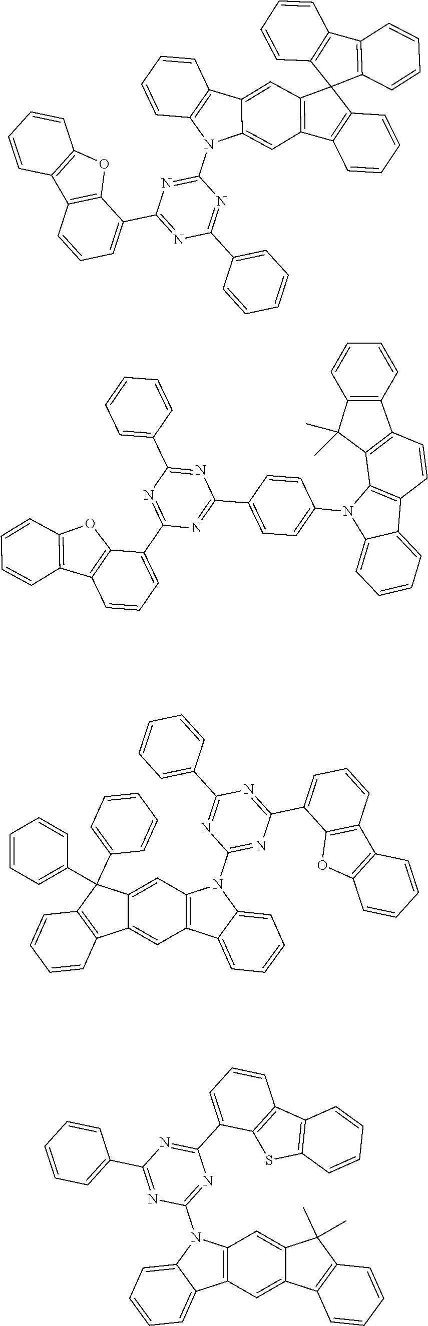 [SMILES: c1ccc(-c2nc(-c3cccc4c3oc3ccccc34)nc(-n3c4ccccc4c4cc5c(cc43)-c3ccccc3C53c4ccccc4-c4ccccc43)n2)cc1 ; CC1(C)c2ccccc2-c2ccc3c4ccccc4n(-c4ccc(-c5nc(-c6ccccc6)nc(-c6cccc7c6oc6ccccc67)n5)cc4)c3c21 ; c1ccc(-c2nc(-c3cccc4c3oc3ccccc34)nc(-n3c4ccccc4c4cc5c(cc43)C(c3ccccc3)(c3ccccc3)c3ccccc3-5)n2)cc1 ; CC1(C)c2ccccc2-c2cc3c4ccccc4n(-c4nc(-c5ccccc5)nc(-c5cccc6c5sc5ccccc56)n4)c3cc21]

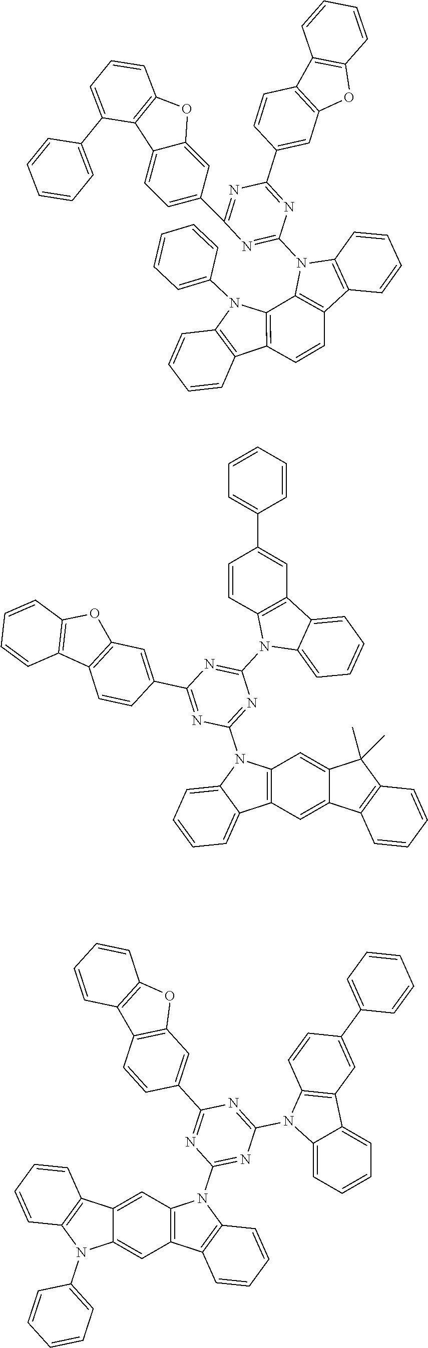 [SMILES: c1ccc(-c2cccc3oc4cc(-c5nc(-c6ccc7c(c6)oc6ccccc67)nc(-n6c7ccccc7c7ccc8c9ccccc9n(-c9ccccc9)c8c76)n5)ccc4c23)cc1 ; CC1(C)c2ccccc2-c2cc3c4ccccc4n(-c4nc(-c5ccc6c(c5)oc5ccccc56)nc(-n5c6ccccc6c6cc(-c7ccccc7)ccc65)n4)c3cc21 ; c1ccc(-c2ccc3c(c2)c2ccccc2n3-c2nc(-c3ccc4c(c3)oc3ccccc34)nc(-n3c4ccccc4c4cc5c(cc43)c3ccccc3n5-c3ccccc3)n2)cc1]

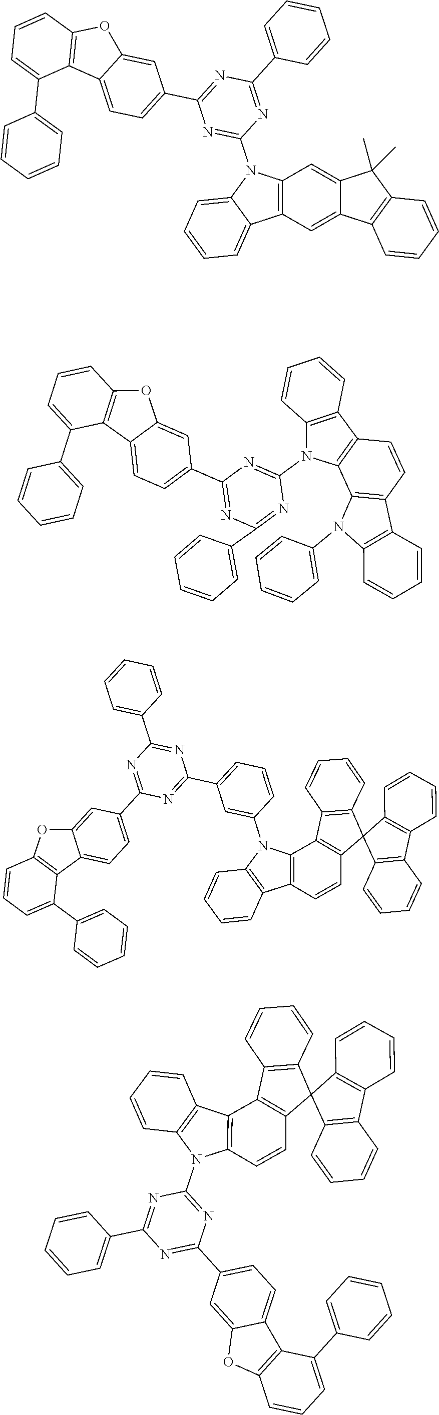

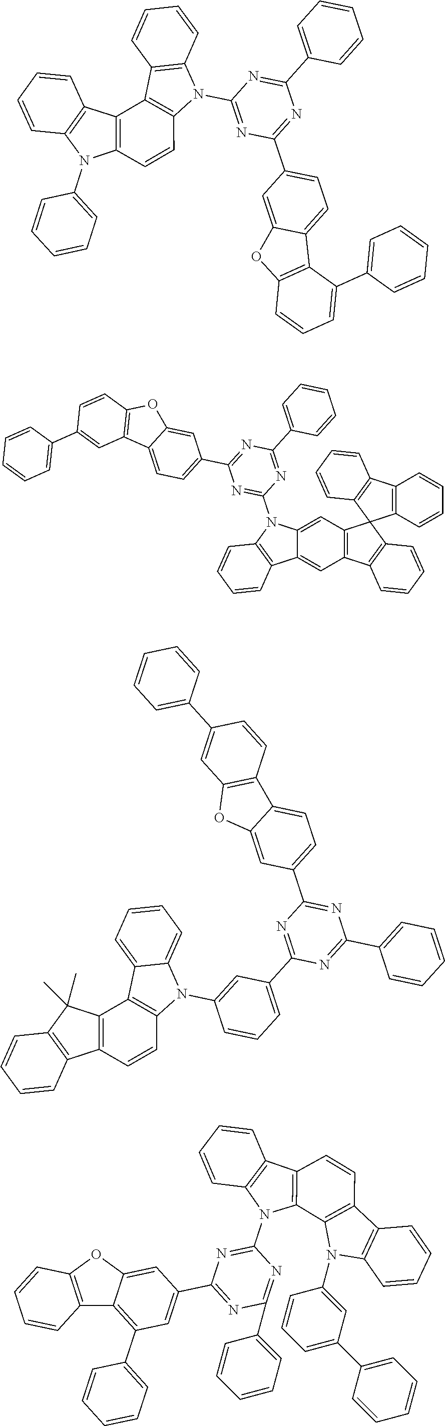 [SMILES: c1ccc(-c2nc(-c3ccc4c(c3)oc3cccc(-c5ccccc5)c34)nc(-n3c4ccccc4c4c5c6ccccc6n(-c6ccccc6)c5ccc43)n2)cc1 ; c1ccc(-c2ccc3oc4cc(-c5nc(-c6ccccc6)nc(-n6c7ccccc7c7cc8c(cc76)C6(c7ccccc7-c7ccccc76)c6ccccc6-8)n5)ccc4c3c2)cc1 ; CC1(C)c2ccccc2-c2ccc3c(c21)c1ccccc1n3-c1cccc(-c2nc(-c3ccccc3)nc(-c3ccc4c(c3)oc3cc(-c5ccccc5)ccc34)n2)c1 ; c1ccc(-c2cccc(-n3c4ccccc4c4ccc5c6ccccc6n(-c6nc(-c7ccccc7)nc(-c7cc(-c8ccccc8)c8c(c7)oc7ccccc78)n6)c5c43)c2)cc1]

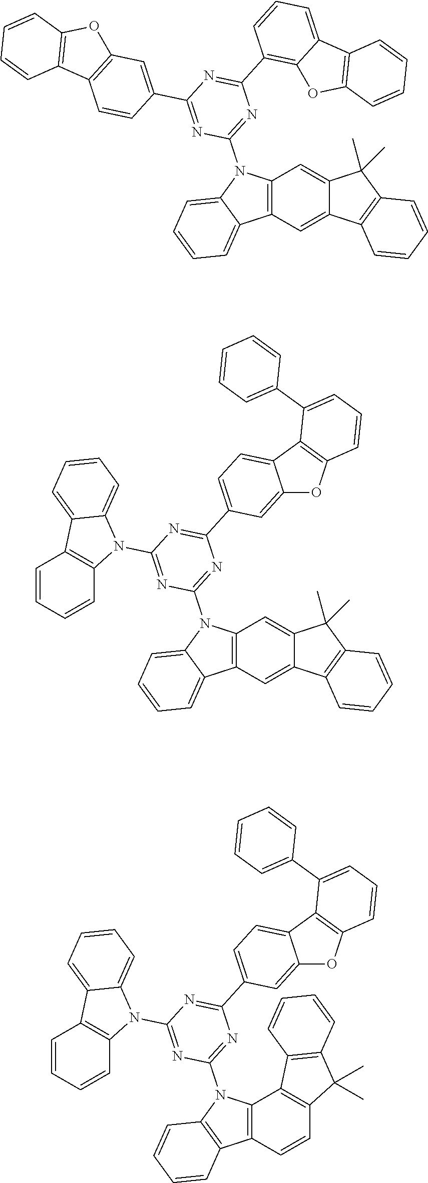 [SMILES: CC1(C)c2ccccc2-c2cc3c4ccccc4n(-c4nc(-c5ccc6c(c5)oc5ccccc56)nc(-c5cccc6c5oc5ccccc56)n4)c3cc21 ; CC1(C)c2ccccc2-c2cc3c4ccccc4n(-c4nc(-c5ccc6c(c5)oc5cccc(-c7ccccc7)c56)nc(-n5c6ccccc6c6ccccc65)n4)c3cc21 ; CC1(C)c2ccccc2-c2c1ccc1c3ccccc3n(-c3nc(-c4ccc5c(c4)oc4cccc(-c6ccccc6)c45)nc(-n4c5ccccc5c5ccccc54)n3)c21]

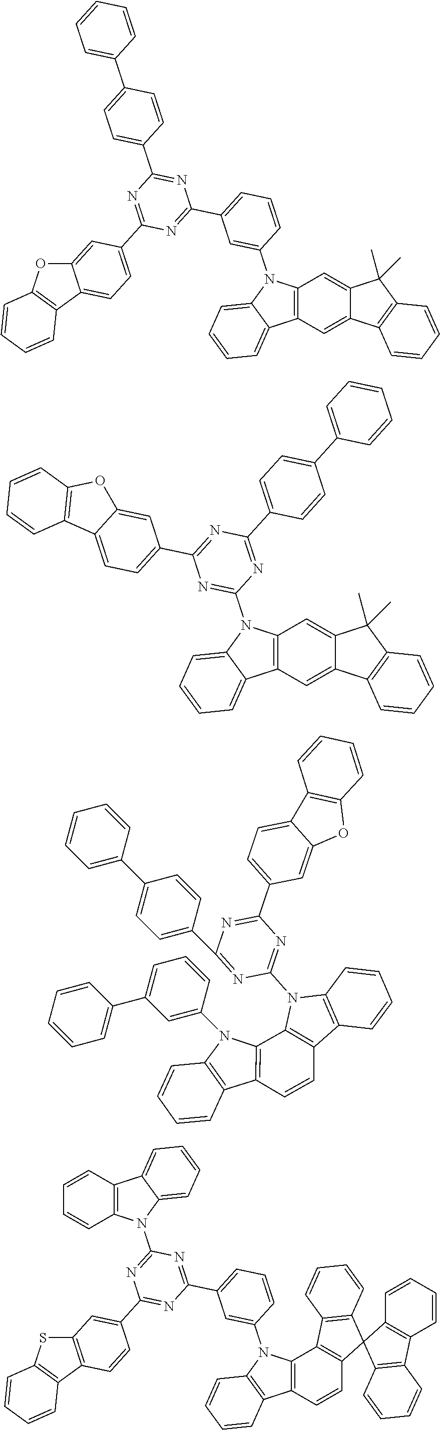

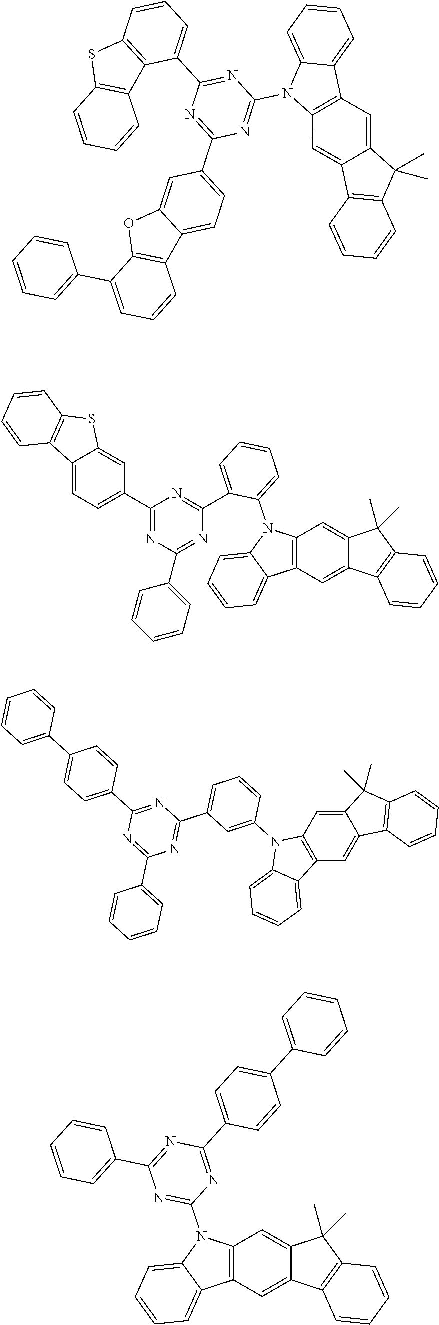 [SMILES: CC1(C)c2ccccc2-c2cc3c(cc21)c1ccccc1n3-c1nc(-c2ccc3c(c2)oc2c(-c4ccccc4)cccc23)nc(-c2cccc3sc4ccccc4c23)n1 ; CC1(C)c2ccccc2-c2cc3c4ccccc4n(-c4ccccc4-c4nc(-c5ccccc5)nc(-c5ccc6c(c5)sc5ccccc56)n4)c3cc21 ; CC1(C)c2ccccc2-c2cc3c4ccccc4n(-c4cccc(-c5nc(-c6ccccc6)nc(-c6ccc(-c7ccccc7)cc6)n5)c4)c3cc21 ; CC1(C)c2ccccc2-c2cc3c4ccccc4n(-c4nc(-c5ccccc5)nc(-c5ccc(-c6ccccc6)cc5)n4)c3cc21]

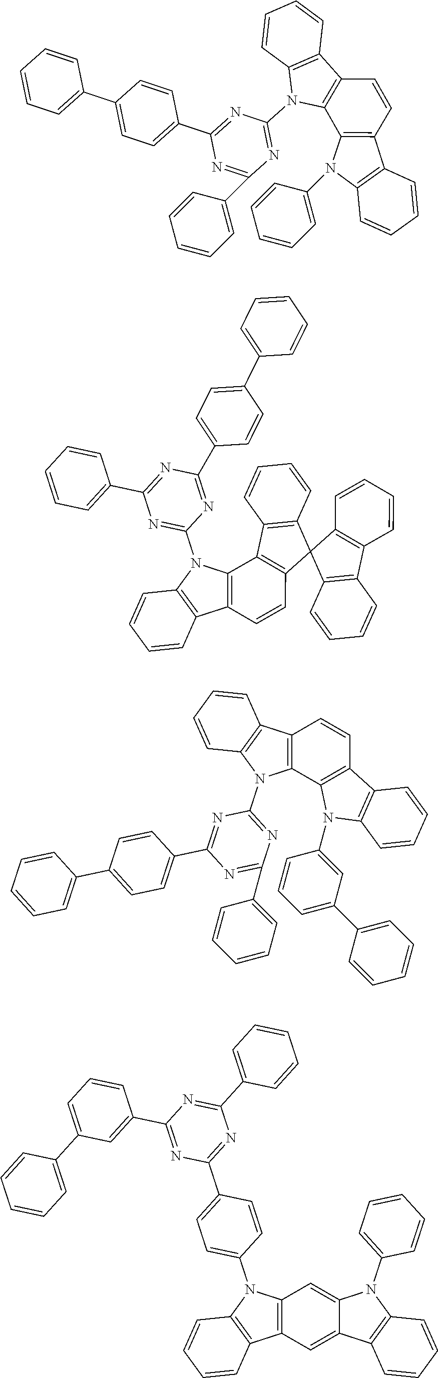 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2ccc(-c3nc(-c4ccccc4)nc(-n4c5ccccc5c5ccc6c(c54)-c4ccccc4C64c5ccccc5-c5ccccc54)n3)cc2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2cccc(-c3nc(-c4ccccc4)nc(-c4ccc(-n5c6ccccc6c6cc7c8ccccc8n(-c8ccccc8)c7cc65)cc4)n3)c2)cc1]

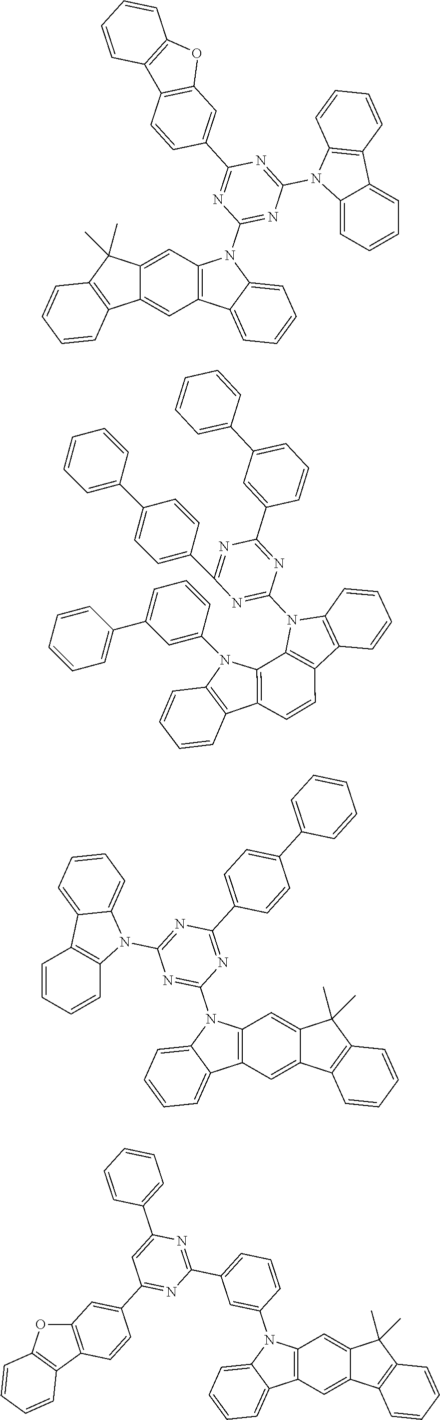

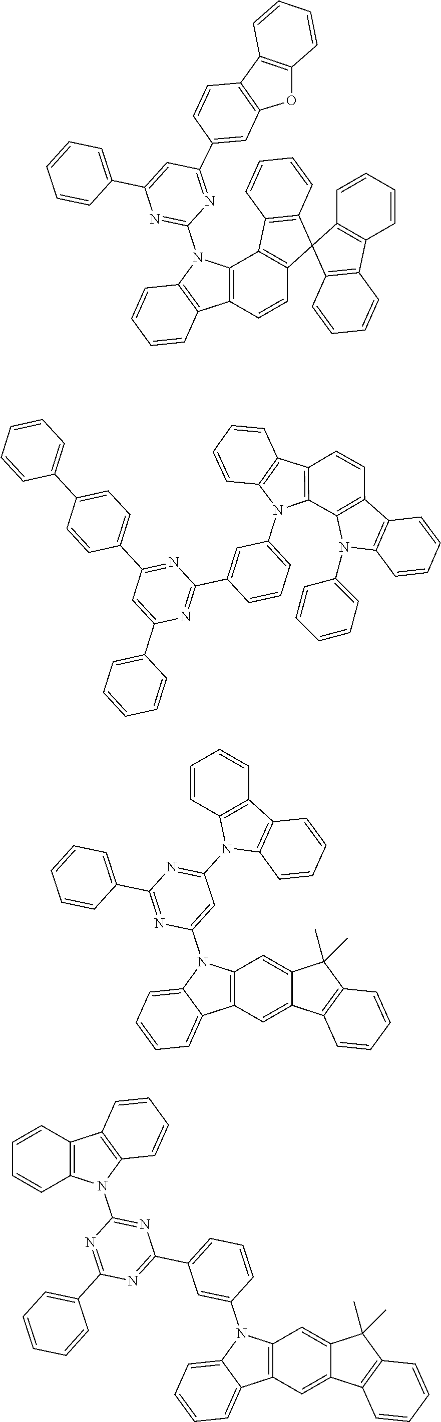 [SMILES: c1ccc(-c2cc(-c3ccc4c(c3)oc3ccccc34)nc(-n3c4ccccc4c4ccc5c(c43)-c3ccccc3C53c4ccccc4-c4ccccc43)n2)cc1 ; c1ccc(-c2ccc(-c3cc(-c4ccccc4)nc(-c4cccc(-n5c6ccccc6c6ccc7c8ccccc8n(-c8ccccc8)c7c65)c4)n3)cc2)cc1 ; CC1(C)c2ccccc2-c2cc3c4ccccc4n(-c4cc(-n5c6ccccc6c6ccccc65)nc(-c5ccccc5)n4)c3cc21 ; CC1(C)c2ccccc2-c2cc3c4ccccc4n(-c4cccc(-c5nc(-c6ccccc6)nc(-n6c7ccccc7c7ccccc76)n5)c4)c3cc21]

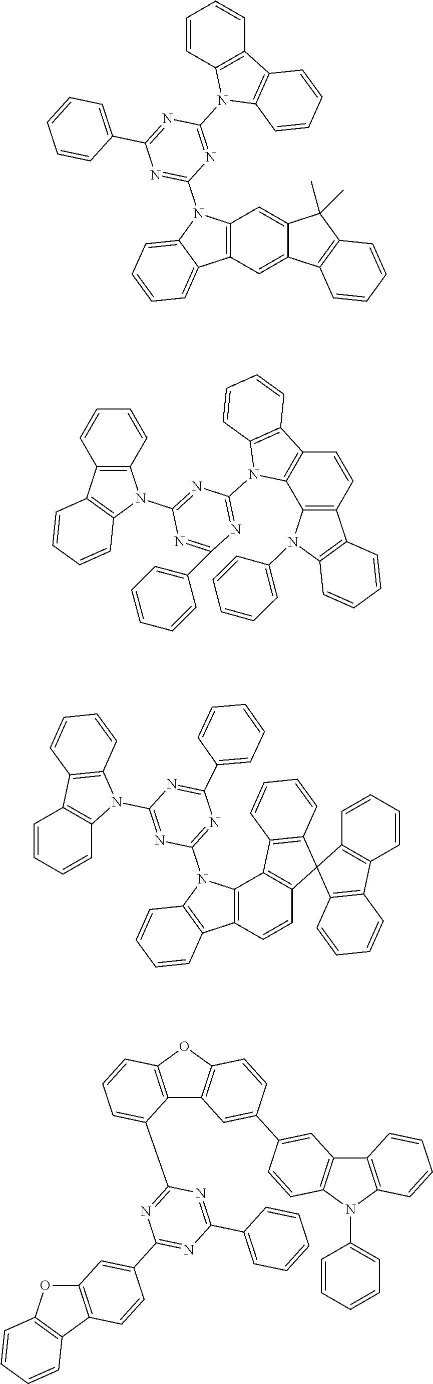 [SMILES: CC1(C)c2ccccc2-c2cc3c4ccccc4n(-c4nc(-c5ccccc5)nc(-n5c6ccccc6c6ccccc65)n4)c3cc21 ; c1ccc(-c2nc(-n3c4ccccc4c4ccccc43)nc(-n3c4ccccc4c4ccc5c6ccccc6n(-c6ccccc6)c5c43)n2)cc1 ; c1ccc(-c2nc(-n3c4ccccc4c4ccccc43)nc(-n3c4ccccc4c4ccc5c(c43)-c3ccccc3C53c4ccccc4-c4ccccc43)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1]

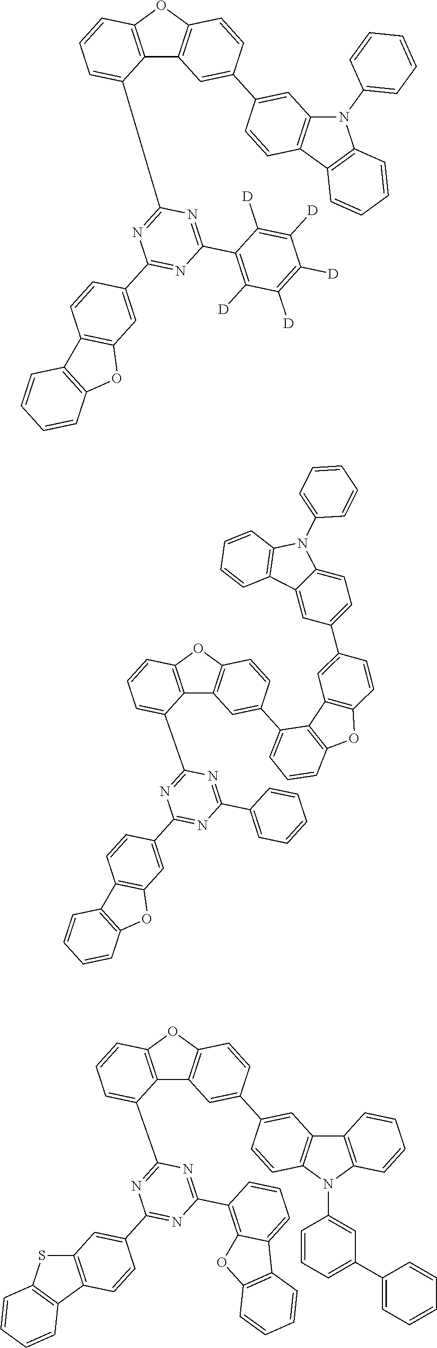 [SMILES: [2H]c1c([2H])c([2H])c(-c2nc(-c3ccc4c(c3)oc3ccccc34)nc(-c3cccc4oc5ccc(-c6ccc7c8ccccc8n(-c8ccccc8)c7c6)cc5c34)n2)c([2H])c1[2H] ; c1ccc(-c2nc(-c3ccc4c(c3)oc3ccccc34)nc(-c3cccc4oc5ccc(-c6cccc7oc8ccc(-c9ccc%10c(c9)c9ccccc9n%10-c9ccccc9)cc8c67)cc5c34)n2)cc1 ; c1ccc(-c2cccc(-n3c4ccccc4c4cc(-c5ccc6oc7cccc(-c8nc(-c9ccc%10c(c9)sc9ccccc9%10)nc(-c9cccc%10c9oc9ccccc9%10)n8)c7c6c5)ccc43)c2)cc1]

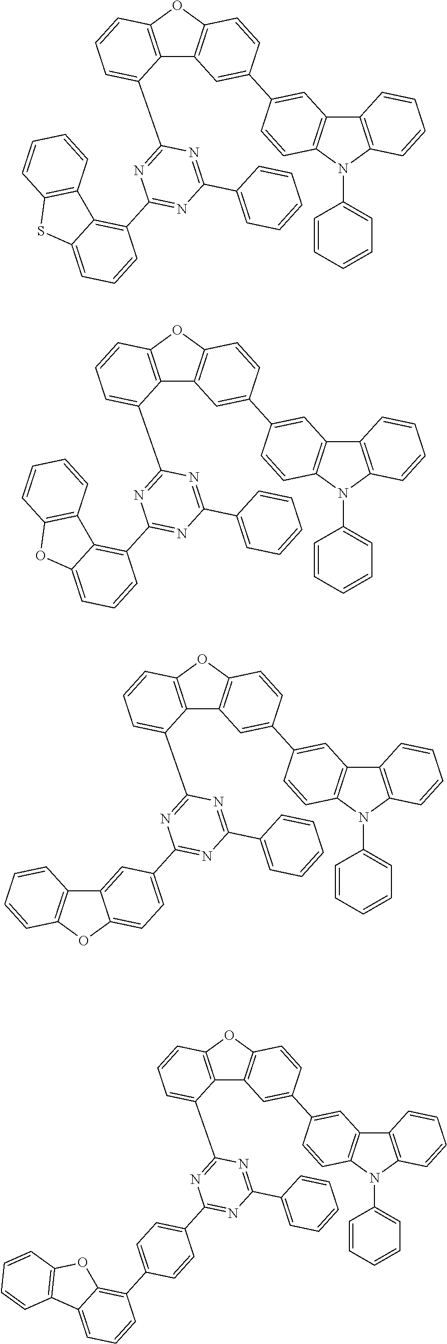 [SMILES: c1ccc(-c2nc(-c3cccc4oc5ccc(-c6ccc7c(c6)c6ccccc6n7-c6ccccc6)cc5c34)nc(-c3cccc4sc5ccccc5c34)n2)cc1 ; c1ccc(-c2nc(-c3cccc4oc5ccccc5c34)nc(-c3cccc4oc5ccc(-c6ccc7c(c6)c6ccccc6n7-c6ccccc6)cc5c34)n2)cc1 ; c1ccc(-c2nc(-c3ccc4oc5ccccc5c4c3)nc(-c3cccc4oc5ccc(-c6ccc7c(c6)c6ccccc6n7-c6ccccc6)cc5c34)n2)cc1 ; c1ccc(-c2nc(-c3ccc(-c4cccc5c4oc4ccccc45)cc3)nc(-c3cccc4oc5ccc(-c6ccc7c(c6)c6ccccc6n7-c6ccccc6)cc5c34)n2)cc1]

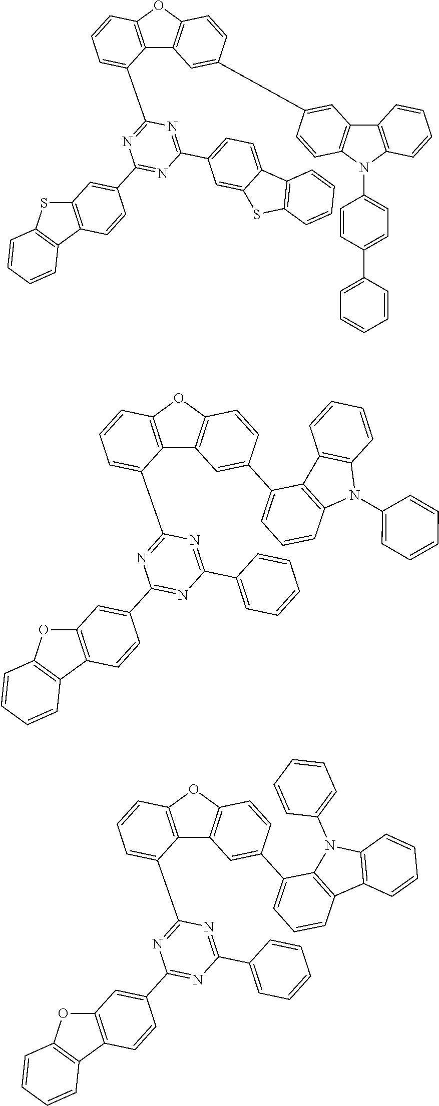 [SMILES: c1ccc(-c2ccc(-n3c4ccccc4c4cc(-c5ccc6oc7cccc(-c8nc(-c9ccc%10c(c9)sc9ccccc9%10)nc(-c9ccc%10c(c9)sc9ccccc9%10)n8)c7c6c5)ccc43)cc2)cc1 ; c1ccc(-c2nc(-c3ccc4c(c3)oc3ccccc34)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6cccc7c8ccccc8n(-c8ccccc8)c67)cc5c34)n2)cc1]

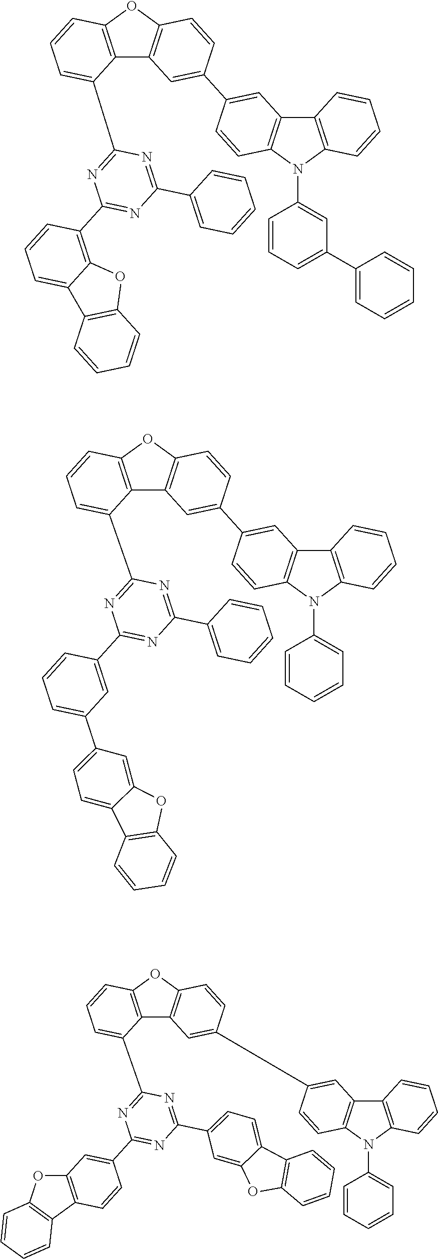 [SMILES: c1ccc(-c2cccc(-n3c4ccccc4c4cc(-c5ccc6oc7cccc(-c8nc(-c9ccccc9)nc(-c9cccc%10c9oc9ccccc9%10)n8)c7c6c5)ccc43)c2)cc1 ; c1ccc(-c2nc(-c3cccc(-c4ccc5c(c4)oc4ccccc45)c3)nc(-c3cccc4oc5ccc(-c6ccc7c(c6)c6ccccc6n7-c6ccccc6)cc5c34)n2)cc1 ; c1ccc(-n2c3ccccc3c3cc(-c4ccc5oc6cccc(-c7nc(-c8ccc9c(c8)oc8ccccc89)nc(-c8ccc9c(c8)oc8ccccc89)n7)c6c5c4)ccc32)cc1]

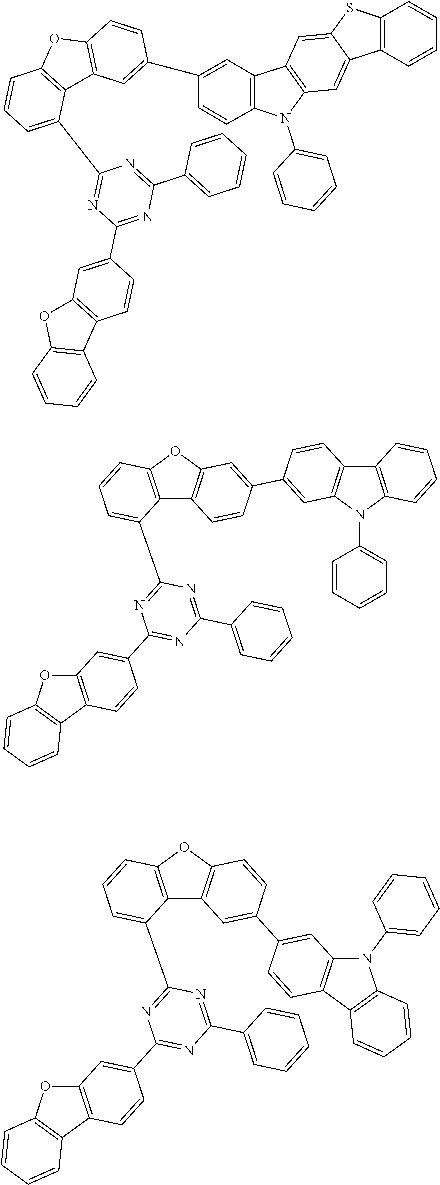 [SMILES: c1ccc(-c2nc(-c3ccc4c(c3)oc3ccccc34)nc(-c3cccc4oc5ccc(-c6ccc7c(c6)c6cc8sc9ccccc9c8cc6n7-c6ccccc6)cc5c34)n2)cc1 ; c1ccc(-c2nc(-c3ccc4c(c3)oc3ccccc34)nc(-c3cccc4oc5cc(-c6ccc7c8ccccc8n(-c8ccccc8)c7c6)ccc5c34)n2)cc1 ; c1ccc(-c2nc(-c3ccc4c(c3)oc3ccccc34)nc(-c3cccc4oc5ccc(-c6ccc7c8ccccc8n(-c8ccccc8)c7c6)cc5c34)n2)cc1]

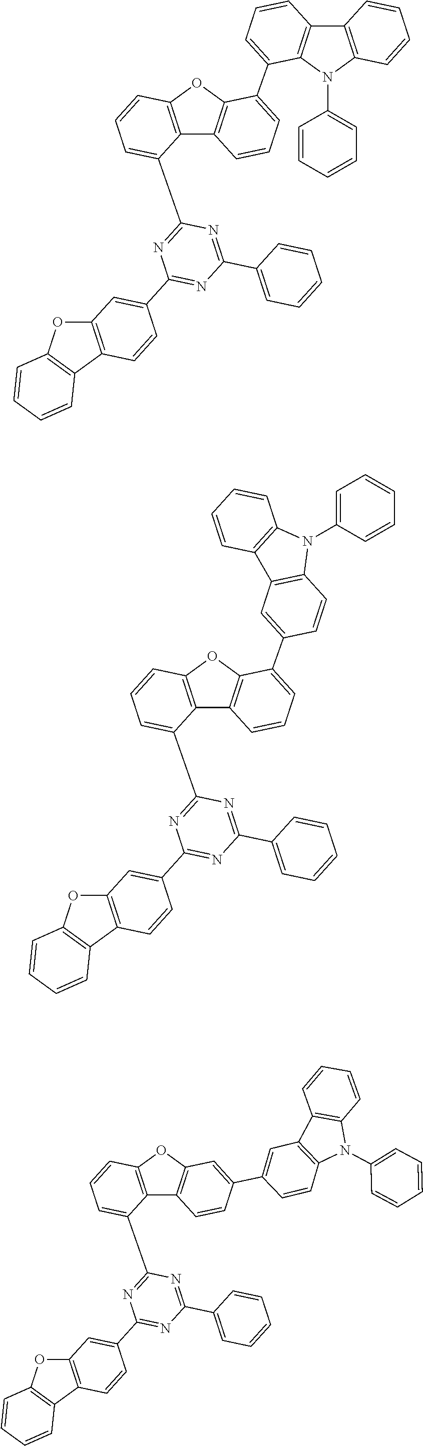 [SMILES: c1ccc(-c2nc(-c3ccc4c(c3)oc3ccccc34)nc(-c3cccc4oc5c(-c6cccc7c8ccccc8n(-c8ccccc8)c67)cccc5c34)n2)cc1 ; c1ccc(-c2nc(-c3ccc4c(c3)oc3ccccc34)nc(-c3cccc4oc5c(-c6ccc7c(c6)c6ccccc6n7-c6ccccc6)cccc5c34)n2)cc1 ; c1ccc(-c2nc(-c3ccc4c(c3)oc3ccccc34)nc(-c3cccc4oc5cc(-c6ccc7c(c6)c6ccccc6n7-c6ccccc6)ccc5c34)n2)cc1]

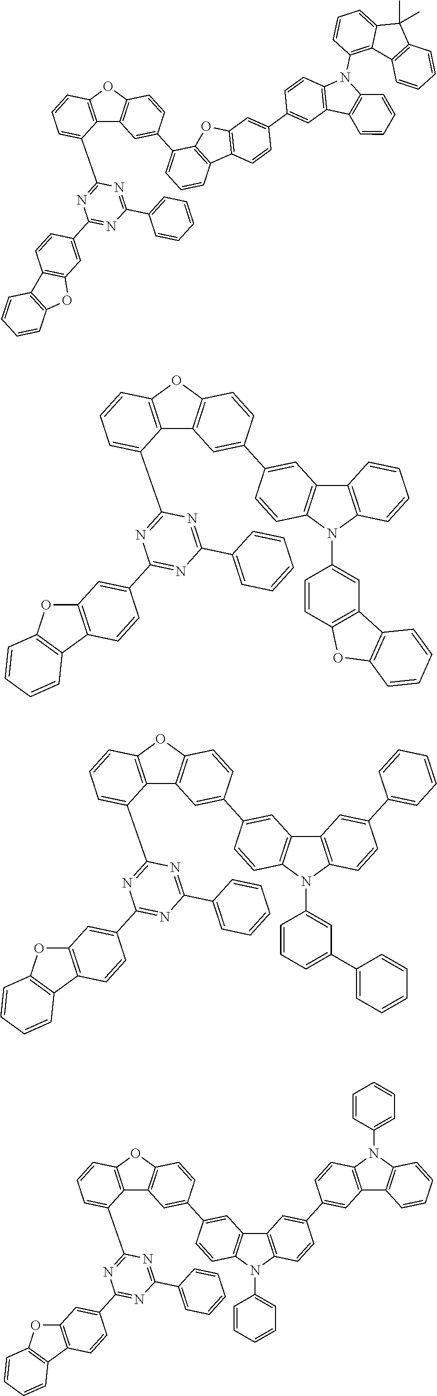

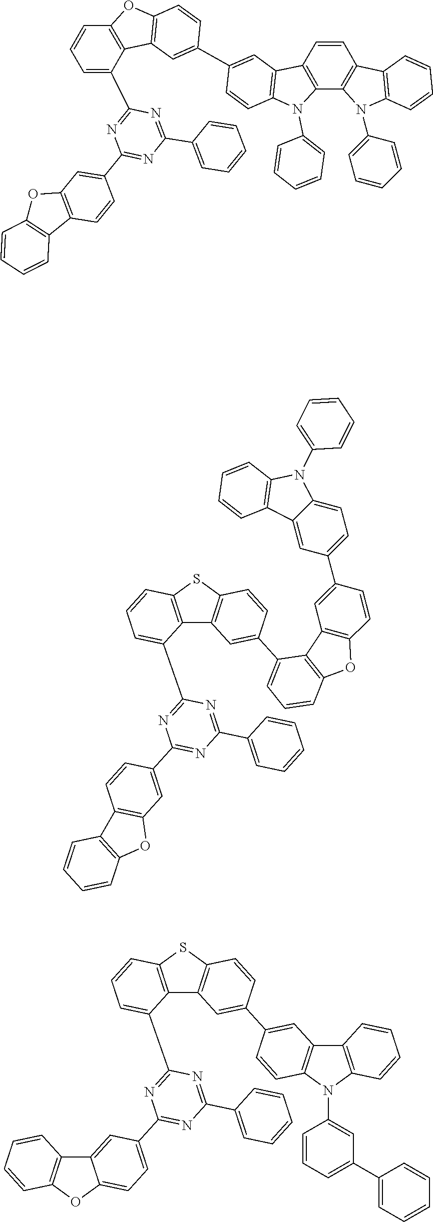 [SMILES: c1ccc(-c2nc(-c3ccc4c(c3)oc3ccccc34)nc(-c3cccc4oc5ccc(-c6ccc7c(c6)c6ccc8c9ccccc9n(-c9ccccc9)c8c6n7-c6ccccc6)cc5c34)n2)cc1 ; c1ccc(-c2nc(-c3ccc4c(c3)oc3ccccc34)nc(-c3cccc4sc5ccc(-c6cccc7oc8ccc(-c9ccc%10c(c9)c9ccccc9n%10-c9ccccc9)cc8c67)cc5c34)n2)cc1 ; c1ccc(-c2cccc(-n3c4ccccc4c4cc(-c5ccc6sc7cccc(-c8nc(-c9ccccc9)nc(-c9ccc%10oc%11ccccc%11c%10c9)n8)c7c6c5)ccc43)c2)cc1]

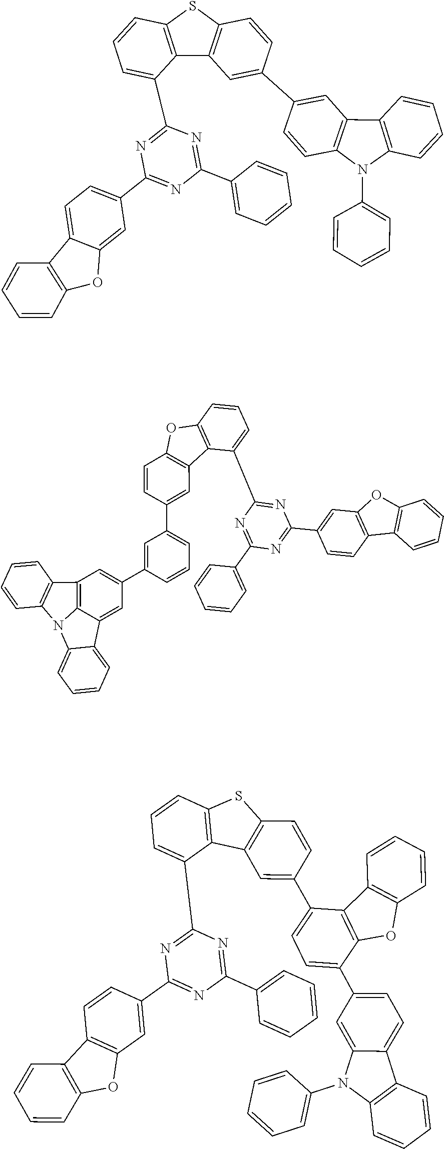 [SMILES: c1ccc(-c2nc(-c3ccc4c(c3)oc3ccccc34)nc(-c3cccc4sc5ccc(-c6ccc7c(c6)c6ccccc6n7-c6ccccc6)cc5c34)n2)cc1 ; c1ccc(-c2nc(-c3ccc4c(c3)oc3ccccc34)nc(-c3cccc4oc5ccc(-c6cccc(-c7cc8c9ccccc9n9c%10ccccc%10c(c7)c89)c6)cc5c34)n2)cc1 ; c1ccc(-c2nc(-c3ccc4c(c3)oc3ccccc34)nc(-c3cccc4sc5ccc(-c6ccc(-c7ccc8c9ccccc9n(-c9ccccc9)c8c7)c7oc8ccccc8c67)cc5c34)n2)cc1]

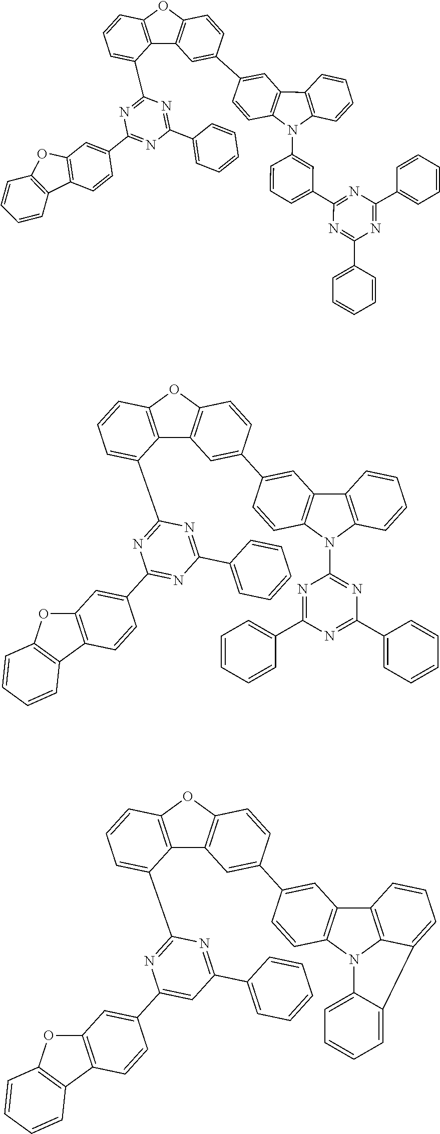 [SMILES: c1ccc(-c2nc(-c3ccccc3)nc(-c3cccc(-n4c5ccccc5c5cc(-c6ccc7oc8cccc(-c9nc(-c%10ccccc%10)nc(-c%10ccc%11c(c%10)oc%10ccccc%10%11)n9)c8c7c6)ccc54)c3)n2)cc1 ; c1ccc(-c2nc(-c3ccc4c(c3)oc3ccccc34)nc(-c3cccc4oc5ccc(-c6ccc7c(c6)c6ccccc6n7-c6nc(-c7ccccc7)nc(-c7ccccc7)n6)cc5c34)n2)cc1 ; c1ccc(-c2cc(-c3ccc4c(c3)oc3ccccc34)nc(-c3cccc4oc5ccc(-c6ccc7c(c6)c6cccc8c9ccccc9n7c86)cc5c34)n2)cc1]

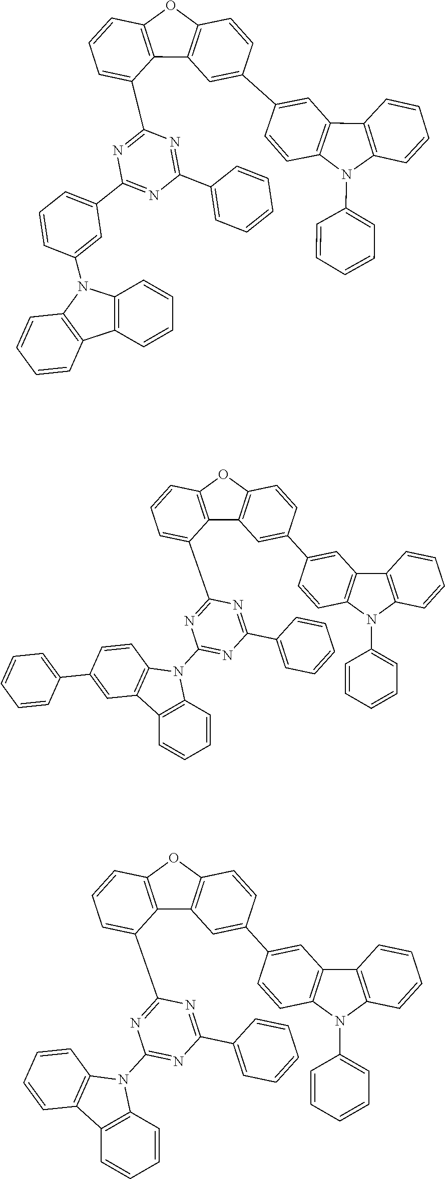 [SMILES: c1ccc(-c2nc(-c3cccc(-n4c5ccccc5c5ccccc54)c3)nc(-c3cccc4oc5ccc(-c6ccc7c(c6)c6ccccc6n7-c6ccccc6)cc5c34)n2)cc1 ; c1ccc(-c2ccc3c(c2)c2ccccc2n3-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3cccc4oc5ccc(-c6ccc7c(c6)c6ccccc6n7-c6ccccc6)cc5c34)nc(-n3c4ccccc4c4ccccc43)n2)cc1]

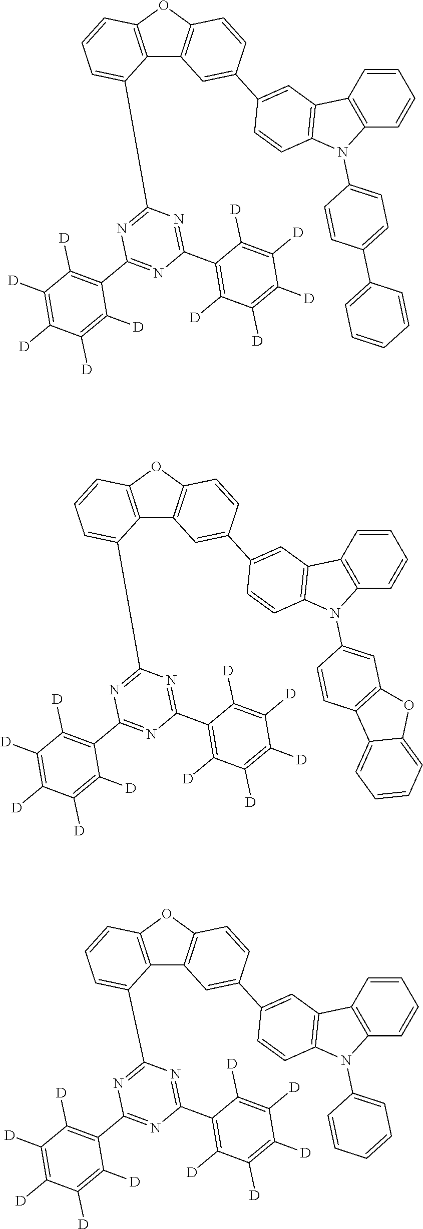 [SMILES: [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccc(-c7ccccc7)cc6)cc5c34)n2)c([2H])c1[2H] ; [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccc7c(c6)oc6ccccc67)cc5c34)n2)c([2H])c1[2H] ; [2H]c1c([2H])c([2H])c(-c2nc(-c3c([2H])c([2H])c([2H])c([2H])c3[2H])nc(-c3cccc4oc5ccc(-c6ccc7c(c6)c6ccccc6n7-c6ccccc6)cc5c34)n2)c([2H])c1[2H]]

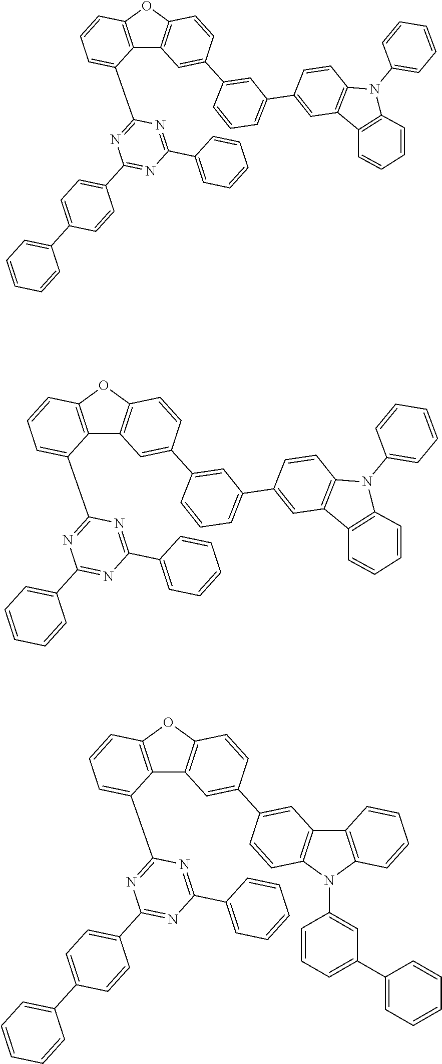 [SMILES: c1ccc(-c2ccc(-c3nc(-c4ccccc4)nc(-c4cccc5oc6ccc(-c7cccc(-c8ccc9c(c8)c8ccccc8n9-c8ccccc8)c7)cc6c45)n3)cc2)cc1 ; c1ccc(-c2nc(-c3ccccc3)nc(-c3cccc4oc5ccc(-c6cccc(-c7ccc8c(c7)c7ccccc7n8-c7ccccc7)c6)cc5c34)n2)cc1 ; c1ccc(-c2ccc(-c3nc(-c4ccccc4)nc(-c4cccc5oc6ccc(-c7ccc8c(c7)c7ccccc7n8-c7cccc(-c8ccccc8)c7)cc6c45)n3)cc2)cc1]

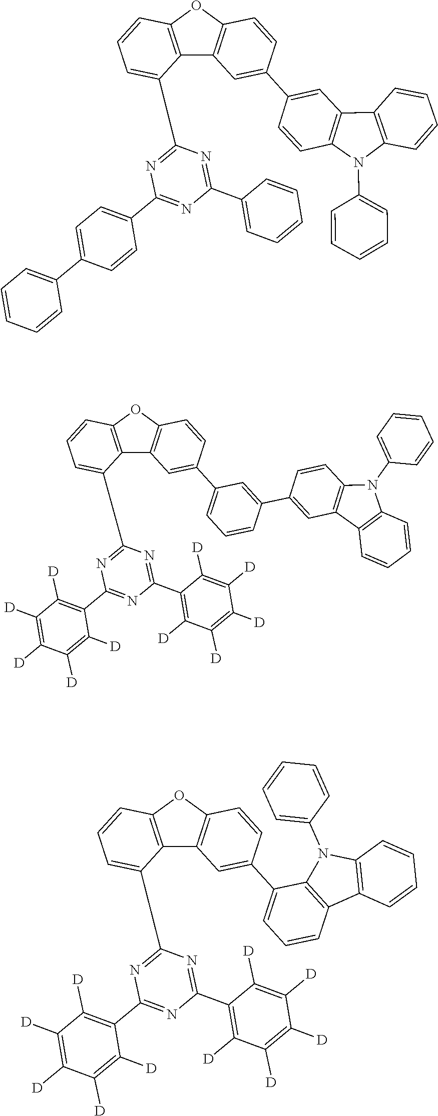 [SMILES: c1ccc(-c2ccc(-c3nc(-c4ccccc4)nc(-c4cccc5oc6ccc(-c7ccc8c(c7)c7ccccc7n8-c7ccccc7)cc6c45)n3)cc2)cc1 ; [2H]c1c([2H])c([2H])c(-c2nc(-c3c([2H])c([2H])c([2H])c([2H])c3[2H])nc(-c3cccc4oc5ccc(-c6cccc(-c7ccc8c(c7)c7ccccc7n8-c7ccccc7)c6)cc5c34)n2)c([2H])c1[2H] ; [2H]c1c([2H])c([2H])c(-c2nc(-c3c([2H])c([2H])c([2H])c([2H])c3[2H])nc(-c3cccc4oc5ccc(-c6cccc7c8ccccc8n(-c8ccccc8)c67)cc5c34)n2)c([2H])c1[2H]]

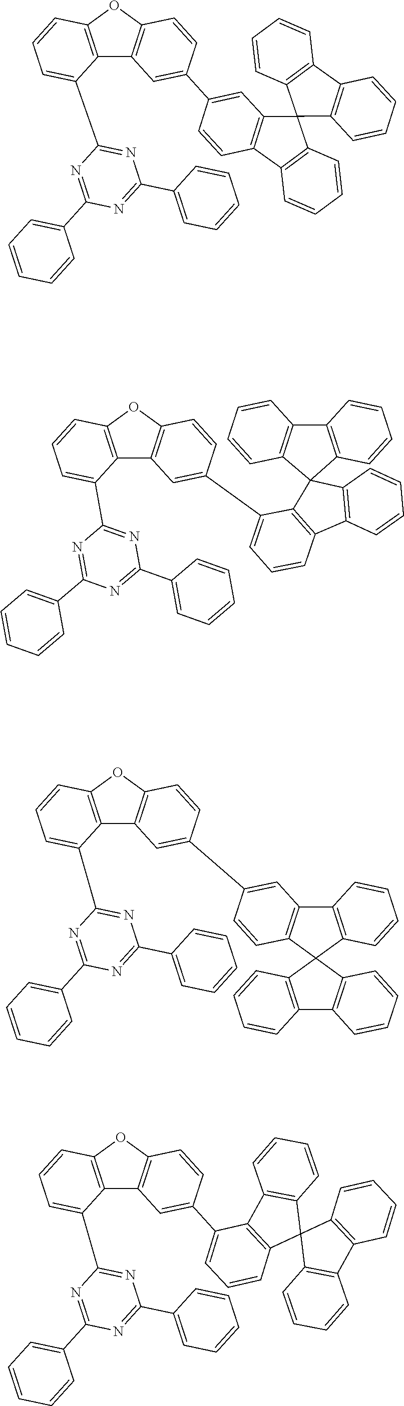 [SMILES: c1ccc(-c2nc(-c3ccccc3)nc(-c3cccc4oc5ccc(-c6ccc7c(c6)C6(c8ccccc8-c8ccccc86)c6ccccc6-7)cc5c34)n2)cc1 ; c1ccc(-c2nc(-c3ccccc3)nc(-c3cccc4oc5ccc(-c6cccc7c6C6(c8ccccc8-c8ccccc86)c6ccccc6-7)cc5c34)n2)cc1 ; c1ccc(-c2nc(-c3ccccc3)nc(-c3cccc4oc5ccc(-c6ccc7c(c6)-c6ccccc6C76c7ccccc7-c7ccccc76)cc5c34)n2)cc1 ; c1ccc(-c2nc(-c3ccccc3)nc(-c3cccc4oc5ccc(-c6cccc7c6-c6ccccc6C76c7ccccc7-c7ccccc76)cc5c34)n2)cc1]

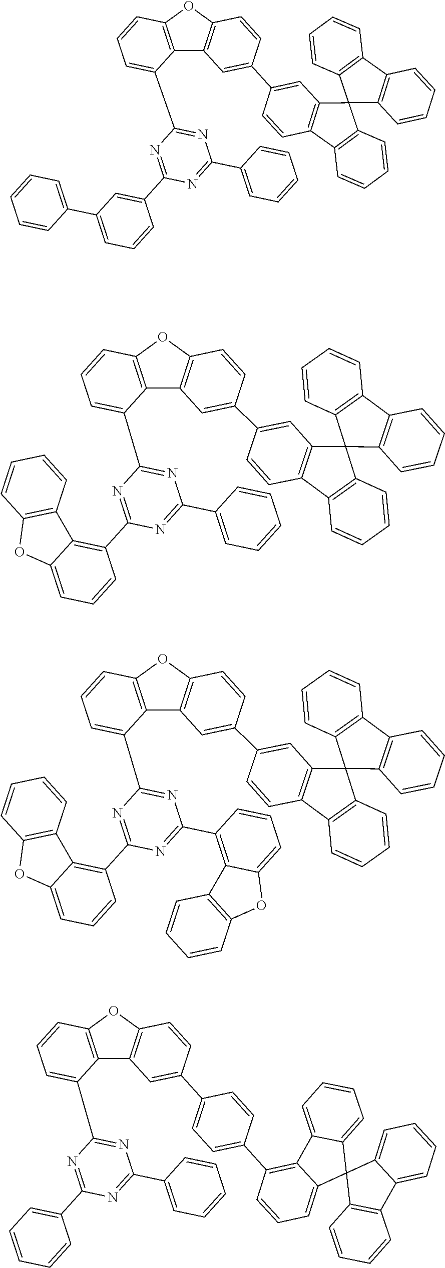 [SMILES: c1ccc(-c2cccc(-c3nc(-c4ccccc4)nc(-c4cccc5oc6ccc(-c7ccc8c(c7)C7(c9ccccc9-c9ccccc97)c7ccccc7-8)cc6c45)n3)c2)cc1 ; c1ccc(-c2nc(-c3cccc4oc5ccccc5c34)nc(-c3cccc4oc5ccc(-c6ccc7c(c6)C6(c8ccccc8-c8ccccc86)c6ccccc6-7)cc5c34)n2)cc1 ; c1ccc2c(c1)-c1ccccc1C21c2ccccc2-c2ccc(-c3ccc4oc5cccc(-c6nc(-c7cccc8oc9ccccc9c78)nc(-c7cccc8oc9ccccc9c78)n6)c5c4c3)cc21 ; c1ccc(-c2nc(-c3ccccc3)nc(-c3cccc4oc5ccc(-c6ccc(-c7cccc8c7-c7ccccc7C87c8ccccc8-c8ccccc87)cc6)cc5c34)n2)cc1]

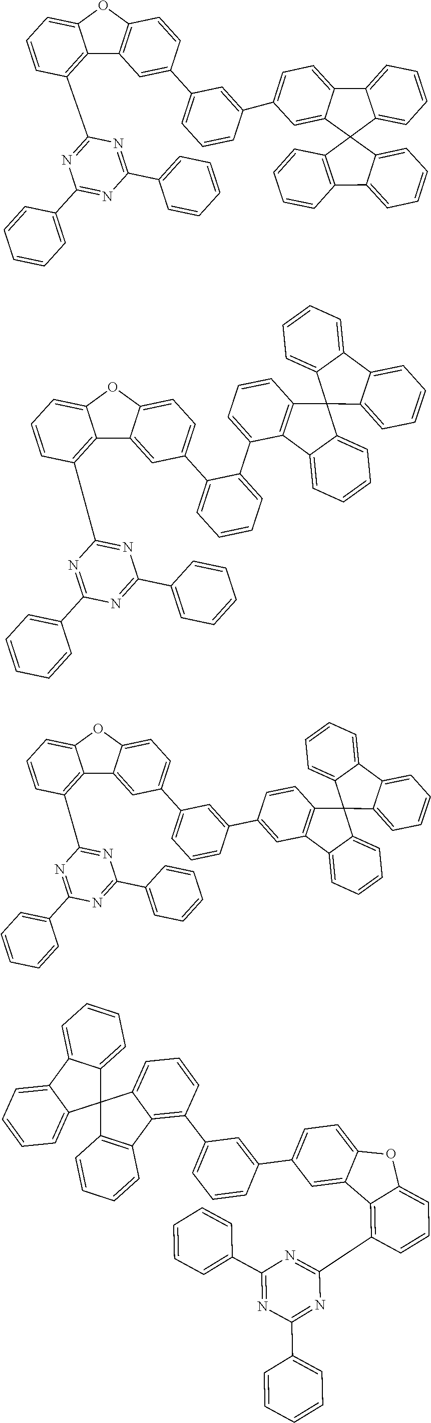 [SMILES: c1ccc(-c2nc(-c3ccccc3)nc(-c3cccc4oc5ccc(-c6cccc(-c7ccc8c(c7)C7(c9ccccc9-c9ccccc97)c7ccccc7-8)c6)cc5c34)n2)cc1 ; c1ccc(-c2nc(-c3ccccc3)nc(-c3cccc4oc5ccc(-c6ccccc6-c6cccc7c6-c6ccccc6C76c7ccccc7-c7ccccc76)cc5c34)n2)cc1 ; c1ccc(-c2nc(-c3ccccc3)nc(-c3cccc4oc5ccc(-c6cccc(-c7ccc8c(c7)-c7ccccc7C87c8ccccc8-c8ccccc87)c6)cc5c34)n2)cc1 ; c1ccc(-c2nc(-c3ccccc3)nc(-c3cccc4oc5ccc(-c6cccc(-c7cccc8c7-c7ccccc7C87c8ccccc8-c8ccccc87)c6)cc5c34)n2)cc1]

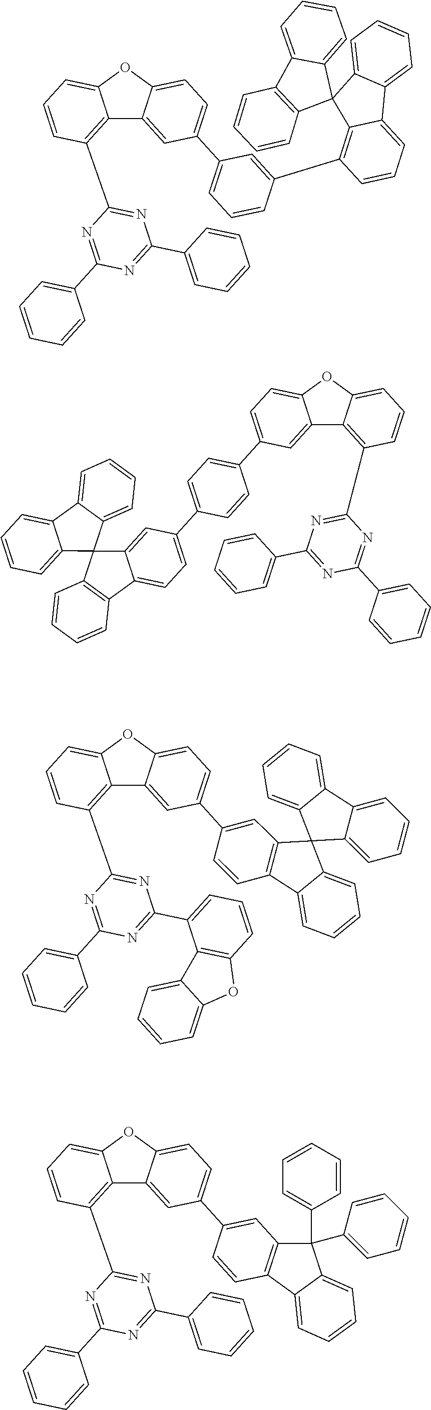 [SMILES: c1ccc(-c2nc(-c3ccccc3)nc(-c3cccc4oc5ccc(-c6cccc(-c7cccc8c7C7(c9ccccc9-c9ccccc97)c7ccccc7-8)c6)cc5c34)n2)cc1 ; c1ccc(-c2nc(-c3ccccc3)nc(-c3cccc4oc5ccc(-c6ccc(-c7ccc8c(c7)C7(c9ccccc9-c9ccccc97)c7ccccc7-8)cc6)cc5c34)n2)cc1 ; c1ccc(-c2nc(-c3cccc4oc5ccccc5c34)nc(-c3cccc4oc5ccc(-c6ccc7c(c6)C6(c8ccccc8-c8ccccc86)c6ccccc6-7)cc5c34)n2)cc1 ; c1ccc(-c2nc(-c3ccccc3)nc(-c3cccc4oc5ccc(-c6ccc7c(c6)C(c6ccccc6)(c6ccccc6)c6ccccc6-7)cc5c34)n2)cc1]

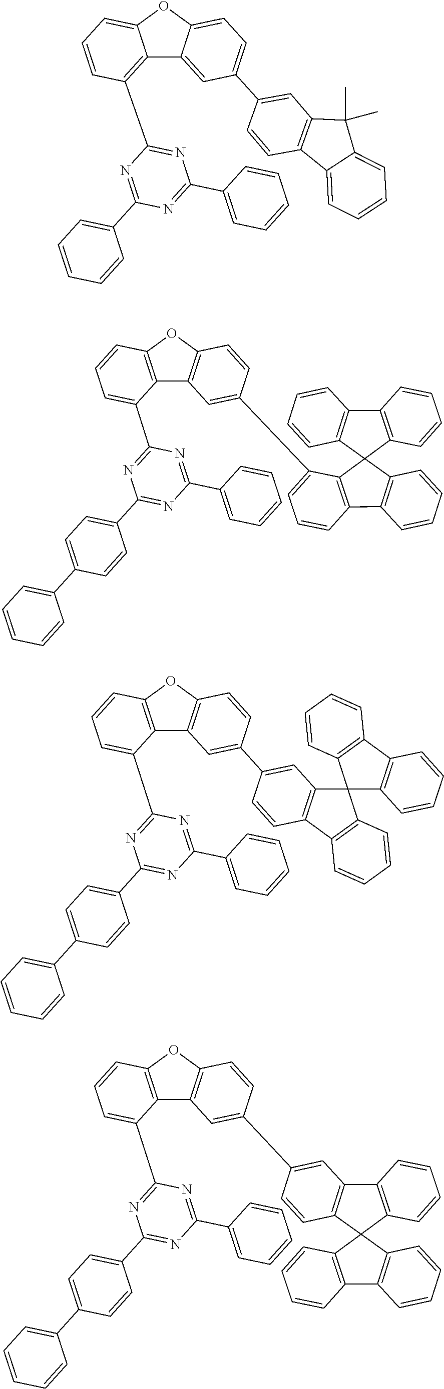 [SMILES: CC1(C)c2ccccc2-c2ccc(-c3ccc4oc5cccc(-c6nc(-c7ccccc7)nc(-c7ccccc7)n6)c5c4c3)cc21 ; c1ccc(-c2ccc(-c3nc(-c4ccccc4)nc(-c4cccc5oc6ccc(-c7cccc8c7C7(c9ccccc9-c9ccccc97)c7ccccc7-8)cc6c45)n3)cc2)cc1 ; c1ccc(-c2ccc(-c3nc(-c4ccccc4)nc(-c4cccc5oc6ccc(-c7ccc8c(c7)C7(c9ccccc9-c9ccccc97)c7ccccc7-8)cc6c45)n3)cc2)cc1 ; c1ccc(-c2ccc(-c3nc(-c4ccccc4)nc(-c4cccc5oc6ccc(-c7ccc8c(c7)-c7ccccc7C87c8ccccc8-c8ccccc87)cc6c45)n3)cc2)cc1]

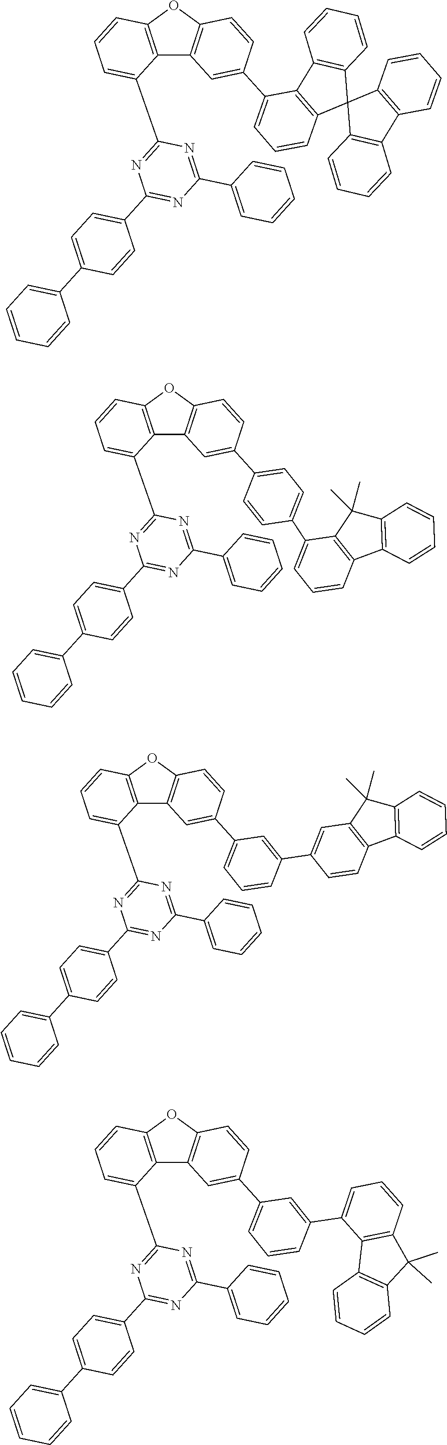 [SMILES: c1ccc(-c2ccc(-c3nc(-c4ccccc4)nc(-c4cccc5oc6ccc(-c7cccc8c7-c7ccccc7C87c8ccccc8-c8ccccc87)cc6c45)n3)cc2)cc1 ; CC1(C)c2ccccc2-c2cccc(-c3ccc(-c4ccc5oc6cccc(-c7nc(-c8ccccc8)nc(-c8ccc(-c9ccccc9)cc8)n7)c6c5c4)cc3)c21 ; CC1(C)c2ccccc2-c2ccc(-c3cccc(-c4ccc5oc6cccc(-c7nc(-c8ccccc8)nc(-c8ccc(-c9ccccc9)cc8)n7)c6c5c4)c3)cc21 ; CC1(C)c2ccccc2-c2c(-c3cccc(-c4ccc5oc6cccc(-c7nc(-c8ccccc8)nc(-c8ccc(-c9ccccc9)cc8)n7)c6c5c4)c3)cccc21]

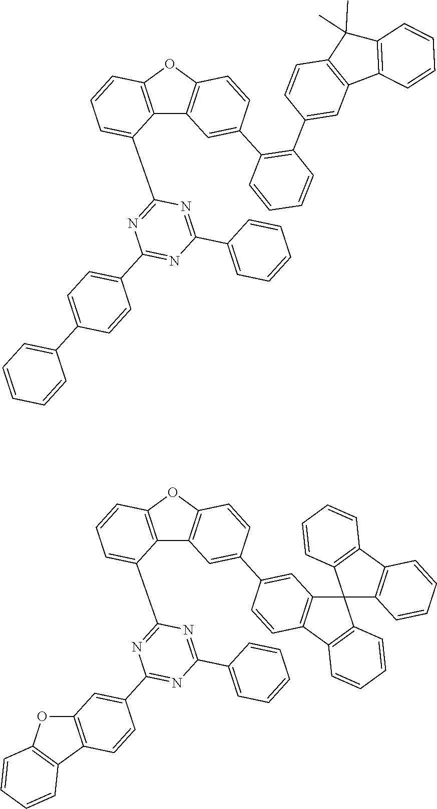 [SMILES: CC1(C)c2ccccc2-c2cc(-c3ccccc3-c3ccc4oc5cccc(-c6nc(-c7ccccc7)nc(-c7ccc(-c8ccccc8)cc7)n6)c5c4c3)ccc21 ; c1ccc(-c2nc(-c3ccc4c(c3)oc3ccccc34)nc(-c3cccc4oc5ccc(-c6ccc7c(c6)C6(c8ccccc8-c8ccccc86)c6ccccc6-7)cc5c34)n2)cc1]

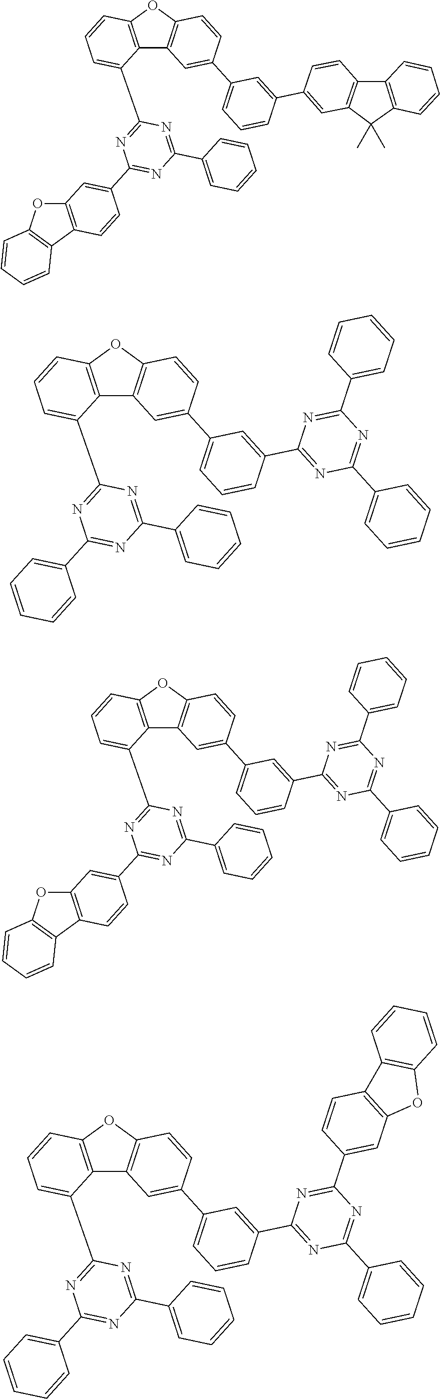 [SMILES: CC1(C)c2ccccc2-c2ccc(-c3cccc(-c4ccc5oc6cccc(-c7nc(-c8ccccc8)nc(-c8ccc9c(c8)oc8ccccc89)n7)c6c5c4)c3)cc21 ; c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1 ; c1ccc(-c2nc(-c3ccccc3)nc(-c3cccc(-c4ccc5oc6cccc(-c7nc(-c8ccccc8)nc(-c8ccc9c(c8)oc8ccccc89)n7)c6c5c4)c3)n2)cc1 ; c1ccc(-c2nc(-c3cccc(-c4ccc5oc6cccc(-c7nc(-c8ccccc8)nc(-c8ccccc8)n7)c6c5c4)c3)nc(-c3ccc4c(c3)oc3ccccc34)n2)cc1]

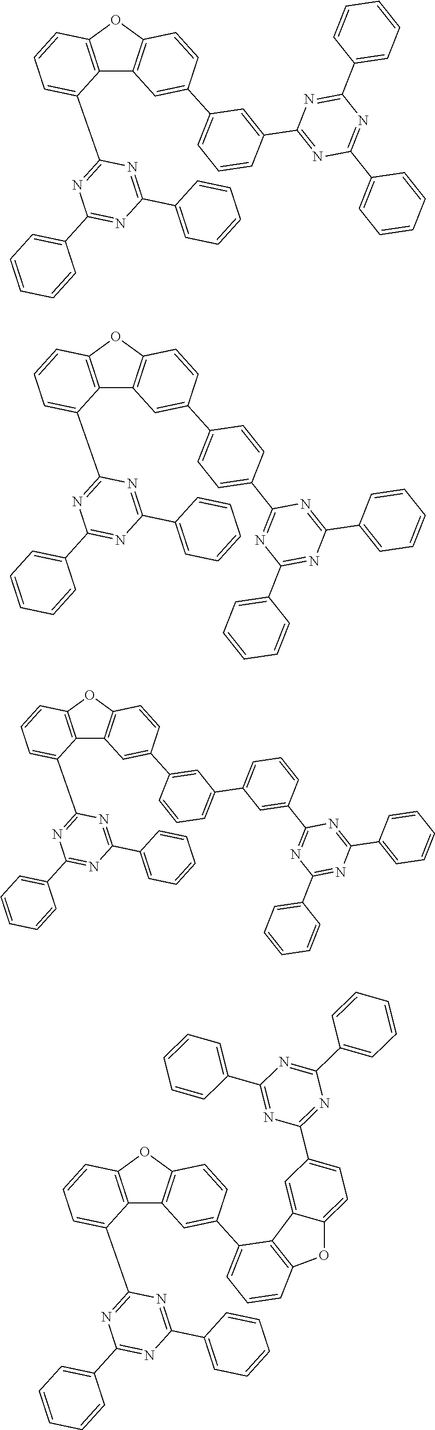 [SMILES: c1ccc(-c2nc(-c3ccccc3)nc(-c3cccc(-c4ccc5oc6cccc(-c7nc(-c8ccccc8)nc(-c8ccccc8)n7)c6c5c4)c3)n2)cc1 ; c1ccc(-c2nc(-c3ccccc3)nc(-c3ccc(-c4ccc5oc6cccc(-c7nc(-c8ccccc8)nc(-c8ccccc8)n7)c6c5c4)cc3)n2)cc1 ; c1ccc(-c2nc(-c3ccccc3)nc(-c3cccc(-c4cccc(-c5ccc6oc7cccc(-c8nc(-c9ccccc9)nc(-c9ccccc9)n8)c7c6c5)c4)c3)n2)cc1 ; c1ccc(-c2nc(-c3ccccc3)nc(-c3ccc4oc5cccc(-c6ccc7oc8cccc(-c9nc(-c%10ccccc%10)nc(-c%10ccccc%10)n9)c8c7c6)c5c4c3)n2)cc1]

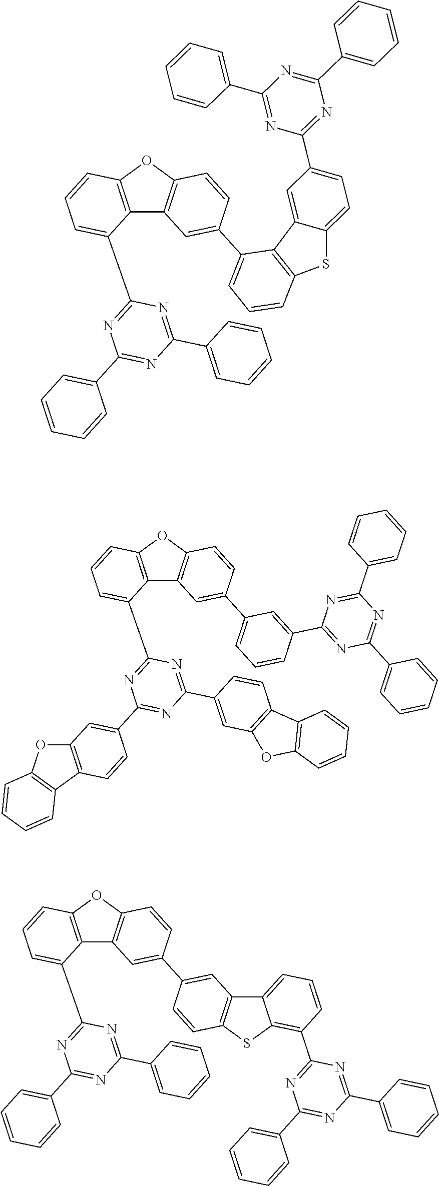 [SMILES: c1ccc(-c2nc(-c3ccccc3)nc(-c3ccc4sc5cccc(-c6ccc7oc8cccc(-c9nc(-c%10ccccc%10)nc(-c%10ccccc%10)n9)c8c7c6)c5c4c3)n2)cc1 ; c1ccc(-c2nc(-c3ccccc3)nc(-c3cccc(-c4ccc5oc6cccc(-c7nc(-c8ccc9c(c8)oc8ccccc89)nc(-c8ccc9c(c8)oc8ccccc89)n7)c6c5c4)c3)n2)cc1 ; c1ccc(-c2nc(-c3ccccc3)nc(-c3cccc4c3sc3ccc(-c5ccc6oc7cccc(-c8nc(-c9ccccc9)nc(-c9ccccc9)n8)c7c6c5)cc34)n2)cc1]

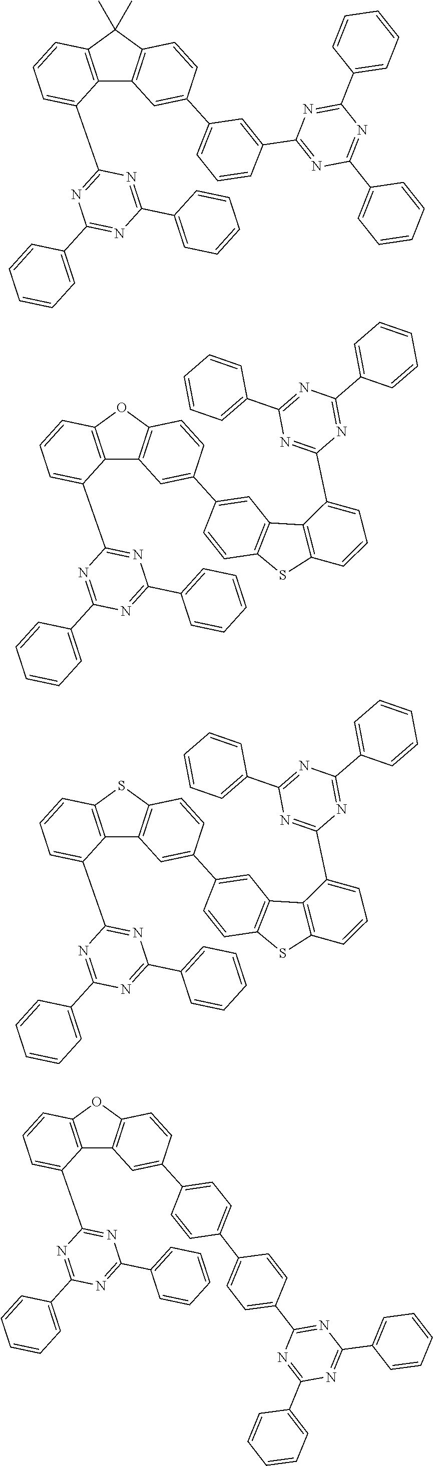 [SMILES: CC1(C)c2ccc(-c3cccc(-c4nc(-c5ccccc5)nc(-c5ccccc5)n4)c3)cc2-c2c(-c3nc(-c4ccccc4)nc(-c4ccccc4)n3)cccc21 ; c1ccc(-c2nc(-c3ccccc3)nc(-c3cccc4oc5ccc(-c6ccc7sc8cccc(-c9nc(-c%10ccccc%10)nc(-c%10ccccc%10)n9)c8c7c6)cc5c34)n2)cc1 ; c1ccc(-c2nc(-c3ccccc3)nc(-c3cccc4sc5ccc(-c6ccc7sc8cccc(-c9nc(-c%10ccccc%10)nc(-c%10ccccc%10)n9)c8c7c6)cc5c34)n2)cc1 ; c1ccc(-c2nc(-c3ccccc3)nc(-c3ccc(-c4ccc(-c5ccc6oc7cccc(-c8nc(-c9ccccc9)nc(-c9ccccc9)n8)c7c6c5)cc4)cc3)n2)cc1]

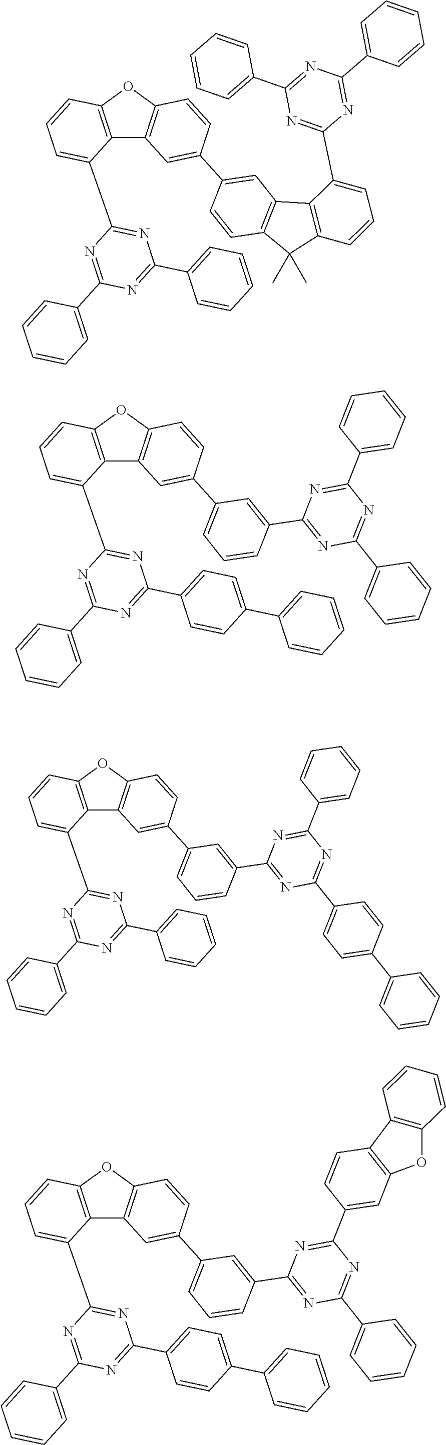

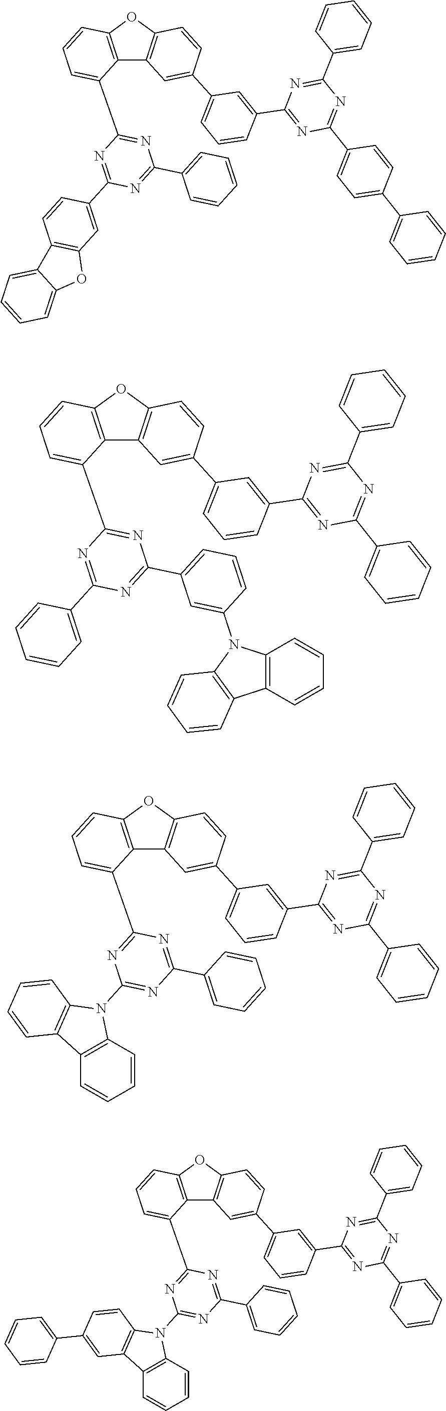 [SMILES: c1ccc(-c2ccc(-c3nc(-c4ccccc4)nc(-c4cccc(-c5ccc6oc7cccc(-c8nc(-c9ccccc9)nc(-c9ccc%10c(c9)oc9ccccc9%10)n8)c7c6c5)c4)n3)cc2)cc1 ; c1ccc(-c2nc(-c3ccccc3)nc(-c3cccc(-c4ccc5oc6cccc(-c7nc(-c8ccccc8)nc(-c8cccc(-n9c%10ccccc%10c%10ccccc%109)c8)n7)c6c5c4)c3)n2)cc1 ; c1ccc(-c2nc(-c3ccccc3)nc(-c3cccc(-c4ccc5oc6cccc(-c7nc(-c8ccccc8)nc(-n8c9ccccc9c9ccccc98)n7)c6c5c4)c3)n2)cc1 ; c1ccc(-c2ccc3c(c2)c2ccccc2n3-c2nc(-c3ccccc3)nc(-c3cccc4oc5ccc(-c6cccc(-c7nc(-c8ccccc8)nc(-c8ccccc8)n7)c6)cc5c34)n2)cc1]

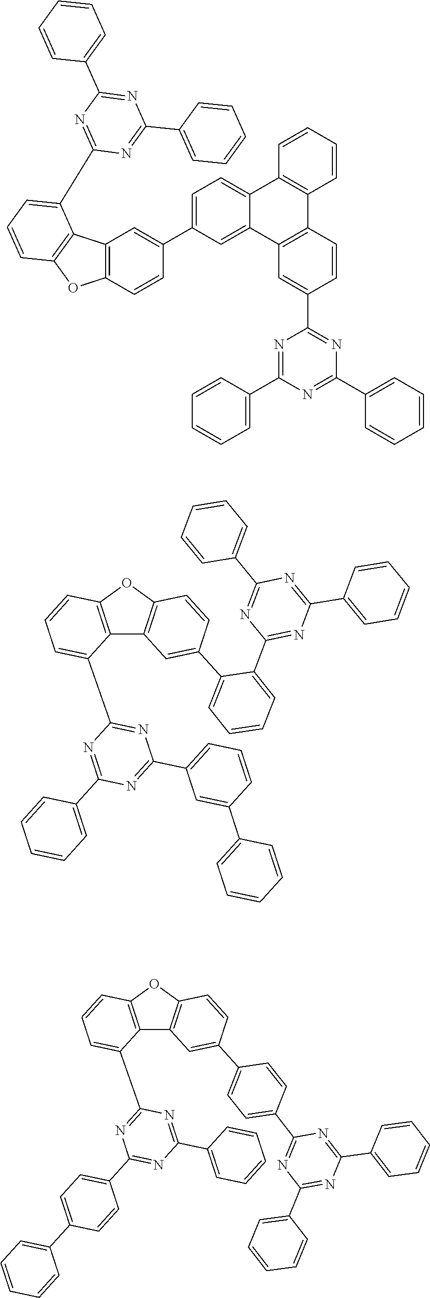 [SMILES: c1ccc(-c2nc(-c3ccccc3)nc(-c3ccc4c5ccccc5c5ccc(-c6ccc7oc8cccc(-c9nc(-c%10ccccc%10)nc(-c%10ccccc%10)n9)c8c7c6)cc5c4c3)n2)cc1 ; c1ccc(-c2cccc(-c3nc(-c4ccccc4)nc(-c4cccc5oc6ccc(-c7ccccc7-c7nc(-c8ccccc8)nc(-c8ccccc8)n7)cc6c45)n3)c2)cc1 ; c1ccc(-c2ccc(-c3nc(-c4ccccc4)nc(-c4cccc5oc6ccc(-c7ccc(-c8nc(-c9ccccc9)nc(-c9ccccc9)n8)cc7)cc6c45)n3)cc2)cc1]

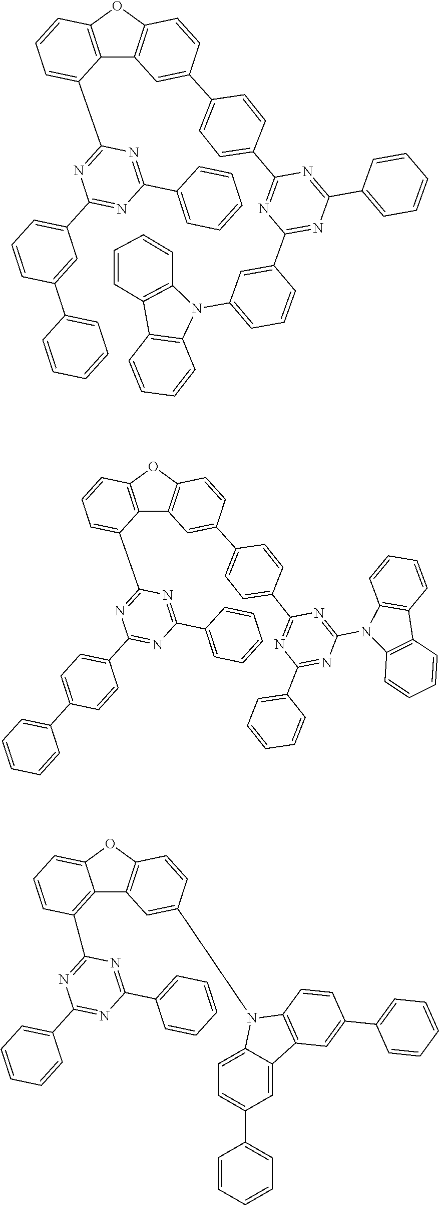 [SMILES: c1ccc(-c2cccc(-c3nc(-c4ccccc4)nc(-c4cccc5oc6ccc(-c7ccc(-c8nc(-c9ccccc9)nc(-c9cccc(-n%10c%11ccccc%11c%11ccccc%11%10)c9)n8)cc7)cc6c45)n3)c2)cc1 ; c1ccc(-c2ccc(-c3nc(-c4ccccc4)nc(-c4cccc5oc6ccc(-c7ccc(-c8nc(-c9ccccc9)nc(-n9c%10ccccc%10c%10ccccc%109)n8)cc7)cc6c45)n3)cc2)cc1 ; c1ccc(-c2ccc3c(c2)c2cc(-c4ccccc4)ccc2n3-c2ccc3oc4cccc(-c5nc(-c6ccccc6)nc(-c6ccccc6)n5)c4c3c2)cc1]

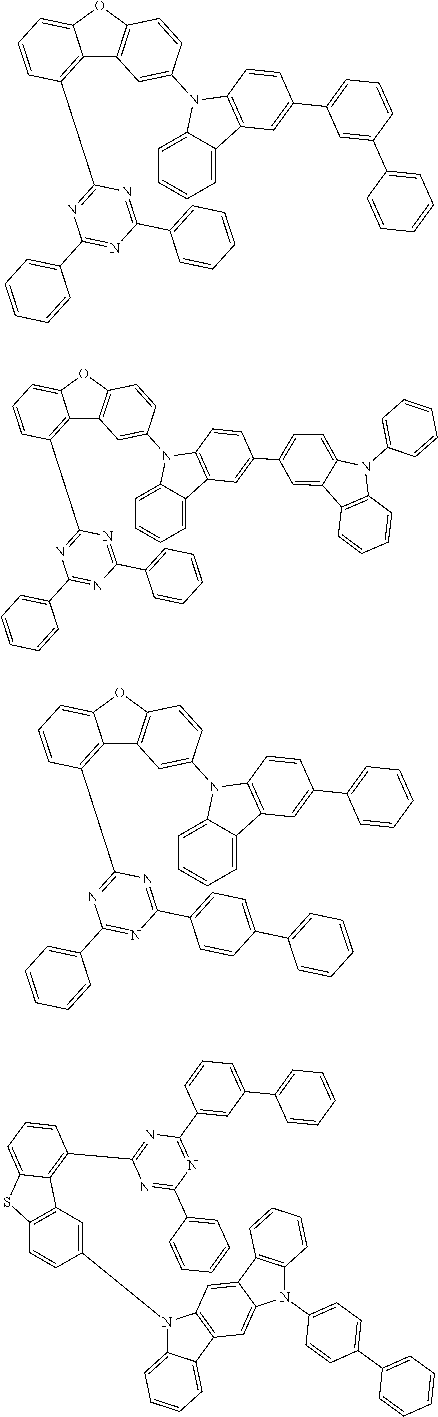 [SMILES: c1ccc(-c2cccc(-c3ccc4c(c3)c3ccccc3n4-c3ccc4oc5cccc(-c6nc(-c7ccccc7)nc(-c7ccccc7)n6)c5c4c3)c2)cc1 ; c1ccc(-c2nc(-c3ccccc3)nc(-c3cccc4oc5ccc(-n6c7ccccc7c7cc(-c8ccc9c(c8)c8ccccc8n9-c8ccccc8)ccc76)cc5c34)n2)cc1 ; c1ccc(-c2ccc(-c3nc(-c4ccccc4)nc(-c4cccc5oc6ccc(-n7c8ccccc8c8cc(-c9ccccc9)ccc87)cc6c45)n3)cc2)cc1 ; c1ccc(-c2ccc(-n3c4ccccc4c4cc5c(cc43)c3ccccc3n5-c3ccc4sc5cccc(-c6nc(-c7ccccc7)nc(-c7cccc(-c8ccccc8)c7)n6)c5c4c3)cc2)cc1]

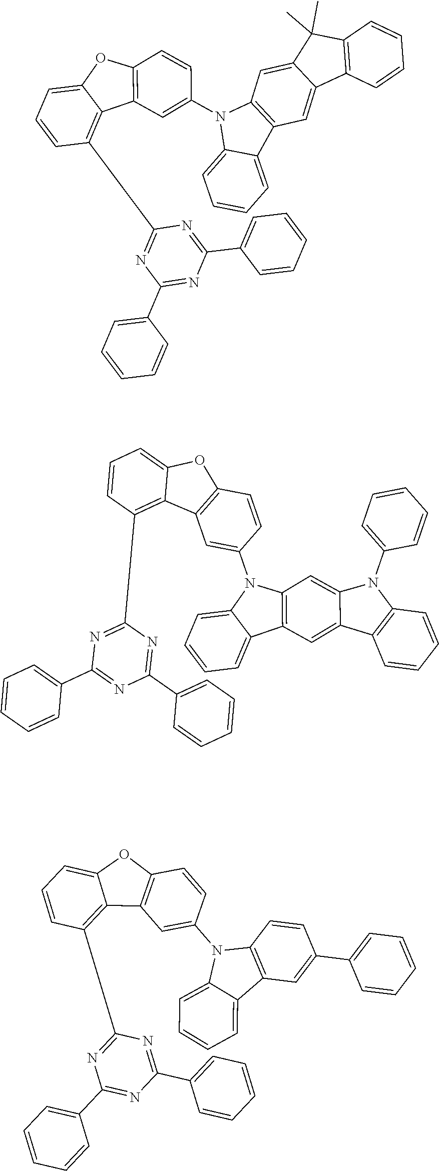 [SMILES: CC1(C)c2ccccc2-c2cc3c4ccccc4n(-c4ccc5oc6cccc(-c7nc(-c8ccccc8)nc(-c8ccccc8)n7)c6c5c4)c3cc21 ; c1ccc(-c2nc(-c3ccccc3)nc(-c3cccc4oc5ccc(-n6c7ccccc7c7cc8c9ccccc9n(-c9ccccc9)c8cc76)cc5c34)n2)cc1 ; c1ccc(-c2ccc3c(c2)c2ccccc2n3-c2ccc3oc4cccc(-c5nc(-c6ccccc6)nc(-c6ccccc6)n5)c4c3c2)cc1]

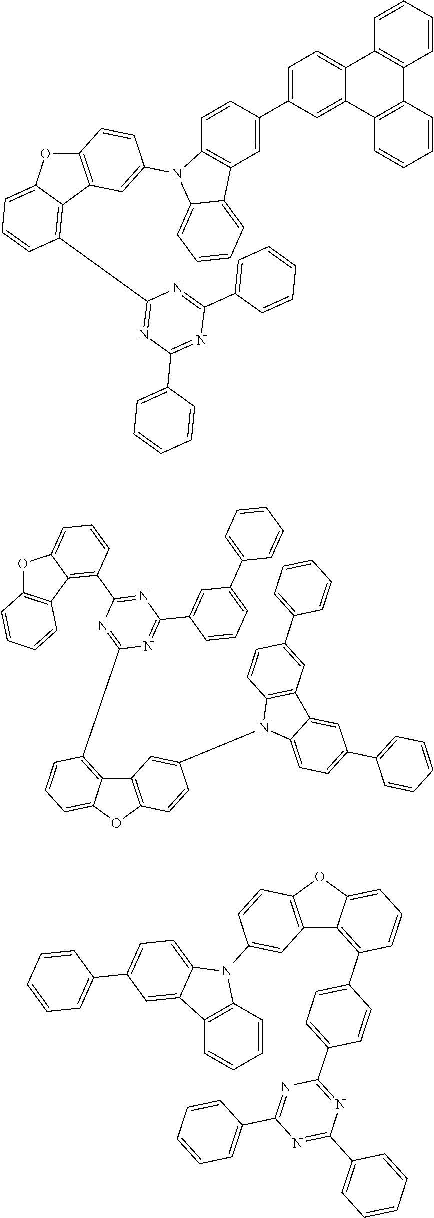 [SMILES: c1ccc(-c2nc(-c3ccccc3)nc(-c3cccc4oc5ccc(-n6c7ccccc7c7cc(-c8ccc9c%10ccccc%10c%10ccccc%10c9c8)ccc76)cc5c34)n2)cc1 ; c1ccc(-c2cccc(-c3nc(-c4cccc5oc6ccccc6c45)nc(-c4cccc5oc6ccc(-n7c8ccc(-c9ccccc9)cc8c8cc(-c9ccccc9)ccc87)cc6c45)n3)c2)cc1 ; c1ccc(-c2ccc3c(c2)c2ccccc2n3-c2ccc3oc4cccc(-c5ccc(-c6nc(-c7ccccc7)nc(-c7ccccc7)n6)cc5)c4c3c2)cc1]

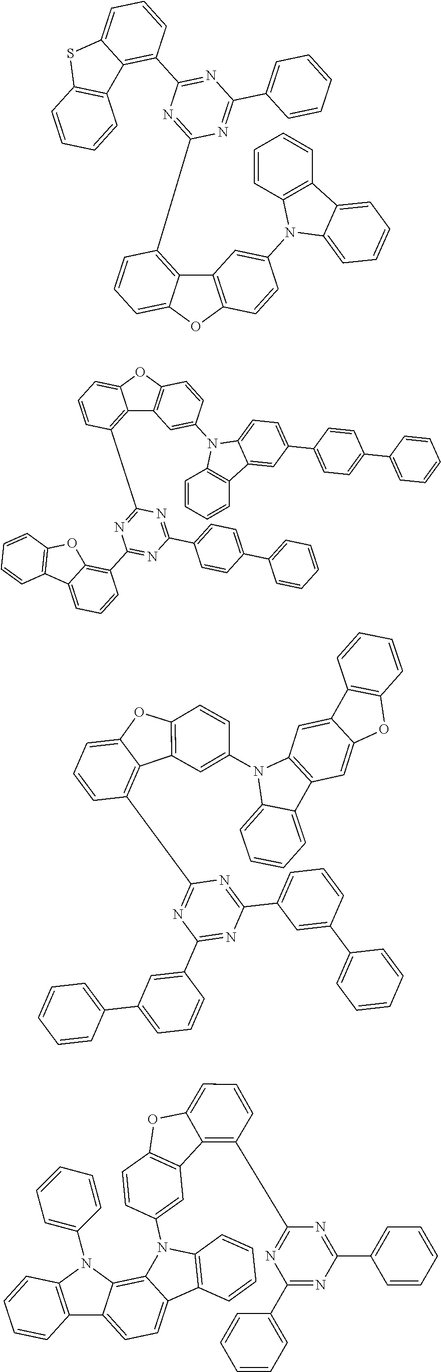 [SMILES: c1ccc(-c2nc(-c3cccc4oc5ccc(-n6c7ccccc7c7ccccc76)cc5c34)nc(-c3cccc4sc5ccccc5c34)n2)cc1 ; c1ccc(-c2ccc(-c3ccc4c(c3)c3ccccc3n4-c3ccc4oc5cccc(-c6nc(-c7ccc(-c8ccccc8)cc7)nc(-c7cccc8c7oc7ccccc78)n6)c5c4c3)cc2)cc1 ; c1ccc(-c2cccc(-c3nc(-c4cccc(-c5ccccc5)c4)nc(-c4cccc5oc6ccc(-n7c8ccccc8c8cc9oc%10ccccc%10c9cc87)cc6c45)n3)c2)cc1 ; c1ccc(-c2nc(-c3ccccc3)nc(-c3cccc4oc5ccc(-n6c7ccccc7c7ccc8c9ccccc9n(-c9ccccc9)c8c76)cc5c34)n2)cc1]

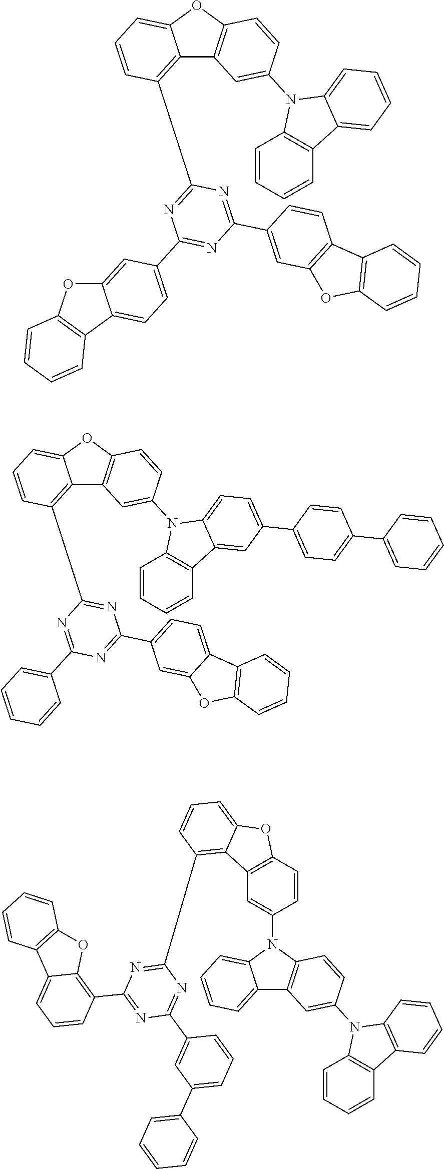 [SMILES: c1ccc2c(c1)oc1cc(-c3nc(-c4ccc5c(c4)oc4ccccc45)nc(-c4cccc5oc6ccc(-n7c8ccccc8c8ccccc87)cc6c45)n3)ccc12 ; c1ccc(-c2ccc(-c3ccc4c(c3)c3ccccc3n4-c3ccc4oc5cccc(-c6nc(-c7ccccc7)nc(-c7ccc8c(c7)oc7ccccc78)n6)c5c4c3)cc2)cc1 ; c1ccc(-c2cccc(-c3nc(-c4cccc5c4oc4ccccc45)nc(-c4cccc5oc6ccc(-n7c8ccccc8c8cc(-n9c%10ccccc%10c%10ccccc%109)ccc87)cc6c45)n3)c2)cc1]

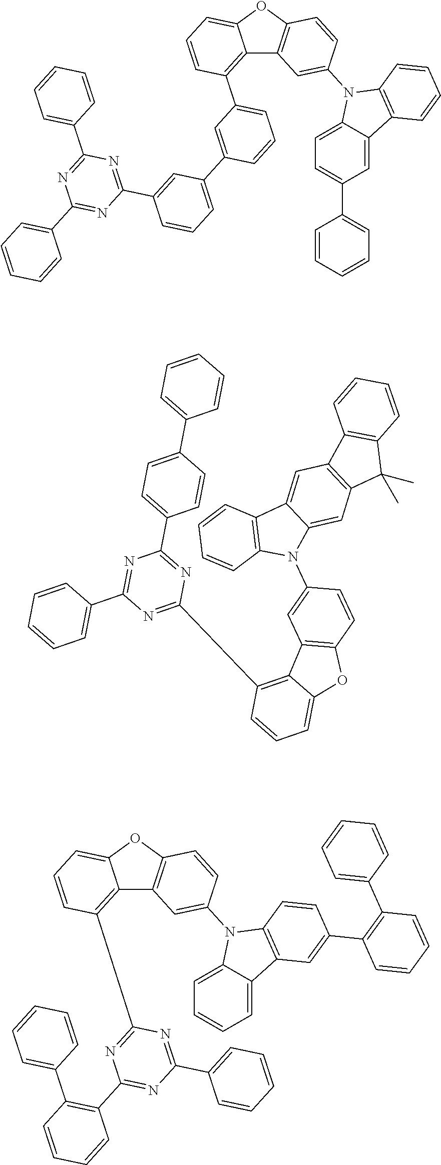 [SMILES: c1ccc(-c2ccc3c(c2)c2ccccc2n3-c2ccc3oc4cccc(-c5cccc(-c6cccc(-c7nc(-c8ccccc8)nc(-c8ccccc8)n7)c6)c5)c4c3c2)cc1 ; CC1(C)c2ccccc2-c2cc3c4ccccc4n(-c4ccc5oc6cccc(-c7nc(-c8ccccc8)nc(-c8ccc(-c9ccccc9)cc8)n7)c6c5c4)c3cc21 ; c1ccc(-c2nc(-c3ccccc3-c3ccccc3)nc(-c3cccc4oc5ccc(-n6c7ccccc7c7cc(-c8ccccc8-c8ccccc8)ccc76)cc5c34)n2)cc1]

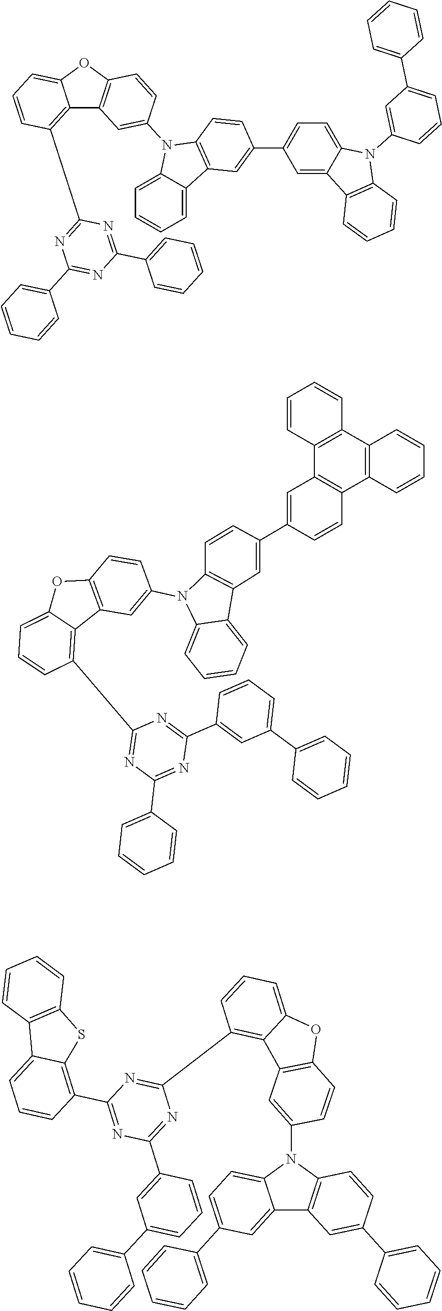 [SMILES: c1ccc(-c2cccc(-n3c4ccccc4c4cc(-c5ccc6c(c5)c5ccccc5n6-c5ccc6oc7cccc(-c8nc(-c9ccccc9)nc(-c9ccccc9)n8)c7c6c5)ccc43)c2)cc1 ; c1ccc(-c2cccc(-c3nc(-c4ccccc4)nc(-c4cccc5oc6ccc(-n7c8ccccc8c8cc(-c9ccc%10c%11ccccc%11c%11ccccc%11c%10c9)ccc87)cc6c45)n3)c2)cc1 ; c1ccc(-c2cccc(-c3nc(-c4cccc5c4sc4ccccc45)nc(-c4cccc5oc6ccc(-n7c8ccc(-c9ccccc9)cc8c8cc(-c9ccccc9)ccc87)cc6c45)n3)c2)cc1]

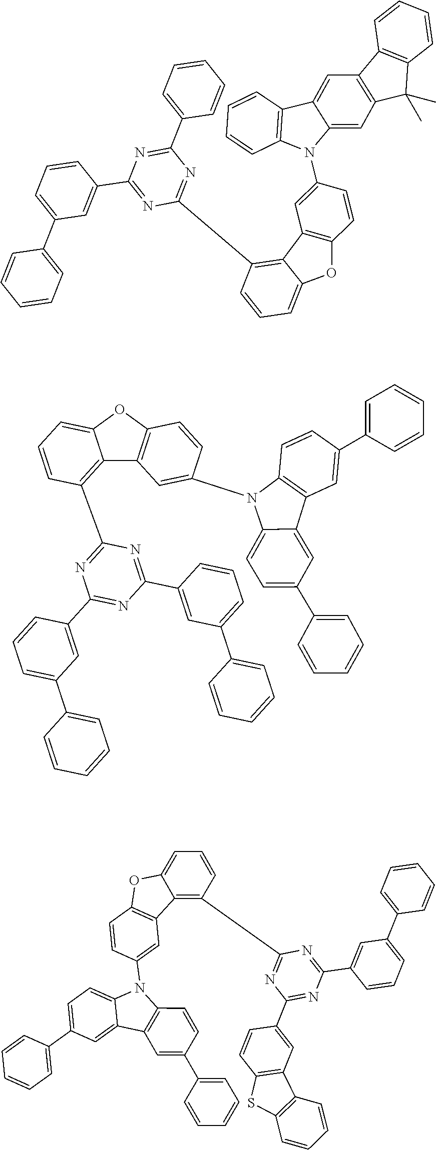 [SMILES: CC1(C)c2ccccc2-c2cc3c4ccccc4n(-c4ccc5oc6cccc(-c7nc(-c8ccccc8)nc(-c8cccc(-c9ccccc9)c8)n7)c6c5c4)c3cc21 ; c1ccc(-c2cccc(-c3nc(-c4cccc(-c5ccccc5)c4)nc(-c4cccc5oc6ccc(-n7c8ccc(-c9ccccc9)cc8c8cc(-c9ccccc9)ccc87)cc6c45)n3)c2)cc1 ; c1ccc(-c2cccc(-c3nc(-c4ccc5sc6ccccc6c5c4)nc(-c4cccc5oc6ccc(-n7c8ccc(-c9ccccc9)cc8c8cc(-c9ccccc9)ccc87)cc6c45)n3)c2)cc1]

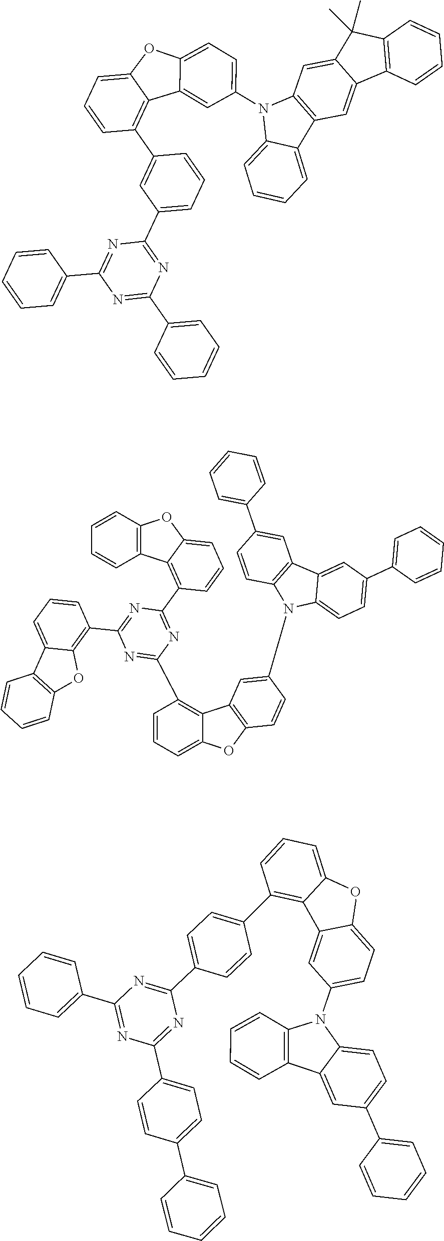 [SMILES: CC1(C)c2ccccc2-c2cc3c4ccccc4n(-c4ccc5oc6cccc(-c7cccc(-c8nc(-c9ccccc9)nc(-c9ccccc9)n8)c7)c6c5c4)c3cc21 ; c1ccc(-c2ccc3c(c2)c2cc(-c4ccccc4)ccc2n3-c2ccc3oc4cccc(-c5nc(-c6cccc7c6oc6ccccc67)nc(-c6cccc7oc8ccccc8c67)n5)c4c3c2)cc1 ; c1ccc(-c2ccc(-c3nc(-c4ccccc4)nc(-c4ccc(-c5cccc6oc7ccc(-n8c9ccccc9c9cc(-c%10ccccc%10)ccc98)cc7c56)cc4)n3)cc2)cc1]

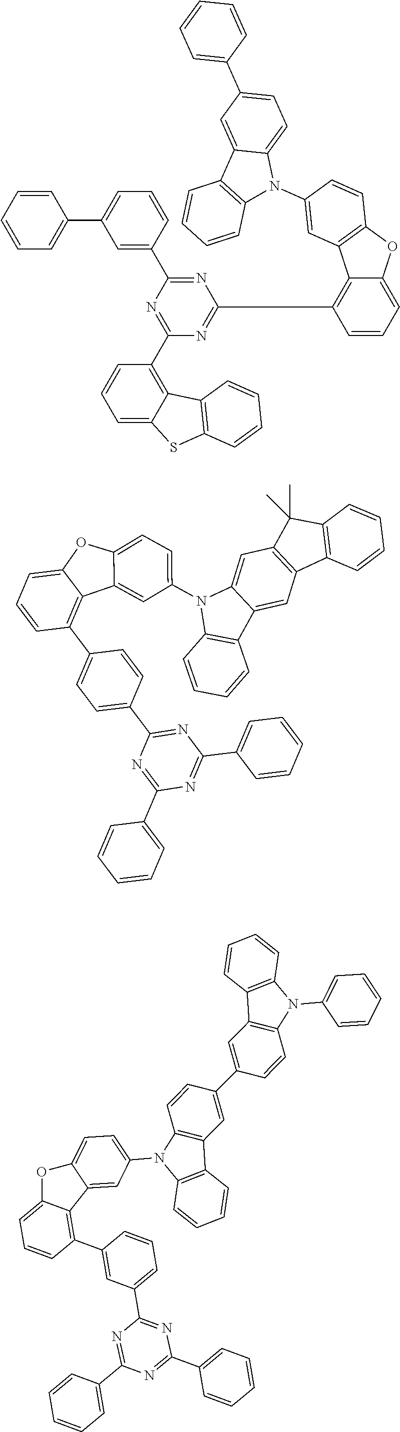 [SMILES: c1ccc(-c2cccc(-c3nc(-c4cccc5oc6ccc(-n7c8ccccc8c8cc(-c9ccccc9)ccc87)cc6c45)nc(-c4cccc5sc6ccccc6c45)n3)c2)cc1 ; CC1(C)c2ccccc2-c2cc3c4ccccc4n(-c4ccc5oc6cccc(-c7ccc(-c8nc(-c9ccccc9)nc(-c9ccccc9)n8)cc7)c6c5c4)c3cc21 ; c1ccc(-c2nc(-c3ccccc3)nc(-c3cccc(-c4cccc5oc6ccc(-n7c8ccccc8c8cc(-c9ccc%10c(c9)c9ccccc9n%10-c9ccccc9)ccc87)cc6c45)c3)n2)cc1]

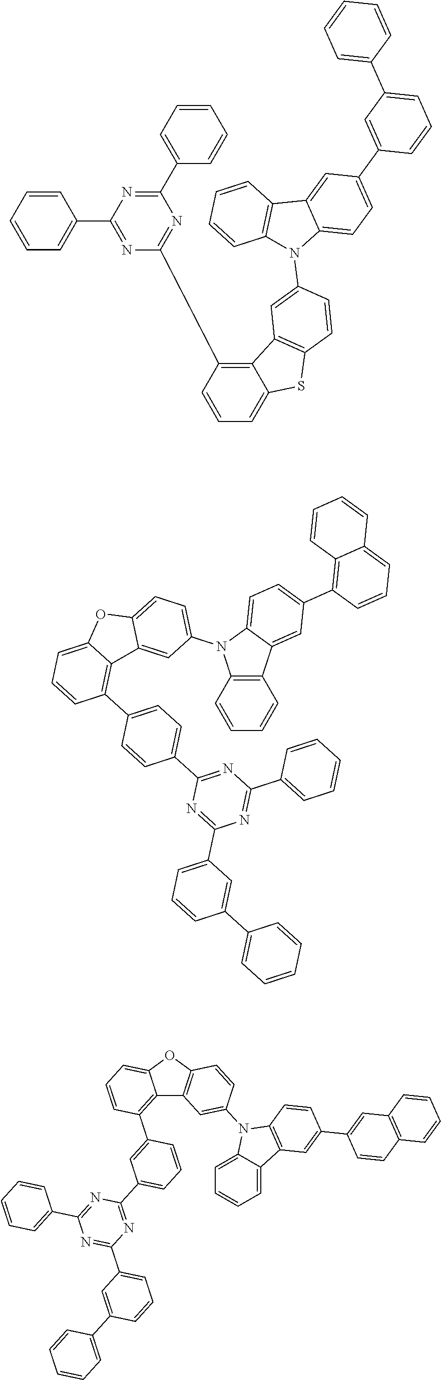 [SMILES: c1ccc(-c2cccc(-c3ccc4c(c3)c3ccccc3n4-c3ccc4sc5cccc(-c6nc(-c7ccccc7)nc(-c7ccccc7)n6)c5c4c3)c2)cc1 ; c1ccc(-c2cccc(-c3nc(-c4ccccc4)nc(-c4ccc(-c5cccc6oc7ccc(-n8c9ccccc9c9cc(-c%10cccc%11ccccc%10%11)ccc98)cc7c56)cc4)n3)c2)cc1 ; c1ccc(-c2cccc(-c3nc(-c4ccccc4)nc(-c4cccc(-c5cccc6oc7ccc(-n8c9ccccc9c9cc(-c%10ccc%11ccccc%11c%10)ccc98)cc7c56)c4)n3)c2)cc1]

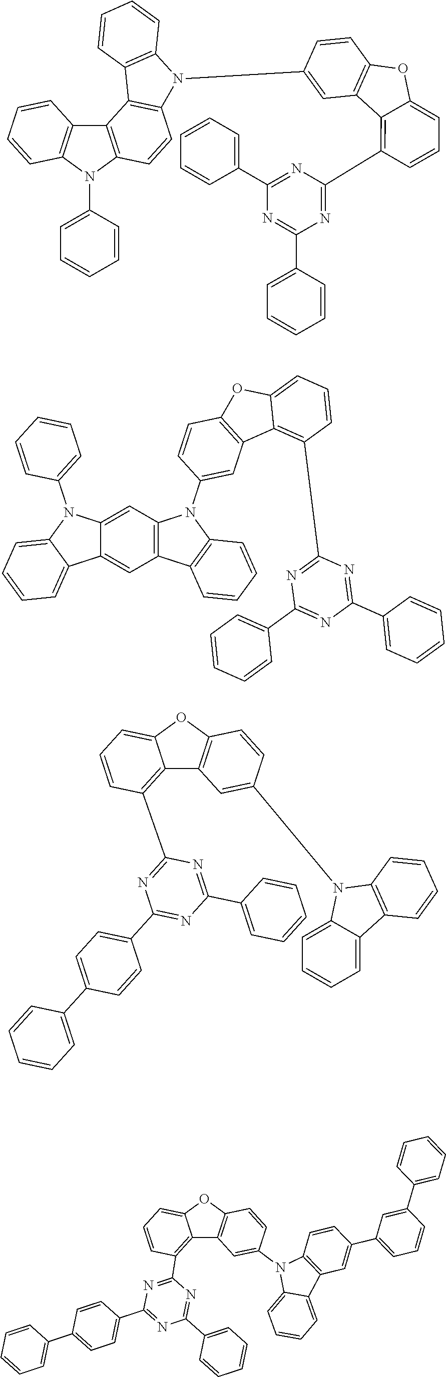

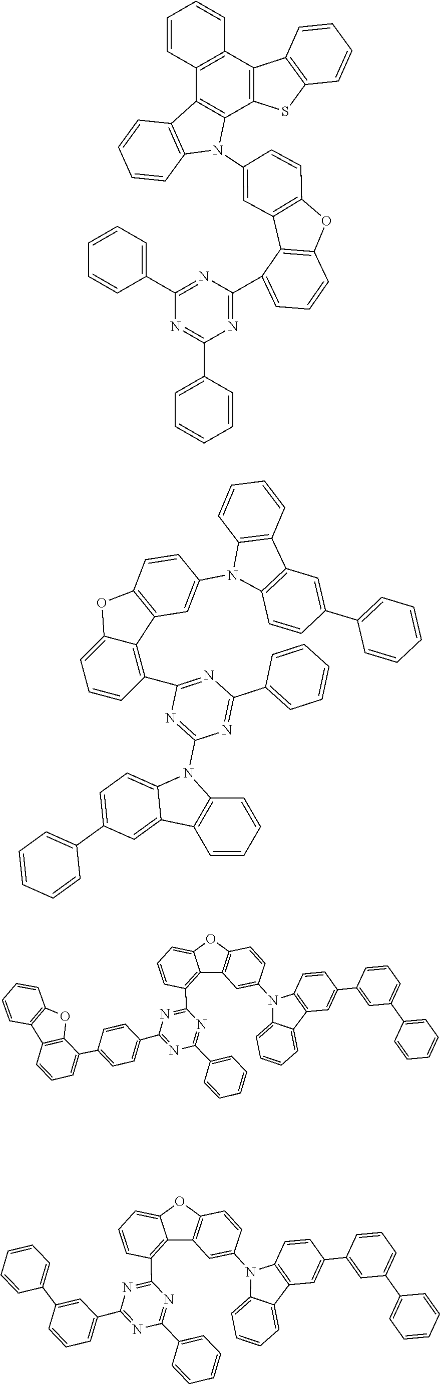 [SMILES: c1ccc(-c2nc(-c3ccccc3)nc(-c3cccc4oc5ccc(-n6c7ccccc7c7c8ccccc8c8c9ccccc9sc8c76)cc5c34)n2)cc1 ; c1ccc(-c2ccc3c(c2)c2ccccc2n3-c2ccc3oc4cccc(-c5nc(-c6ccccc6)nc(-n6c7ccccc7c7cc(-c8ccccc8)ccc76)n5)c4c3c2)cc1 ; c1ccc(-c2cccc(-c3ccc4c(c3)c3ccccc3n4-c3ccc4oc5cccc(-c6nc(-c7ccccc7)nc(-c7ccc(-c8cccc9c8oc8ccccc89)cc7)n6)c5c4c3)c2)cc1 ; c1ccc(-c2cccc(-c3ccc4c(c3)c3ccccc3n4-c3ccc4oc5cccc(-c6nc(-c7ccccc7)nc(-c7cccc(-c8ccccc8)c7)n6)c5c4c3)c2)cc1]

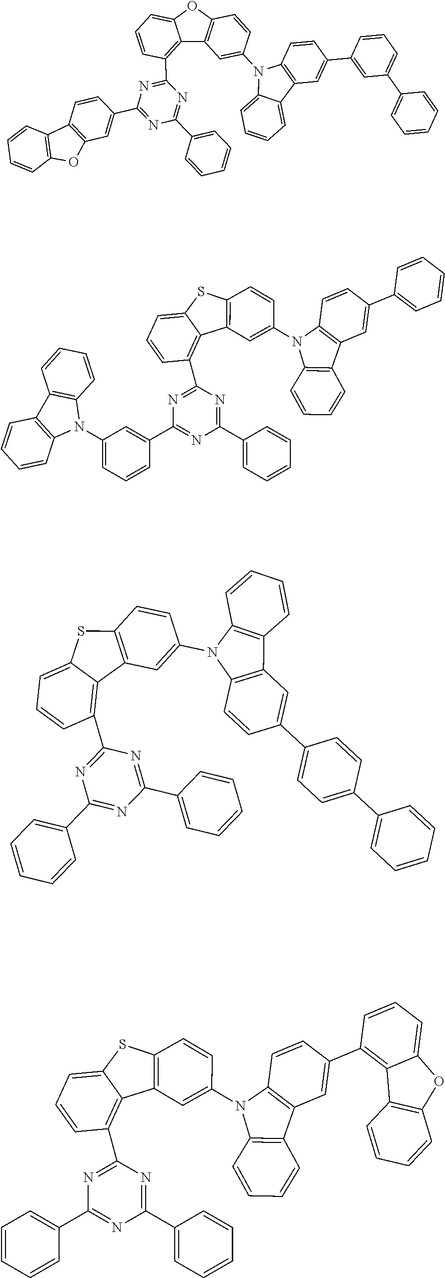 [SMILES: c1ccc(-c2cccc(-c3ccc4c(c3)c3ccccc3n4-c3ccc4oc5cccc(-c6nc(-c7ccccc7)nc(-c7ccc8c(c7)oc7ccccc78)n6)c5c4c3)c2)cc1 ; c1ccc(-c2ccc3c(c2)c2ccccc2n3-c2ccc3sc4cccc(-c5nc(-c6ccccc6)nc(-c6cccc(-n7c8ccccc8c8ccccc87)c6)n5)c4c3c2)cc1 ; c1ccc(-c2ccc(-c3ccc4c(c3)c3ccccc3n4-c3ccc4sc5cccc(-c6nc(-c7ccccc7)nc(-c7ccccc7)n6)c5c4c3)cc2)cc1 ; c1ccc(-c2nc(-c3ccccc3)nc(-c3cccc4sc5ccc(-n6c7ccccc7c7cc(-c8cccc9oc%10ccccc%10c89)ccc76)cc5c34)n2)cc1]

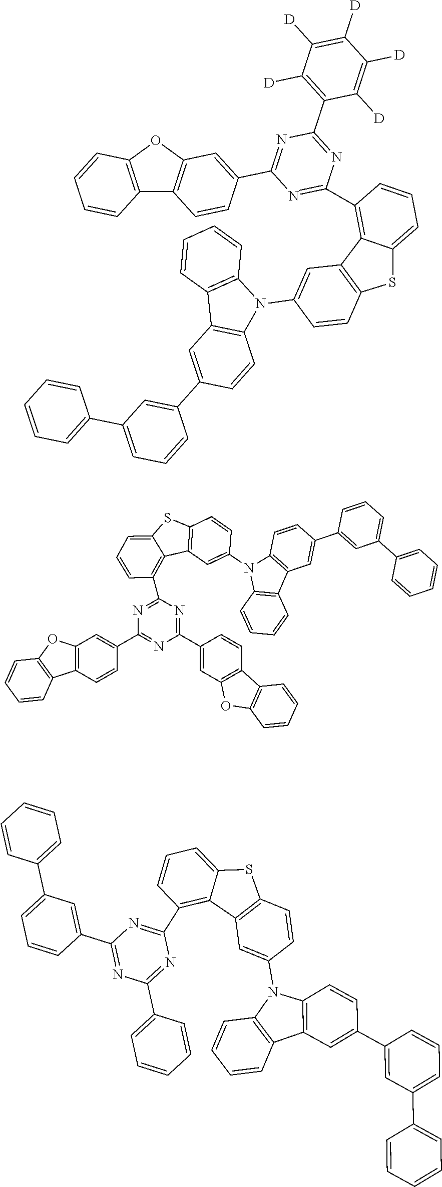 [SMILES: [2H]c1c([2H])c([2H])c(-c2nc(-c3ccc4c(c3)oc3ccccc34)nc(-c3cccc4sc5ccc(-n6c7ccccc7c7cc(-c8cccc(-c9ccccc9)c8)ccc76)cc5c34)n2)c([2H])c1[2H] ; c1ccc(-c2cccc(-c3ccc4c(c3)c3ccccc3n4-c3ccc4sc5cccc(-c6nc(-c7ccc8c(c7)oc7ccccc78)nc(-c7ccc8c(c7)oc7ccccc78)n6)c5c4c3)c2)cc1 ; c1ccc(-c2cccc(-c3ccc4c(c3)c3ccccc3n4-c3ccc4sc5cccc(-c6nc(-c7ccccc7)nc(-c7cccc(-c8ccccc8)c7)n6)c5c4c3)c2)cc1]

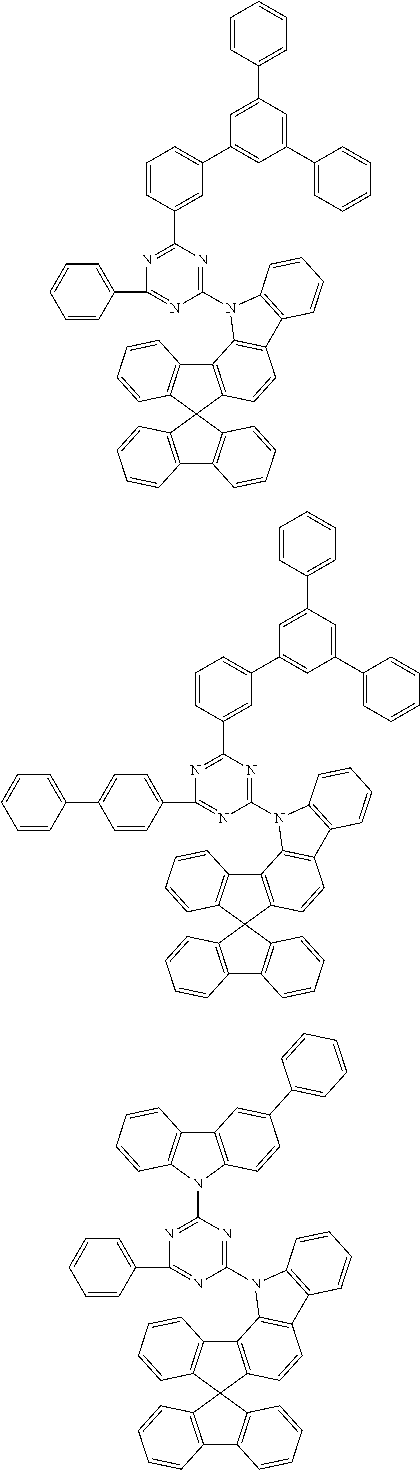

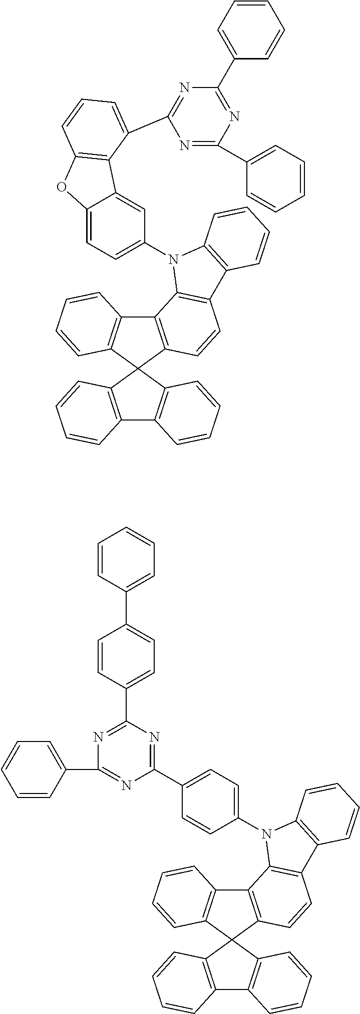 [SMILES: c1ccc(-c2nc(-c3ccccc3)nc(-c3cccc4oc5ccc(-n6c7ccccc7c7ccc8c(c76)-c6ccccc6C86c7ccccc7-c7ccccc76)cc5c34)n2)cc1 ; c1ccc(-c2ccc(-c3nc(-c4ccccc4)nc(-c4ccc(-n5c6ccccc6c6ccc7c(c65)-c5ccccc5C75c6ccccc6-c6ccccc65)cc4)n3)cc2)cc1]

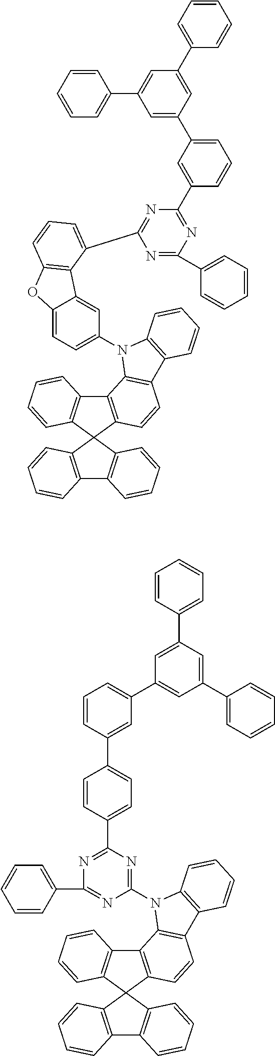 [SMILES: c1ccc(-c2cc(-c3ccccc3)cc(-c3cccc(-c4nc(-c5ccccc5)nc(-c5cccc6oc7ccc(-n8c9ccccc9c9ccc%10c(c98)-c8ccccc8C%108c9ccccc9-c9ccccc98)cc7c56)n4)c3)c2)cc1 ; c1ccc(-c2cc(-c3ccccc3)cc(-c3cccc(-c4ccc(-c5nc(-c6ccccc6)nc(-n6c7ccccc7c7ccc8c(c76)-c6ccccc6C86c7ccccc7-c7ccccc76)n5)cc4)c3)c2)cc1]

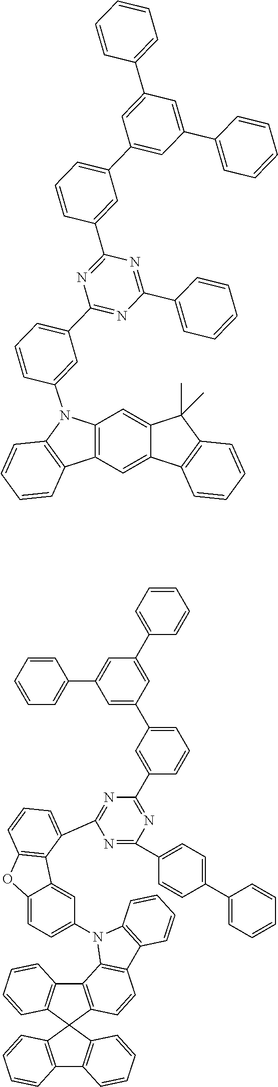 [SMILES: CC1(C)c2ccccc2-c2cc3c4ccccc4n(-c4cccc(-c5nc(-c6ccccc6)nc(-c6cccc(-c7cc(-c8ccccc8)cc(-c8ccccc8)c7)c6)n5)c4)c3cc21 ; c1ccc(-c2ccc(-c3nc(-c4cccc(-c5cc(-c6ccccc6)cc(-c6ccccc6)c5)c4)nc(-c4cccc5oc6ccc(-n7c8ccccc8c8ccc9c(c87)-c7ccccc7C97c8ccccc8-c8ccccc87)cc6c45)n3)cc2)cc1]

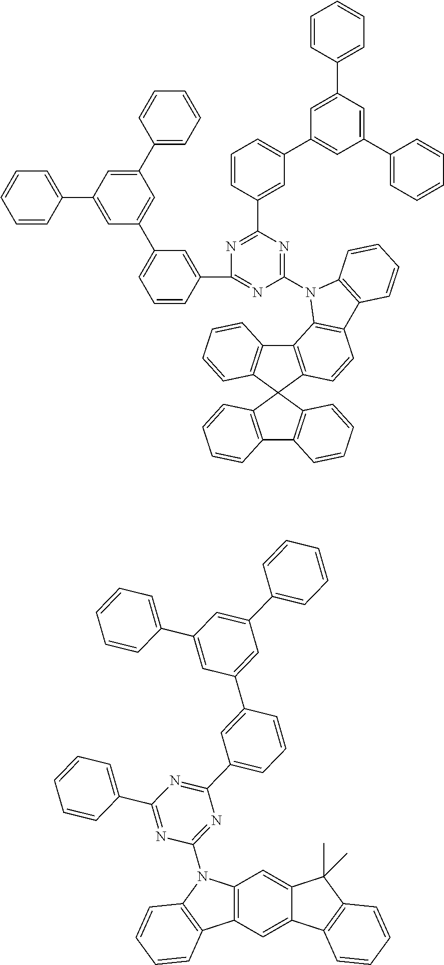 [SMILES: c1ccc(-c2cc(-c3ccccc3)cc(-c3cccc(-c4nc(-c5cccc(-c6cc(-c7ccccc7)cc(-c7ccccc7)c6)c5)nc(-n5c6ccccc6c6ccc7c(c65)-c5ccccc5C75c6ccccc6-c6ccccc65)n4)c3)c2)cc1 ; CC1(C)c2ccccc2-c2cc3c4ccccc4n(-c4nc(-c5ccccc5)nc(-c5cccc(-c6cc(-c7ccccc7)cc(-c7ccccc7)c6)c5)n4)c3cc21]

Examples of suitable quinazoline compounds are those shown in the following table:

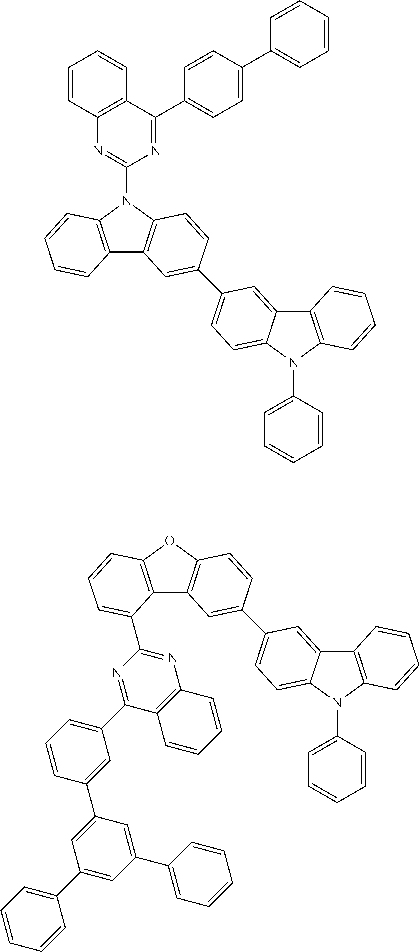 [SMILES: c1ccc(-c2ccc(-c3nc(-n4c5ccccc5c5cc(-c6ccc7c(c6)c6ccccc6n7-c6ccccc6)ccc54)nc4ccccc34)cc2)cc1 ; c1ccc(-c2cc(-c3ccccc3)cc(-c3cccc(-c4nc(-c5cccc6oc7ccc(-c8ccc9c(c8)c8ccccc8n9-c8ccccc8)cc7c56)nc5ccccc45)c3)c2)cc1]

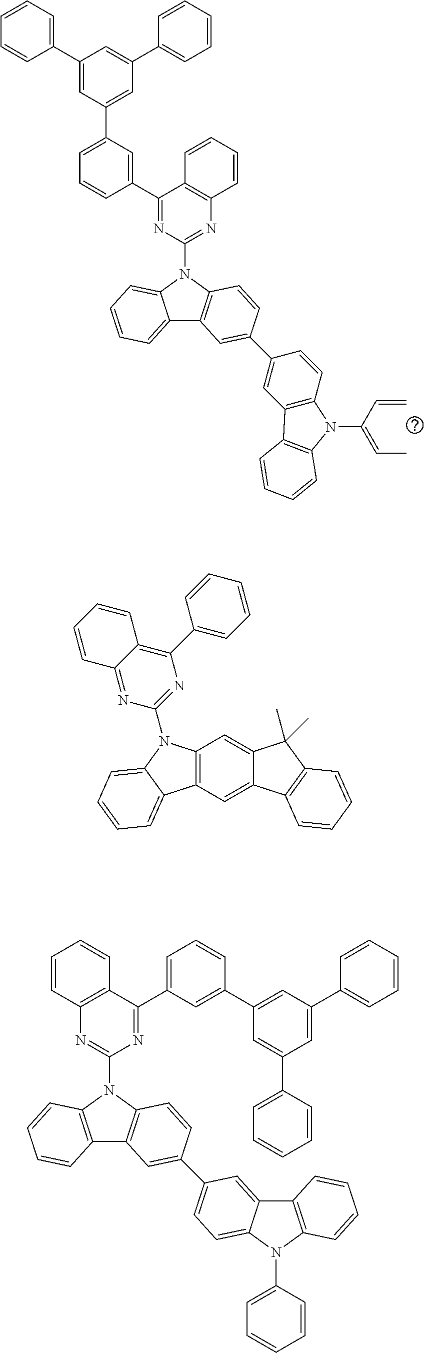 [SMILES: C=C/C(=C\C)n1c2ccccc2c2cc(-c3ccc4c(c3)c3ccccc3n4-c3nc(-c4cccc(-c5cc(-c6ccccc6)cc(-c6ccccc6)c5)c4)c4ccccc4n3)ccc21 ; CC1(C)c2ccccc2-c2cc3c4ccccc4n(-c4nc(-c5ccccc5)c5ccccc5n4)c3cc21 ; c1ccc(-c2cc(-c3ccccc3)cc(-c3cccc(-c4nc(-n5c6ccccc6c6cc(-c7ccc8c(c7)c7ccccc7n8-c7ccccc7)ccc65)nc5ccccc45)c3)c2)cc1]

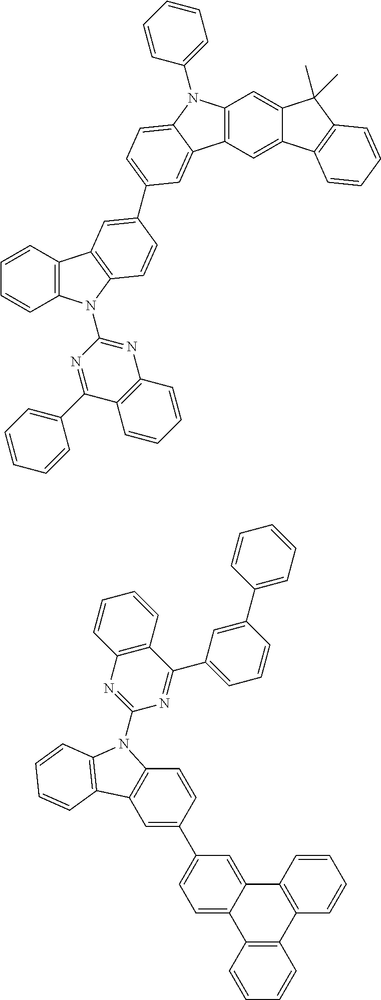 [SMILES: CC1(C)c2ccccc2-c2cc3c4cc(-c5ccc6c(c5)c5ccccc5n6-c5nc(-c6ccccc6)c6ccccc6n5)ccc4n(-c4ccccc4)c3cc21 ; c1ccc(-c2cccc(-c3nc(-n4c5ccccc5c5cc(-c6ccc7c8ccccc8c8ccccc8c7c6)ccc54)nc4ccccc34)c2)cc1]

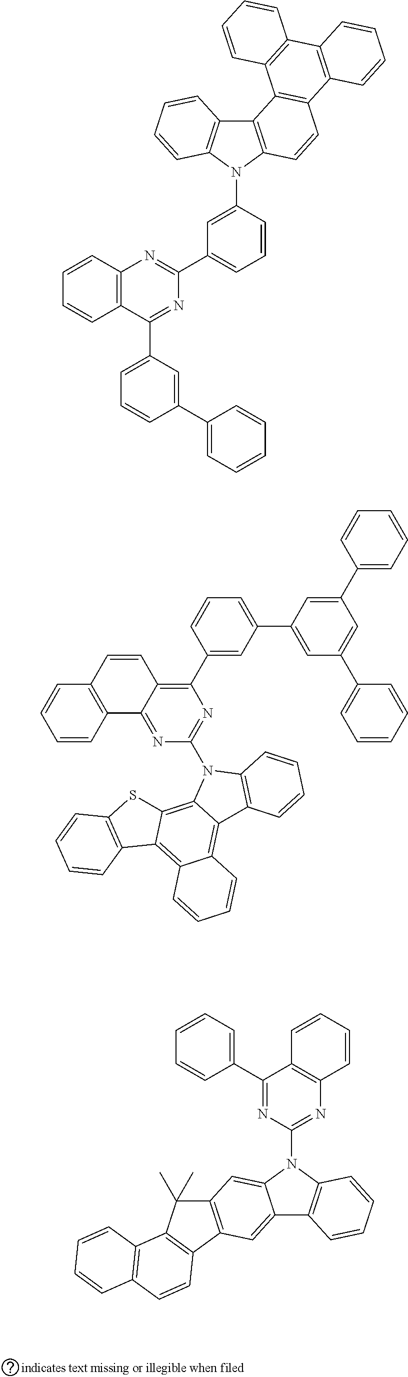 [SMILES: c1ccc(-c2cccc(-c3nc(-c4cccc(-n5c6ccccc6c6c7c8ccccc8c8ccccc8c7ccc65)c4)nc4ccccc34)c2)cc1 ; c1ccc(-c2cc(-c3ccccc3)cc(-c3cccc(-c4nc(-n5c6ccccc6c6c7ccccc7c7c8ccccc8sc7c65)nc5c4ccc4ccccc45)c3)c2)cc1 ; CC1(C)c2cc3c(cc2-c2ccc4ccccc4c21)c1ccccc1n3-c1nc(-c2ccccc2)c2ccccc2n1]

Examples of suitable hole transporting host materials are the compounds of the following formulas (hTMM-1) to (hTMM-6),

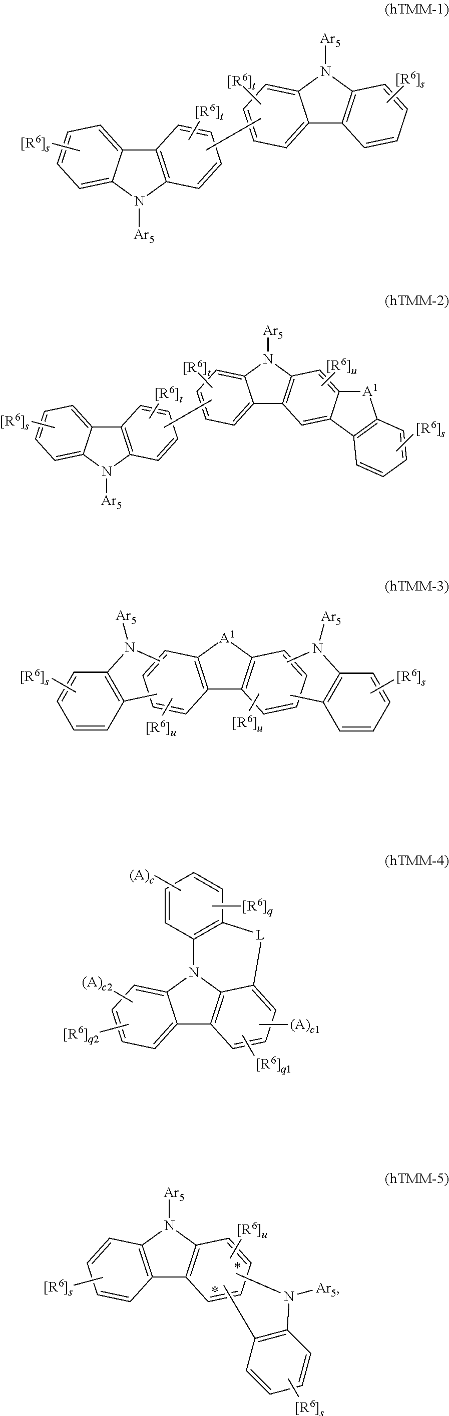

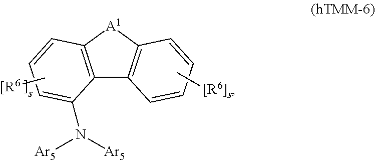

wherein the following applies to the symbols and indices used:
A¹ is C(R⁷)₂, NR⁷, O, or S;
L is a bond, O, S, C(R⁷)₂, or NR⁷;
A is at each occurrence independently a group of the formula (Carb-1) or (Carb-2),

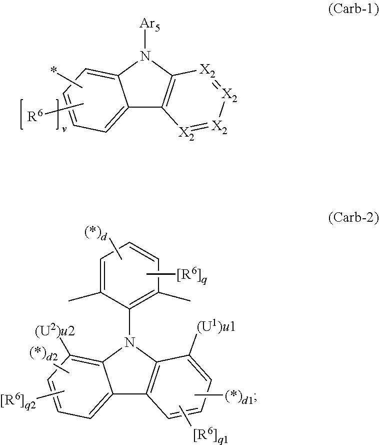

X₂ is at each occurrence the same or different and is CH, CR⁶ or N, wherein a maximum of 2 symbols X₂ can be N;
* indicates the binding site to the formula (hTMM-4);
U¹, U² when present, are a bond, O, S, C(R⁷)₂, or NR¹;
R⁶ is at each occurrence the same or different and is D, F, CN, a straight chain alkyl group having 1 to 20 C-atoms, or an alkenyl- or alkynyl group having 2 to 20 C-atoms, or a branched or cyclic alkyl group having 3 to 20 C-atoms, wherein the alkyl-, alkenyl or alkynyl group may in each case be substituted by one or more radicals R⁷, and wherein one or more non-adjacent CH₂ groups may be replaced by Si(R⁷)₂, C═O, NR⁷, O, S, or CONR⁷, or an aromatic or heteroaromatic ring system having 5 to 60 ring atoms, which may in each case be substituted by one or more radicals R⁷; two radicals R⁶ can also form an aromatic, heteroaromatic, aliphatic, or heteroaliphatic ring system with each other;
Ar₅ is at each occurrence the same or different and is independently an aromatic or heteroaromatic ring system having from 5 to 40 ring atoms, which may be substituted with one or more R⁷ radicals;
R⁷ is at each occurrence the same or different and is D, F, Cl, Br, I, N(R⁸)₂, CN, NO₂, OR⁸, SR⁸, Si(R⁸)₃, B(OR⁸)₂, C(═O)R⁸, P(═O)(R⁸)₂, S(═O)R⁸, S(═O)₂R⁸, OSO₂R⁸, a straight-chain alkyl group having 1 to 20 carbon atoms, or an alkenyl or alkynyl group having 2 to 20 carbon atoms, or a branched or cyclic alkyl group having 3 to 20 carbon atoms, wherein the alkyl, alkenyl or alkynyl group may in each case be substituted by one or more radicals R⁸, wherein one or more non-adjacent CH₂ groups may be replaced by Si(R⁸)₂, C═O, NR^{B}, O, S, or CONR⁸, or an aromatic or heteroaromatic ring system having 5 to 40 ring atoms, which may in each case be substituted by one or more radicals R⁸; wherein two or more radicals R⁷ can together form an aromatic, heteroaromatic, aliphatic, or heteroaliphatic ring system, preferably the radicals R⁷ do not form such a ring system;
R⁸ is at each occurrence the same or different and is H, D, F, or an aliphatic, aromatic, or heteroaromatic organic radical, in particular a hydrocarbon radical, having 1 to 20 carbon atoms, in which one or more H-atoms may also be replaced by F;
c, c1, c2 each independently are 0 or 1 at each occurrence, wherein the sum of the indices at each occurrence is c+c1+c2=1;
d, d1, d2 independently of each other are 0 or 1 at each occurrence, wherein the sum of the indices at each occurrence is d+d1+d2=1;
q, q1, q2 independently are 0 or 1 at each occurrence;
s is at each occurrence the same or different and is 0, 1, 2, 3, or 4;
t is at each occurrence the same or different and is 0, 1, 2, or 3;
u is at each occurrence the same or different and is 0, 1, or 2;
u1, u2 each independently are 0 or 1 at each occurrence, wherein the sum u1+u2=1; and
v is 0 or 1.

In compounds of the formulae (hTMM-1) to (hTMM-3), (hTMM-5) and (hTMM-6), s is preferably 0 or 1 if the radical R⁶ is different from D, or particularly preferably 0. In compounds of the formulae (hTMM-1) to (hTMM-3), t is preferably 0 or 1 if the radical R⁶ is different from D, or particularly preferably 0. In compounds of the formulae (hTMM-1) to (hTMM-3) or (hTMM-5), u is preferably 0 or 1 if the radical R⁶ is different from D, or particularly preferably 0. The sum of the indices s, t and u in compounds of the formulae (hTMM-1) to (hTMM-3), (hTMM-5) and (hTMM-6) is preferably at most 6, in particular preferably at most 4 and particularly preferably at most 2. This applies preferably if R⁶ is different from D.

In compounds of formula (hTMM-4), c, c1, c2 are each independently 0 or 1 at each occurrence, the sum of the indices c+c1+c2 at each occurrence being 1. Preferably, c2 is 1. In compounds of formula (hTMM-4), L is preferably a single bond or C(R⁷)₂, wherein R⁷ has a previously mentioned meaning, particularly preferably L is a single bond.

In formula (Carb-2), U¹ or U² when occurring is preferably a single bond or C(R⁷)₂ wherein R⁷ has the previously mentioned meaning, U¹ or U² when occurring is particularly preferably a single bond.

In a preferred embodiment of the compounds of the formulae (hTMM-1) to (hTMM-6), R⁶ is the same or different at each occurrence selected from the group consisting of D, F, CN, a straight-chain alkyl group having 1 to 20 carbon atoms or a branched or cyclic alkyl group having 3 to 20 carbon atoms, wherein the alkyl group may in each case be substituted by one or more radicals R⁷, or an aromatic or heteroaromatic ring system having 5 to 60 ring atoms, preferably having 5 to 40 ring atoms, which may in each case be substituted by one or more radicals R⁷. In a particularly preferred embodiment of the compounds of the formulae (hTM-1) to (hTMM-6), which can be combined in accordance with the invention with compounds of the formula (1) as described above, R⁶ is the same or different at each occurrence and is selected from the group consisting of D, or an aromatic or heteroaromatic ring system having 6 to 30 ring atoms, which can be substituted by one or more radicals R⁷.

Ar₅ in compounds of the formulae (hTMM-1) to (hTMM-3), (hTMM-5) or (hTMM-6) is preferably selected from phenyl, biphenyl, in particular ortho-, meta- or para-biphenyl, terphenyl, in particular ortho-, meta-, para-, or branched terphenyl, quaterphenyl, in particular ortho-, meta-, para-, or branched quaterphenyl, fluorenyl, which can be linked via the 1-, 2-, 3-, or 4-position, spirobifluorenyl, which can be linked via the 1-, 2-, 3-, or 4-position, naphthyl, in particular 1- or 2-linked naphthyl, or radicals derived from indole, benzofuran, benzothiophene, carbazole, which can be linked via the 1-, 2-, 3-, or 4-position, dibenzofuran, which can be linked via the 1-, 2-, 3-, or 4-position, dibenzothiophene, which can be linked via the 1-, 2-, 3-, or 4-position, indenocarbazole, indolocarbazole, pyridine, pyrimidine, pyrazine, pyridazine, triazine, quinoline, iso quinoline, quinazoline, quinoxaline, phenanthrene or triphenylene, each of which may be substituted with one or more R⁷ radicals. Preferably, Ar₅ is unsubstituted.

If A¹ in formula (hTMM-2), (hTMM-3) or (hTMM-6) stands for NR⁷, the substituent R⁷, which is bonded to the nitrogen atom, preferably is an aromatic or heteroaromatic ring system with 5 to 24 aromatic ring atoms, which can also be substituted by one or more radicals R⁸. In a particularly preferred embodiment, this substituent R⁷, the same or different at each occurrence, represents an aromatic or heteroaromatic ring system having 6 to 24 aromatic ring atoms, in particular having 6 to 18 aromatic ring atoms.

Preferred embodiments for R⁷ are phenyl, biphenyl, terphenyl, and quaterphenyl, which are preferably unsubstituted, and radicals derived from triazine, pyrimidine, and quinazoline, which may be substituted by one or more radicals R⁸.

When A¹ in formula (hTMM-2), (hTMM-3), or (hTMM-6) stands for C(R⁷)₂, the substituents R⁷ bonded to this carbon atom, preferably the same or different at each occurrence, represent a linear alkyl group having 1 to 10 carbon atoms or a branched or cyclic alkyl group having 3 to 10 carbon atoms, or an aromatic or heteroaromatic ring system having 5 to 24 aromatic ring atoms, which may also be substituted by one or more radicals R⁸. Very preferably, R⁷ represents a methyl group or a phenyl group. The radicals R⁷ can also form a ring system with each other, resulting in a spiro system.

In a preferred embodiment of the compounds of formulae (hTMM-1) to (hTMM-6), these compounds are partially or completely deuterated, particularly preferably completely deuterated.

The preparation of the compounds of formulae (hTMM-1) to (hTMM-6) are generally known, and some of the compounds are commercially available.

Further examples of suitable host materials of formulae (hTMM-1) to (hTMM-6) for combination with compounds of formula (1) are the structures mentioned below.

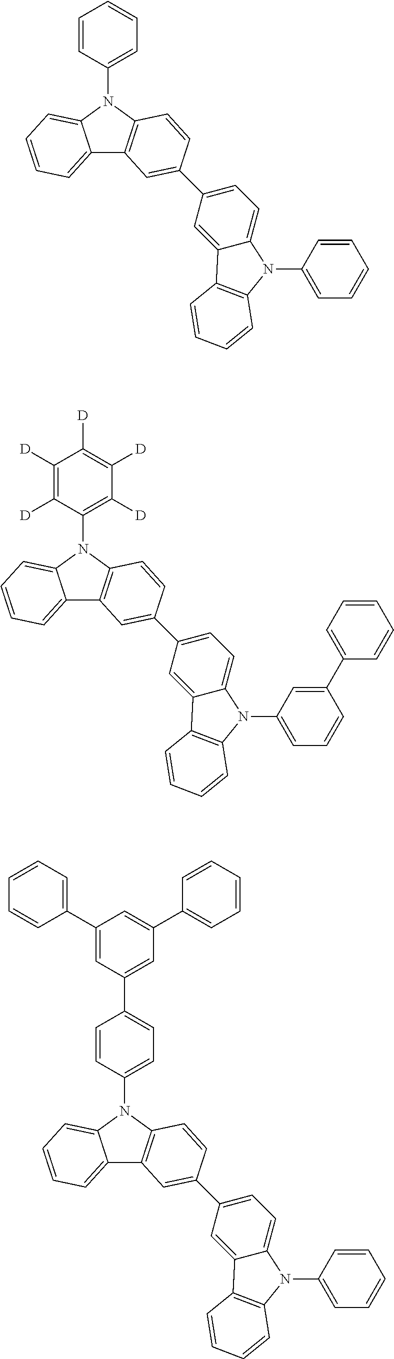 [SMILES: c1ccc(-n2c3ccccc3c3cc(-c4ccc5c(c4)c4ccccc4n5-c4ccccc4)ccc32)cc1 ; [2H]c1c([2H])c([2H])c(-n2c3ccccc3c3cc(-c4ccc5c(c4)c4ccccc4n5-c4cccc(-c5ccccc5)c4)ccc32)c([2H])c1[2H] ; c1ccc(-c2cc(-c3ccccc3)cc(-c3ccc(-n4c5ccccc5c5cc(-c6ccc7c(c6)c6ccccc6n7-c6ccccc6)ccc54)cc3)c2)cc1]

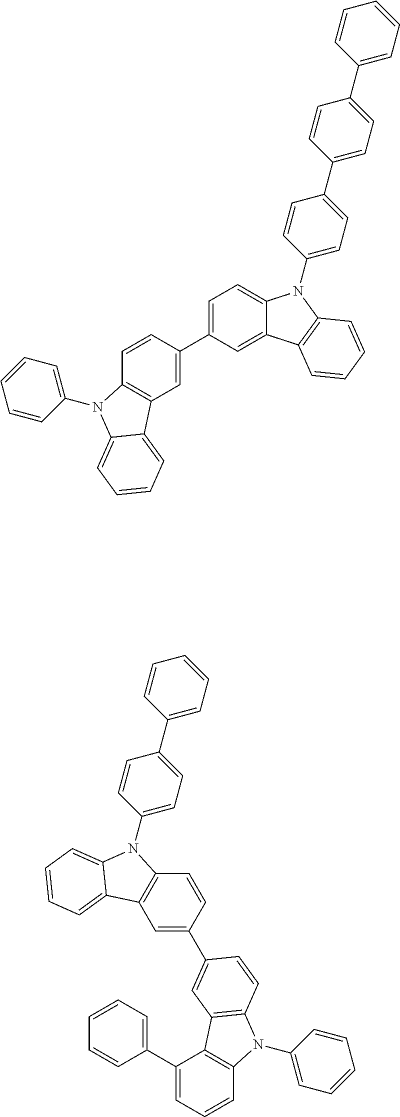 [SMILES: c1ccc(-c2ccc(-c3ccc(-n4c5ccccc5c5cc(-c6ccc7c(c6)c6ccccc6n7-c6ccccc6)ccc54)cc3)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1]

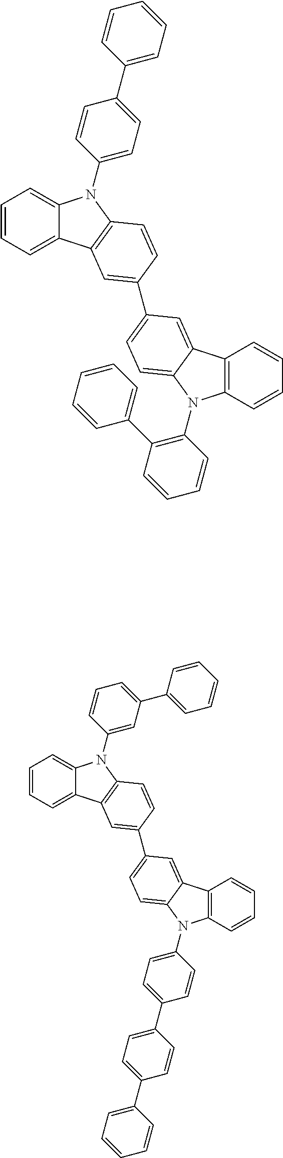 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-c3ccc(-n4c5ccccc5c5cc(-c6ccc7c(c6)c6ccccc6n7-c6cccc(-c7ccccc7)c6)ccc54)cc3)cc2)cc1]

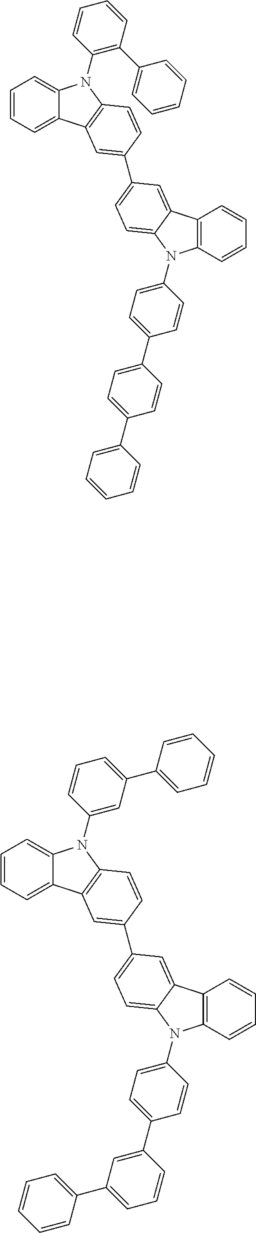 [SMILES: c1ccc(-c2ccc(-c3ccc(-n4c5ccccc5c5cc(-c6ccc7c(c6)c6ccccc6n7-c6ccccc6-c6ccccc6)ccc54)cc3)cc2)cc1 ; c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1]

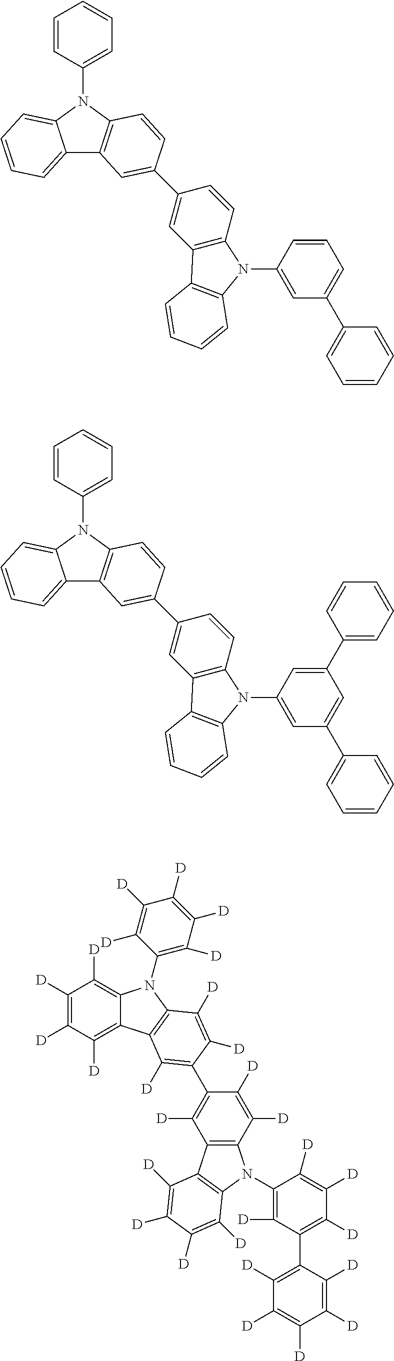 [SMILES: c1ccc(-c2cccc(-n3c4ccccc4c4cc(-c5ccc6c(c5)c5ccccc5n6-c5ccccc5)ccc43)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1 ; [2H]c1c([2H])c([2H])c(-c2c([2H])c([2H])c([2H])c(-n3c4c([2H])c([2H])c([2H])c([2H])c4c4c([2H])c(-c5c([2H])c([2H])c6c(c5[2H])c5c([2H])c([2H])c([2H])c([2H])c5n6-c5c([2H])c([2H])c([2H])c([2H])c5[2H])c([2H])c([2H])c43)c2[2H])c([2H])c1[2H]]

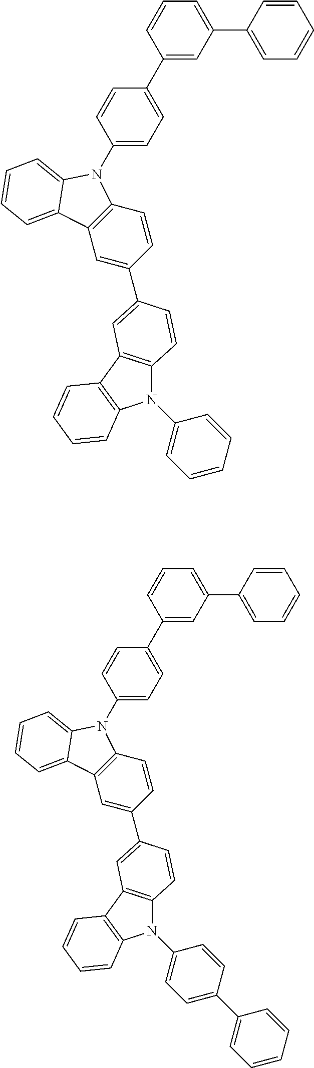 [SMILES: c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2ccc(-n3c4ccccc4c4cc(-c5ccc6c(c5)c5ccccc5n6-c5ccc(-c6cccc(-c7ccccc7)c6)cc5)ccc43)cc2)cc1]

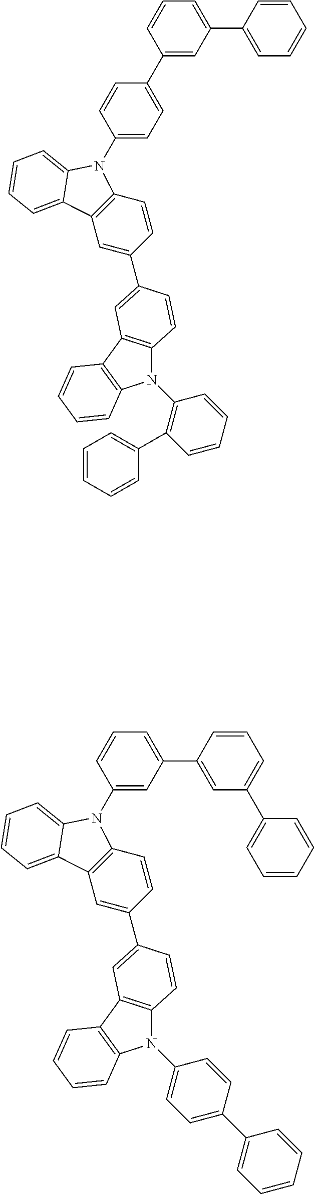 [SMILES: c1ccc(-c2cccc(-c3ccc(-n4c5ccccc5c5cc(-c6ccc7c(c6)c6ccccc6n7-c6ccccc6-c6ccccc6)ccc54)cc3)c2)cc1 ; c1ccc(-c2ccc(-n3c4ccccc4c4cc(-c5ccc6c(c5)c5ccccc5n6-c5cccc(-c6cccc(-c7ccccc7)c6)c5)ccc43)cc2)cc1]

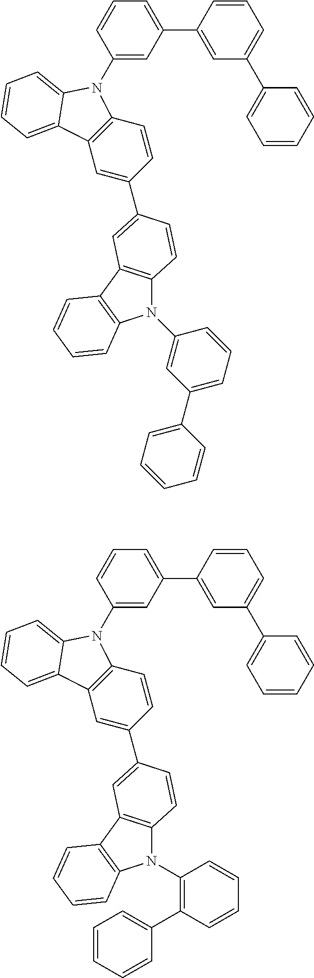 [SMILES: c1ccc(-c2cccc(-c3cccc(-n4c5ccccc5c5cc(-c6ccc7c(c6)c6ccccc6n7-c6cccc(-c7ccccc7)c6)ccc54)c3)c2)cc1 ; c1ccc(-c2cccc(-c3cccc(-n4c5ccccc5c5cc(-c6ccc7c(c6)c6ccccc6n7-c6ccccc6-c6ccccc6)ccc54)c3)c2)cc1]

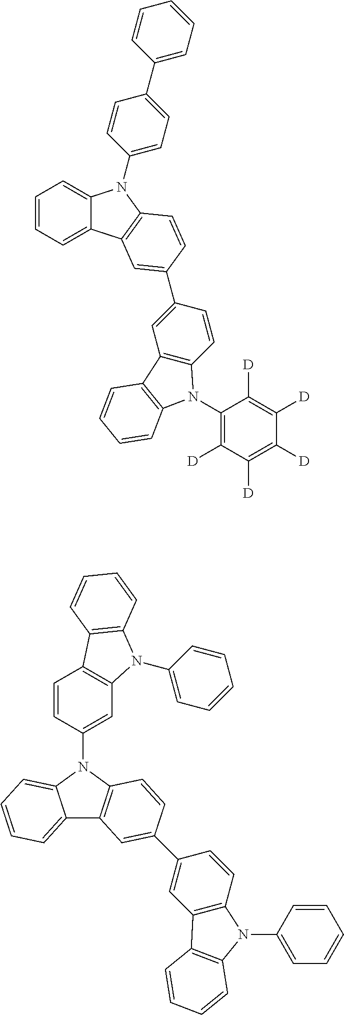 [SMILES: [2H]c1c([2H])c([2H])c(-n2c3ccccc3c3cc(-c4ccc5c(c4)c4ccccc4n5-c4ccc(-c5ccccc5)cc4)ccc32)c([2H])c1[2H] ; c1ccc(-n2c3ccccc3c3cc(-c4ccc5c(c4)c4ccccc4n5-c4ccc5c6ccccc6n(-c6ccccc6)c5c4)ccc32)cc1]

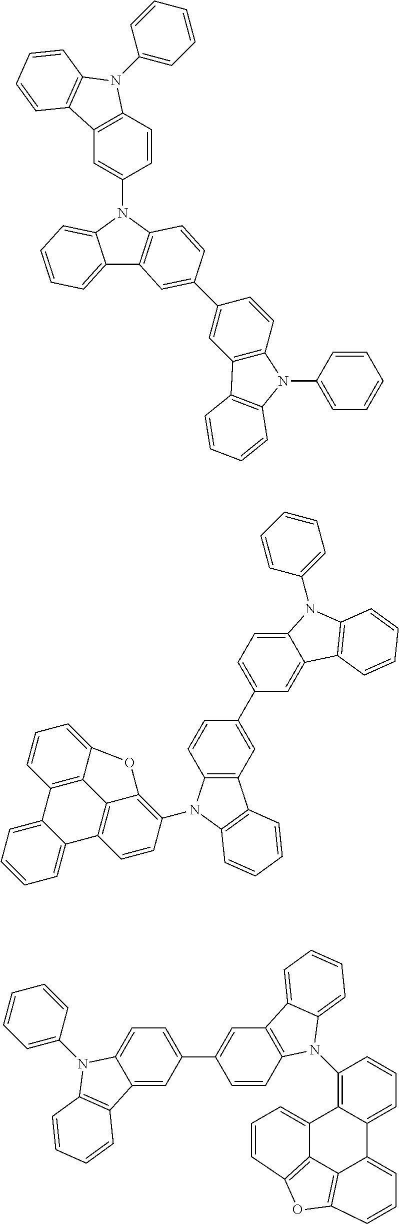 [SMILES: c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5c6ccccc6c6cccc7oc4c5c76)ccc32)cc1 ; c1ccc(-n2c3ccccc3c3cc(-c4ccc5c(c4)c4ccccc4n5-c4cccc5c6cccc7oc8cccc(c45)c8c76)ccc32)cc1]

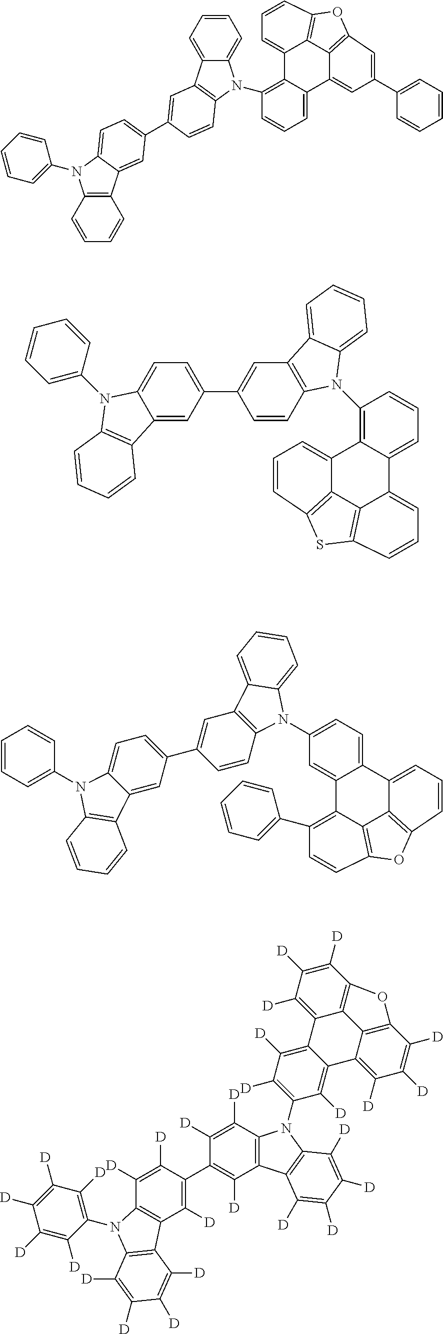

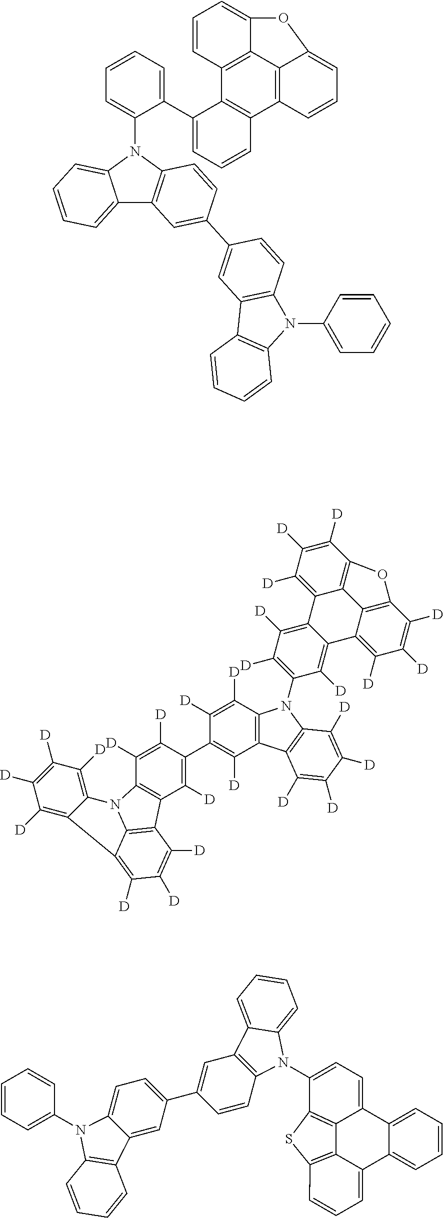 [SMILES: c1ccc(-n2c3ccccc3c3cc(-c4ccc5c(c4)c4ccccc4n5-c4ccccc4-c4cccc5c6cccc7oc8cccc(c45)c8c76)ccc32)cc1 ; [2H]c1c(-n2c3c([2H])c([2H])c([2H])c([2H])c3c3c([2H])c(-c4c([2H])c([2H])c5c(c4[2H])c4c([2H])c([2H])c([2H])c6c7c([2H])c([2H])c([2H])c([2H])c7n5c64)c([2H])c([2H])c32)c([2H])c2c(c1[2H])c1c([2H])c([2H])c([2H])c3oc4c([2H])c([2H])c([2H])c2c4c31 ; c1ccc(-n2c3ccccc3c3cc(-c4ccc5c(c4)c4ccccc4n5-c4ccc5c6ccccc6c6cccc7sc4c5c76)ccc32)cc1]

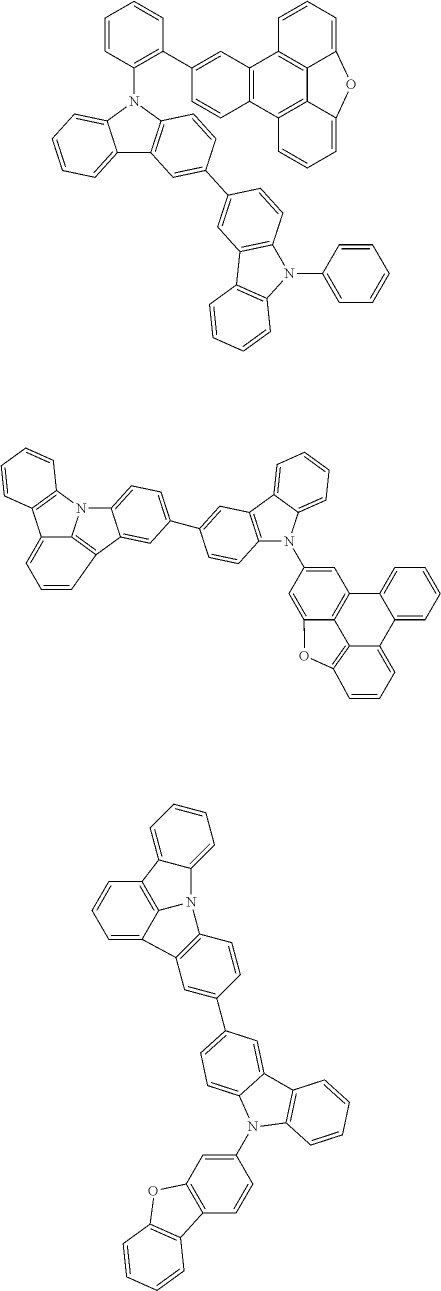 [SMILES: c1ccc(-n2c3ccccc3c3cc(-c4ccc5c(c4)c4ccccc4n5-c4ccccc4-c4ccc5c(c4)c4cccc6oc7cccc5c7c64)ccc32)cc1 ; c1ccc2c(c1)c1cccc3oc4cc(-n5c6ccccc6c6cc(-c7ccc8c(c7)c7cccc9c%10ccccc%10n8c97)ccc65)cc2c4c31 ; c1ccc2c(c1)oc1cc(-n3c4ccccc4c4cc(-c5ccc6c(c5)c5cccc7c8ccccc8n6c75)ccc43)ccc12]

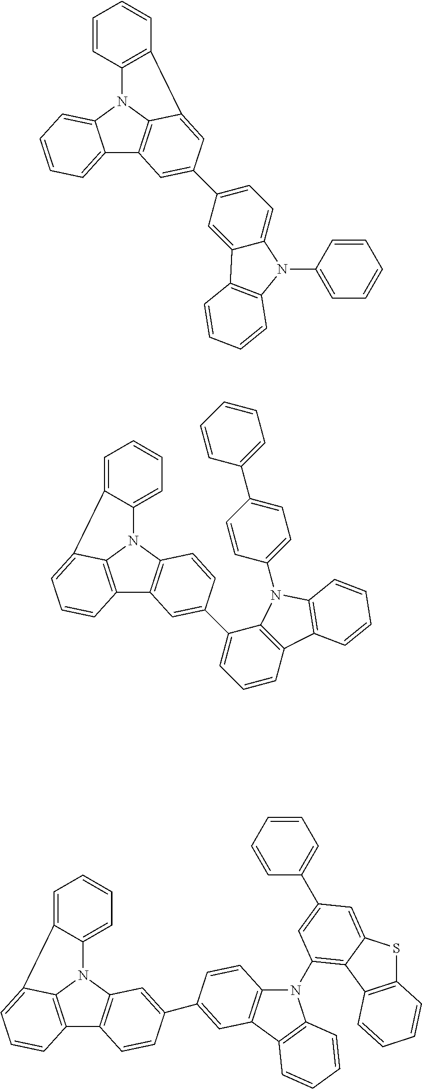 [SMILES: c1ccc(-n2c3ccccc3c3cc(-c4cc5c6ccccc6n6c7ccccc7c(c4)c56)ccc32)cc1 ; c1ccc(-c2ccc(-n3c4ccccc4c4cccc(-c5ccc6c(c5)c5cccc7c8ccccc8n6c75)c43)cc2)cc1 ; c1ccc(-c2cc(-n3c4ccccc4c4cc(-c5ccc6c7cccc8c9ccccc9n(c6c5)c87)ccc43)c3c(c2)sc2ccccc23)cc1]

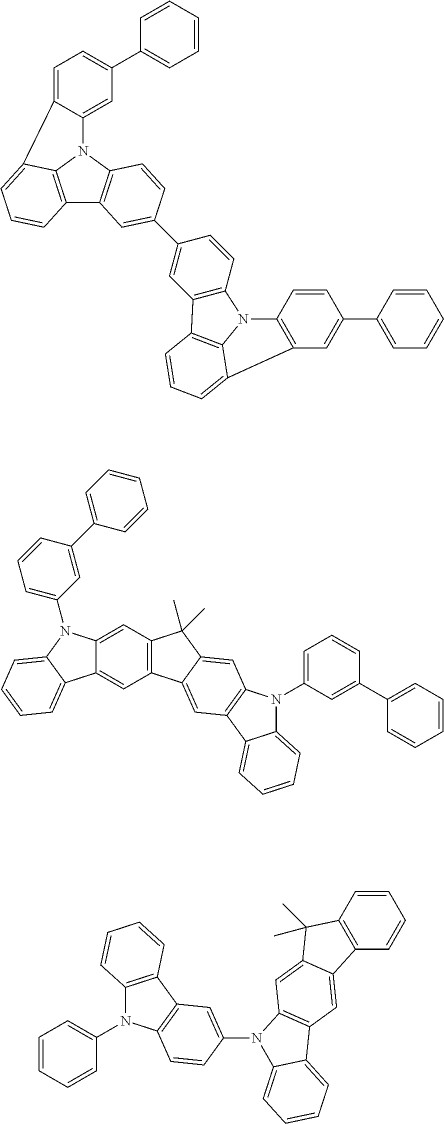 [SMILES: c1ccc(-c2ccc3c(c2)c2cccc4c5cc(-c6ccc7c(c6)c6cccc8c9ccc(-c%10ccccc%10)cc9n7c68)ccc5n3c24)cc1 ; CC1(C)c2cc3c(cc2-c2cc4c5ccccc5n(-c5cccc(-c6ccccc6)c5)c4cc21)c1ccccc1n3-c1cccc(-c2ccccc2)c1 ; CC1(C)c2ccccc2-c2cc3c4ccccc4n(-c4ccc5c(c4)c4ccccc4n5-c4ccccc4)c3cc21]

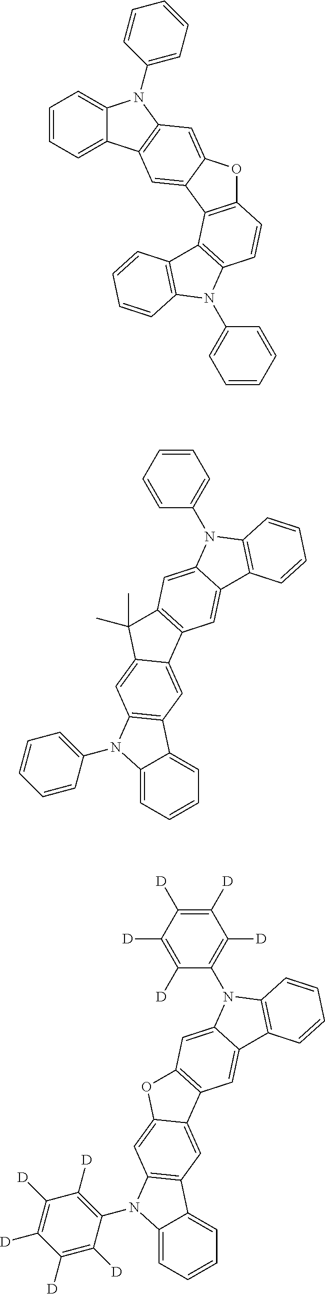 [SMILES: c1ccc(-n2c3ccccc3c3cc4c(cc32)oc2ccc3c(c5ccccc5n3-c3ccccc3)c24)cc1 ; CC1(C)c2cc3c(cc2-c2cc4c5ccccc5n(-c5ccccc5)c4cc21)c1ccccc1n3-c1ccccc1 ; [2H]c1c([2H])c([2H])c(-n2c3ccccc3c3cc4c(cc32)oc2cc3c(cc24)c2ccccc2n3-c2c([2H])c([2H])c([2H])c([2H])c2[2H])c([2H])c1[2H]]

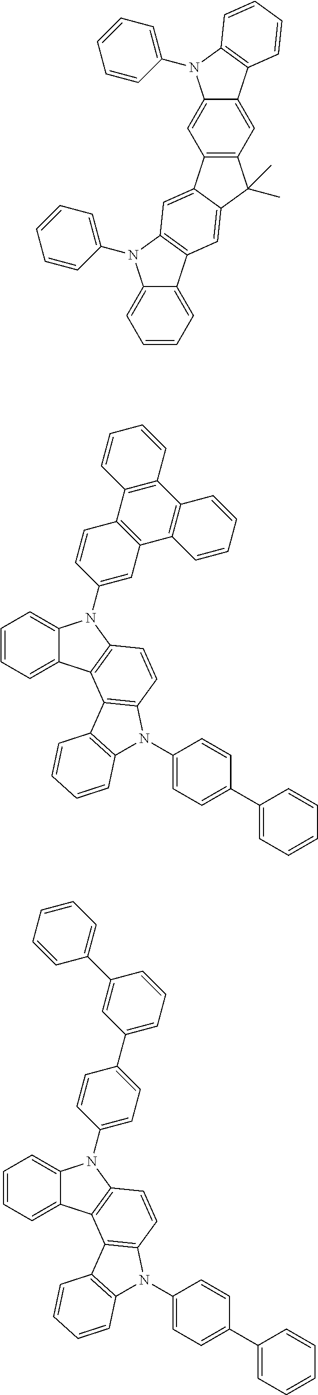 [SMILES: CC1(C)c2cc3c4ccccc4n(-c4ccccc4)c3cc2-c2cc3c(cc21)c1ccccc1n3-c1ccccc1 ; c1ccc(-c2ccc(-n3c4ccccc4c4c5c6ccccc6n(-c6ccc7c8ccccc8c8ccccc8c7c6)c5ccc43)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1]

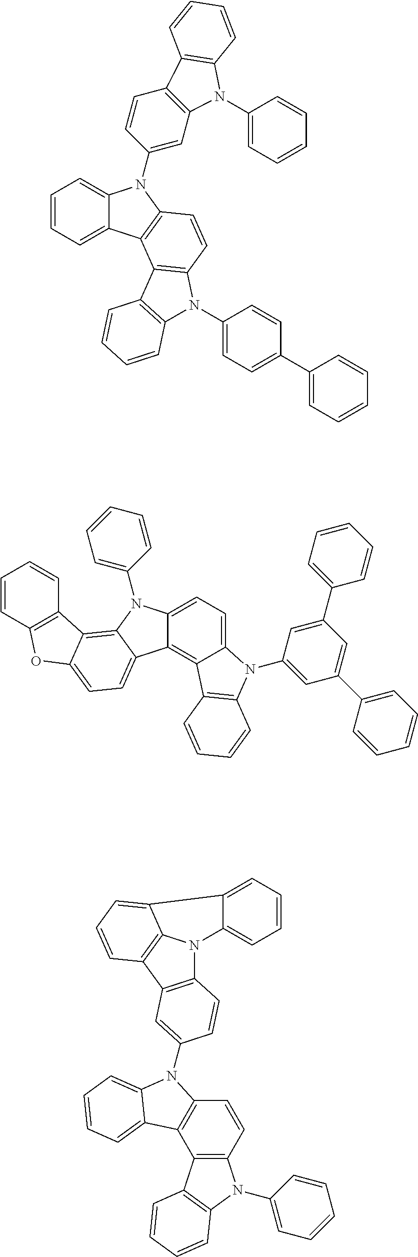 [SMILES: c1ccc(-c2ccc(-n3c4ccccc4c4c5c6ccccc6n(-c6ccc7c8ccccc8n(-c8ccccc8)c7c6)c5ccc43)cc2)cc1 ; c1ccc(-c2cc(-c3ccccc3)cc(-n3c4ccccc4c4c5c6ccc7oc8ccccc8c7c6n(-c6ccccc6)c5ccc43)c2)cc1 ; c1ccc(-n2c3ccccc3c3c4c5ccccc5n(-c5ccc6c(c5)c5cccc7c8ccccc8n6c75)c4ccc32)cc1]

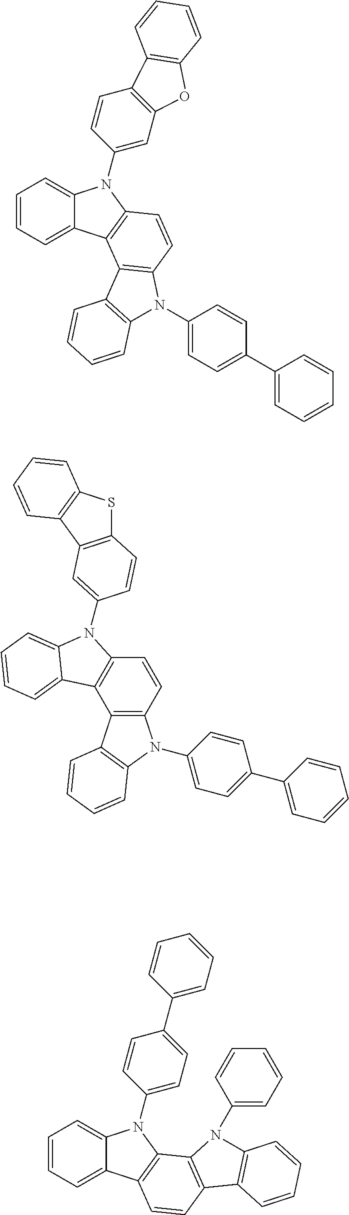 [SMILES: c1ccc(-c2ccc(-n3c4ccccc4c4c5c6ccccc6n(-c6ccc7c(c6)oc6ccccc67)c5ccc43)cc2)cc1 ; c1ccc(-c2ccc(-n3c4ccccc4c4c5c6ccccc6n(-c6ccc7sc8ccccc8c7c6)c5ccc43)cc2)cc1 ; c1ccc(-c2ccc(-n3c4ccccc4c4ccc5c6ccccc6n(-c6ccccc6)c5c43)cc2)cc1]

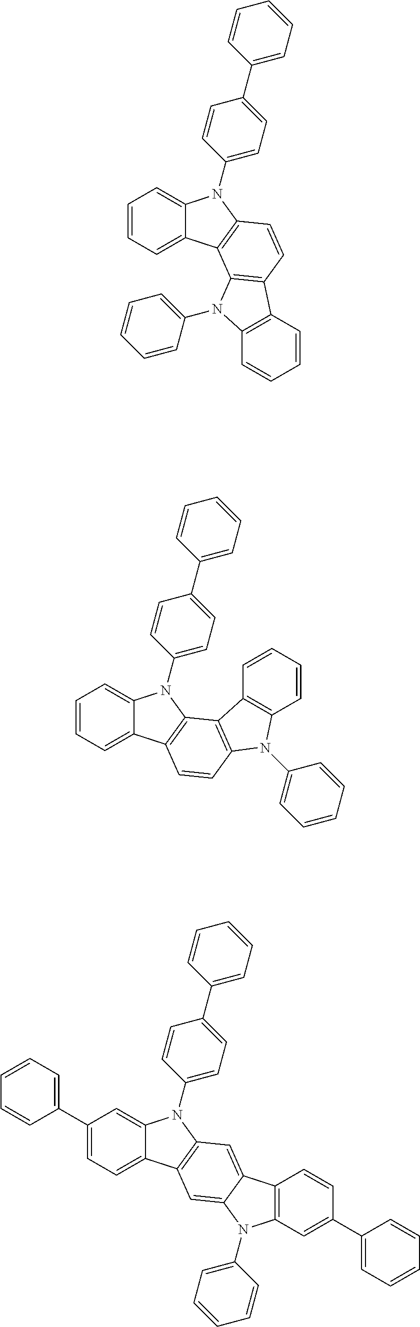 [SMILES: c1ccc(-c2ccc(-n3c4ccccc4c4c3ccc3c5ccccc5n(-c5ccccc5)c34)cc2)cc1 ; c1ccc(-c2ccc(-n3c4ccccc4c4ccc5c(c6ccccc6n5-c5ccccc5)c43)cc2)cc1 ; c1ccc(-c2ccc(-n3c4cc(-c5ccccc5)ccc4c4cc5c(cc43)c3ccc(-c4ccccc4)cc3n5-c3ccccc3)cc2)cc1]

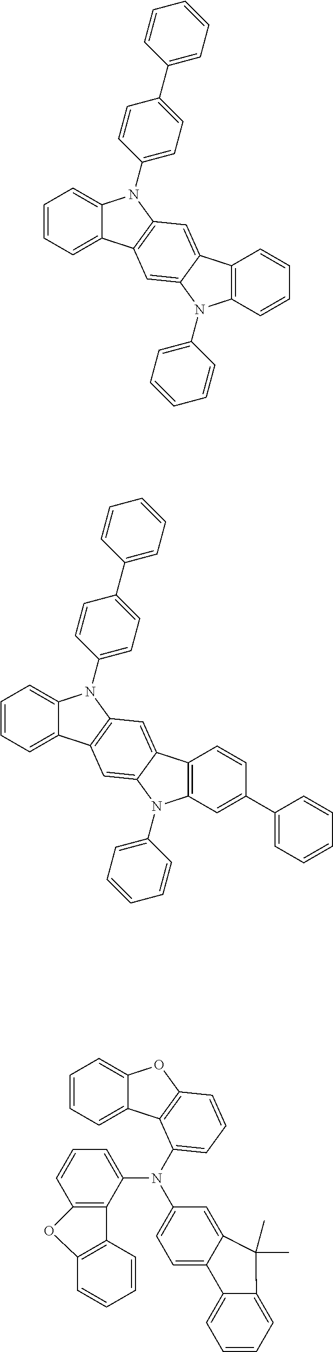 [SMILES: c1ccc(-c2ccc(-n3c4ccccc4c4cc5c(cc43)c3ccccc3n5-c3ccccc3)cc2)cc1 ; c1ccc(-c2ccc(-n3c4ccccc4c4cc5c(cc43)c3ccc(-c4ccccc4)cc3n5-c3ccccc3)cc2)cc1 ; CC1(C)c2ccccc2-c2ccc(N(c3cccc4oc5ccccc5c34)c3cccc4oc5ccccc5c34)cc21]

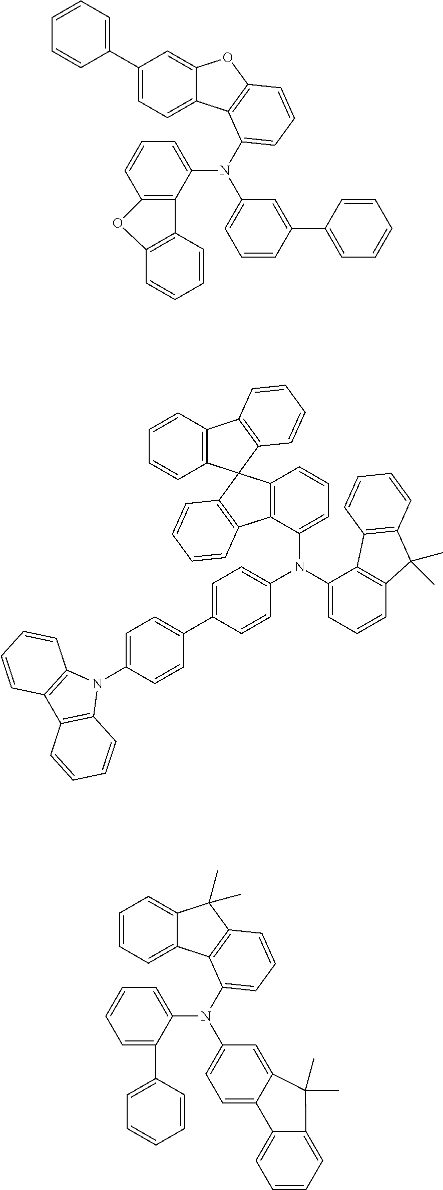 [SMILES: c1ccc(-c2cccc(N(c3cccc4oc5ccccc5c34)c3cccc4oc5cc(-c6ccccc6)ccc5c34)c2)cc1 ; CC1(C)c2ccccc2-c2c(N(c3ccc(-c4ccc(-n5c6ccccc6c6ccccc65)cc4)cc3)c3cccc4c3-c3ccccc3C43c4ccccc4-c4ccccc43)cccc21 ; CC1(C)c2ccccc2-c2ccc(N(c3ccccc3-c3ccccc3)c3cccc4c3-c3ccccc3C4(C)C)cc21]

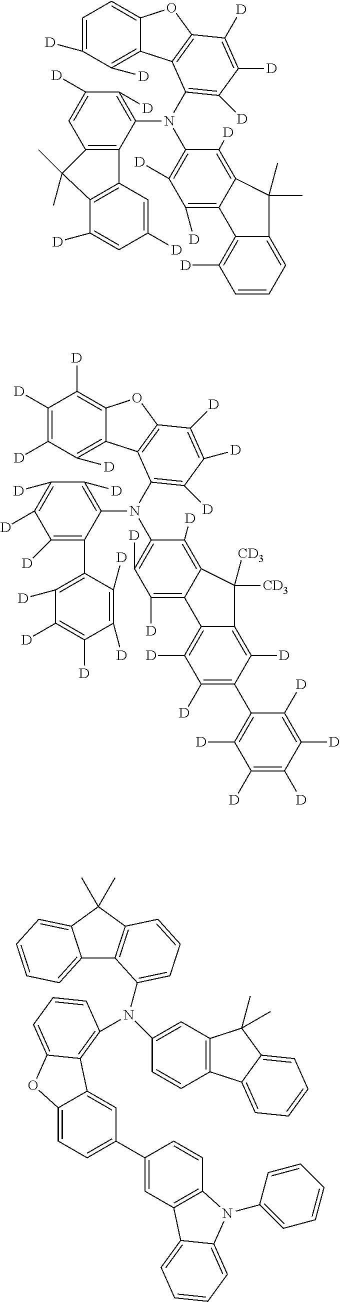

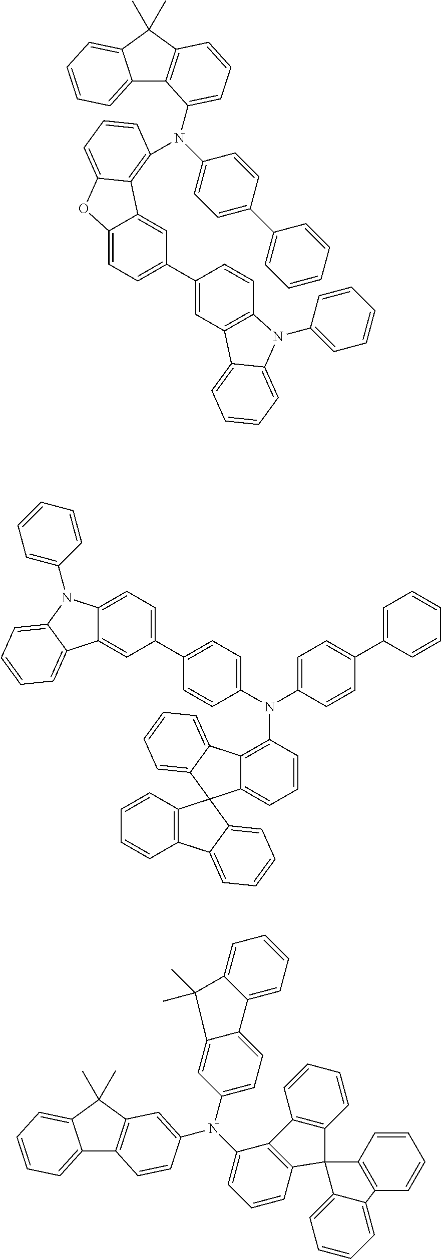 [SMILES: CC1(C)c2ccccc2-c2c(N(c3ccc(-c4ccccc4)cc3)c3cccc4oc5ccc(-c6ccc7c(c6)c6ccccc6n7-c6ccccc6)cc5c34)cccc21 ; c1ccc(-c2ccc(N(c3ccc(-c4ccc5c(c4)c4ccccc4n5-c4ccccc4)cc3)c3cccc4c3-c3ccccc3C43c4ccccc4-c4ccccc43)cc2)cc1 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

Examples of materials that can be used as wide bandgap matrix materials include the compounds shown below:

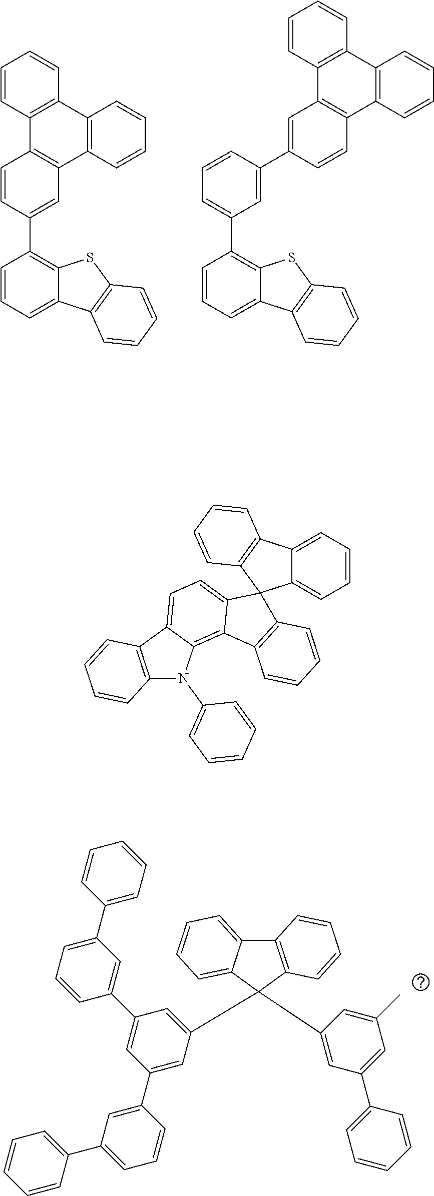

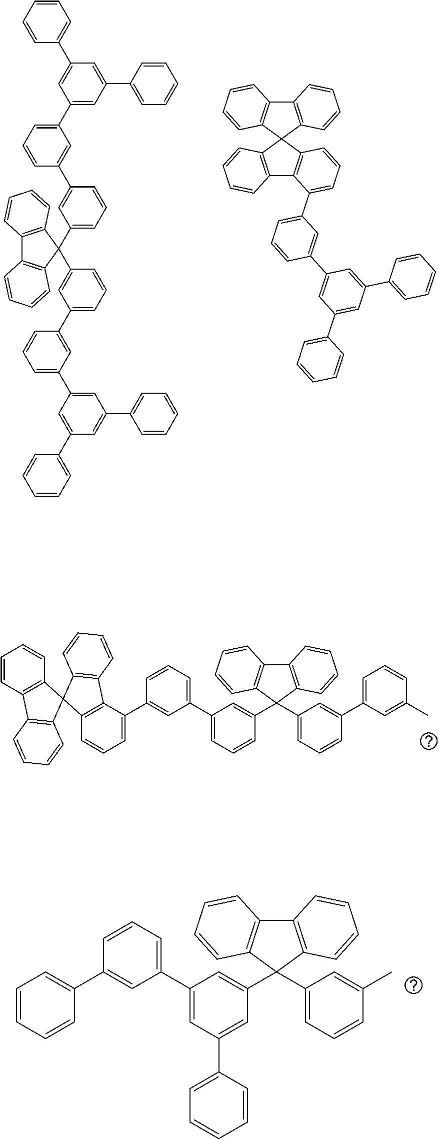

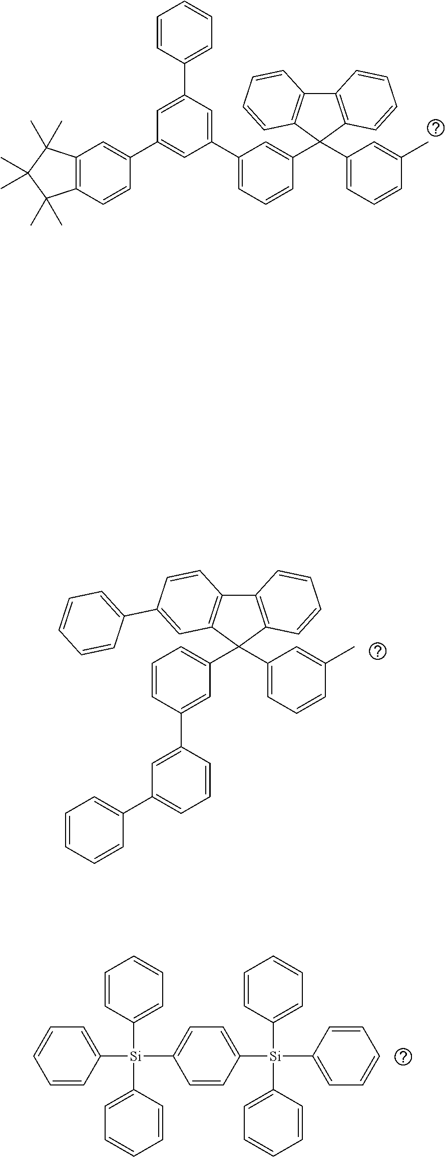

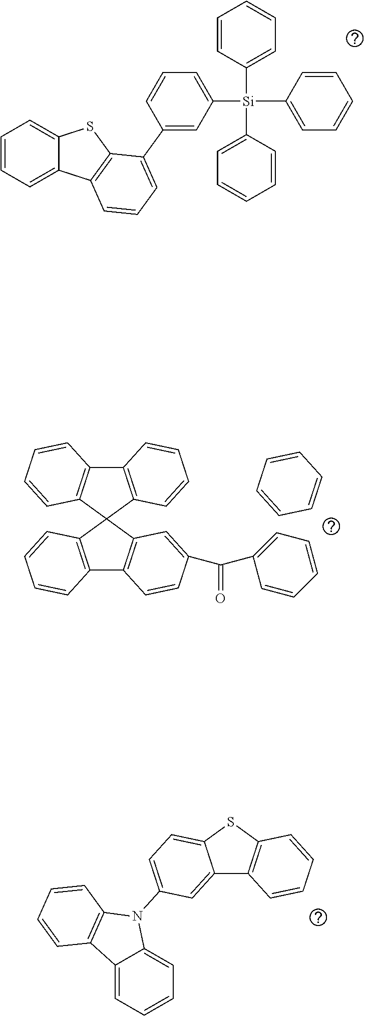

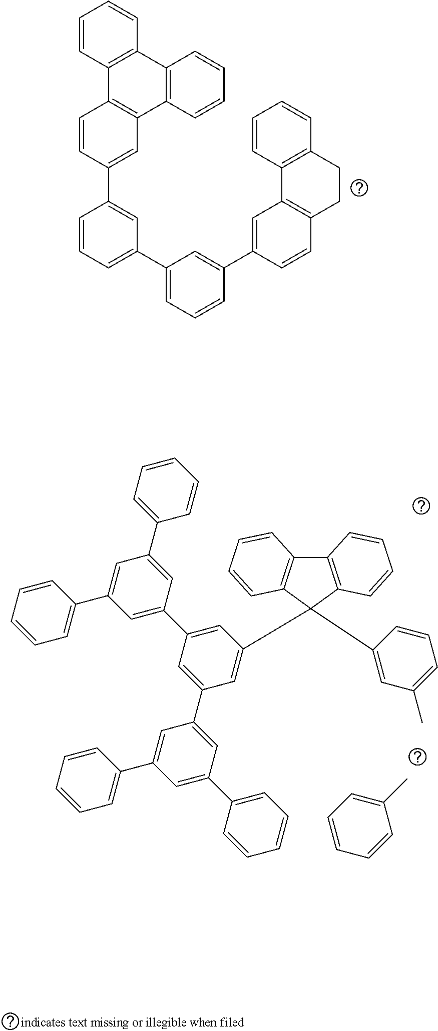

It is further preferred to use a mixture of two or more triplet emitters, in particular two or three triplet emitters, together with one or more matrix materials. In this case, the triplet emitter with the shorter-wavelength emission spectrum serves as a co-matrix for the triplet emitter with the longer-wavelength emission spectrum. For example, the metal complexes according to the invention can be combined with a shorter-wavelength, e.g., blue, green or yellow emitting, metal complex as a co-matrix. For example, metal complexes according to the invention can also be used as a co-matrix for longer wavelength emitting triplet emitters, for example for red emitting triplet emitters. In this context, it may also be preferred if both the shorter-wavelength and the longer-wavelength emitting metal complex is a compound according to the invention. A preferred embodiment when using a mixture of three triplet emitters is when two are used as co-host and one as emitting material. Preferably, these triplet emitters have the emission colors green, yellow and red or blue, green and orange.

A preferred mixture in the emitting layer contains an electron transporting host material, a so-called “wide bandgap” host material, which due to its electronic properties is not or not substantially involved in charge transport in the layer, a co-dopant, which is a triplet emitter emitting at a shorter wavelength than the compound according to the invention, and a compound according to the invention.

Another preferred mixture in the emitting layer contains an electron transporting host material, a so-called “wide band gap” host material which, due to its electronic properties, is not or not substantially involved in charge transport in the layer, a hole transporting host material, a co-dopant which is a triplet emitter emitting at a shorter wavelength than the compound according to the invention, and a compound according to the invention.

The metal complexes according to the invention can also be used in other functions in the electronic device, for example, as a hole transport material in a hole injection or transport layer, as a charge generation material, as an electron blocking material, as a hole blocking material, or as an electron transport material, for example, in an electron transport layer, depending on the choice of metal and the exact structure of the ligand. If the metal complex according to the invention is an aluminum complex, it is preferably used in an electron transport layer. Similarly, the metal complexes according to the invention can be used as matrix material for other phosphorescent metal complexes in an emitting layer.

In the further layers, generally all materials can be used as they are used for the layers according to the prior art, and the skilled person can combine any of these materials in an electronic device with the materials according to the invention without any inventive intervention.

Suitable charge transport materials, such as those that can be used in the hole injection or hole transport layer or electron blocking layer or in the electron transport layer of the organic electroluminescent device according to the invention, are for example the compounds disclosed in Y. Shirota et al, Chem. Rev. 2007, 107(4), 953-1010 or other materials as disclosed in the prior art used in these layers. Preferred hole transport materials that can be used in a hole transport-, hole injection or electron blocking layer in the electroluminescence device of the invention are indenofluorene amine derivatives (e.g., according to WO 06/122630 or WO 06/100896), amine derivatives disclosed in EP 1661888, hexaazatriphenylene derivatives (e.g., according to WO 01/049806), amine derivatives with condensed aromatics (e.g. according to U.S. Pat. No. 5,061,569), amine derivatives disclosed in WO 95/09147, monobenzoindenofluorene amines (e.g. according to WO 08/006449), dibenzoindenofluorene amines (e.g. according to WO 07/140847), spirobifluorene amines (e.g. according to WO 2012/034627, WO2014/056565), fluorene amines (e.g. according to EP 2875092, EP 2875699 and EP 2875004), spiro-dibenzopyran amines (e.g. EP 2780325) and dihydroacridine derivatives (e.g. according to WO 2012/150001).

The device is appropriately structured (depending on the application), contacted and finally hermetically sealed, as the life of such devices is drastically reduced in the presence of water and/or air.

Further preferred is an organic electroluminescent device, characterized in that one or more layers are coated by a sublimation process. In this process, the materials are vapor deposited in vacuum sublimation systems at an initial pressure of usually less than 10⁻⁵ mbar, preferably less than 10⁻⁶ mbar. It is also possible for the initial pressure to be even lower or even higher, for example less than 10⁻⁷ mbar.

An organic electroluminescent device is also preferred, characterized in that one or more layers are coated using the OVPD (organic vapor phase deposition) process or with the aid of carrier gas sublimation. In this process, the materials are applied at a pressure between 10⁻⁵ mbar and 1 bar. A special case of this process is the OVJP (Organic Vapor Jet Printing) process, in which the materials are applied directly through a nozzle and thus structured.

Further preferred is an organic electroluminescent device, characterized in that one or more layers are produced from solution, such as by spin coating, or by any printing process, such as screen printing, flexographic printing, offset printing or nozzle printing, but especially preferably LITI (Light Induced Thermal Imaging, Thermo transfer printing) or ink-jet printing. Soluble compounds are required for this purpose, which can be obtained, for example, by suitable substitution. In a preferred embodiment of the invention, the layer containing the compound according to the invention is applied from solution.

The organic electroluminescent device can also be fabricated as a hybrid system by depositing one or more layers of solution and vapor depositing one or more other layers. For example, it is possible to deposit an emitting layer containing a metal complex of the invention and a matrix material of solution and to vacuum evaporate a hole-blocking layer and/or an electron transport layer on top of it.

These methods are generally known to those skilled in the art and can be readily applied by them to organic electroluminescent devices containing compounds according to formula (1) or (2) or the preferred embodiments listed above.

The compounds according to the invention are characterized by a narrower emission spectrum compared to corresponding binuclear compounds according to the prior art, which do not contain a coordinating fused heteroaryl group as in the compounds according to the invention. Narrow emission spectra whose emission maximum is at the correct desired wavelength result in CIE color coordinates far out in the chromaticity triangle, so that very deep, rich colors and a wide color gamut can be displayed in the screen, making narrow emission spectra a necessary prerequisite for simultaneously achieving deep CIEx and high efficiency in cd/A.

These above-mentioned advantages are not accompanied by a deterioration of the other electronic properties.

The invention is explained in more detail by the following examples without wishing to limit it. The person skilled in the art can produce further electronic devices according to the invention from the descriptions without inventive intervention and thus carry out the invention in the entire claimed EXPERIMENTAL EXAMPLES

### A) Synthesis of Synthons S

### Example S1

### a) Step 1:

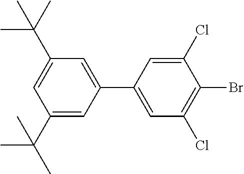 [SMILES: CC(C)(C)c1cc(-c2cc(Cl)c(Br)c(Cl)c2)cc(C(C)(C)C)c1]

A mixture of 35.2 g (100 mmol) 2-bromo-1,3-dichloro-5-iodobenzene [1000574-29-7], 23.4 g (100 mmol) 1,3-di-tert-butylphenylboronic acid [197223-39-5], 21.2 g (200 mmol) sodium carbonate, 787 mg (3 mmol) triphenylphosphine, 224 mg (1 mmol) palladium(II) acetate, 300 ml toluene, 80 ml ethanol, and 300 ml water is heated at reflux for 12 h. After cooling, separate the organic phase, wash it twice with 100 ml of water and once with 100 ml of saturated sodium chloride, and dry over magnesium sulfate. Filter over a silica gel bed pre-slurried with toluene, concentrate the filtrate to dryness and stir the residue hot twice with iso-propanol. Yield: 36.3 g (87 mmol), 87%; purity: approx. 97% purity by ¹H-NMR.

### b) Step 2:

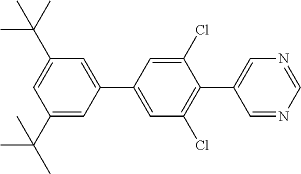 [SMILES: CC(C)(C)c1cc(-c2cc(Cl)c(-c3cncnc3)c(Cl)c2)cc(C(C)(C)C)c1]

A mixture of 41.2 g (100 mmol) step 1, 12.4 g (100 mmol) pyrimidine-5-boronic acid [109299-78-7], 21.2 g (200 mmol) sodium carbonate, 787 mg (3 mmol) triphenylphosphine, 224 mg (1 mmol) palladium(II) acetate, 300 ml toluene, 80 ml ethanol and 300 ml water is heated for 24 h under reflux. After cooling, separate the organic phase, wash it twice with 100 ml of water and once with 100 ml of saturated sodium chloride, and dry over magnesium sulfate. Filter off over a silica gel bed pre-slurried with toluene, concentrate the filtrate to dryness, stir the residue hot once with iso-propanol and chromatigraphize it (silica gel n-Heptane/ethyl acatate (EE)). Yield: 33.3 g (80 mmol), 80%; purity: approx. 97% by ¹H-NMR.

### Example S2

Similarly, S2 can be prepared from S31.

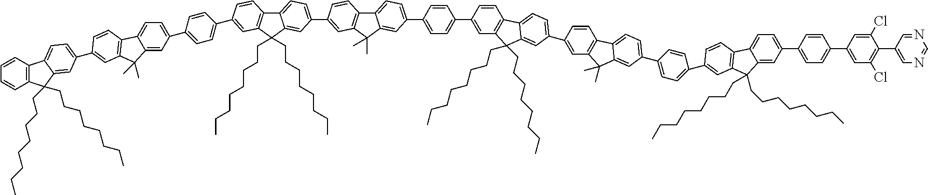 [SMILES: CCCCCCCCC1(CCCCCCCC)c2ccccc2-c2ccc(-c3ccc4c(c3)C(C)(C)c3cc(-c5ccc(-c6ccc7c(c6)C(CCCCCCCC)(CCCCCCCC)c6cc(-c8ccc9c(c8)C(C)(C)c8cc(-c%10ccc(-c%11ccc%12c(c%11)C(CCCCCCCC)(CCCCCCCC)c%11cc(-c%13ccc%14c(c%13)C(C)(C)c%13cc(-c%15ccc(-c%16ccc%17c(c%16)C(CCCCCCCC)(CCCCCCCC)c%16cc(-c%18ccc(-c%19cc(Cl)c(-c%20cncnc%20)c(Cl)c%19)cc%18)ccc%16-%17)cc%15)ccc%13-%14)ccc%11-%12)cc%10)ccc8-9)ccc6-7)cc5)ccc3-4)cc21]

### Example S10

### a) Step 1:

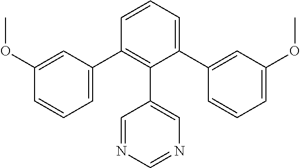 [SMILES: COc1cccc(-c2cccc(-c3cccc(OC)c3)c2-c2cncnc2)c1]

A well-stirred mixture of 22.4 g (100 mmol) 5-(2,6-dichlorophenyl) pyrimidine [1361761-54-7], 30.4 g (200 mmol) 3-methoxyphenylboronic acid [10365-98-7], 822 mg (2 mmol) SPhos, 224 mg (1 mmol) palladium(II) acetate, 84.9 g (400 mmol) of tripotassium phosphate, 400 ml of dioxane, 100 ml of dioxane and 300 ml of water is heated for 12 h under reflux. After cooling, separate the organic phase, wash it twice with 100 ml of water each, once with 100 ml of saturated saline and dry over magnesium sulfate, filter on the desiccant, concentrate the filtrate in vacuo and recrystallize the residue from acetonitrile/dichloromethane (DCM). Yield: 29.5 g (80 mmol), 80%; purity: approx. 97% by ¹H-NMR.

### b) Step 2:

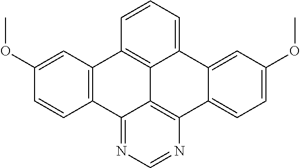 [SMILES: COc1ccc2c(c1)c1cccc3c4cc(OC)ccc4c4ncnc2c4c13]

To a well-stirred solution of 7.4 g (20 mmol) step 1 in 1500 ml DCM is added 16.2 g (100 mmol) iron(III) chloride, anhydrous and then 1.6 ml (30 mmol) conc. sulfuric acid and stirred for 30 min at room temperature. Pour the reaction mixture into 300 ml methanol with good stirring, then adjust to weakly alkaline with cooling carefully by adding 5 wt % aqueous sodium hydroxide solution, filter off over a Celite bed preslurried with DCM, separate the organic phase, wash it once with 200 ml of total cooking liquor, and dry over magnesium sulfate. Filter off the desiccant, add 300 ml methanol to the filtrate and slowly reduce to 200 ml in a weak vacuum. Aspirate from the precipitated product and recrystallize three times from acetonitrile/DCM. Yield: 2.9 g (8 mmol), 40%; Purity: mixture of about 90% syn-isomer and about 10% anti-isomer by ¹H-NMR. The anti-isomer can be separated chromatographically at step 4 because of the more soluble bis-triflate.

### c) Step 3:

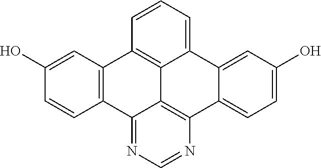 [SMILES: Oc1ccc2c(c1)c1cccc3c4cc(O)ccc4c4ncnc2c4c13]

A mixture of 7.3 g (20 mmol) step 2 and 23.2 g (200 mmol) pyridinium hydrochloride is stirred for 2 h at 240° C. After cooling to 70° C., 400 ml of water is added and stirring is continued for 30 min. Filter off the precipitated solid, wash it three times with 100 ml water each time and dry in vacuo. Yield: 6.7 g (20 mmol) quantitative; purity: mixture of approx. 90% syn-isomer and approx. 10% anti-isomer by ¹H-NMR. The anti-isomer can be separated chromatographically at step 4 because of the more soluble bis-triflate.

### d) Step 4:

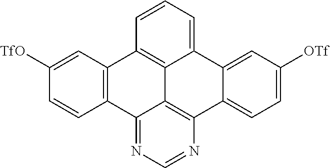 [SMILES: O=S(=O)(Oc1ccc2c(c1)c1cccc3c4cc(OS(=O)(=O)C(F)(F)F)ccc4c4ncnc2c4c13)C(F)(F)F]

To a mixture cooled to +5° C. of 6.7 g (20 mmol) Step 3, 6.4 ml (46 mmol) triethylamine and 150 ml DCM is added dropwise 64.0 ml (46 mmol) trifluoromethanesulfonic anhydride. After heating and stirring at RT for 12 h, quench by adding 50 g of ice and 100 ml of water, separate the org. phase, wash it twice with 100 ml of water each and once with 100 ml of saturates saline, and dry over magnesium sulfate. Filter off the desiccant and chromatograph the residue (Torrent automatic column apparatus from A. Semrau). Yield: 10.8 g (16 mmol), 80%; purity: approx. 98% by ¹H-NMR, syn-isomer.

### e) Step 5: S10

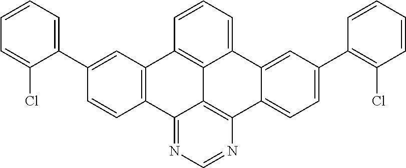 [SMILES: Clc1ccccc1-c1ccc2c(c1)c1cccc3c4cc(-c5ccccc5Cl)ccc4c4ncnc2c4c13]

A mixture of 12.0 g (20 mmol) step 4, g (21 mmol) 2-chloro-phenyl boronic acid [3900-89-8], 8.5 g (80 mmol) sodium carbonate, 394 mg (1.5 mmol) triphenylphosphine, 112 mg (0.5 mmol) palladium(II) acetate, 200 ml toluene, 50 ml ethanol, and 100 ml water is heated at reflux for 18 h. The mixture is then separated by filtration. After cooling, filter off from the precipitated solid, wash twice with 50 ml each of water, three times with 50 ml each of methanol, dry in vacuo, and purify by hot extraction crystallization twice (DCM/acetonitrile 1:1 vv). Yield: 6.3 g (12 mmol), 60%; purity: approx. 97% by ¹H-NMR.

Analogously, the following compunds can be prepared in 5 steps:

| Ex. | Educt | Product | Yield |
|---|---|---|---|
| S11 | S1 | 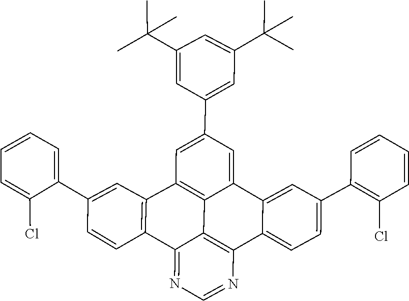 [SMILES: CC(C)(C)c1cc(-c2cc3c4cc(-c5ccccc5Cl)ccc4c4ncnc5c6ccc(-c7ccccc7Cl)cc6c(c2)c3c45)cc(C(C)(C)C)c1] | 21% |
| S12 | S2 | 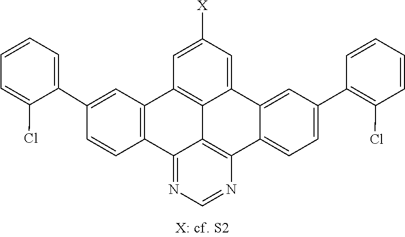 | 17% |
| S13 | 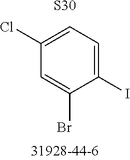 | 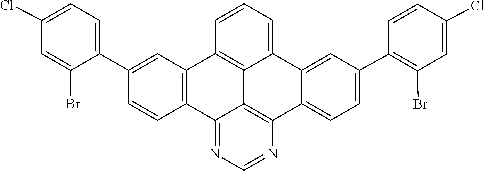 [SMILES: Clc1ccc(-c2ccc3c(c2)c2cccc4c5cc(-c6ccc(Cl)cc6Br)ccc5c5ncnc3c5c24)c(Br)c1] | 20% |

### Example S20

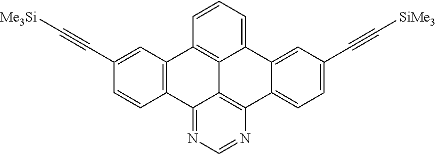 [SMILES: C[Si](C)(C)C#Cc1ccc2c(c1)c1cccc3c4cc(C#C[Si](C)(C)C)ccc4c4ncnc2c4c13]

A well-stirred mixture of 12.0 g (20 mmol) S10 step 4, 50 ml DMF, 11.5 ml (40 mmol) trimethylsilyl acetylene, 28.0 ml (200 mmol) triethylamine, 1.4 g (2 mmol) bis-triphenylphosphinopalladium dichloride, and 381 mg (2 mmol) copper(I) iodide is stirred at 70° C. for 20 h. The reaction mixture is then allowed to settle. Filter the reaction mixture while still warm over a Celite bed (reverse frit) pre-slurried with DMF, concentrate the filtrate at 60° C. in vacuo, and chromatograph the residue under argon on silica gel (n-heptane/EE 2:1>1:1). Yield: 6.47 g (13 mmol), 75%; purity: approx. 97% by ¹H-NMR.

### Example S21

Analogously, S21 can be prepared from S12 step 4.

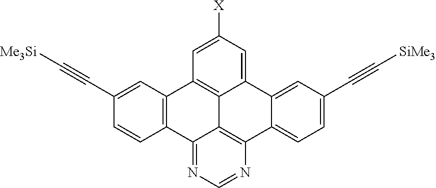

### Example S22

Analogously, S22 can be prepared from [141034-81-3].

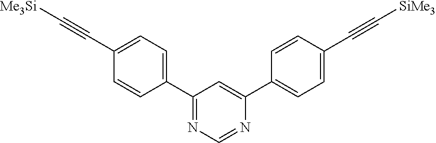 [SMILES: C[Si](C)(C)C#Cc1ccc(-c2cc(-c3ccc(C#C[Si](C)(C)C)cc3)ncn2)cc1]

### Example 30

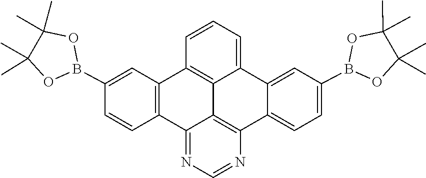

A well-stirred mixture of 12.0 g (20 mmol) S10 step 4, 12.7 g (50 mmol) bis(pinacolato)diborane, 11.8 g (120 mmol) potassium acetate, anhydrous, 1.64 g (4 mmol) SPhos, 499 mg (2 mmol) palladium acetate, 200 g glass spheres (3 mm diameter) and 250 ml dioxane is stirred at 100° C. for 16 h. The mixture is then filtered. While still warm, exhaust over a Celite bed pre-slurried with dioxane, condense the filtrate to dryness and stir out the residue with 200 ml methanol. Aspirate from the solid, wash three times with 30 ml methanol each, dry in vacuo, and chromatograph on silica gel, DCM/EE 5:1. Yield: 10.5 g (18 mmol), 90%; purity: about 97% by ¹H-NMR.

### Example S31

Analogously, S31 can be prepared from [2761726-60-5].

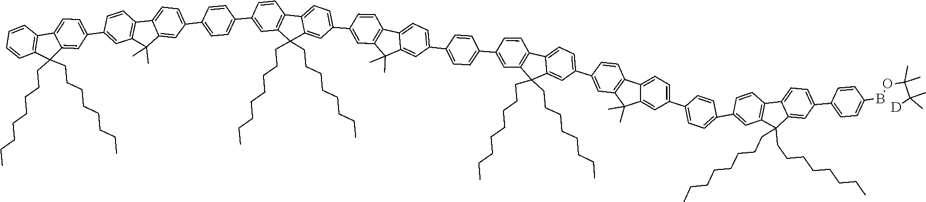

### Example S100

### a) Step 1:

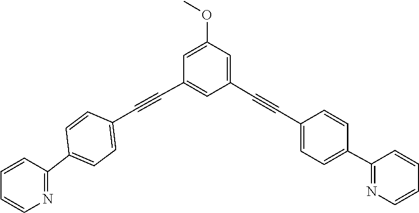 [SMILES: COc1cc(C#Cc2ccc(-c3ccccn3)cc2)cc(C#Cc2ccc(-c3ccccn3)cc2)c1]

Synthesis according to A. Komaromi et al, Chem. Commun., 2008, 4968. Preparation: 7.81 g (50 mmol) 1-methoxy-3,5-bis-ethynylbenzene [1542157-70-9], g (110 mmol) 2-(4-chlorophenyl)pyridine [5969-83-5]. Yield: 19.7 g (43 mmol), 86%, purity: 97%.

### b) Step 2:

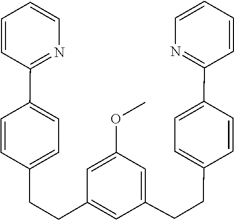 [SMILES: COc1cc(CCc2ccc(-c3ccccn3)cc2)cc(CCc2ccc(-c3ccccn3)cc2)c1]

23.1 g (50 mmol) Step 1 is hydrogenated in a mixture of 500 ml THE and 300 ml MeOH with the addition of 2 g palladium (5 wt. %) on charcoal and 16.1 g (300 mmol) NH₄ Cl at 40° C. under 1.5 bar hydrogen atmosphere until hydrogen uptake is completed (approx. 12 h). Filter off from the catalyst over a Celite bed pre-slurried with THF, remove the solvent in vacuo and chromatograph the residue (Torrent from A Semrau). Yield: 18.1 g (38 mmol), 76%; purity: approximately 97% by ¹H-NMR.

### c) Step 3:

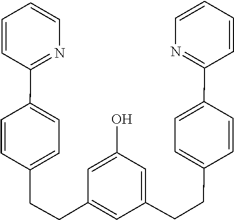 [SMILES: Oc1cc(CCc2ccc(-c3ccccn3)cc2)cc(CCc2ccc(-c3ccccn3)cc2)c1]

Procedure analogous to S10 Step 3. Preparation: 23.5 g (50 mmol) Step 2. Work-up: addition of 400 ml water to the reaction mixture, extraction three times with 200 ml EE each, washing of the combined EE phases with water (3×200 ml), drying with 200 ml saturated saline and magnesium sulfate, chromatography on silica gel, DCM:EE 9:1. Yield: 18.4 g (40 mmol), 90%; purity: approx. 97% by ¹H-NMR.

### d) Level 4:S100

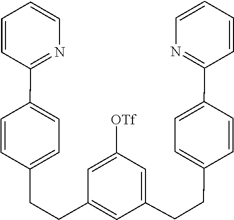 [SMILES: O=S(=O)(Oc1cc(CCc2ccc(-c3ccccn3)cc2)cc(CCc2ccc(-c3ccccn3)cc2)c1)C(F)(F)F]

Procedure analogous to S10 Step 4. Preparation: 22.8 g (50 mmol) Step 3. Yield: 26.5 g (45 mmol), 90%; purity: approx. 97% by ¹H-NMR.

Analogously, the following compounds can be prepared in 4 steps:

| Ex. | Educt | Product | Yield |
|---|---|---|---|
| S101 | 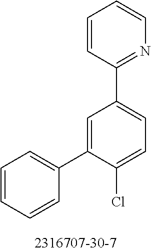 [SMILES: Clc1ccc(-c2ccccn2)cc1-c1ccccc1] | 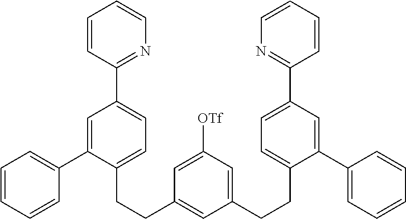 [SMILES: O=S(=O)(Oc1cc(CCc2ccc(-c3ccccn3)cc2-c2ccccc2)cc(CCc2ccc(-c3ccccn3)cc2-c2ccccc2)c1)C(F)(F)F] | 50% |
| S102 | 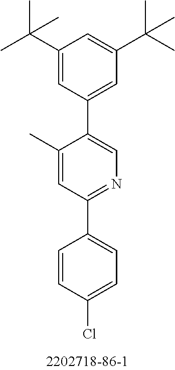 [SMILES: Cc1cc(-c2ccc(Cl)cc2)ncc1-c1cc(C(C)(C)C)cc(C(C)(C)C)c1] | 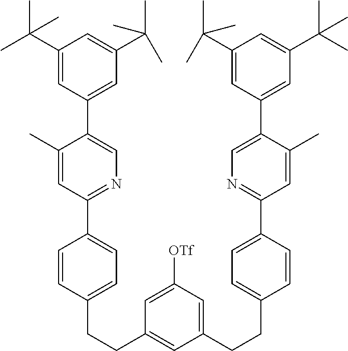 [SMILES: Cc1cc(-c2ccc(CCc3cc(CCc4ccc(-c5cc(C)c(-c6cc(C(C)(C)C)cc(C(C)(C)C)c6)cn5)cc4)cc(OS(=O)(=O)C(F)(F)F)c3)cc2)ncc1-c1cc(C(C)(C)C)cc(C(C)(C)C)c1] | 47% |

### Example S200

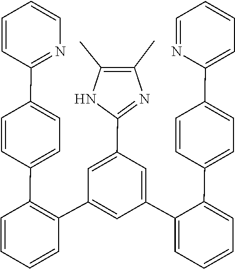 [SMILES: Cc1nc(-c2cc(-c3ccccc3-c3ccc(-c4ccccn4)cc3)cc(-c3ccccc3-c3ccc(-c4ccccn4)cc3)c2)[nH]c1C]

A mixture of 6.2 g (10 mmol) 2,2′-(5″-bromo[1,1′:2′,1″:3″,1′″:2′″,1″″-quinquephenyl]-4,4″″-diyl)bis-pyridine [1989597-66-1], 2.5 g (11 mmol) 4,5Dimethyl-2-(4,4,5,5-tetramethyl-1,3,2-dioxaborolan-2-yl)-1H-imidazole [2096459-10-6], 4.3 g (40 mmol) sodium carbonate, 394 mg (1.5 mmol) triphenylphosphine, 112 mg (0.5 mmol) palladium(II) acetate, 100 ml toluene, 30 ml ethanol, and 100 ml water is heated at reflux for 18 h. The mixture is refluxed. After cooling, separate the aqueous phase, wash the organic phase twice with 50 ml water and once with 50 ml saturated saline, and dry over magnesuim sulfate. Filter off the desiccant, concentrate the filtrate to dryness and chromatograph the residue (Torrent automatic column from A. Semrau). Yield: 5.1 g (8 mmol), 80%; purity: about 97% by ¹H-NMR.

Analogously, the following compounds can be prepared:

| Ex. | Educts | Product | Yield |
|---|---|---|---|
| S201 | 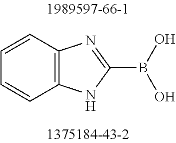 [SMILES: OB(O)c1nc2ccccc2[nH]1] | 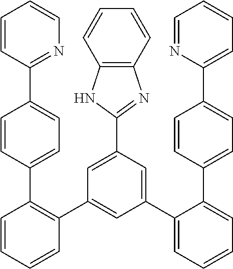 [SMILES: c1ccc(-c2ccc(-c3ccccc3-c3cc(-c4nc5ccccc5[nH]4)cc(-c4ccccc4-c4ccc(-c5ccccn5)cc4)c3)cc2)nc1] | 75% |
| S202 | 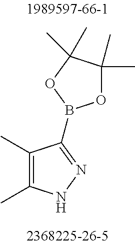 | 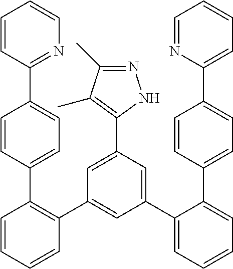 [SMILES: Cc1n[nH]c(-c2cc(-c3ccccc3-c3ccc(-c4ccccn4)cc3)cc(-c3ccccc3-c3ccc(-c4ccccn4)cc3)c2)c1C] | 66% |
| S203 | 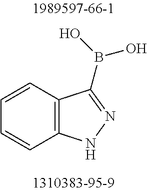 [SMILES: OB(O)c1n[nH]c2ccccc12] | 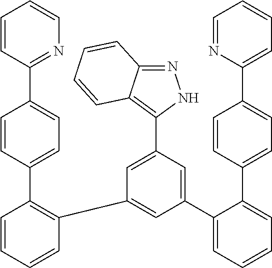 [SMILES: c1ccc(-c2ccc(-c3ccccc3-c3cc(-c4ccccc4-c4ccc(-c5ccccn5)cc4)cc(-c4[nH]nc5ccccc45)c3)cc2)nc1] | 57% |

### B) Synthesis of the Ligands L

### Example L1

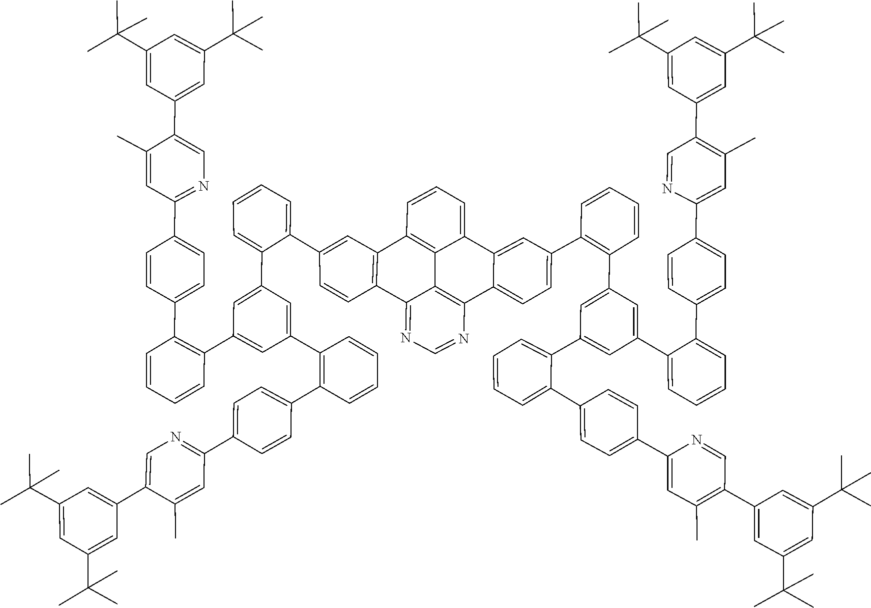 [SMILES: Cc1cc(-c2ccc(-c3ccccc3-c3cc(-c4ccccc4-c4ccc(-c5cc(C)c(-c6cc(C(C)(C)C)cc(C(C)(C)C)c6)cn5)cc4)cc(-c4ccccc4-c4ccc5c(c4)c4cccc6c7cc(-c8ccccc8-c8cc(-c9ccccc9-c9ccc(-c%10cc(C)c(-c%11cc(C(C)(C)C)cc(C(C)(C)C)c%11)cn%10)cc9)cc(-c9ccccc9-c9ccc(-c%10cc(C)c(-c%11cc(C(C)(C)C)cc(C(C)(C)C)c%11)cn%10)cc9)c8)ccc7c7ncnc5c7c46)c3)cc2)ncc1-c1cc(C(C)(C)C)cc(C(C)(C)C)c1]

A well-stirred mixture of 10.5 g (10 mmol) S10, 23.5 g (22 mmol) 2,2′-[5″-(4,4,5,5-tetramethyl-1,3,2-dioxaborolan-2-yl)[1,1′:2′,1″:3″,1′″:2′″,1″″-quinquephenyl]-4,4″″-diyl]bis[5-[3,5-bis(1,1-dimethylethyl)phenyl]-4-methyl-pyridin [2202718-90-7], 8.5 g (40 mmol) tripotassium phosphate, 339 mg (0.4 mmol) XPhos Pd G3 [1445085-55-1], 400 ml tetrahydrofuran (THF), and 200 ml water is heated for 20 h under weak reflux. After cooling, add 500 ml of EE, separate the aqueous phase, wash twice with 200 ml of water each, once with 200 ml of saturated saline, dry over magnesium sulfate, filter off the desiccant, concentrate and chromatograph the residue (Torrent automatic column from A. Semrau). Yield: 16.7 g (7.1 mmol) 71%; purity approx. 95% by ¹H-NMR.

Analogously, the following compounds can be prepared, coupling bromides using tetrakis(triphenylphosphino)palladium(0) instead of XPhos Pd G3.

| Ex. | Educt Product | Yield |
|---|---|---|
| L2 | 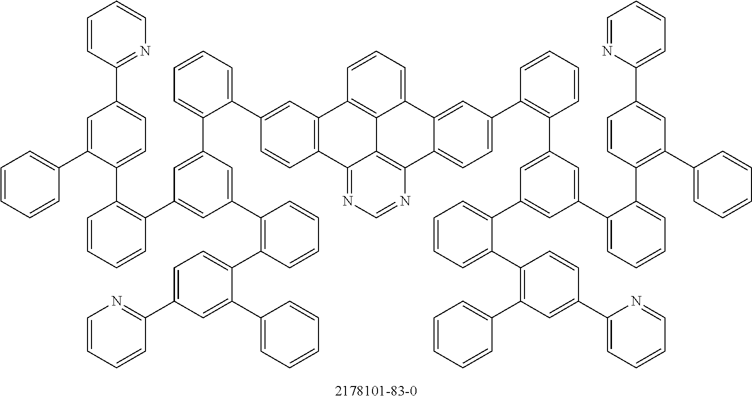 [SMILES: c1ccc(-c2cc(-c3ccccn3)ccc2-c2ccccc2-c2cc(-c3ccccc3-c3ccc4c(c3)c3cccc5c6cc(-c7ccccc7-c7cc(-c8ccccc8-c8ccc(-c9ccccn9)cc8-c8ccccc8)cc(-c8ccccc8-c8ccc(-c9ccccn9)cc8-c8ccccc8)c7)ccc6c6ncnc4c6c35)cc(-c3ccccc3-c3ccc(-c4ccccn4)cc3-c3ccccc3)c2)cc1] | 68% |
| L3 | 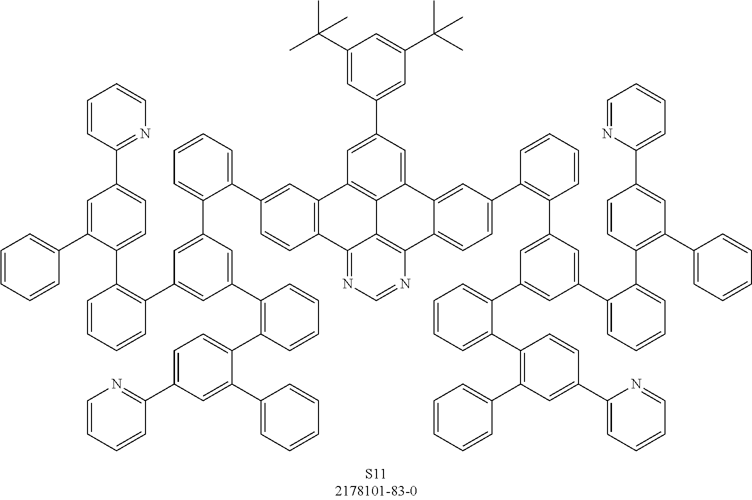 [SMILES: CC(C)(C)c1cc(-c2cc3c4cc(-c5ccccc5-c5cc(-c6ccccc6-c6ccc(-c7ccccn7)cc6-c6ccccc6)cc(-c6ccccc6-c6ccc(-c7ccccn7)cc6-c6ccccc6)c5)ccc4c4ncnc5c6ccc(-c7ccccc7-c7cc(-c8ccccc8-c8ccc(-c9ccccn9)cc8-c8ccccc8)cc(-c8ccccc8-c8ccc(-c9ccccn9)cc8-c8ccccc8)c7)cc6c(c2)c3c45)cc(C(C)(C)C)c1] | 72% |
| L4 | 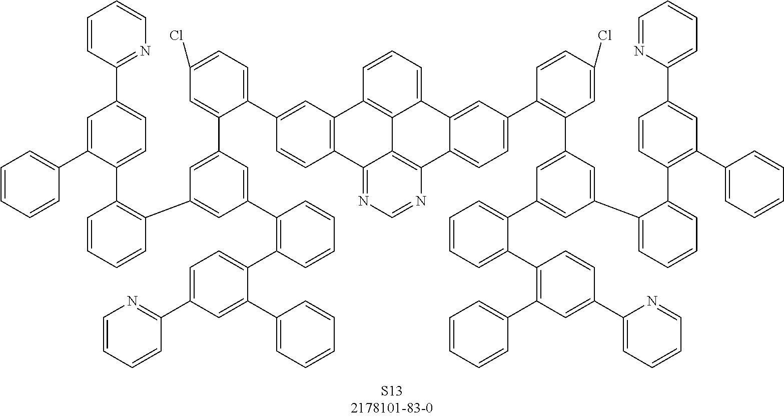 [SMILES: Clc1ccc(-c2ccc3c(c2)c2cccc4c5cc(-c6ccc(Cl)cc6-c6cc(-c7ccccc7-c7ccc(-c8ccccn8)cc7-c7ccccc7)cc(-c7ccccc7-c7ccc(-c8ccccn8)cc7-c7ccccc7)c6)ccc5c5ncnc3c5c24)c(-c2cc(-c3ccccc3-c3ccc(-c4ccccn4)cc3-c3ccccc3)cc(-c3ccccc3-c3ccc(-c4ccccn4)cc3-c3ccccc3)c2)c1] | 70% |
| L5 | 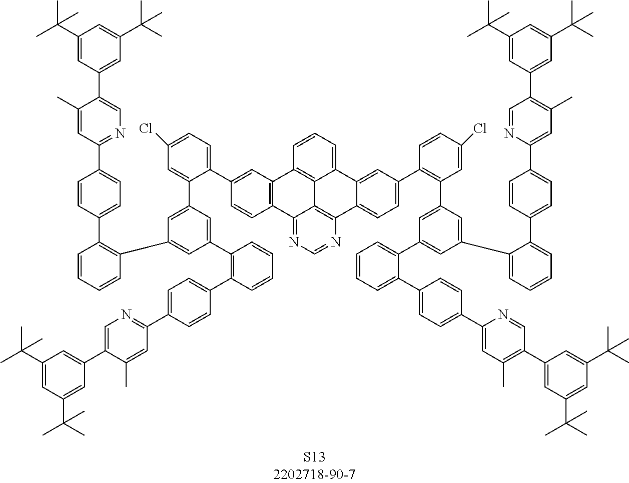 [SMILES: Cc1cc(-c2ccc(-c3ccccc3-c3cc(-c4ccccc4-c4ccc(-c5cc(C)c(-c6cc(C(C)(C)C)cc(C(C)(C)C)c6)cn5)cc4)cc(-c4cc(Cl)ccc4-c4ccc5c(c4)c4cccc6c7cc(-c8ccc(Cl)cc8-c8cc(-c9ccccc9-c9ccc(-c%10cc(C)c(-c%11cc(C(C)(C)C)cc(C(C)(C)C)c%11)cn%10)cc9)cc(-c9ccccc9-c9ccc(-c%10cc(C)c(-c%11cc(C(C)(C)C)cc(C(C)(C)C)c%11)cn%10)cc9)c8)ccc7c7ncnc5c7c46)c3)cc2)ncc1-c1cc(C(C)(C)C)cc(C(C)(C)C)c1] | 59% |
| L200 | 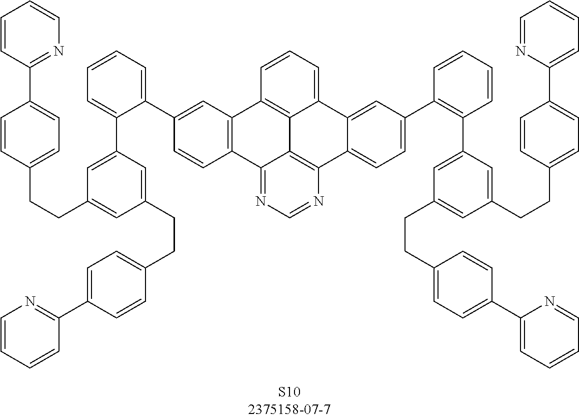 [SMILES: c1ccc(-c2ccc(CCc3cc(CCc4ccc(-c5ccccn5)cc4)cc(-c4ccccc4-c4ccc5c(c4)c4cccc6c7cc(-c8ccccc8-c8cc(CCc9ccc(-c%10ccccn%10)cc9)cc(CCc9ccc(-c%10ccccn%10)cc9)c8)ccc7c7ncnc5c7c46)c3)cc2)nc1] | 66% |
| L201 | 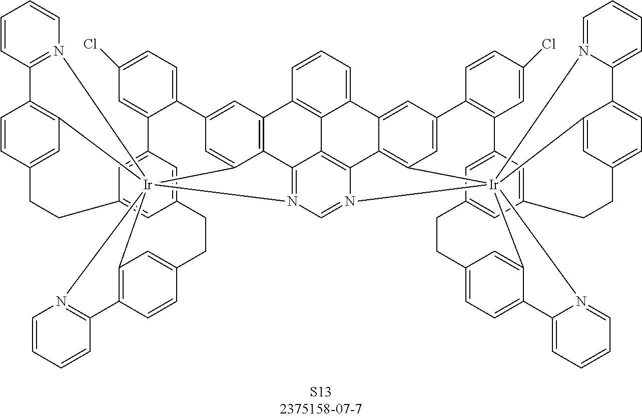 | 60% |
| LD2 | 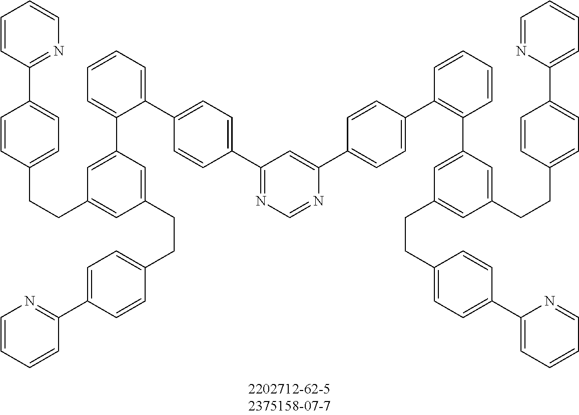 [SMILES: c1ccc(-c2ccc(CCc3cc(CCc4ccc(-c5ccccn5)cc4)cc(-c4ccccc4-c4ccc(-c5cc(-c6ccc(-c7ccccc7-c7cc(CCc8ccc(-c9ccccn9)cc8)cc(CCc8ccc(-c9ccccn9)cc8)c7)cc6)ncn5)cc4)c3)cc2)nc1] | 65% |

### Example L300

### a) Step 1:

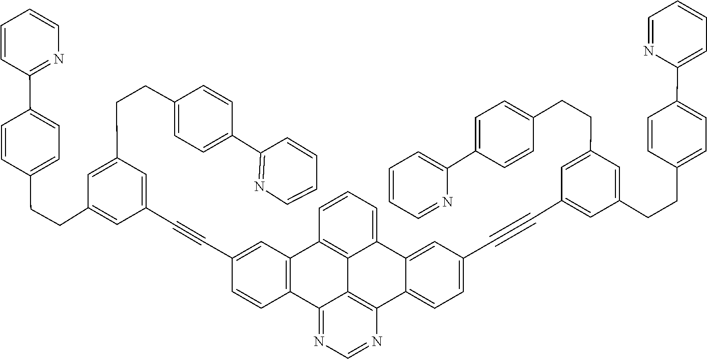 [SMILES: C(#Cc1ccc2c(c1)c1cccc3c4cc(C#Cc5cc(CCc6ccc(-c7ccccn7)cc6)cc(CCc6ccc(-c7ccccn7)cc6)c5)ccc4c4ncnc2c4c13)c1cc(CCc2ccc(-c3ccccn3)cc2)cc(CCc2ccc(-c3ccccn3)cc2)c1]

To a well-stirred solution of 24.8 g (50 mmol) S20 in 500 ml acetonitrile and 4.3 ml (105 mmol) methanol, add 13.8 g (100 mmol) potassium carbonate and 100 g glass beads at room temperature. After weakly exothermic reaction, stir for 1 h more, add 58.9 g (100 mmol) S100, 20.7 g (150 mmol) potassium carbonate, 1.91 g (4 mmol) X-Phos and 449 mg (2 mmol) palladium(II) acetate and stir for 16 h under reflux. Aspirate while still warm over a Celite bed pre-slurried with acetonitrile, condense the filtrate in vacuo at 40° C., take up the reflux in 600 ml DCM, wash three times each with 200 ml water and once with 200 ml saline, and dry over magnesium sulfate. Add 200 ml EE, filter off over a silica gel bed pre-slurried with DCM/EE (4:1 vv), concentrate the filtrate to about 150 ml in vacuo, aspirate from the precipitated product, wash three times with 100 ml methanol each, and dry in vacuo at 40° C. Yield: 48.0 g (39 mmol) 78%; purity: approx. 97% by ¹H-NMR.

### b) Step 2:

Procedure analogous to S100 Step 2. Preparation: 24.6 g (20 mmol). Yield: 20.8 g (17 mmol), 85%; purity: 97% by ¹H-NMR.

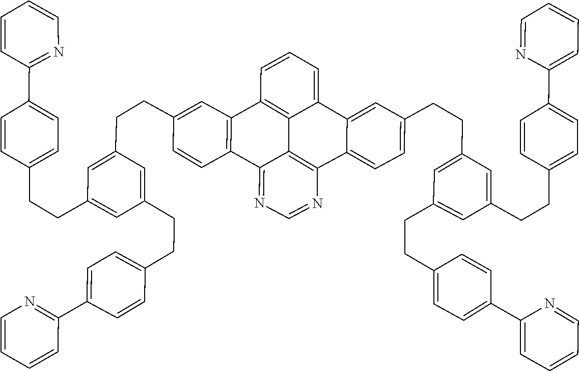 [SMILES: c1ccc(-c2ccc(CCc3cc(CCc4ccc(-c5ccccn5)cc4)cc(CCc4ccc5c(c4)c4cccc6c7cc(CCc8cc(CCc9ccc(-c%10ccccn%10)cc9)cc(CCc9ccc(-c%10ccccn%10)cc9)c8)ccc7c7ncnc5c7c46)c3)cc2)nc1]

Analogously, the following compounds can be prepared.

| Ex. | Educt Product | Yield |
|---|---|---|
| L301 | 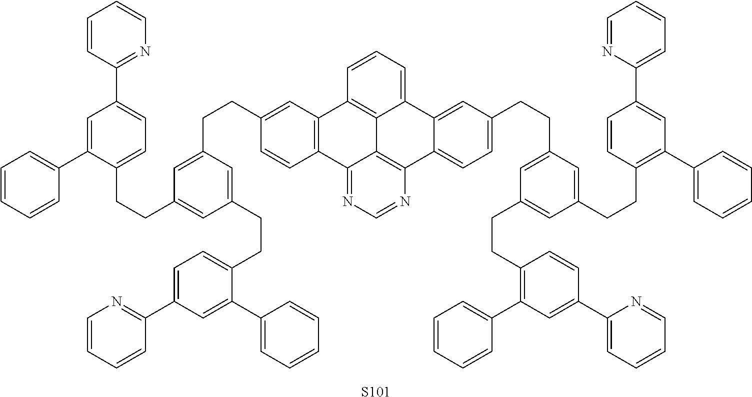 [SMILES: c1ccc(-c2cc(-c3ccccn3)ccc2CCc2cc(CCc3ccc4c(c3)c3cccc5c6cc(CCc7cc(CCc8ccc(-c9ccccn9)cc8-c8ccccc8)cc(CCc8ccc(-c9ccccn9)cc8-c8ccccc8)c7)ccc6c6ncnc4c6c35)cc(CCc3ccc(-c4ccccn4)cc3-c3ccccc3)c2)cc1 ; "S101"] | 65% |
| L302 | 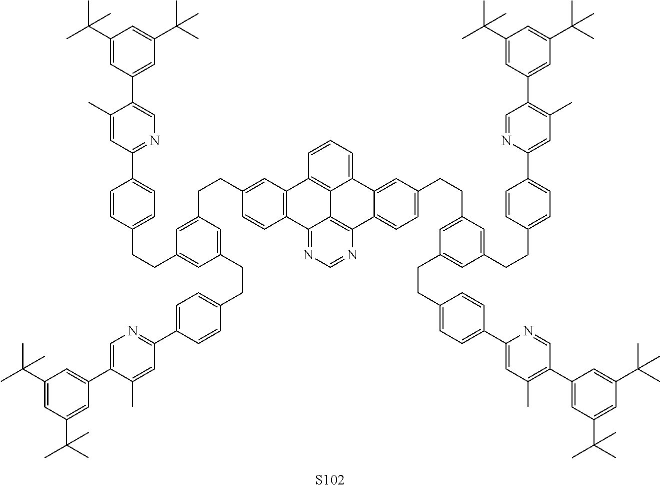 [SMILES: Cc1cc(-c2ccc(CCc3cc(CCc4ccc(-c5cc(C)c(-c6cc(C(C)(C)C)cc(C(C)(C)C)c6)cn5)cc4)cc(CCc4ccc5c(c4)c4cccc6c7cc(CCc8cc(CCc9ccc(-c%10cc(C)c(-c%11cc(C(C)(C)C)cc(C(C)(C)C)c%11)cn%10)cc9)cc(CCc9ccc(-c%10cc(C)c(-c%11cc(C(C)(C)C)cc(C(C)(C)C)c%11)cn%10)cc9)c8)ccc7c7ncnc5c7c46)c3)cc2)ncc1-c1cc(C(C)(C)C)cc(C(C)(C)C)c1 ; "S102"] | 61% |
| L303 | 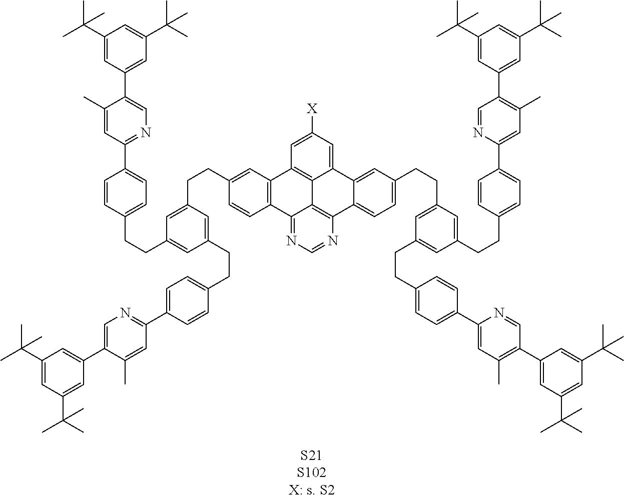 | 58% |
| LD3 | 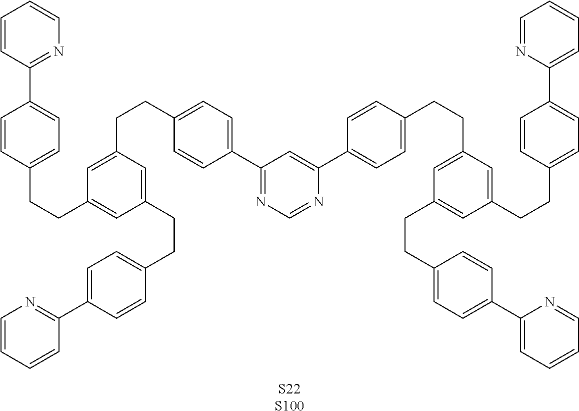 [SMILES: c1ccc(-c2ccc(CCc3cc(CCc4ccc(-c5ccccn5)cc4)cc(CCc4ccc(-c5cc(-c6ccc(CCc7cc(CCc8ccc(-c9ccccn9)cc8)cc(CCc8ccc(-c9ccccn9)cc8)c7)cc6)ncn5)cc4)c3)cc2)nc1 ; "S22S100"] | 66% |

### Example L600

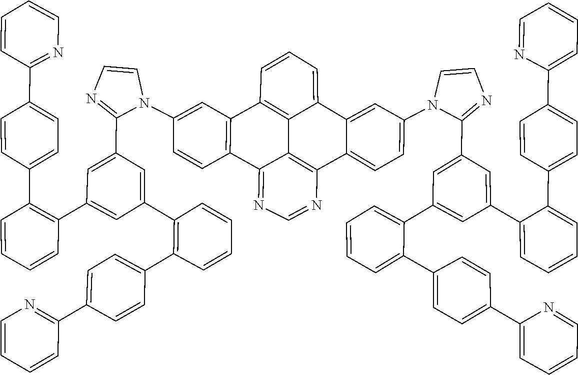 [SMILES: c1ccc(-c2ccc(-c3ccccc3-c3cc(-c4ccccc4-c4ccc(-c5ccccn5)cc4)cc(-c4nccn4-c4ccc5c(c4)c4cccc6c7cc(-n8ccnc8-c8cc(-c9ccccc9-c9ccc(-c%10ccccn%10)cc9)cc(-c9ccccc9-c9ccc(-c%10ccccn%10)cc9)c8)ccc7c7ncnc5c7c46)c3)cc2)nc1]

A well-stirred mixture of 6.0 g (5 mmol) S1 step 4, 6.3 g (10 mmol) S200, 6.5 g (20 mmol) caesium carbonate, 180 mg (1 mmol) 1,10-phenanthroline, 95 mg (0.5 mmol) copper iodide, 30 g glass spheres (3 mm diameter), and 100 ml dimethylacetamide (DMAc) is heated to 150° C. for 16 h with stirring. Draw off while still warm over a Celite bed pre-slurried with DMAc, condense the filtrate in vacuo, take up the residue in 300 ml DCM, wash three times with 200 ml each of water and once with 200 ml of saturated saline, and dry over magnesium sulfate. Add 100 ml of EE, filter off over a silica gel bed pre-slurried with DCM/EE (3:1 vv), concentrate the filtrate to about 50 ml in vacuo, draw off from the precipitated product, wash three times with 30 ml of methanol each, and dry in vacuo. Yield: 4.7 g (3.1 mmol) 62%; purity: approx. 97% by ¹H-NMR.

Analogously, the following ligands can be prepared:

| Ex. | Product | Yield |
|---|---|---|
| L601 | 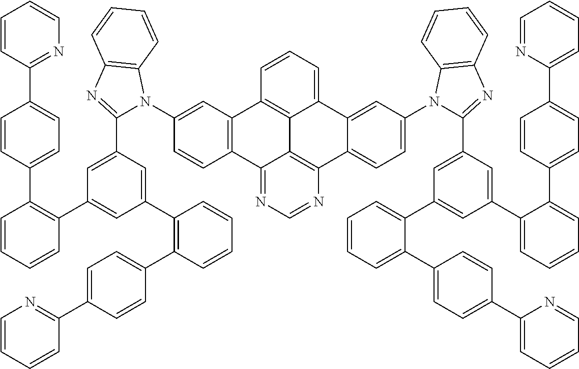 [SMILES: c1ccc(-c2ccc(-c3ccccc3-c3cc(-c4ccccc4-c4ccc(-c5ccccn5)cc4)cc(-c4nc5ccccc5n4-c4ccc5c(c4)c4cccc6c7cc(-n8c(-c9cc(-c%10ccccc%10-c%10ccc(-c%11ccccn%11)cc%10)cc(-c%10ccccc%10-c%10ccc(-c%11ccccn%11)cc%10)c9)nc9ccccc98)ccc7c7ncnc5c7c46)c3)cc2)nc1] | 60% |
| L602 | 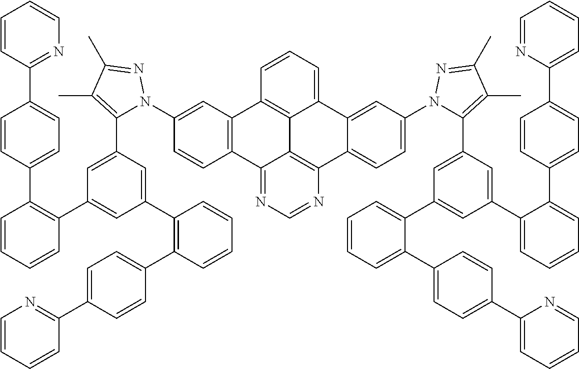 [SMILES: Cc1nn(-c2ccc3c(c2)c2cccc4c5cc(-n6nc(C)c(C)c6-c6cc(-c7ccccc7-c7ccc(-c8ccccn8)cc7)cc(-c7ccccc7-c7ccc(-c8ccccn8)cc7)c6)ccc5c5ncnc3c5c24)c(-c2cc(-c3ccccc3-c3ccc(-c4ccccn4)cc3)cc(-c3ccccc3-c3ccc(-c4ccccn4)cc3)c2)c1C] | 27% |
| L603 | 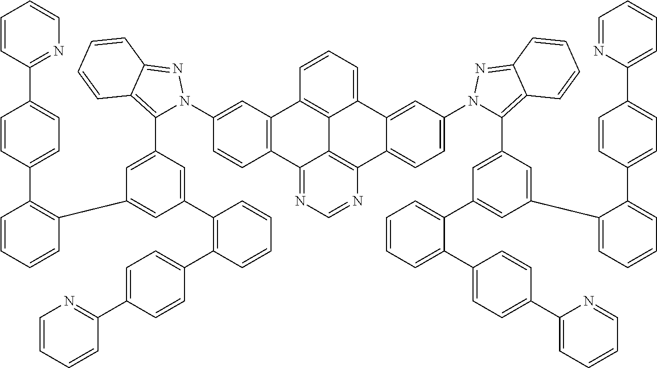 [SMILES: c1ccc(-c2ccc(-c3ccccc3-c3cc(-c4ccccc4-c4ccc(-c5ccccn5)cc4)cc(-c4c5ccccc5nn4-c4ccc5c(c4)c4cccc6c7cc(-n8nc9ccccc9c8-c8cc(-c9ccccc9-c9ccc(-c%10ccccn%10)cc9)cc(-c9ccccc9-c9ccc(-c%10ccccn%10)cc9)c8)ccc7c7ncnc5c7c46)c3)cc2)nc1] | 32% |

### C) Synthesis of the Ir Complexes According to the Invention

### Example Isomer I1-Ir₂(L1) and Isomer 12-Ir₂(L1)

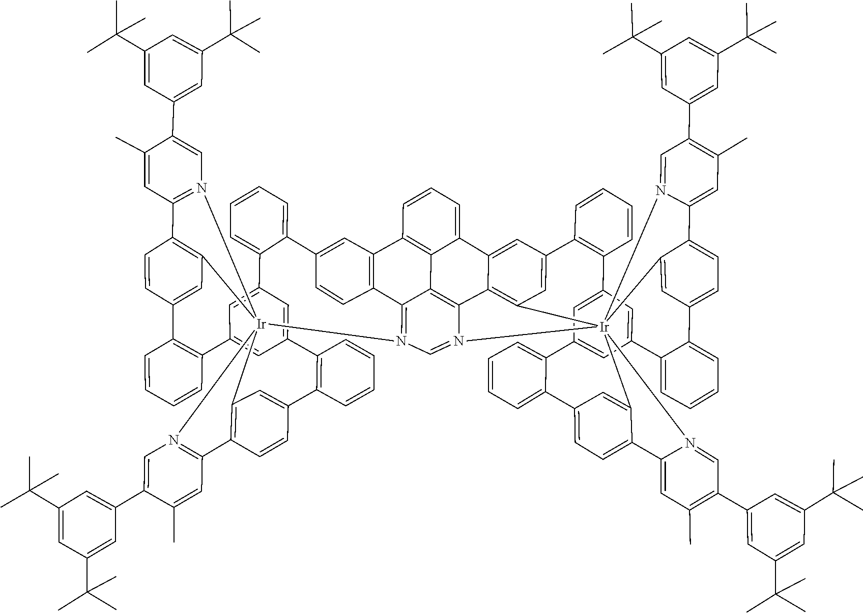

A mixture of 23.4 g (10 mmol) of ligand L1, 9.8 g (20 mmol) of tris-acetylacetonato-iridium(III) [15635-87-7], and 200 g of hydroquinone [123-31-9] is placed in a 1000 mL two-necked round-bottom flask with a glass-encased magnetic core. The flask is fitted with a water separator (for media of lower density than water) and an air cooler with argon via storage and placed in a metal heating pan. The apparatus is purged with argon from above the argon overlay for 15 min, allowing argon to flow out of the side neck of the two-necked flask. A glass-jacketed Pt-100 thermocouple is inserted into the flask via the side neck of the two-neck flask and the end is placed just above the magnetic stirrer core. Thermally insulate the apparatus with several loose wraps of household aluminum foil, extending the insulation to the center of the riser tube of the water separator. The apparatus is then rapidly heated with a laboratory heating stirrer to 250° C. as measured by the Pt-100 thermal probe immersed in the molten, stirred reaction mixture. During the next 2 h, the reaction mixture is maintained at 250° C., with little condensate distilling off and collecting in the water separator. The reaction mixture is allowed to cool to 190° C., then 100 mL of ethylene glycol is added. Allow to cool further to 80° C. and then add 500 mL of methanol, heat for 1 h under reflux. The resulting suspension is filtered through a reverse frit, the solid is washed twice with 50 mL of methanol and then dried in vacuo. The solid obtained is dissolved in 200 mL of dichloromethane and filtered over about 1 kg of silica gel (column diameter about 18 cm) pre-slurried with dichloromethane, excluding air and light, leaving dark portions at the start. The core fraction is cut out, concentrated on the rotary evaporator, while at the same time MeOH is continuously added until crystallization. After aspiration, washing with some MeOH and drying in vacuo, further purification of the diastereomeric product mixture takes place.

The diastereomeric metal complex mixture containing AA- and AA-isomers (racemic) as well as AA-isomer (meso) in a molar ratio of about 1:1 (determined by ¹H-NMR) is dissolved in 300 mL of dichloromethane, drawn up onto 100 g of isolute and chromatographically separated over a silica gel column pre-slurried with toluene/ethyl acetate 95:5 (amount of silica gel about 1.8 kg). First elute the front spot and then gradually increase the amount of ethyl acetate until the toluene/ethyl acetate ratio is 6:1. 10.86 g (4.0 mmol, purity 99%) of the earlier eluting isomer, hereafter referred to as isomer 1 (11), and 10.30 g (3.8 mmol, purity 98%) of the later eluting isomer, hereafter referred to as isomer 2 (12), are obtained. Isomer 1 (11) and isomer 2 (12) are further purified separately by hot extraction four times with dichlor methane/acetonitrile (2:1>1:2) (receiving volume approx. 150 ml each, extraction tube: standard cellulose Soxhlet tubes from Whatman) with careful exclusion of air and light. Finally, the products were annealed in high vacuum at 280° C. Yield: Isomer 1 (11) 9.22 g red solid (3.4 mmol), 34% based on the amount of ligand used. Purity: >99.9% by HPLC; isomer 2 (12) 8.12 g red solid (3.0 mmol), 30% based on amount of ligand used. Purity 99.9% according to HPLC.

Analogously the following compounds can be synthesized

| Ex. | Educt Product | Yield |
|---|---|---|
| I1-Ir₂(L2) | 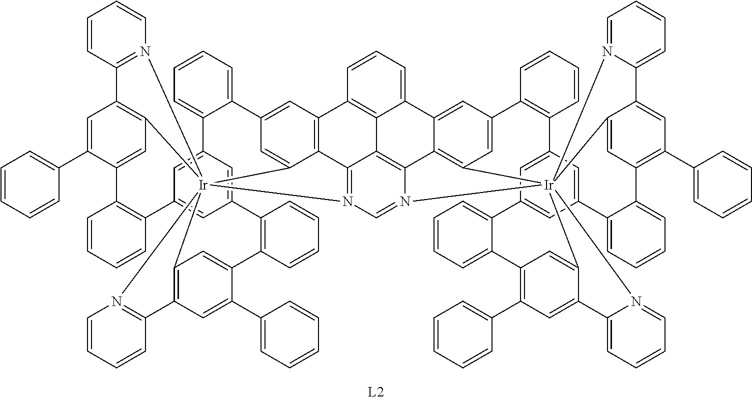 | 30% |
| I2-Ir₂(L2) | 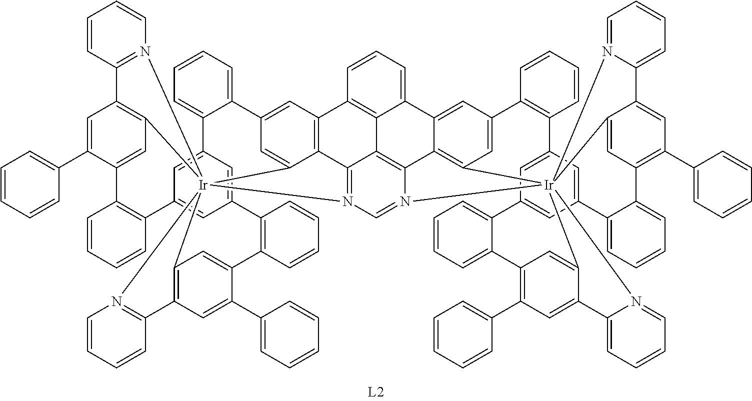 | 23% |
| I1-Ir₂(L3) | 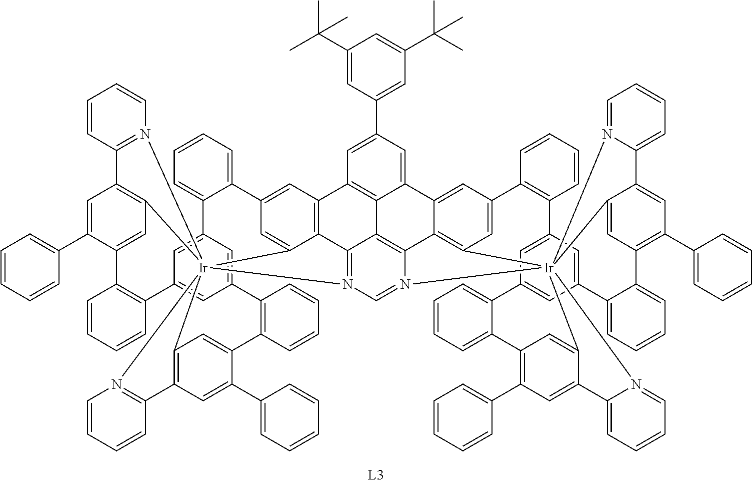 | 32% |
| I1-Ir₂(L4) | 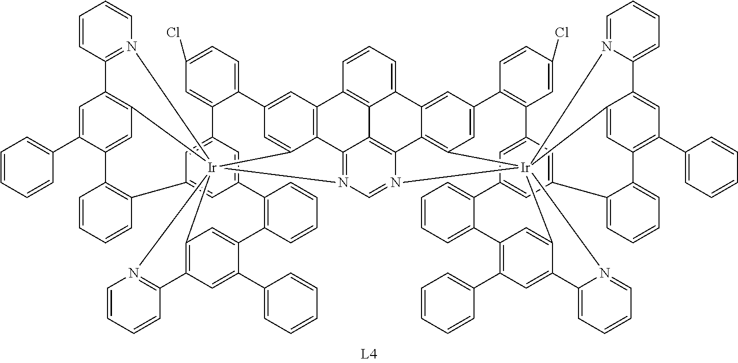 | 35% |
| I1-Ir₂(L5) | 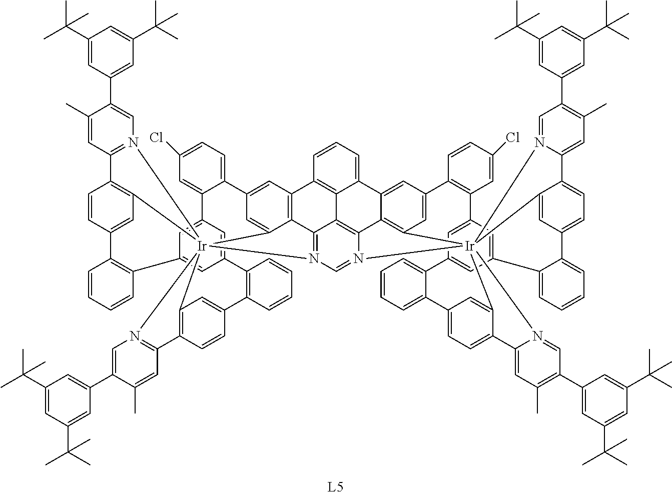 | 37% |
| I1-Ir₂(L200) | 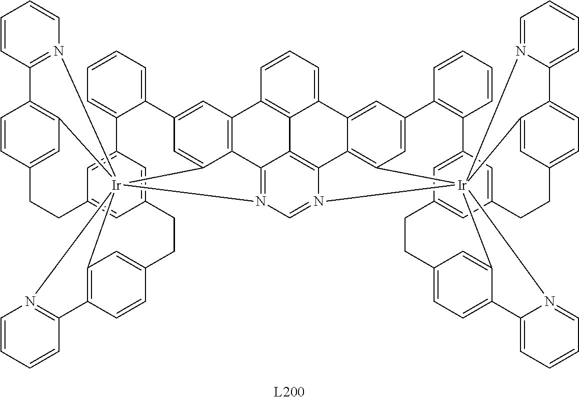 | 31% |
| I1-Ir₂(L201) | 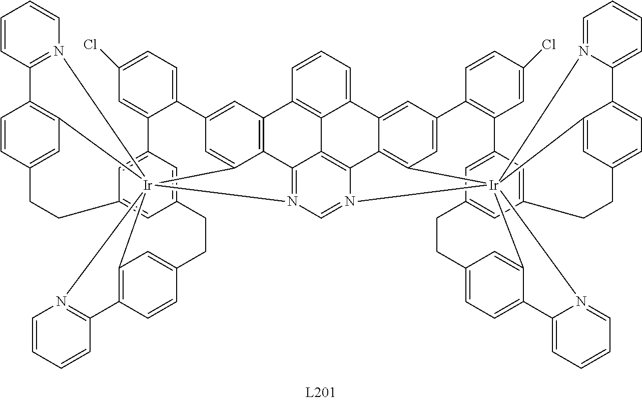 | 32% |
| I1-Ir₂(L300) | 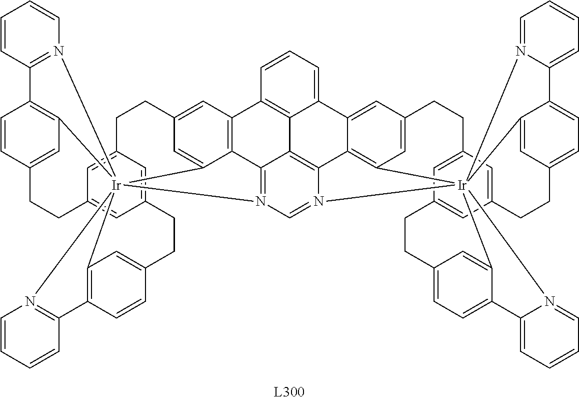 | 29% |
| I1-Ir₂(L301) | 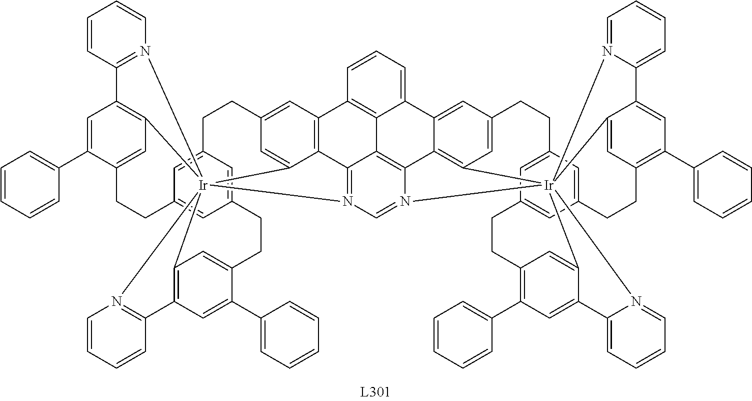 | 33% |
| I1-Ir₂(L302) | 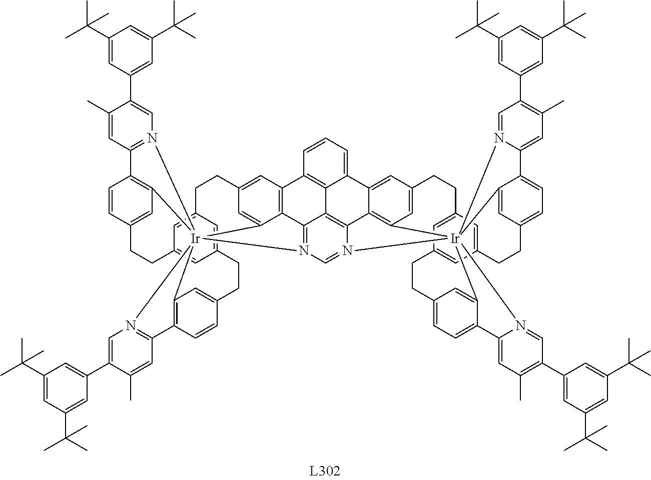 | 30% |
| I1-Ir₂(L303) | 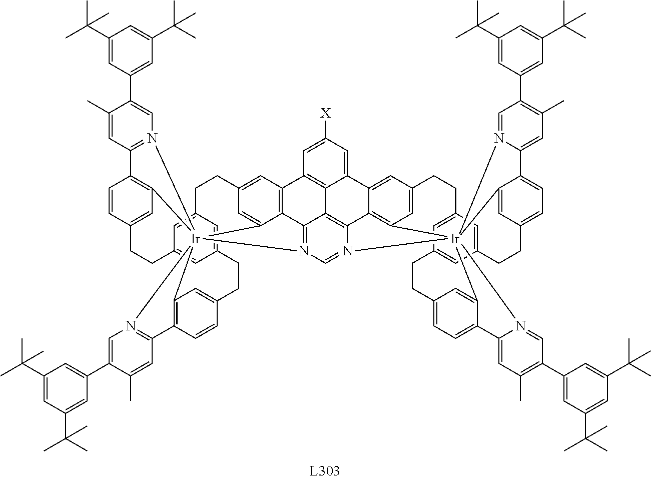 | 26% |
| | 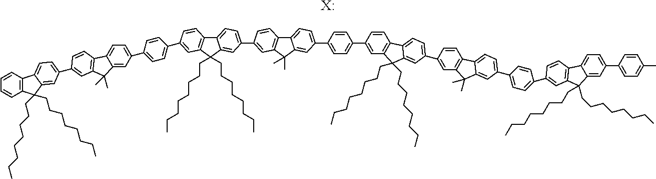 | |
| I1-Ir₂(L600) | 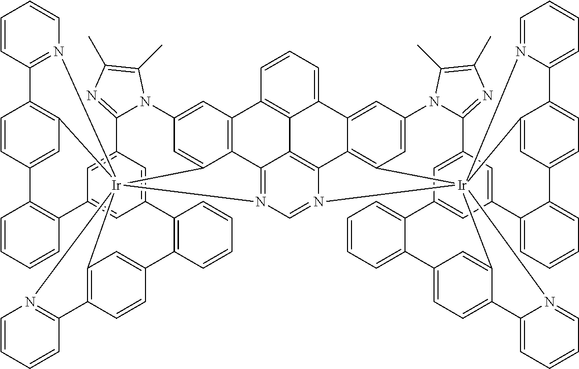 | 32% |
| I1-Ir₂(L601) | 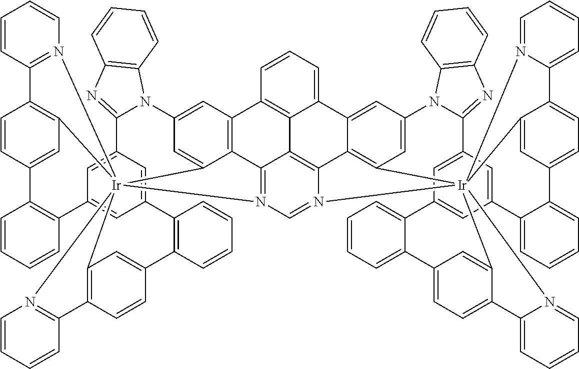 | 35% |
| I1-Ir₂(L602) | 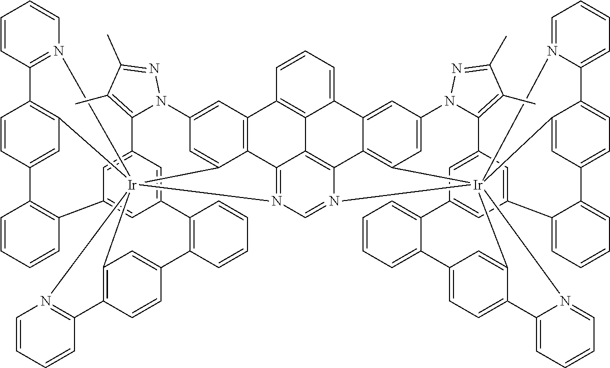 | 28% |
| I1-Ir₂(L603) | 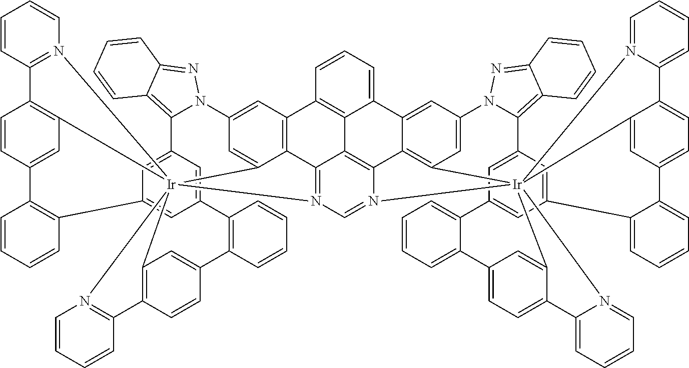 | 30% |
| D2 = I1-Ir₂(LD2) | 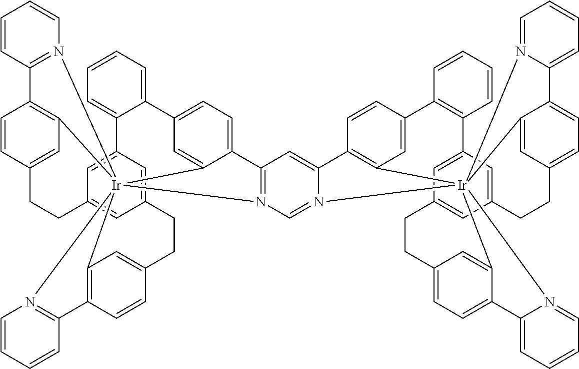 | 35% |
| D3 = I1-Ir₂(LD3) | 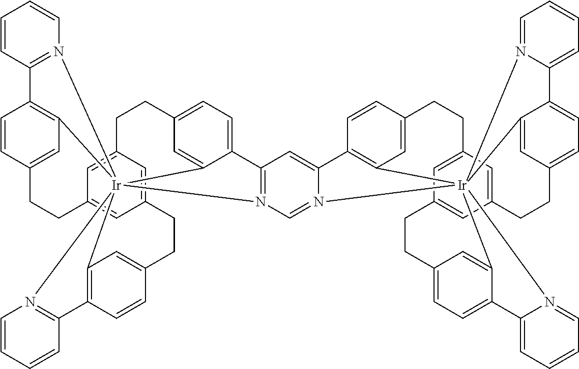 | 30% |

### Example Isomer I1-Ir₂(L4)-BRSE

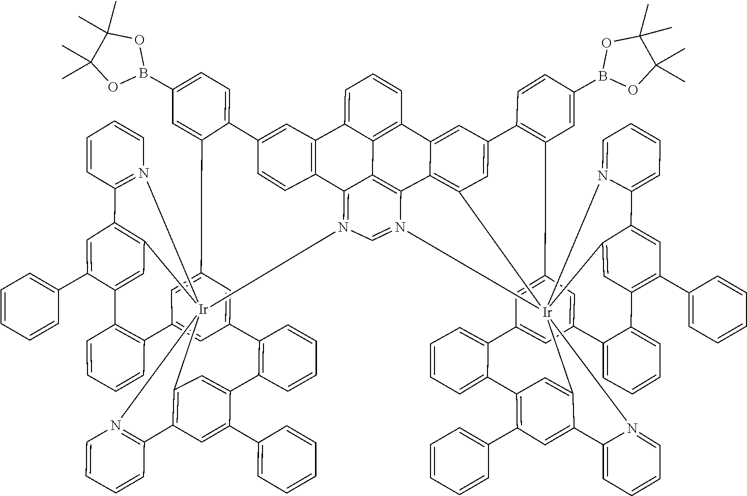

11.38 g (5.0 mmol) I1-Ir₂ (L4), 2.8 g (11 mmol) bis(pinacolato)diborane, 2.4 g (25 mmol) potassium acetate and 453 mg (0.61 mmol) trans-dichlorobis (tricylohexylphosphine)palladium(II) are placed in 300 ml dioxane and stirred for 16 h at 100° C. After cooling to room temperature, 300 ml water is added, extracted three times with 200 ml DCM each, the combined organic phases are washed three times with 200 ml water extracted each, and dried over magnesium sulfate. Filter off from the desiccant over a silica gel bed pre-slurried with DCM, add 100 ml methanol and concentrate in vacuo to about 100 ml. Aspirate the crystallized product, wash twice with 20 ml methanol each and dry in vacuo. Yield: 11.30 g (4.6 mmol), 92% of theory.

Analogously, the following compounds can be synthesized.

| Ex. | Educt Product | Yield |
|---|---|---|
| I1- Ir₂(L5)- BRSE | 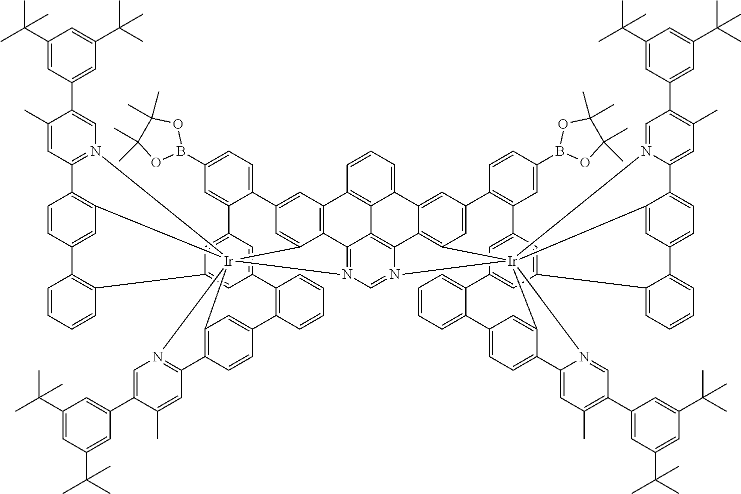 | 90% |
| | I1-Ir₂(L5) | |
| I1- Ir₂(L201)- BRSE | 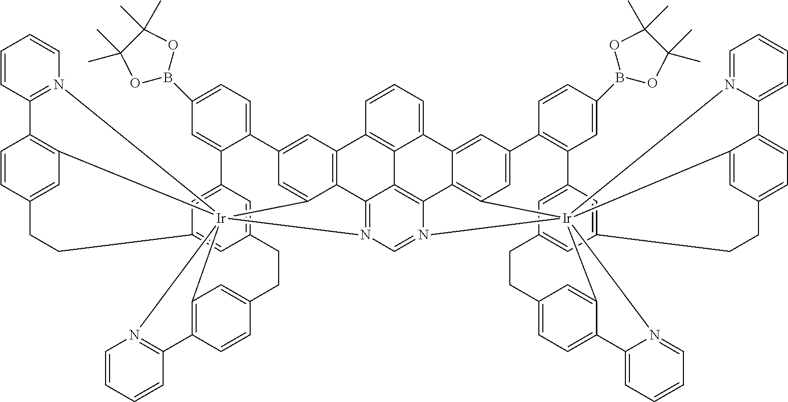 | 85% |

### Example I1-Ir₂(L400)

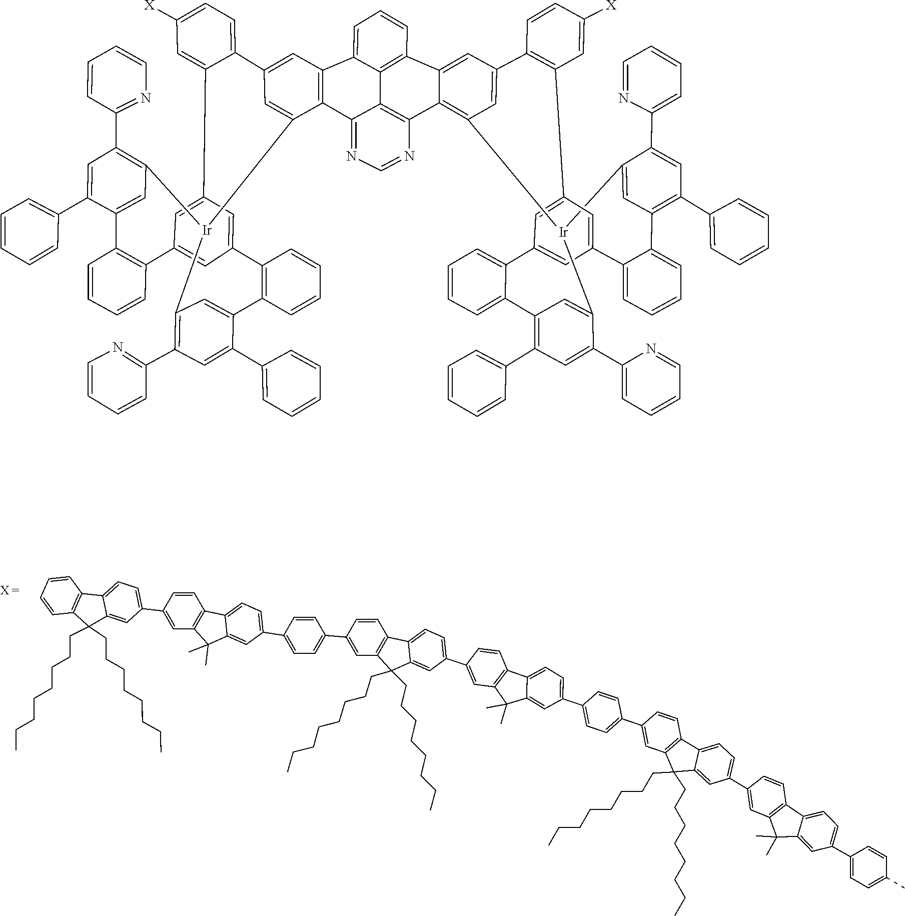

12.3 g (5 mmol) I1-Ir₂ (L4)-BRSE, 24.8 g (10 mmol) 7-[4-[7′-[4-[7-(4-chlorophenyl)-9,9-dioctyl-9H-fluoren-2-yl]phenyl]-9′,9′-dimethyl-9,9-dioctyl[2,2′-bi-9H-fluoren]-7-yl]phenyl]-7′-[4-(9,9-dimethyl-9′,9′-dioctyl[2,2′-bi-9H-fluoren]-7-yl)phenyl]-9,9-dimethyl-9′,9′-dioctyl-2,2′-bi-9H-fluoren [2761726-60-5], 3.0 g (20 mmol) of cesium fluoride and 373 mg (0.5 mmol) of trans-dichlorobis(tricylohexylphosphine) palladium(II) are dissolved in 300 mL of dioxane and heated at reflux for 16 h. The reaction mixture is refluxed. Dichloromethane and water are added to the reaction mixture after cooling to room temperature, and the organic phase is separated. The aqueous phase is extracted twice with dichloromethane, and the combined organic phases are extracted with water and then concentrated under reduced pressure. The residue is chromatographically purified several times (SiO₂, heptane/dichloromethane) and then crystallized again from dichloromethane/methanol. The solid obtained is dried under reduced pressure at 200° C. Yield: 20.7 g (3.4 mmol), 68% of theory.

Analogously, the following compounds can be prepared.

| Ex. | Educts Product | Yield |
|---|---|---|
| I1- Ir₂(L401) | 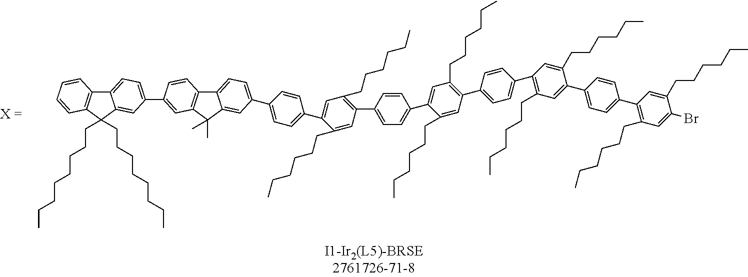 | 64% |
| | 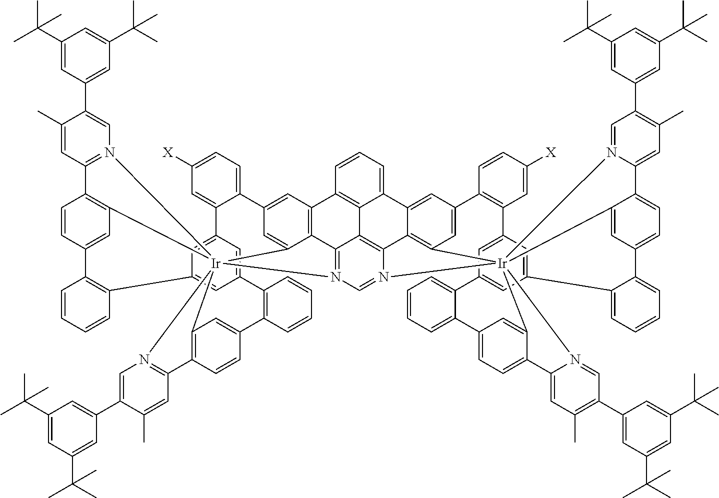 | |
| | 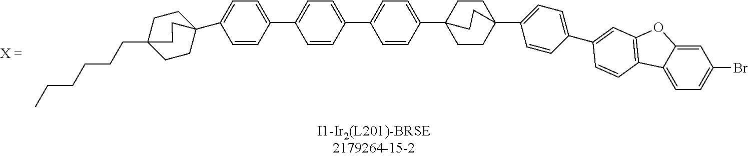 | 59% |
| I1- Ir_{₂}(L402) | 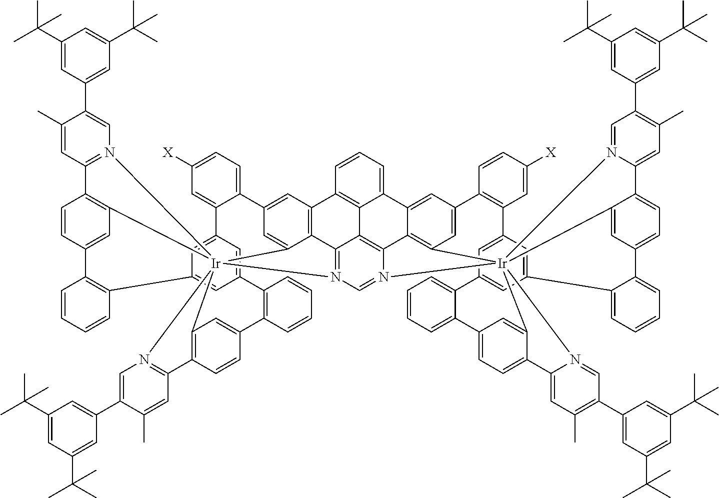 | |

### Example I1-Ir₂(L1)Br₄

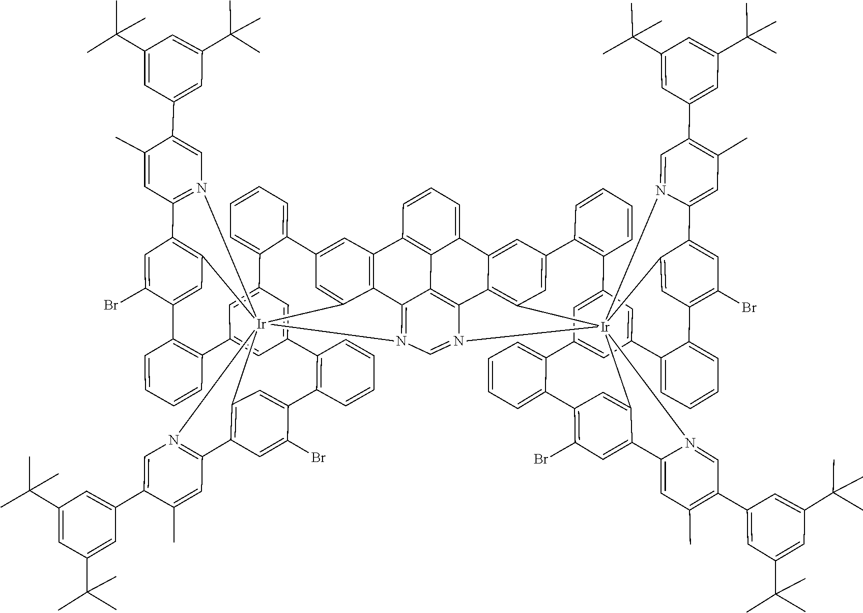

To a suspension of 13.6 g (5 mmol) I1-Ir₂ (L1) in 1000 ml DCM stirred at 0° C., 7.2 g (40 mmol)N-bromosuccinimide is added at one time and then stirred for an additional 20 hr. After removing about 1900 ml of the DCM in vacuo, 100 ml of methanol is added to the yellow suspension, the solid is aspirated, washed three times with about 50 ml of methanol, and then dried in vacuo. Yield: 6.8 g (4.5 mmol) 90%; purity: >99.0% by NMR.

Analogously, I1-Ir₂(L300)Br₄ can be prepared.

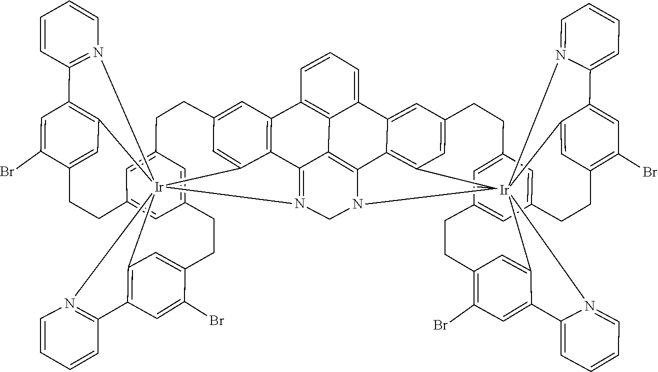

### Example I1-Ir₂(L500)

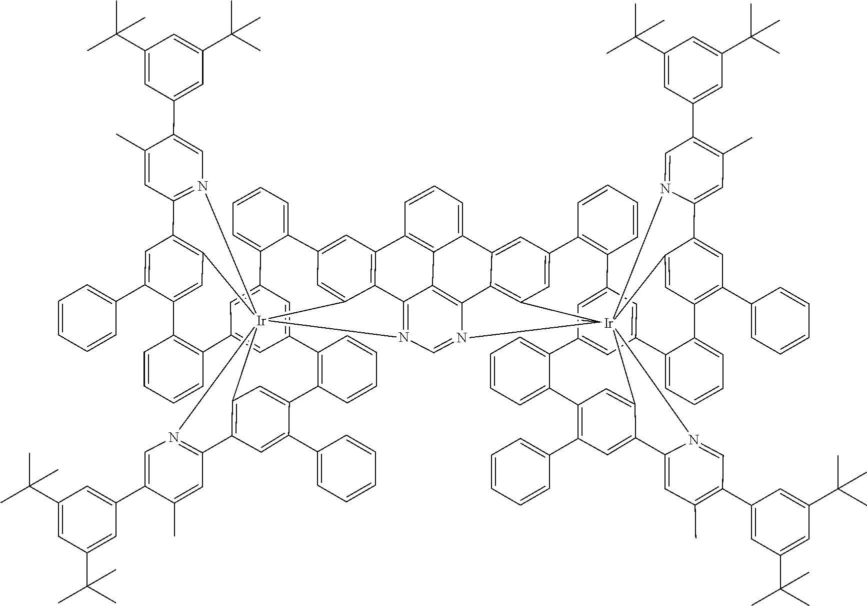

Preparation analogous to WO 2016/124304, 2) Suzuki coupling to the brominated iridium complexes, variant A, two-phase reaction mixture (see p. 353). Preparation: 15.1 g (5 mmol) I1-Ir₂(L1)Br₄ and 6.1 g (50 mmol) phenylboronic acid [98-80-6]. Yield: 12.9 g (4.3 mmol) 86%; Purity: >99.5% by ¹H-NMR.

Analogously, the following-compounds can be prepared.

| Ex. | Educts Product | Yield |
|---|---|---|
| I1- Ir₂(L501) | 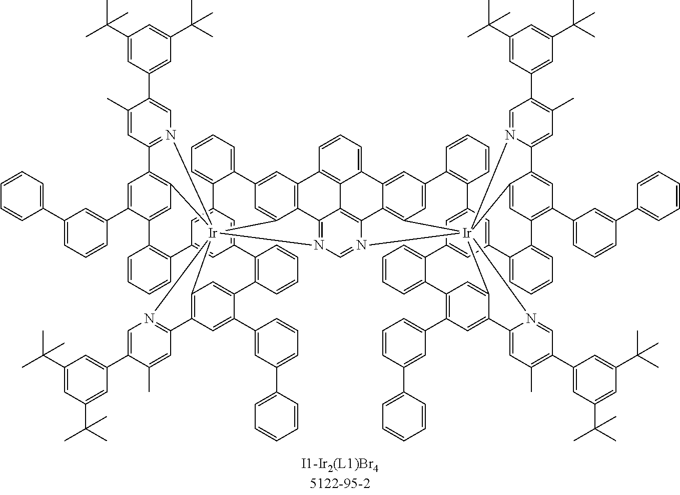 | 83% |
| I1- Ir₂(L502) | 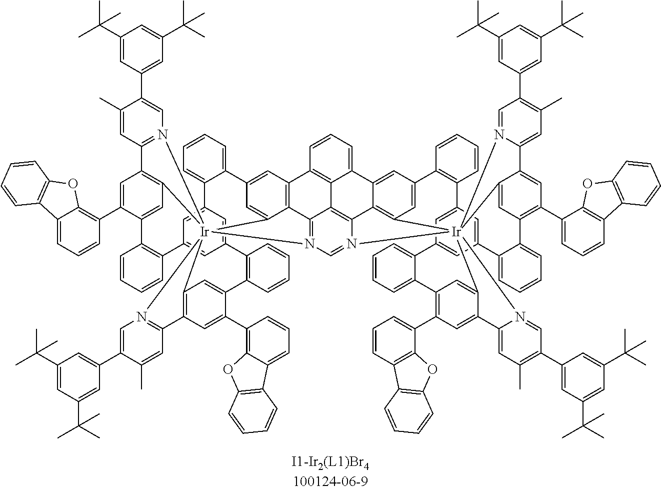 | 80% |
| I1- Ir₂(L503) | 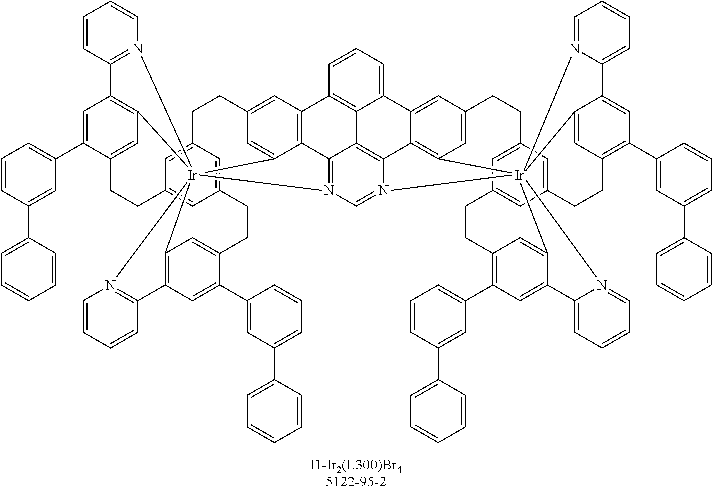 | 88% |
| I1- Ir₂(L504) | 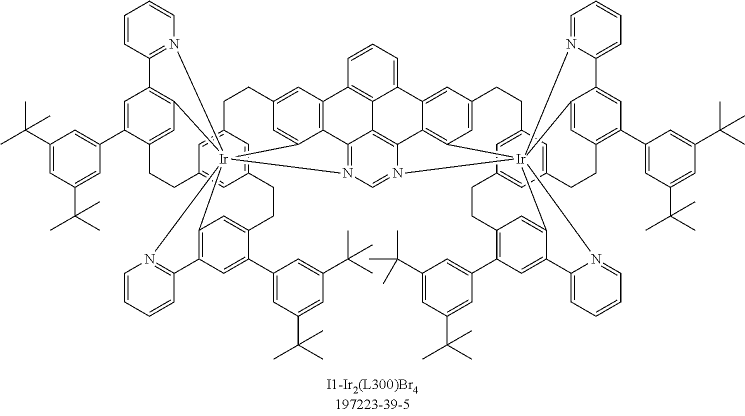 | 85% |
| I1- Ir₂(L505) | 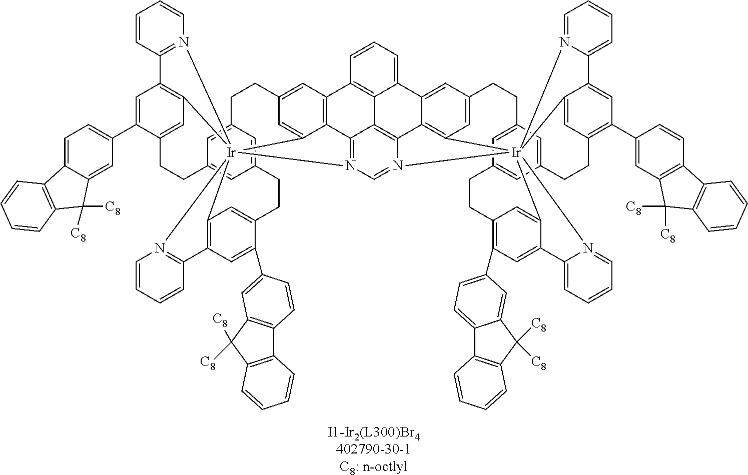 | 79% |

### Physics Examples

### Photophysical Characterization

The compounds according to the invention can be brought into solution and photophysically characterized. Table 1 summarizes the maximum and half-width FWHM (in nm and in eV) of the photo luminescence spectrum in solution for materials according to the invention and associated reference materials. Degassed, approx. 10⁻⁵ molar solutions in toluene at room temperature are examined. Compounds according to the invention show narrower half-widths in each case than structurally associated unbridged compounds. The structures of the comparative compounds are shown in Table 2.

TABLE 1

| | | PL-Maximum | FWHM | FWHM |
|---|---|---|---|---|
| Example | Complex | (nm) | (nm) | (eV) |
| V1 | D1 | 626 | 49.0 | 0.152 |
| E1 | I1-Ir2(L1) | 633 | 36.7 | 0.113 |
| V2 | D2 | 614 | 53.9 | 0.173 |
| E2 | I1-Ir₂(L200) | 627 | 45.2 | 0.141 |
| V3 | D3 | 593 | 60.2 | 0.205 |
| E3a | I1-Ir₂(L300) | 607 | 45.2 | 0.150 |
| E3b | I1-Ir₂(L301) | 608 | 43.7 | 0.144 |
| E3c | I1-Ir₂(L302) | 616 | 38.4 | 0.124 |
| V4 | D4 | 608 | 58.0 | 0.189 |
| E4a | I1-Ir₂(L2) | 623 | 44.8 | 0.142 |
| E4b | I1-Ir₂(L3) | 623 | 43.3 | 0.137 |

TABLE 2

| | |
|---|---|
| 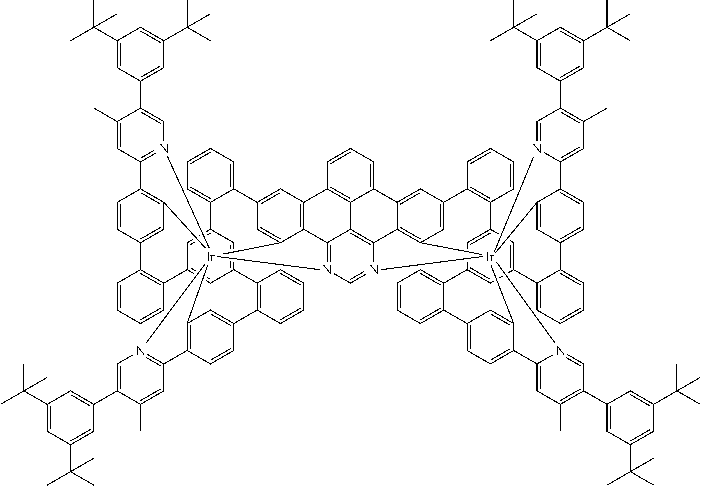 | D1 |
| (WO 2018/041769) | |
| 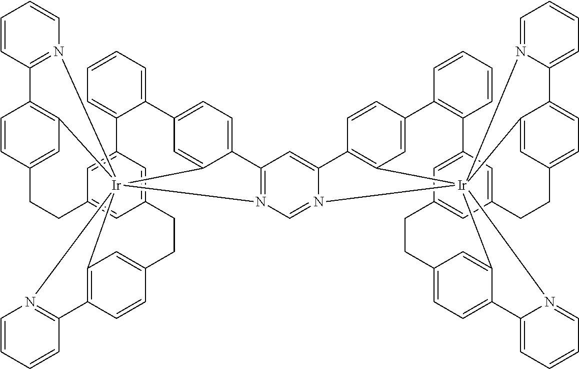 | D2 |
| (see synthesis section) | |
| 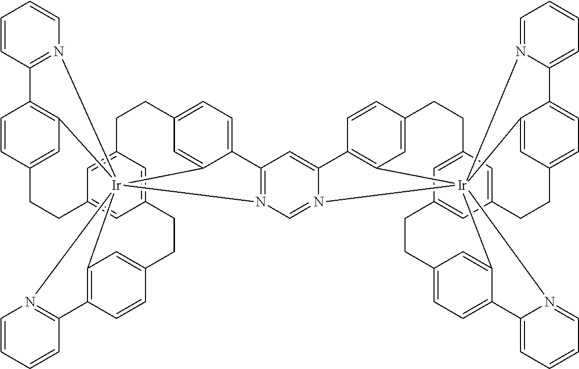 | D3 |
| (see synthesis section) | |
| 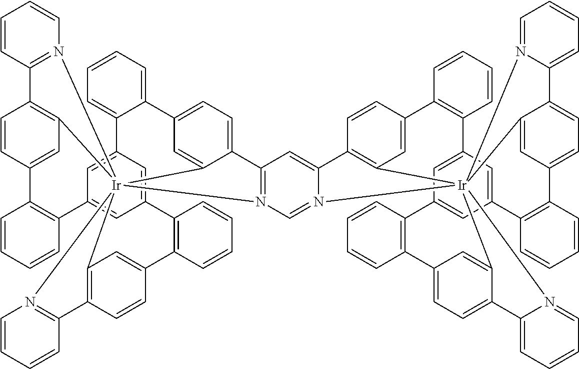 | D4 |
| (WO 2018/041769) | |

### Production of the OLEDS

The complexes according to the invention can be processed from the solution. The fabrication of fully solution-based OLEDS has been described many times in the literature, e.g., in WO 2004/037887 using spin coating. The fabrication of vacuum-based OLEDS has also been described many times, including in WO 2004/058911. In the examples discussed below, solution based, and vacuum-based deposited layers are combined within an OLED, such that processing up to and including the emission layer is from solution and in the subsequent layers (hole blocking layer and electron transport layer) is from vacuum. For this purpose, the general processes described above are adapted and combined to the conditions described here (layer thickness variation, materials) as described below. The general setup is as follows: Substrate/ITO (50 nm)/hole injection layer (HIL) (60 nm)/hole transport layer (HTL) (20 nm)/emission layer (EML) (60 nm)/hole blocking layer (HBL) (10 nm)/electron transport layer (ETL) (40 nm)/cathode (aluminum, 100 nm). Glass plates coated with patterned ITO (indium tin oxide) of thickness 50 nm are used as substrate. For better processing, these are coated with PEDOT:PSS (poly(3,4-ethylenedioxy-2,5-thiophene): polystyrene sulfonate, purchased from Heraeus Precious Metals GmbH & Co. KG, Germany). PEDOT:PSS is spun in air from water to and subsequently heated in air at 180° C. for 10 minutes from to remove residual water. The hole transport layer and the emission layer are applied to these coated glass plates. The hole transport layer used is crosslinkable. A polymer is used according to the structure shown below, which can be synthesized according to WO 2013/156130:

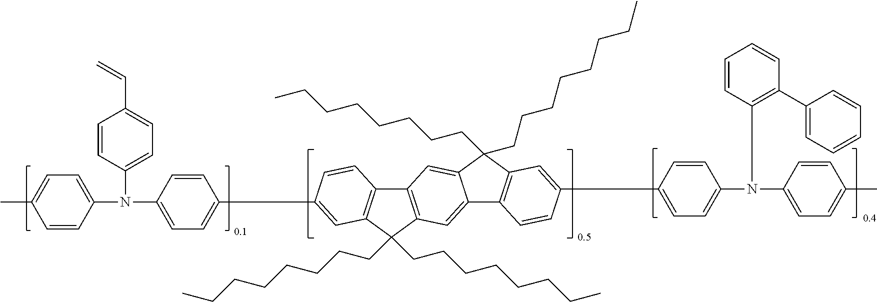

The hole transport polymer is dissolved in toluene. The typical solids content of such solutions is about 5 g/I if, as here, the typical layer thickness of 20 nm for a device is to be achieved by means of spin coating. The layers are spuncoated in an inert gas atmosphere, in this case argon, and baked at 220° C. for 30 minutes.

The emission layer is always composed of at least one matrix material (host material, host material) and an emitting dopant (dopant, emitter).

Furthermore, mixtures of several matrix materials as well as co-dopants can be used. A specification like TMM-A (92%): Dopant (8%) means here that the material TMM-A is present in a weight fraction of 92% and Dopant in a weight fraction of 8% in the emission layer. The mixture for the emission layer is dissolved in toluene or, if necessary, chlorobenzene. The typical solids content of such solutions is about 17 g/l if, as here, the typical layer thickness of 60 nm for a device is to be achieved by spin coating. The layers are spuncoated in an inert gas atmosphere, in the present case argon, and baked at 160° C. for 10 minutes. The materials used in the present case are shown in Table 3.

TABLE 3
EML materials used

| | |
|---|---|
| See WO14094963 | A-1 |
| 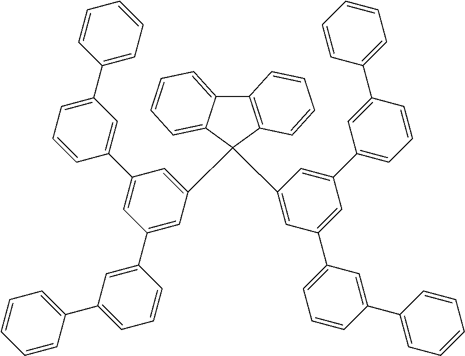 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1] | B-1 |
| See WO09124627 | |
| 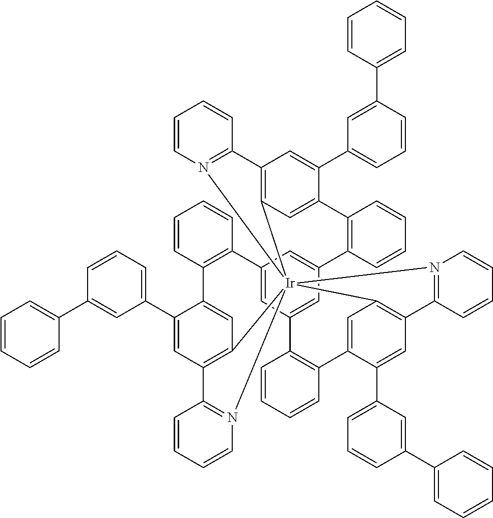 | C-1 |
| See WO 2016/124304 | |

Table 4 shows the mixtures used for the emission layers in the present examples.

TABLE 4
Mixtures used

| | | Mixing ratio |
|---|---|---|
| Ex. | Complex | A1:B1:C1:Complex |
| E5 | I1-Ir2(L1) | 30:45:17:8 |
| E6 | I2-Ir2(L1) | 30:42:20:8 |
| E7 | I1-Ir₂(L200) | 30:45:17:8 |
| E8 | I1-Ir₂L300) | 30:42:20:8 |
| E9 | I1-Ir₂(L301) | 30:50:12:8 |
| E10 | I1-Ir₂(L301) | 40:45:0:15 |
| E11 | I1-Ir₂(L302) | 30:42:20:8 |
| E12 | I1-Ir₂(L2) | 30:47:15:8 |
| E13 | I1-Ir₂(L3) | 30:47:15:8 |
| E14 | I1-Ir₂(L500) | 30:45:17:8 |
| E15 | I1-Ir₂(L501) | 30:45:17:8 |
| E16 | I1-Ir₂(L502) | 30:45:17:8 |
| E17 | I1-Ir₂(L503) | 30:45:17:8 |
| E18 | I1-Ir₂(L504) | 30:45:17:8 |
| E19 | I1-Ir₂(L505) | 30:45:17:8 |
| E20 | I1-Ir₂(L600) | 30:47:15:8 |
| E21 | I1-Ir₂(L601) | 30:47:15:8 |
| E22 | I1-Ir₂(L602) | 30:47:15:8 |
| E23 | I1-Ir₂(L603) | 30:47:15:8 |
| E24 | I1-Ir₂(L303) | 30:40:20:10 |
| E25 | I1-Ir₂(L401) | 30:38:17:15 |
| E26 | I1-Ir₂(L402) | 30:41:17:12 |

The materials for the hole blocking layer and electron transport layer are thermally evaporated in a vacuum chamber. The electron transport layer, for example, can consist of more than one material, which are mixed with each other in a certain volume proportion by co-evaporation. A specification such as ETM1:ETM2 (50%:50%) means here that the materials ETM1 and ETM2 are present in the layer in a volume fraction of 50% each. The materials used in the present case are shown in Table 5. In the OLED devices described here, ETM3 was used as the HBL material and ETM1:ETM2 (50:50) as the ETL blend.

TABLE 5
HBL and ETL materials used

| 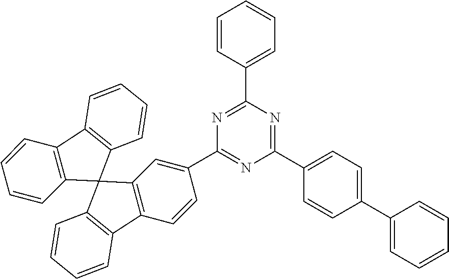 [SMILES: c1ccc(-c2ccc(-c3nc(-c4ccccc4)nc(-c4ccc5c(c4)C4(c6ccccc6-c6ccccc64)c4ccccc4-5)n3)cc2)cc1] | ETM1 |
|---|---|
| [1819335-36-8] | |
| 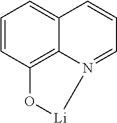 | ETM2 |
| [25387-93-3] | |
| 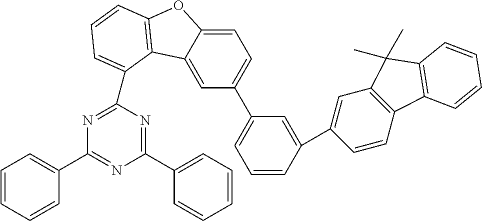 [SMILES: CC1(C)c2ccccc2-c2ccc(-c3cccc(-c4ccc5oc6cccc(-c7nc(-c8ccccc8)nc(-c8ccccc8)n7)c6c5c4)c3)cc21] | ETM3 |
| [2392900-45-5] | |

The cathode is formed by thermal evaporation of a 100 nm aluminum layer. The samples are encapsulated.

OLEDs made from the compounds of the invention as described above emit deep red light. All of the complexes according to the invention listed above can be used analogously and lead to comparable results.

1. A compound according to formula (1), 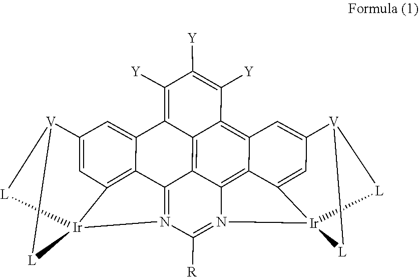
wherein the compound may be partially or fully deuterated and the following applies to the symbols used:
V is at each occurrence the same or different and is a group of formula (2), 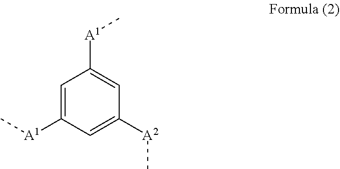
wherein the H atoms not explicitly drawn in may also be partially or completely replaced by D, the dashed bonds at A¹ each represent the bonds to the partial ligands L, and the dashed bond at A² represents the bond to the fused heteroaryl group shown in formula (1);
A¹ is at each occurrence the same or different and is —CR₂—CR₂— or a group according to one of the formulae (3), (4), (5), (6), or (7), 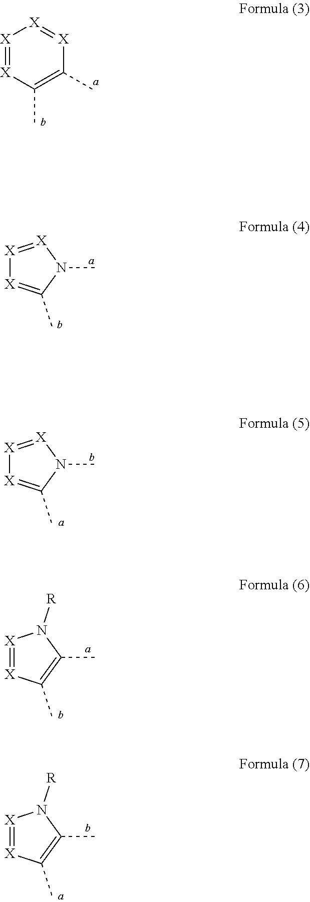
wherein in each case the dashed bond marked “a” represents the bond to the partial ligand L and the dashed bond marked “b” represents the bond to the central benzene group in formula (2);
A² is the same or different as A¹, or is a group according to one of the following formulas (8) to (12) 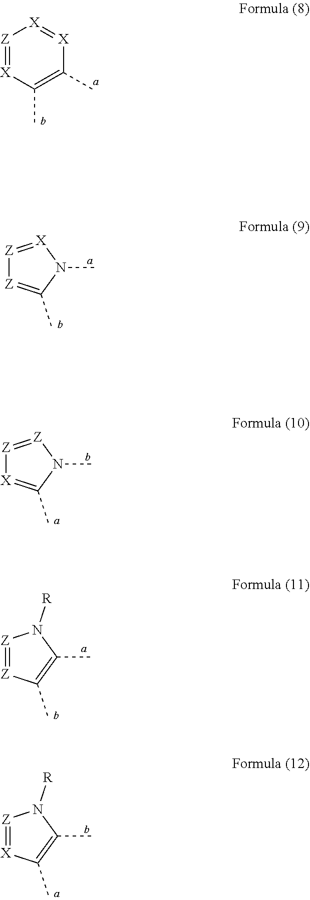
wherein in each case the dashed bond marked “a” represents the bond to the fused heteroaryl group shown in formula (1). and the dashed bond marked “b” represents the bond to the central benzene group in formula (2);
X is at each occurrence the same or different and is CR or N;
Z is at each occurrence the same or different and is CY or N;
L is at each occurrence the same or different and is a bidentate monoanionic partial ligand of the following formula (L-1) 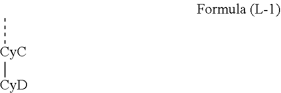
wherein the dashed bond represents the bond to A¹ and the bond between CyC and CyD represents a covalent bond;
CyC is at each occurrence the same or different and is an aryl or heteroaryl group having 5 to 14 aromatic ring atoms, which coordinates to the iridium via an anionic carbon atom, and which may be substituted by one or more radicals R;
CyD is at each occurrence the same or different and is a heteroaryl group with 5 to 14 aromatic ring atoms, which coordinates to the iridium via a neutral nitrogen atom, or via a carbene-carbon atom, and which may be substituted by one or more radicals R;
Y is at each occurrence the same or different and is R or —(Ar)ₙ—R, with the formulae (9) to (12) each containing a maximum of one group Y which is —(Ar)ₙ—R, and at the central condensed heteroaryl group in formula (1) a maximum of two groups Y are —(Ar)ₙ—R;
Ar is at each occurrence the same or different and is a bivalent group selected from the structures (Ar1) to (Ar7), 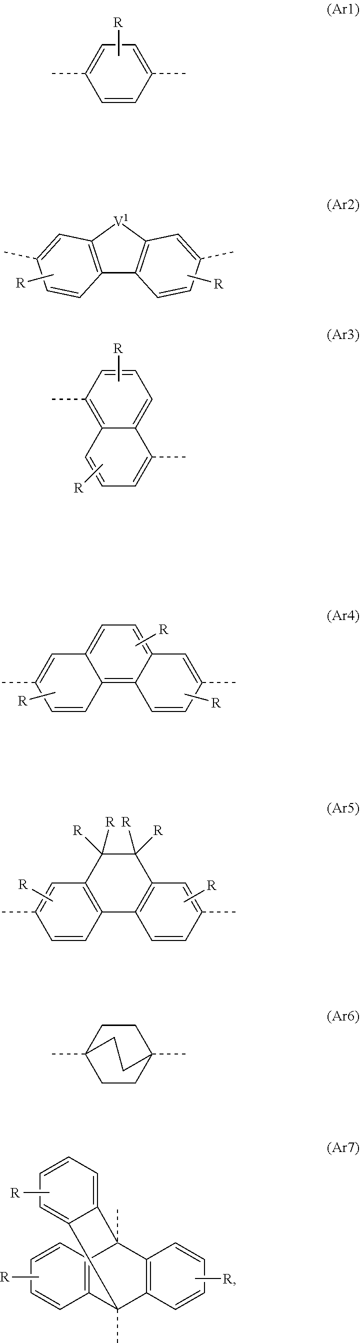
wherein the dashed bond represents the linkage of the units and V¹ is CR₂, O, S, or NR;
n is at each occurrence the same or different and is an integer from 3 to 20, with the proviso that in each unit —(Ar)ₙ—R at least 5 phenyl and/or cyclohexyl groups are linearly linked to each other;
R is at each occurrence the same or different and is H, D, F, Cl, Br, I, N(R¹)₂, CN, NO₂, OR¹, SR¹, COOH, C(═O)N(R¹)₂, Si(R¹)₃, B(OR¹)₂, C(═O)R¹, P(═O)(R¹)₂, S(═O)R¹, S(═O)₂R¹, OSO₂R¹, a straight-chain alkyl group having 1 to 20 carbon atoms, or an alkenyl or alkynyl group having 2 to 20 carbon atoms, or a branched or cyclic alkyl group having 3 to 20 carbon atoms, the alkyl, alkenyl, or alkynyl group may in each case be substituted by one or more radicals R¹, wherein one or more non-adjacent CH₂ groups may be replaced by Si(R¹)₂, C═O, NR¹, O, S, or CONR¹, or an aromatic or heteroaromatic ring system having 5 to 40 aromatic ring atoms, which in each case may be substituted by one or more radicals R¹; wherein two radicals R can also form a ring system with each other;
R¹ is at each occurrence the same or different and is H, D, F, Cl, Br, I, N(R²)₂, CN, NO₂, OR², SR², Si(R²)₃, B(OR²)₂, C(═O)R², P(═O)(R²)₂, S(═O)R², S(═O)₂R², OSO₂R², a straight-chain alkyl group having 1 to 20 carbon atoms, or an alkenyl or alkynyl group having 2 to 20 carbon atoms, or a branched or cyclic alkyl group having 3 to 20 carbon atoms, wherein the alkyl, alkenyl, or alkynyl group may in each case be substituted by one or more radicals R², wherein one or more non-adjacent CH₂ groups may be replaced by Si(R²)₂, C═O, NR², O, S, or CONR², or an aromatic or heteroaromatic ring system having 5 to 40 aromatic ring atoms, which in each case may be substituted by one or more radicals R²; wherein two or more radicals R¹ can form a ring system with each other;
R² is at each occurrence the same or different and is H, D, F, or an aliphatic, aromatic or heteroaromatic organic radical, in particular a hydrocarbon radical, having 1 to 20 carbon atoms, wherein one or more H-atoms may also-be replaced by F.

2. The compound according to claim 1, selected from the compounds of formulae (1a), (1b) or (1c), 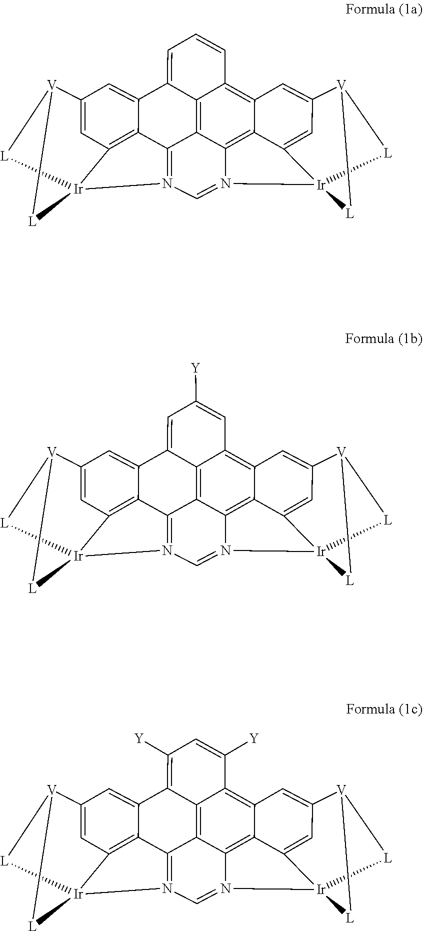
wherein the compound may also be partially or completely deuterated, Y is at each occurrence the same or different and is —(Ar)ₙ—R, and the further symbols and indices used have the meanings given in claim 1.

3. The compound according to claim 1, characterized in that the groups A¹ at each occurrence are the same or different and are —CR₂—CR₂—, or a group according to one of the formulae (3a) to (7c), 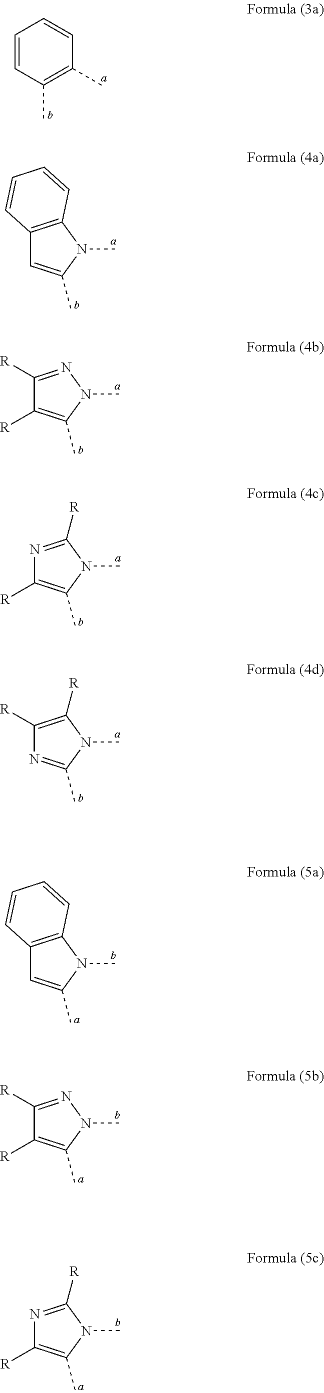 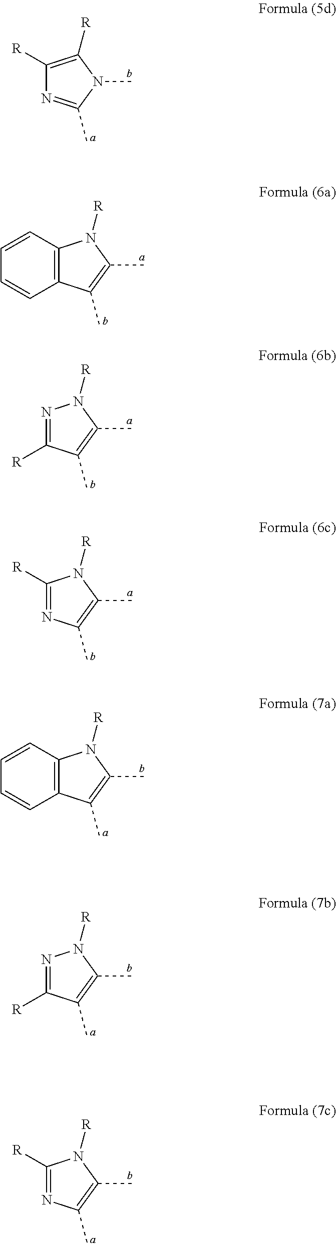
wherein in each case the dashed bond marked with “a” represents the bond to the partial ligand L, the dashed bond marked with “b” represents the bond to the central benzene group in formula (2), the H atoms not explicitly drawn in may be partially or fully replaced by D all the time, R, which may be the same or different at each occurrence, is H, D, optionally deuterated methyl or optionally deuterated phenyl, and wherein the two radicals R in the formulae (4b), (4d), (5b) and (5d) together may also form an optionally deuterated fused-on benzo group.

4. The compound according to claim 1, characterized in that the group A² is —CR₂—CR₂—, or a group according to one of the formulae (8a) to (12d), 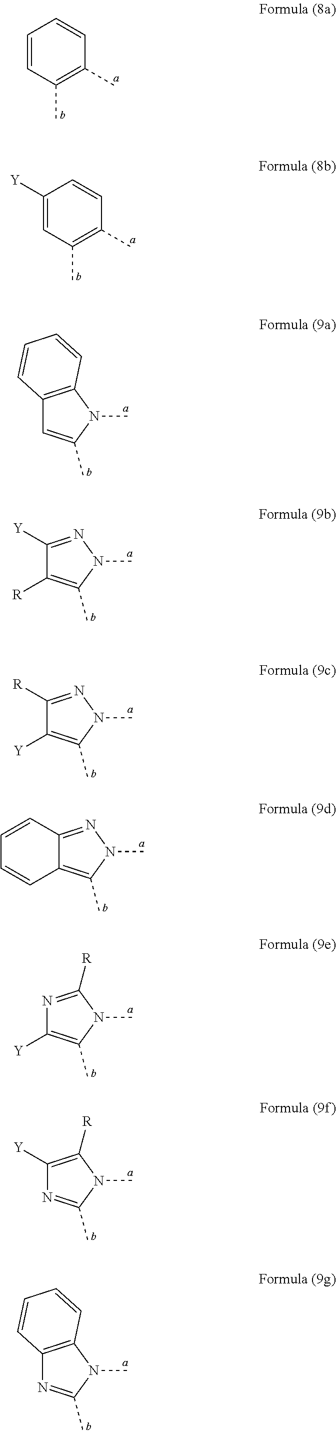 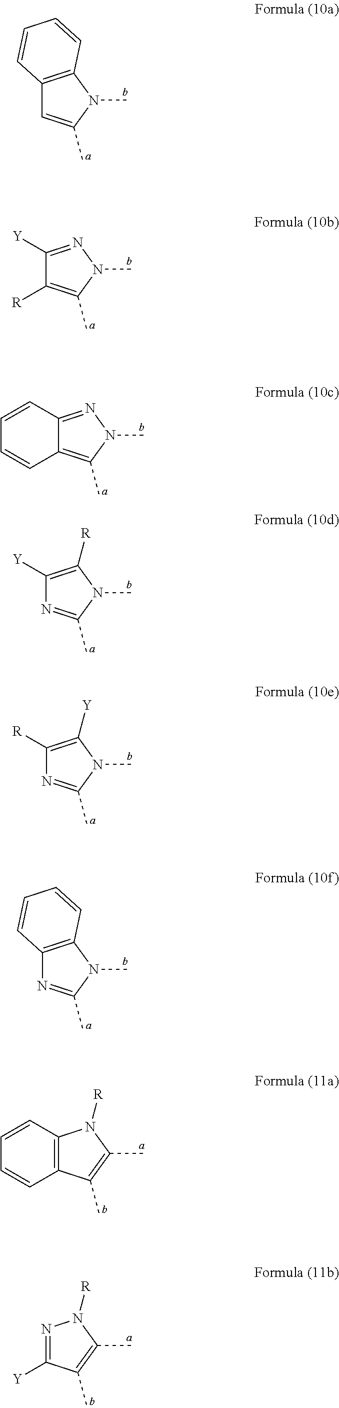 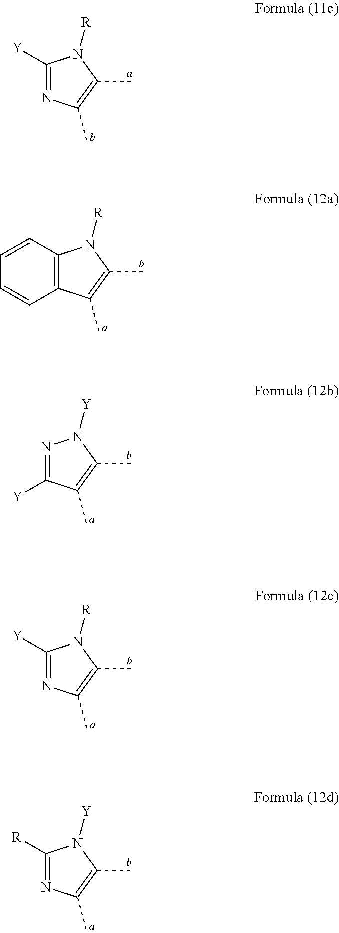
wherein in each case the dashed bond marked with “a” represents the bond to the central fused heteroaryl group, the dashed bond marked with “b” represents the bond to the central benzene group in formula (2), the H atoms not explicitly drawn in may be partially or completely replaced by D, Y represents R or —(Ar)ₙ—R, and R, which may be the same or different at each occurrence, is H, D, optionally deuterated methyl or optionally deuterated phenyl.

5. The compound according to claim 1, characterized in that, if A¹ and/or A² is —CR₂—CR₂—, R, which is the same or different at each occurrence, is H or CH₃, wherein this structure may be partially or completely deuterated, or if it is a group —CHR—CHR—, the two radicals R together with the C-atoms to which they bind form a cyclopentyl or cyclohexyl group, wherein these structures may be partially or completely deuterated.

6. The compound according to claim 1, characterized in that, when A¹ and/or A² is —CR₂—CR₂—, this group is selected from the group consisting of —CH₂—CH₂—, —CH₂—C(CH₃)₂—, —C(CH₃)₂—C(CH₃)₂—, 1,2-cyclopentyl, and 1,2-cyclohexyl, wherein these structures may be partially or completely deuterated.

7. The compound according to claim 1, characterized in that it is selected from compounds of formulae (13), (14), and (15), 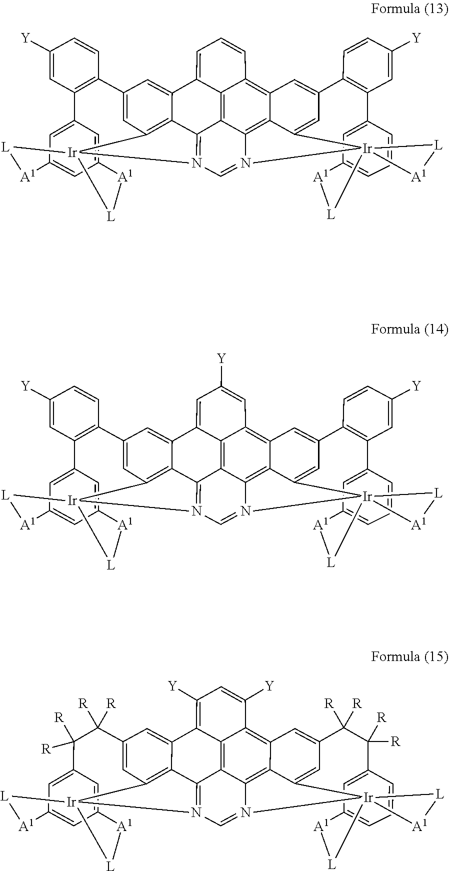
wherein Y is at each occurrence the same or different and is H, D, or a group —(Ar)ₙ—R, and the compound may also be partially or completely deuterated, and the explicitly drawn in radicals R in formula (15), which may be the same or different at each occurrence, are H, D, or optionally deuterated methyl.

8. The compound according to claim 1, characterized in that CyC is at each occurrence the same or different and is selected from the structures of the formulae (CyC-1) to (CyC-7), wherein each group binds to CyD at the position indicated by #, coordinates to the iridium at the position indicated by *, and binds to the bridge V at the position indicated by “o”, 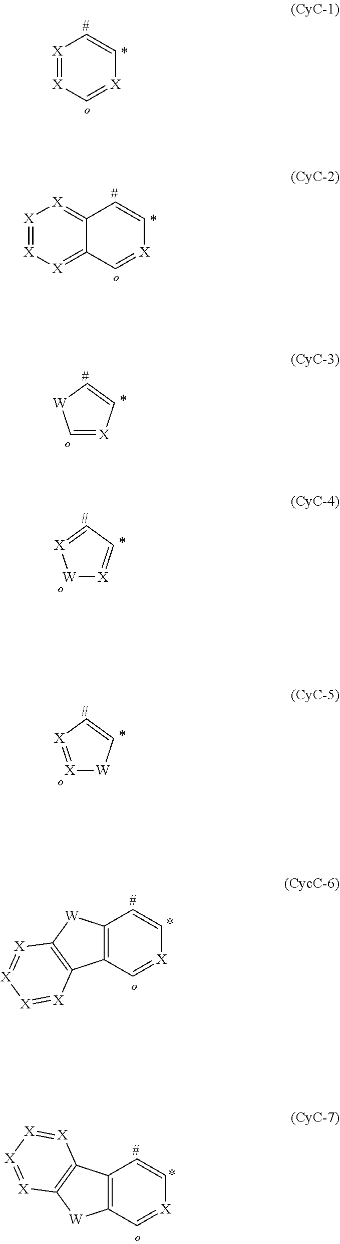
and CyD is at each occurrence the same or different and is selected from the structures of the formulae (CyD-1) to (CyD-18), wherein each group binds to CyC at the position denoted by # and coordinates to the iridium at the position denoted by *, 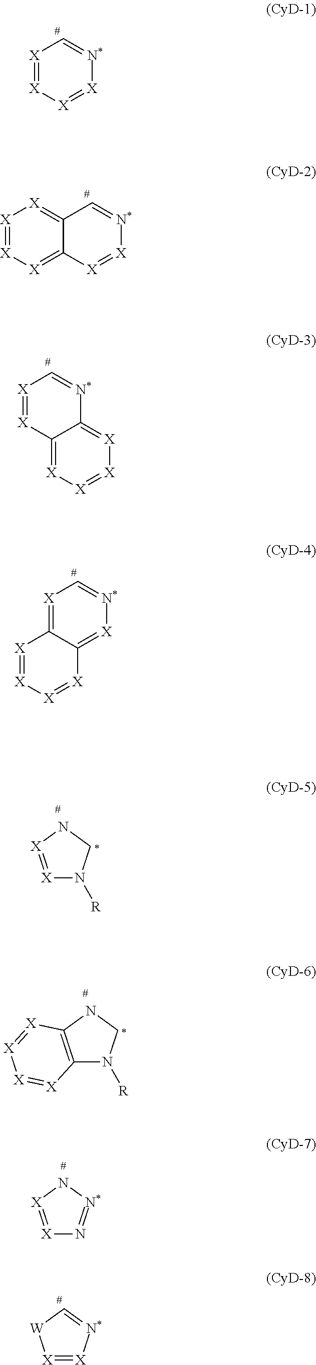 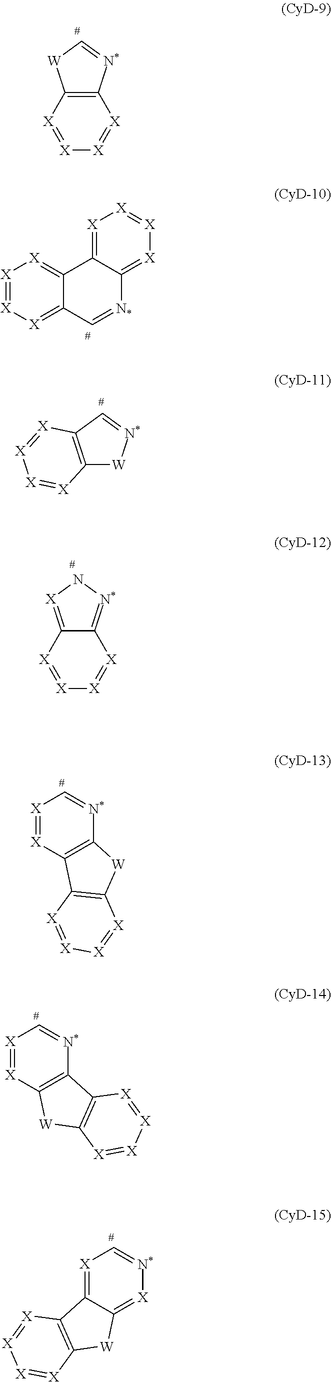 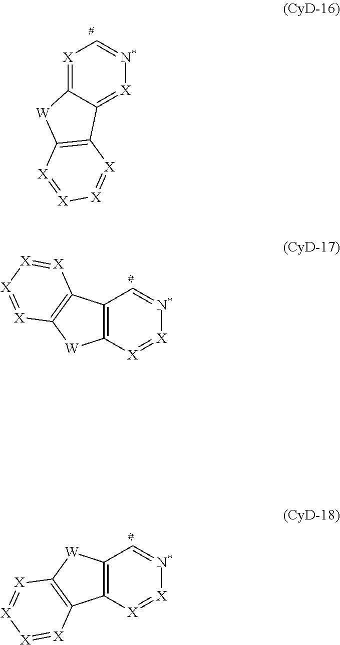
wherein R has the meanings given in claim 1 and the following applies to the further symbols used:
X is at each occurrence the same or different and is CR or N, with the proviso that at most two symbols X per cycle are N;
W is at each occurrence the same or different and is NR, O, S, or CR₂.

9. The compound according to claim 1, characterized in that L is at each occurrence the same or different and is selected from the structures of formulae (L-1-1) to (L-1-5), 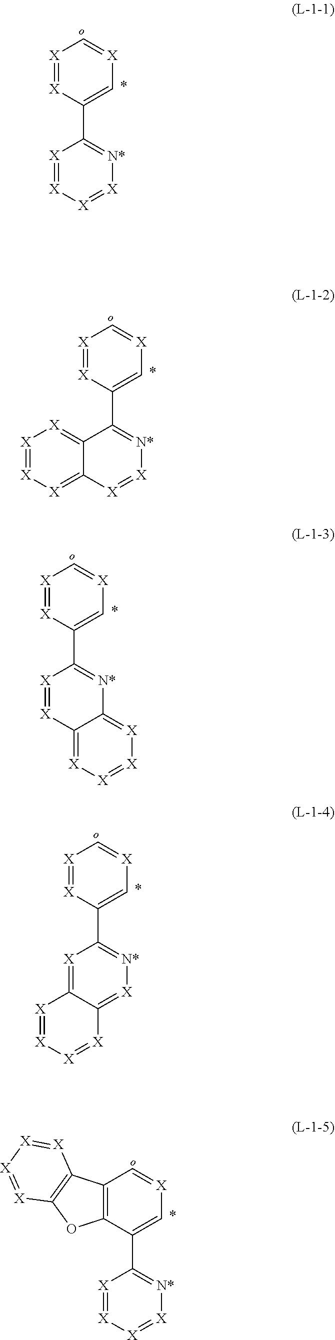
wherein the symbols used have the meanings given in claim 8, * represent the positions of coordination to the iridium and “o” represents the position of bonding to the bridge V.

10. The compound according to claim 1, characterized in that L is selected from the structures of formulae (L-1-1a) to (L-1-5b), 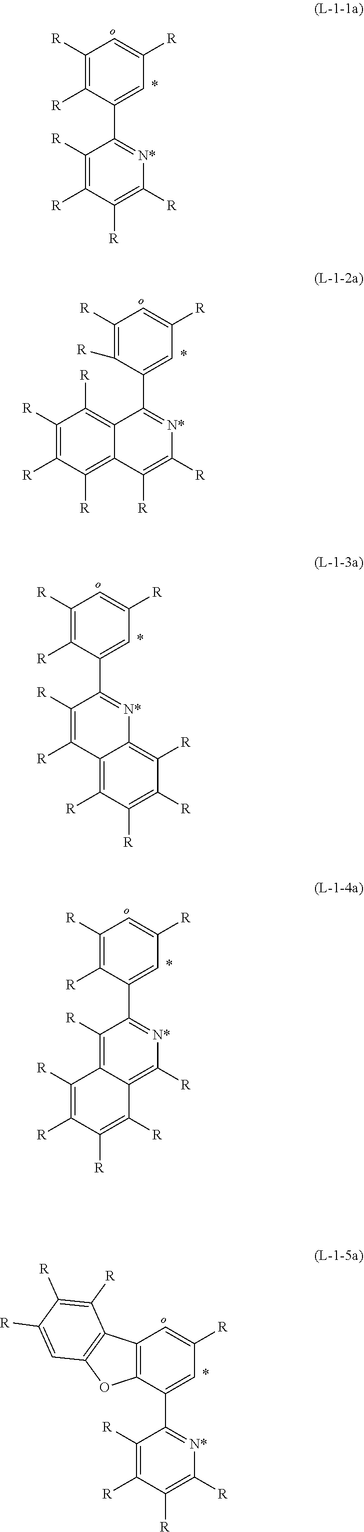 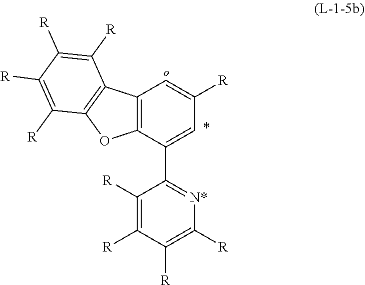
wherein R has the meanings given in claim 1, * represent the positions of coordination to the iridium, and “o” represents the position of binding to the bridge V.

11. A process for preparing a compound according to claim 1 by reacting the corresponding free ligands with iridium alcoholates of formula (Ir-1), with iridium ketoketonates of formula (Ir-2), with iridium halides of formula (Ir-3) or with iridium carboxylates of formula (Ir-4), 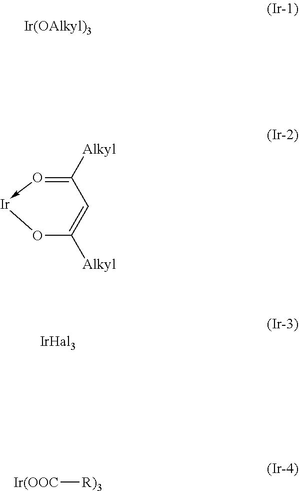
wherein R has the meanings given in claim 1, Hal=F, Cl, Br or I, alkyl is an alkyl group having 1 to 4 C-atoms and the iridium educts may also be present as hydrates, or wherein iridium compounds carrying alcoholate and/or halide and/or hydroxyl radicals as well as ketoketonate radicals are used as starting materials.

12. A formulation comprising at least one compound according claim 1 and at least one further compound and/or a solvent.

13. (canceled)

14. An electronic device comprising at least one compound according to claim 1.

15. The electronic device of claim 14, characterized in that it is an organic electroluminescent device and the compound of claim 1 is used as an emitting compound in an emitting layer.

16. The electronic device of claim 15, characterized in that the emitting layer further comprises one or more matrix materials selected from the group consisting of ketones, phosphine oxides, sulfoxides, sulfones, triarylamines, carbazole derivatives, biscarbazole derivatives, indolocarbazole derivatives, indenocarbazole derivatives, azacarbazoles, bipolar matrix materials, azaboroles, boronic esters, diazasilol derivatives, diazaphosphol derivatives, triazine derivatives, pyrimidine derivatives, quinazoline derivatives, quinoxaline derivatives, zinc complexes, dibenzofuran derivatives, aza- or diazadibenzofuran derivatives, dibenzothiophene derivatives, triphenylene derivatives, bridged carbazole derivatives and/or wide bandgap materials.
